(19) United States
(12) Patent Application Publication
(10) Pub. No.: US 2023/0389344 A1
(43) Pub. Date: Nov. 30, 2023

(54) ORGANIC ELECTROLUMINESCENT DEVICE

(71) Applicant: Merck Patent GmbH, Darmstadt (DE)

(72) Inventors: Amir Hossain PARHAM, Darmstadt (DE); Jonas Valentin KROEBER, Darmstadt (DE); Christian EICKHOFF, Darmstadt (DE); Christian EHRENREICH, Darmstadt (DE)

(21) Appl. No.: 18/027,647

(22) PCT Filed: Sep. 21, 2021
(86) PCT No.: PCT/EP2021/075870

§ 371 Date: Mar. 22, 2023

(30) Foreign Application Priority Data
Sep. 24, 2020 (EP) 20198149.5

(51) Int. Cl. H10K 50/11; H10K 85/60; H10K 50/15; H10K 50/17; H10K 50/16; C09K 11/06

(52) U.S. Cl. CPC H10K 50/11; H10K 85/6572; H10K 50/15; H10K 50/171; H10K 50/16; C09K 11/06

(57) ABSTRACT

The present invention relates to an organic electroluminescent device comprising a light-emitting layer comprising an electron-transporting host material and a hole-transporting host material, and to a formulation comprising a mixture of the host materials and to a mixture comprising the host materials. The electron-transporting host material corresponds to a compound of the formula (1) comprising diazadibenzofuran or diazadibenzothiophene units. The hole-transporting host material corresponds to a compound of the formula (2) from the class of the biscarbazoles or the derivatives thereof.

### SUBJECT-MATTER OF THE INVENTION

The present invention relates to an organic electroluminescent device comprising a light-emitting layer comprising an electron-transporting host material and a hole-transporting host material, and to a formulation comprising a mixture of the host materials and to a mixture comprising the host materials. The electron-transporting host material corresponds to a compound of the formula (1) comprising diazadibenzofuran or diazadibenzothiophene units. The hole-transporting host material corresponds to a compound of the formula (2) from the class of the biscarbazoles or the derivatives thereof.

### BACKGROUND OF THE INVENTION

The structure of organic electroluminescent devices (e.g. OLEDs—organic light-emitting diodes or OLECs—organic light-emitting electrochemical cells) in which organic semiconductors are used as functional materials has long been known. Emitting materials used here, aside from fluorescent emitters, are increasingly organometallic complexes which exhibit phosphorescence rather than fluorescence. In general terms, however, there is still a need for improvement in OLEDs, especially also in OLEDs which exhibit triplet emission (phosphorescence), for example with regard to efficiency, operating voltage and lifetime.

The properties of organic electroluminescent devices are not only determined by the emitters used. Also of particular significance here are especially the other materials used, such as host and matrix materials, hole blocker materials, electron transport materials, hole transport materials and electron or exciton blocker materials, and among these especially the host or matrix materials. Improvements to these materials can lead to distinct improvements to electroluminescent devices.

Host materials for use in organic electronic devices are well known to the person skilled in the art. The term “matrix material” is also frequently used in the prior art when what is meant is a host material for phosphorescent emitters. This use of the term is also applicable to the present invention. In the meantime, a multitude of host materials has been developed both for fluorescent and for phosphorescent electronic devices.

A further means of improving the performance data of electronic devices, especially of organic electroluminescent devices, is to use combinations of two or more materials, especially host materials or matrix materials.

U.S. Pat. No. 6,392,250 B1 discloses the use of a mixture consisting of an electron transport material, a hole transport material and a fluorescent emitter in the emission layer of an OLED. With the aid of this mixture, it was possible to improve the lifetime of the OLED compared to the prior art.

U.S. Pat. No. 6,803,720 B1 discloses the use of a mixture comprising a phosphorescent emitter and a hole transport material and an electron transport material in the emission layer of an OLED. Both the hole transport material and the electron transport material are small organic molecules.

WO15037675 discloses benzothienopyrimidine compounds and the use thereof in an organic electroluminescent device as an electron transport material.

WO2015105315 and WO2015105316 disclose heterocycles comprising two nitrogen atoms and the use thereof in organic electroluminescent devices as a host material, optionally in combination with a further host material.

US2015207082 describes aza- and diazadibenzofuran compounds and aza- and diazadibenzothiophene compounds and the use thereof in an organic electroluminescent device, in particular as an electron transport material.

US2016013421 discloses benzothienopyrimidine compounds and the use thereof in an organic electroluminescent device as a host material.

US2016072078 describes electron-transporting host materials comprising carbazole units.

US2017200903 describes diazadibenzofuran compounds and diazadibenzothiophene compounds and the use thereof in an organic electroluminescent device, in particular as an electron transport material.

KR1020160046077 and KR102016004678 describe an organic light-emitting device comprising a light-emitting layer comprising special emitters in combination with various host materials.

US2017186971 describes benzothienopyrimidine compounds and benzofuropyrimidine compounds and the use thereof in an organic electroluminescent device as a host material, wherein the benzothienopyrimidine compounds and benzofuropyrimidine compounds each bear two substituents comprising a furan, thiophene or pyrrole unit.

WO17186760 discloses diazacarbazole compounds and the use thereof in an organic electroluminescent device as a host material, electron transport material and hole blocker material.

WO18060218 discloses diazadibenzofuran compounds and diazadibenzothiophene compounds and the use thereof in an organic electroluminescent device, wherein the benzothienopyrimidine compounds and benzofuropyrimidine compounds each bear at least one substituent comprising a carbazole unit.

WO18060307 describes diazadibenzofuran compounds and diazadibenzothiophene compounds and the use thereof in an organic electroluminescent device.

WO18088665 describes compounds having a triphenylene substituent which is disubstituted with phenyl and bears a further substituent comprising an electron-transporting group and the use thereof in an organic electroluminescent device.

WO18234926, WO18234932, WO19059577, WO19058200 and WO19229584 describe diazadibenzofuran and diazadibenzothiophene derivatives which may be used as host materials in an electroluminescent device.

WO20067657 describes a composition of materials and the use thereof in optoelectronic devices.

However, there is still need for improvement in the case of use of these materials or in the case of use of mixtures of the materials, especially in relation to efficiency, operating voltage and/or lifetime of the organic electroluminescent device.

The problem addressed by the present invention is therefore that of providing a combination of host materials which are suitable for use in an organic electroluminescent device, especially in a fluorescent or phosphorescent OLED, and lead to good device properties, especially with regard to an improved lifetime, and that of providing the corresponding electroluminescent device.

### SUMMARY OF THE INVENTION

It has now been found that this problem is solved, and the disadvantages from the prior art are eliminated, by the combination of at least one compound of the formula (1) as first host material and at least one hole-transporting compound of the formula (2) as second host material in a light-emitting layer of an organic electroluminescent device. The use of such a material combination for production of the light-emitting layer in an organic electroluminescent device leads to very good properties of these devices, especially with regard to lifetime, especially with equal or improved efficiency and/or operating voltage.

The advantages are especially also manifested in the presence of a light-emitting component in the emission layer, especially in the case of combination with emitters of the formula (3) or emitters of the formulae (I) to (VI) at concentrations between 2% and 15% by weight or in combination with monoamines of formula (4) in the hole injection layer and/or hole transport layer.

The present invention therefore first provides an organic electroluminescent device comprising an anode, a cathode and at least one organic layer containing at least one light-emitting layer, wherein the at least one light-emitting layer contains at least one compound of the formula (1) as host material 1 and at least one compound of the formula (2) as host material 2

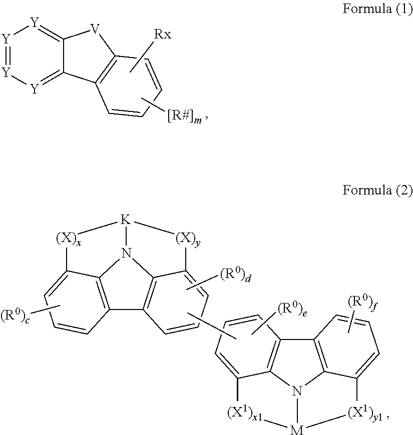

where the symbols and indices used are as follows:
Y is independently at each occurrence N, [L]ₙ-Ar₂ or [L]-R*, wherein precisely two Y are N and are separated by at least one group [L]-R* or [L]ₙ-Ar₂;
V is O or S;
Rx is [L]ₙ-Ar₂ or [L]-R*;
R* is a triphenylenyl group which may be substituted with precisely one substituent R^{#}and/or may be substituted with one or more radicals R;
with the proviso that the substituent [L]-R* occurs precisely once in compounds of the formula (1);
n is 0 or 1;
m is 0 or 1;
L is independently at each occurrence identical or different and represents an arylene group having 6 to 20 carbon atoms, a divalent dibenzofuran group or a divalent dibenzothiophene group, each of which may be substituted with one or more radicals R;
Ar₂ is identical or different at each occurrence and represents an aromatic ring system which has 6 to 30 ring atoms and may be substituted by one or more radicals R;
R is identical or different at each occurrence and selected from D, F, CN, a straight-chain alkyl group having 1 to 20 carbon atoms or a branched or cyclic alkyl group having 3 to 20 carbon atoms, wherein one or more nonadjacent CH₂ groups may be replaced by R²C═CR², O or S and wherein one or more hydrogen atoms may be replaced by D, F, or CN;
R #is an aryl group having 6 to 20 carbon atoms which may be substituted with one or more radicals R;
R² is identical or different at each occurrence and selected from the group consisting of H, D, F, CN, a straight-chain alkyl group having 1 to 20 carbon atoms or a branched or cyclic alkyl group having 3 to 20 carbon atoms, wherein one or more nonadjacent CH₂ groups may be replaced by O or S and wherein one or more hydrogen atoms may be replaced by D, F, or CN;
K, M are each independently an unsubstituted or partially or completely deuterated or R*-monosubstituted aromatic ring system having 6 to 40 ring atoms when x and y are 0 and when x₁ and y₁ are 0, or
K, M each independently together with X or X¹ form a heteroaromatic ring system having 14 to 40 ring atoms, as soon as the value of x, x1, y and/or y1 is 1;
x, x1 are each independently at each occurrence 0 or 1;
y, y1 are each independently at each occurrence 0 or 1;
X and X¹ are each independently at each occurrence a bond or C(R⁺)₂;
R⁰ is independently at each occurrence an unsubstituted or partially or completely deuterated aromatic ring system having 6 to 18 ring atoms;
R⁺ is independently at each occurrence a straight-chain or branched alkyl group having 1 to 4 carbon atoms and
c, d, e and f are independently 0 or 1.

The invention further provides a process for producing the organic electroluminescent devices and mixtures comprising at least one compound of the formula (1) and at least one compound of the formula (2), specific material combinations and formulations that contain such mixtures or material combinations. The corresponding preferred embodiments as described hereinafter likewise form part of the subject-matter of the present invention. The surprising and advantageous effects are achieved through specific selection of the compounds of the formula (1) and the compounds of the formula (2). The surprising and advantageous effects are achieved through specific selection of the compounds of the formula (1) and the compounds of the formula (2) together with special emitters in the light-emitting layer and with special monoamines in the hole injection and/or hole transport layer.

### DETAILED DESCRIPTION OF THE INVENTION

The organic electroluminescent device of the invention is, for example, an organic light-emitting transistor (OLET), an organic field quench device (OFQD), an organic light-emitting electrochemical cell (OLEC, LEC, LEEC), an organic laser diode (0-laser) or an organic light-emitting diode (OLED). The organic electroluminescent device of the invention is especially an organic light-emitting diode or an organic light-emitting electrochemical cell. The device of the invention is more preferably an OLED.

The organic layer of the device of the invention that comprises the light-emitting layer comprising the material combination of at least one compound of the formula (1) and at least one compound of the formula (2), as described above or described hereinafter, preferably comprises, in addition to this light-emitting layer (EML), a hole injection layer (HIL), a hole transport layer (HTL), an electron transport layer (ETL), an electron injection layer (EIL) and/or a hole blocker layer (HBL). It is also possible for the device of the invention to include multiple layers from this group selected from EML, HIL, HTL, ETL, EIL and HBL.

However, the device may also comprise inorganic materials or else layers formed entirely from inorganic materials.

It is preferable when the organic layer of the device according to the invention comprises a hole injection layer and/or the hole transport layer whose hole-injecting material and hole-transporting material is a monoamine that does not contain a carbazole unit. A suitable selection of monoamine compounds and preferred monoamines is described hereinbelow.

It is preferable when the light-emitting layer comprising at least one compound of the formula (1) and at least one compound of the formula (2) is a phosphorescent layer which is characterized in that it comprises, in addition to the host material combination of compounds of the formula (1) and formula (2), as described above, at least one phosphorescent emitter. A suitable selection of emitters and preferred emitters is described hereinafter.

An aryl group in the context of this invention contains 6 to 40 aromatic ring atoms, preferably carbon atoms. A heteroaryl group in the context of this invention contains 5 to 40 aromatic ring atoms, where the ring atoms include carbon atoms and at least one heteroatom, with the proviso that the sum total of carbon atoms and heteroatoms adds up to at least 5. The heteroatoms are preferably selected from N, O and/or S. An aryl group or heteroaryl group is understood here to mean either a simple aromatic cycle, i.e. phenyl, derived from benzene, or a simple heteroaromatic cycle, for example derived from pyridine, pyrimidine or thiophene, or a fused aryl or heteroaryl group, for example derived from naphthalene, anthracene, phenanthrene, quinoline or isoquinoline. An aryl group having 6 to 18 carbon atoms is therefore preferably phenyl, naphthyl or phenanthryl, with no restriction in the attachment of the aryl group as substituent. The aryl or heteroaryl group in the context of this invention may bear one or more radicals R, where the substituent R is described below.

An aromatic ring system in the context of this invention contains 6 to 40 ring atoms. The aromatic ring system also includes aryl groups as described above.

An aromatic ring system having 6 to 18 carbon atoms as ring atoms is preferably selected from phenyl, biphenyl, naphthyl and phenanthryl.

A heteroaromatic ring system in the context of this invention contains 5 to 40 ring atoms and at least one heteroatom. A preferred heteroaromatic ring system has 10 to 40 ring atoms and at least one heteroatom. The heteroaromatic ring system also includes heteroaryl groups as described above. The heteroatoms in the heteroaromatic ring system are preferably selected from N, O and/or S.

An aromatic or heteroaromatic ring system in the context of this invention is understood to mean a system which does not necessarily contain only aryl or heteroaryl groups, but in which it is also possible for a plurality of aryl or heteroaryl groups to be interrupted by a nonaromatic unit (preferably less than 10% of the atoms other than H), for example a carbon, nitrogen or oxygen atom or a carbonyl group. For example, systems such as 9,9′-spirobifluorene, 9,9-diarylfluorene, triarylamine, diaryl ethers, stilbene, etc. shall thus also be regarded as aromatic or heteroaromatic ring systems in the context of this invention, and likewise systems in which two or more aryl groups are interrupted, for example, by a linear or cyclic alkyl group or by a silyl group. In addition, systems in which two or more aryl or heteroaryl groups are bonded directly to one another, for example biphenyl, terphenyl, quaterphenyl or bipyridine, are likewise encompassed by the definition of the aromatic or heteroaromatic ring system.

The abbreviation Ar₂ is independently at each occurrence identical or different and represents an aromatic ring system having 6 to 30 carbon atoms which may be substituted with one or more radicals R, wherein the radical R is defined as described above or hereinafter.

A cyclic alkyl group in the context of this invention is understood to mean a monocyclic, bicyclic or polycyclic group.

In the context of the present invention, a straight-chain, branched or cyclic C₁- to C₂₀-alkyl group is understood to mean, for example, the methyl, ethyl, n-propyl, i-propyl, cyclopropyl, n-butyl, i-butyl, s-butyl, t-butyl, cyclobutyl, 2-methylbutyl, n-pentyl, s-pentyl, t-pentyl, 2-pentyl, neopentyl, cyclopentyl, n-hexyl, s-hexyl, t-hexyl, 2-hexyl, 3-hexyl, neohexyl, cyclohexyl, 1-methylcyclopentyl, 2-methylpentyl, n-heptyl, 2-heptyl, 3-heptyl, 4-heptyl, cycloheptyl, 1-methylcyclohexyl, n-octyl, 2-ethylhexyl, cyclooctyl, 1-bicyclo[2.2.2]octyl, 2-bicyclo[2.2.2]octyl, 2-(2,6-dimethyl)octyl, 3-(3,7-dimethyl)octyl, adamantyl, trifluoromethyl, pentafluoroethyl, 2,2,2-trifluoroethyl, 1,1-dimethyl-n-hex-1-yl, 1,1-dimethyl-n-hept-1-yl, 1,1-dimethyl-n-oct-1-yl, 1,1-dimethyl-n-dec-1-yl, 1,1-dimethyl-n-dodec-1-yl, 1,1-dimethyl-n-tetradec-1-yl, 1,1-dimethyl-n-hexadec-1-yl, 1,1-dimethyl-n-octadec-1-yl, 1,1-diethyl-n-hex-1-yl, 1,1-diethyl-n-hept-1-yl, 1,1-diethyl-n-oct-1-yl, 1,1-diethyl-n-dec-1-yl, 1,1-diethyl-n-dodec-1-yl, 1,1-diethyl-n-tetradec-1-yl, 1,1-diethyl-n-hexadec-1-yl, 1,1-diethyl-n-octadec-1-yl, 1-(n-propyl)cyclohex-1-yl, 1-(n-butyl)cyclohex-1-yl, 1-(n-hexyl)cyclohex-1-yl, 1-(n-octyl)cyclohex-1-yl and 1-(n-decyl)cyclohex-1-yl radicals.

When the host materials of the light-emitting layer comprising at least one compound of the formula (1) as described above or described as preferred hereinafter and at least one compound of the formula (2) as described above or described hereinafter are used for a phosphorescent emitter, it is preferable when the triplet energy thereof is not significantly less than the triplet energy of the phosphorescent emitter. In respect of the triplet level, it is preferably the case that T₁(emitter)−T₁(matrix)≤0.2 eV, more preferably ≤0.15 eV, most preferably ≤0.1 eV. T₁(matrix) here is the triplet level of the matrix material in the emission layer, this condition being applicable to each of the two matrix materials, and T₁(emitter) is the triplet level of the phosphorescent emitter. If the emission layer contains more than two matrix materials, the abovementioned relationship is preferably also applicable to every further matrix material.

There follows a description of the host material 1 and its preferred embodiments that is/are present in the device of the invention. The preferred embodiments of the host material 1 of the formula (1) are also applicable to the mixture and/or formulation of the invention.

In compounds of the formula (1) Y is independently at each occurrence N, [L]ₙ-Ar₂ or [L]-R*, wherein precisely two Y are N and are separated by at least one group [L]-R* or [L]ₙ-Ar₂, with the proviso that the substituent [L]-R* occurs precisely once in compounds of the formula (1).

Preferred embodiments of the compounds of the formula (1) are compounds of the formulae (1a), (1b) or (1c) in which the position of the two nitrogen atoms is more particularly described, the remaining Y independently represent [L]-R* or [L]ₙ-Ar₂, V represents O or S and Rx represents [L]ₙ-Ar₂ or [L]-R*,

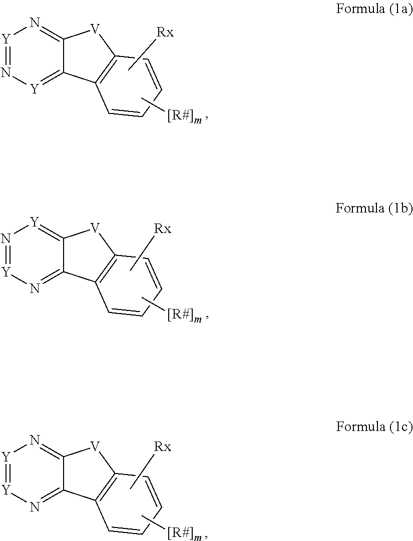

with the proviso that the substituent [L]-R* occurs precisely once in compounds of the formulae (1a), (1b) and (1c) and wherein m and R #are preferably defined as described above or hereinafter.

The invention further provides the organic electroluminescent device as described above, wherein the host material 1 conforms to one of the formulae (1a), (1b) or (1c) as described above.

Preferred compounds of the formula (1) correspond to the formulae (1a) and (1b).

Preferred compounds of the formula (1) correspond to the formulae (1aa), (1ab) and (1ac),

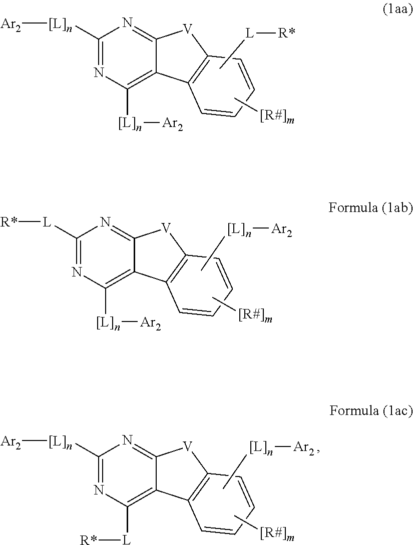

where Ar₂, L, n, V, m, R #and R* have a definition given above or a definition given hereinafter as preferred.

Preferred compounds of the formula (1b) correspond to the formulae (1ba), (1bb) and (1bc),

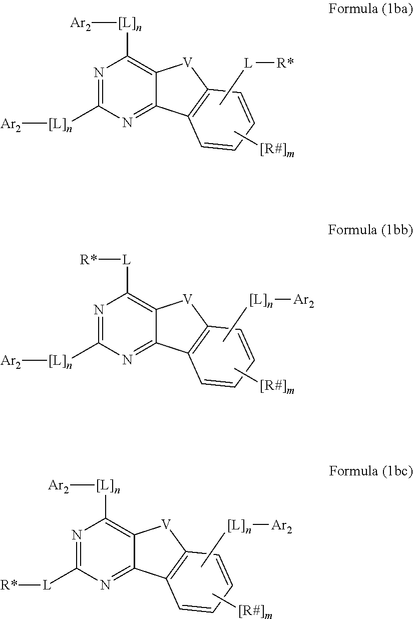

where Ar₂, L, n, V, m, R #and R* have a definition given above or a definition given hereinafter as preferred.

Preferred compounds of the formula (1c) correspond to the formulae (1ca), (1cb) and (1cc),

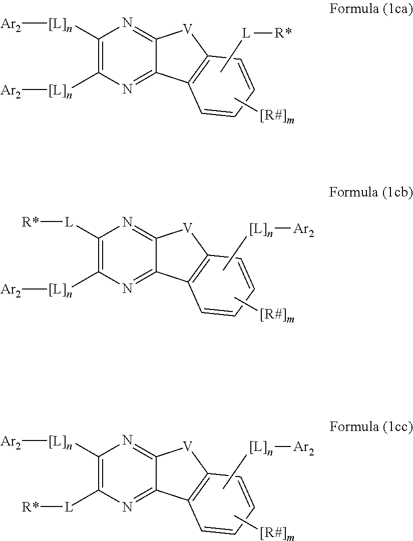

where Ar₂, L, n, V, m, R #and R* have a definition given above or a definition given hereinafter as preferred.

Particularly preferred compounds of the formula (1) correspond to the formulae (1aa) and (1ba).

In compounds of the formulae (1), (1a), (1b), (1c), (1aa), (1ab), (1ac), (1ba), (1bb), (1bc), (1ca), (1cb) and (1cc) V preferably represents O.

Accordingly, the invention further provides the organic electroluminescent device as described above, wherein in the host material 1 of the formulae (1), (1a), (1b), (1c), (1aa), (1ab), (1ac), (1ba), (1bb), (1bc), (1ca), (1cb) or (1cc) V represents O.

In compounds of the formulae (1), (1a), (1b), (1c), (1aa), (1ab), (1ac), (1ba), (1bb), (1bc), (1ca), (1cb) and (1cc) L is independently at each occurrence preferably selected from the groups L-1 to L-23,

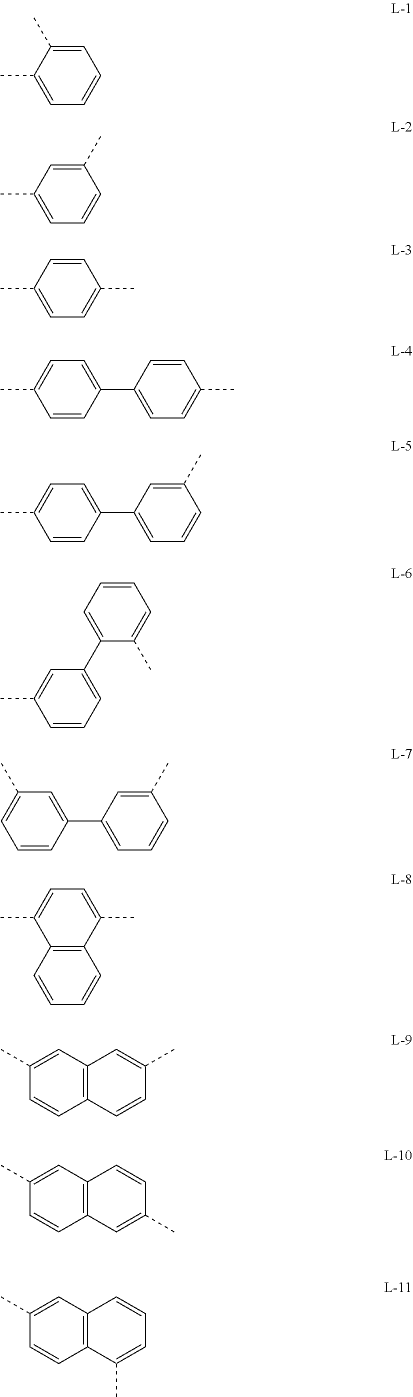

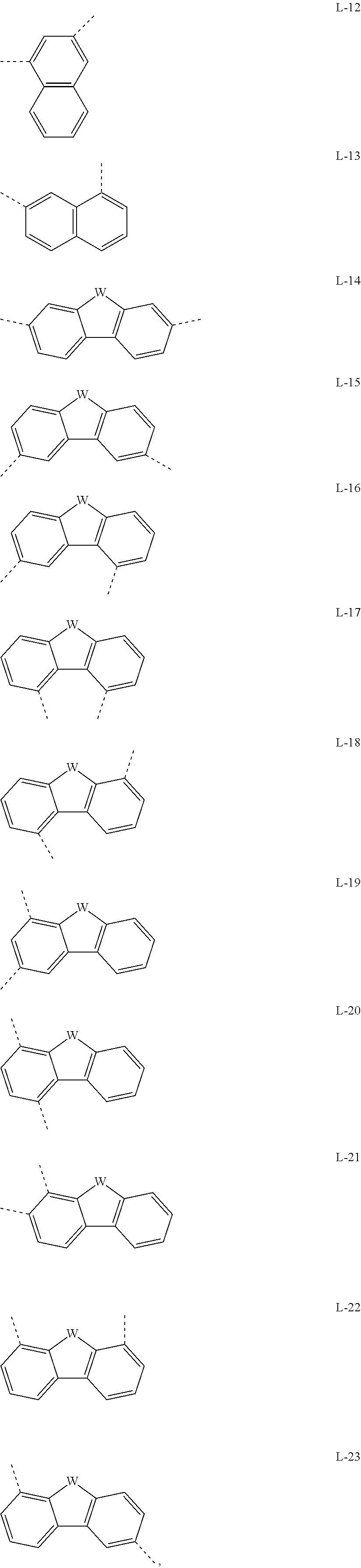

where W represents O or S. In the linkers L-14 to L-23 W is preferably O.

The invention accordingly further provides the organic electroluminescent device as described above, wherein in the host material 1 of the formulae (1), (1a), (1b), (1c), (1aa), (1ab), (1ac), (1ba), (1bb), (1bc), (1ca), (1cb) or (1cc) L is independently at each occurrence selected from the linkers L-1 to L-23.

In compounds of the formulae (1), (1a), (1b), (1c), (1aa), (1ab), (1ac), (1ba), (1bb), (1bc), (1ca), (1cb) and (1cc) L is independently at each occurrence particularly preferably selected from the groups L-2, L-3, L-7, L-8, L-15, L-16, L-20 and L-22 as described or described as preferable above.

In compounds of the formulae (1), (1a), (1b), (1c), (1aa), (1ab), (1ac), (1ba), (1bb), (1bc), (1ca), (1cb) and (1cc) L is independently at each occurrence particularly preferably selected from the groups L-2, L-3, L-8, L-16, and L-22 as described or described as preferable above.

In compounds of the formulae (1), (1a), (1b), (1c), (1aa), (1ab), (1ac), (1ba), (1bb), (1bc), (1ca), (1cb) and (1cc) L is independently at each occurrence particularly preferably selected from the groups L-2, L-3, L-4 and L-5 as described or described as preferable above.

In compounds of the formulae (1), (1a), (1b), (1c), (1aa), (1ab), (1ac), (1ba), (1bb), (1bc), (1ca), (1cb) and (1cc) or compounds of the formulae (1), (1a), (1b), (1c), (1aa), (1ab), (1ac), (1ba), (1bb), (1bc), (1ca), (1cb) and (1cc) described as preferable n is preferably 0.

In compounds of the formulae (1), (1a), (1b), (1c), (1aa), (1ab), (1ac), (1ba), (1bb), (1bc), (1ca), (1cb) and (1cc) or compounds of the formulae (1), (1a), (1b), (1c), (1aa), (1ab), (1ac), (1ba), (1bb), (1bc), (1ca), (1cb) and (1cc) described as preferable n is preferably 1.

In compounds of the formulae (1), (1a), (1b), (1c), (1aa), (1ab), (1ac), (1ba), (1bb), (1bc), (1ca), (1cb) and (1cc) or compounds of the formulae (1), (1a), (1b), (1c), (1aa), (1ab), (1ac), (1ba), (1bb), (1bc), (1 ca), (1 cb) and (1 cc) described as preferred the substituent Rx selected from [L]ₙ-Ar₂ or [L]-R* may be in position 1, 2, 3 and 4 of the diazadibenzofuran or diazadibenzothiophene.

In compounds of the formulae Formeln (1), (1a), (1b), (1c), (1aa), (1ab), (1ac), (1ba), (1bb), (1bc), (1ca), (1cb) and (1cc) or compounds of the formulae ((1), (1a), (1b), (1c), (1aa), (1ab), (1ac), (1ba), (1bb), (1bc), (1ca), (1cb) and (1cc) described as preferred the substituent Rx selected from [L]ₙ-Ar₂ or [L]-R* is preferably in position 2, 3 and 4, particularly preferably in position 2 and 3, very particularly preferably in position 3, of the diazadibenzofuran or diazadibenzothiophene. The positions are accordingly indicated in the following scheme:

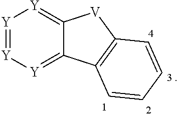

In compounds of the formulae (1), (1a), (1b), (1c), (1aa), (1ab), (1ac), (1ba), (1bb), (1bc), (1ca), (1cb) and (1cc) or compounds of the formulae (1), (1a), (1b), (1c), (1aa), (1ab), (1ac), (1ba), (1bb), (1bc), (1ca), (1cb) and (1cc) described as preferable Ar₂ is identical or different at each occurrence and represents an aromatic ring system having 6 to 30 ring atoms which may be substituted with one or more radicals R.

In compounds of the formulae (1), (1a), (1b), (1c), (1aa), (1ab), (1ac), (1ba), (1bb), (1bc), (1ca), (1cb) and (1cc) or compounds of the formulae (1), (1a), (1b), (1c), (1aa), (1ab), (1ac), (1ba), (1bb), (1bc), (1ca), (1cb) and (1cc) described as preferable R* is a triphenylenyl group which may be substituted with precisely one substituent R #and/or may be substituted with one or more radicals R, wherein R* preferably represents a triphenylenyl group which is substituted with precisely one substituent R #or is unsubstituted. The triphenylenyl group R* is particularly preferably not substituted. The bonding of the triphenylene is preferably effected via position 2 thereof as shown below by the dashed line.

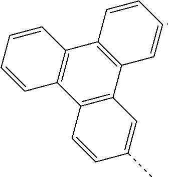

The substituent R in compounds of the formulae (1), (1a), (1b), (1c), (1aa), (1ab), (1ac), (1ba), (1bb), (1bc), (1ca), (1cb) and (1cc) or compounds of the formulae (1), (1a), (1b), (1c), (1aa), (1ab), (1ac), (1ba), (1bb), (1bc), (1ca), (1cb) and (1cc) described as preferable is independently at each occurrence selected from D, F, CN, a straight-chain alkyl group having 1 to 20 carbon atoms or a branched or cyclic alkyl group having 3 to 20 carbon atoms, wherein one or more nonadjacent CH₂ groups may be replaced by R²C═CR², O or S and wherein one or more hydrogen atoms may be replaced by D, F, or CN. The substituent R is independently at each occurrence preferably selected from D, F, CN, a straight-chain alkyl group having 1 to 10 carbon atoms or a branched or cyclic alkyl group having 3 to 10 carbon atoms, wherein one or more hydrogen atoms of the alkyl group may be replaced by D, F, or CN.

The substituent R² is identical or different at each occurrence and is preferably H or D.

The substituent R #is an aryl group having 6 to 20 carbon atoms which may be substituted with one or more radicals R, wherein R is defined as described or described as preferable above. The substituent R #is preferably phenyl which may be substituted with one or more radicals R, wherein R is defined as described or described as preferable above. R #is preferably unsubstituted phenyl.

In compounds of the formulae (1), (1a), (1b), (1c), (1aa), (1ab), (1ac), (1ba), (1bb), (1bc), (1ca), (1cb) and (1cc) m is 0 or 1. The substituent R #is defined as described or described as preferable above. In compounds of the formulae (1), (1a), (1b), (1c), (1aa), (1ab), (1ac), (1ba), (1bb), (1bc), (1ca), (1cb) and (1cc) m is preferably 0.

Examples of suitable host materials of the formula (1) that are selected in accordance with the invention and are preferably used in combination with at least one compound of the formula (2) in the electroluminescent device of the invention are the structures given below in table 1.

TABLE 1

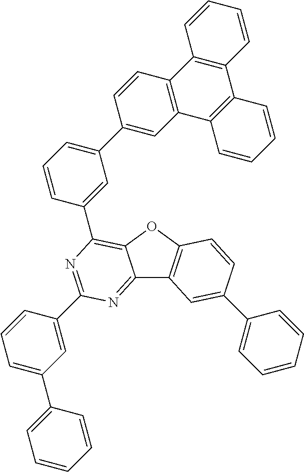 [SMILES: c1ccc(-c2cccc(-c3nc(-c4cccc(-c5ccc6c7ccccc7c7ccccc7c6c5)c4)c4oc5ccc(-c6ccccc6)cc5c4n3)c2)cc1]

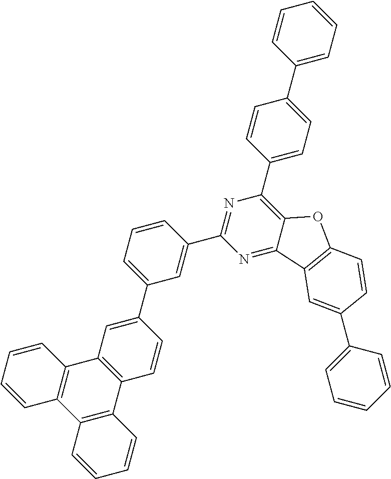 [SMILES: c1ccc(-c2ccc(-c3nc(-c4cccc(-c5ccc6c7ccccc7c7ccccc7c6c5)c4)nc4c3oc3ccc(-c5ccccc5)cc34)cc2)cc1]

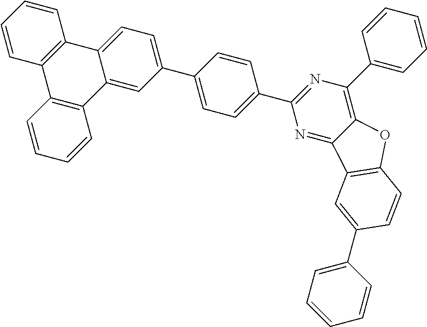 [SMILES: c1ccc(-c2ccc3oc4c(-c5ccccc5)nc(-c5ccc(-c6ccc7c8ccccc8c8ccccc8c7c6)cc5)nc4c3c2)cc1]

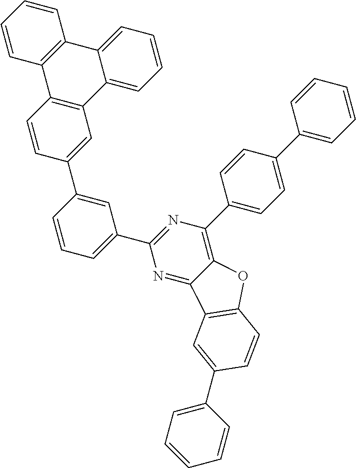 [SMILES: c1ccc(-c2ccc(-c3nc(-c4cccc(-c5ccc6c7ccccc7c7ccccc7c6c5)c4)nc4c3oc3ccc(-c5ccccc5)cc34)cc2)cc1]

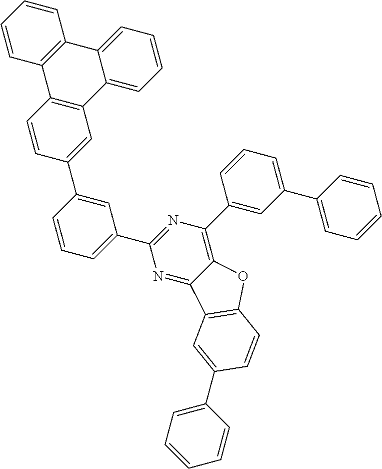 [SMILES: c1ccc(-c2cccc(-c3nc(-c4cccc(-c5ccc6c7ccccc7c7ccccc7c6c5)c4)nc4c3oc3ccc(-c5ccccc5)cc34)c2)cc1]

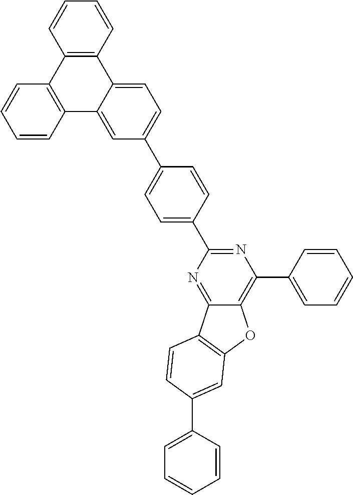 [SMILES: c1ccc(-c2ccc3c(c2)oc2c(-c4ccccc4)nc(-c4ccc(-c5ccc6c7ccccc7c7ccccc7c6c5)cc4)nc23)cc1]

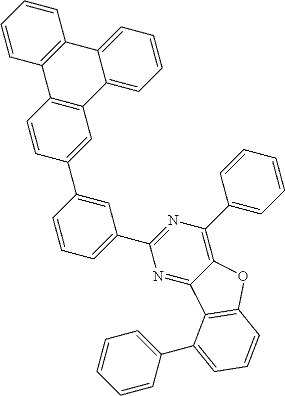 [SMILES: c1ccc(-c2nc(-c3cccc(-c4ccc5c6ccccc6c6ccccc6c5c4)c3)nc3c2oc2cccc(-c4ccccc4)c23)cc1]

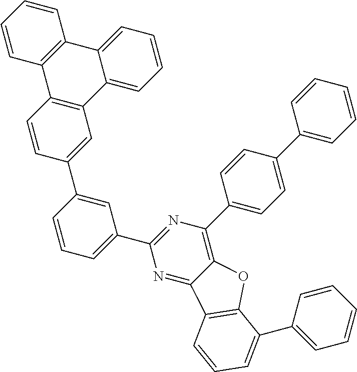 [SMILES: c1ccc(-c2ccc(-c3nc(-c4cccc(-c5ccc6c7ccccc7c7ccccc7c6c5)c4)nc4c3oc3c(-c5ccccc5)cccc34)cc2)cc1]

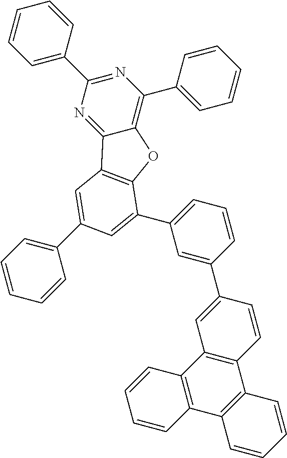 [SMILES: c1ccc(-c2cc(-c3cccc(-c4ccc5c6ccccc6c6ccccc6c5c4)c3)c3oc4c(-c5ccccc5)nc(-c5ccccc5)nc4c3c2)cc1]

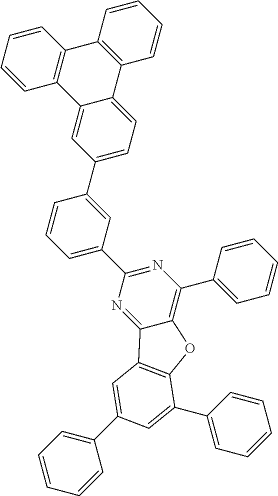 [SMILES: c1ccc(-c2cc(-c3ccccc3)c3oc4c(-c5ccccc5)nc(-c5cccc(-c6ccc7c8ccccc8c8ccccc8c7c6)c5)nc4c3c2)cc1]

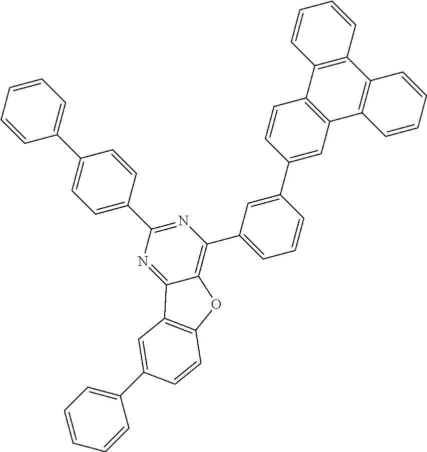 [SMILES: c1ccc(-c2ccc(-c3nc(-c4cccc(-c5ccc6c7ccccc7c7ccccc7c6c5)c4)c4oc5ccc(-c6ccccc6)cc5c4n3)cc2)cc1]

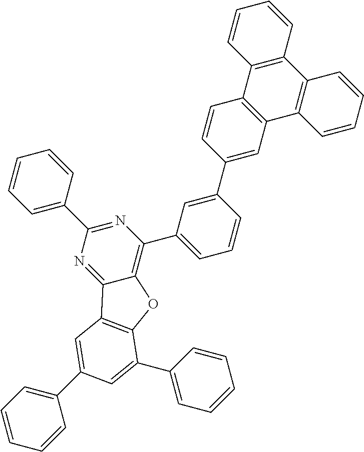 [SMILES: c1ccc(-c2cc(-c3ccccc3)c3oc4c(-c5cccc(-c6ccc7c8ccccc8c8ccccc8c7c6)c5)nc(-c5ccccc5)nc4c3c2)cc1]

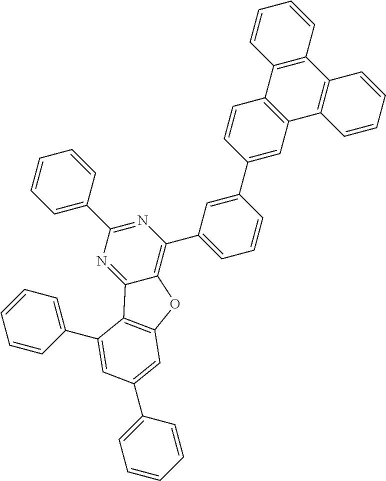 [SMILES: c1ccc(-c2cc(-c3ccccc3)c3c(c2)oc2c(-c4cccc(-c5ccc6c7ccccc7c7ccccc7c6c5)c4)nc(-c4ccccc4)nc23)cc1]

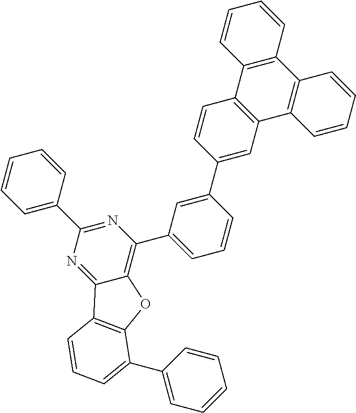 [SMILES: c1ccc(-c2nc(-c3cccc(-c4ccc5c6ccccc6c6ccccc6c5c4)c3)c3oc4c(-c5ccccc5)cccc4c3n2)cc1]

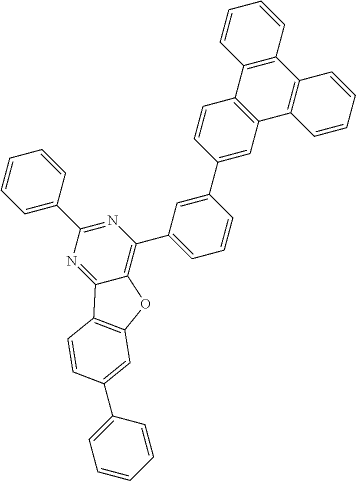 [SMILES: c1ccc(-c2ccc3c(c2)oc2c(-c4cccc(-c5ccc6c7ccccc7c7ccccc7c6c5)c4)nc(-c4ccccc4)nc23)cc1]

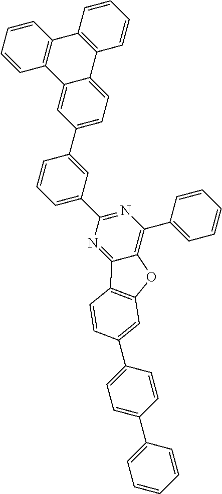 [SMILES: c1ccc(-c2ccc(-c3ccc4c(c3)oc3c(-c5ccccc5)nc(-c5cccc(-c6ccc7c8ccccc8c8ccccc8c7c6)c5)nc34)cc2)cc1]

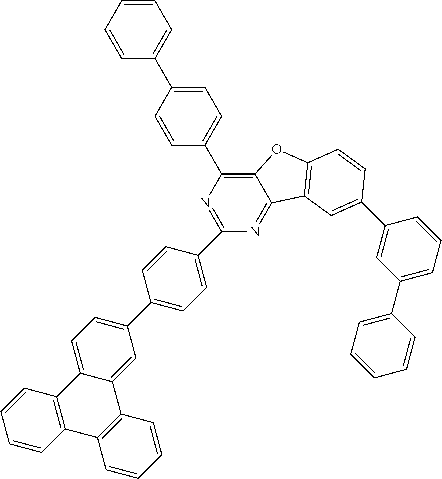 [SMILES: c1ccc(-c2ccc(-c3nc(-c4ccc(-c5ccc6c7ccccc7c7ccccc7c6c5)cc4)nc4c3oc3ccc(-c5cccc(-c6ccccc6)c5)cc34)cc2)cc1]

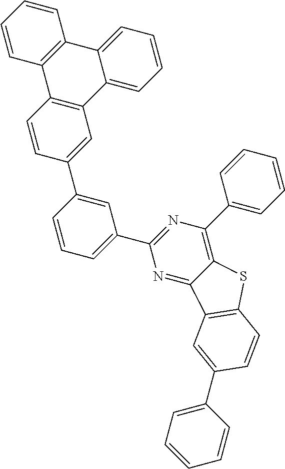 [SMILES: c1ccc(-c2ccc3sc4c(-c5ccccc5)nc(-c5cccc(-c6ccc7c8ccccc8c8ccccc8c7c6)c5)nc4c3c2)cc1]

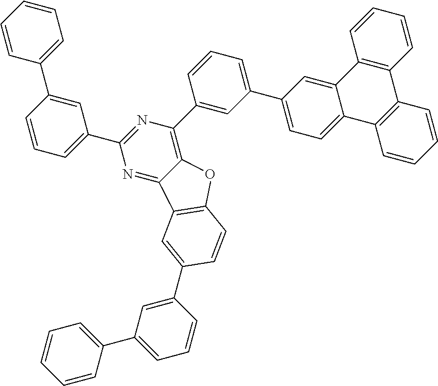 [SMILES: c1ccc(-c2cccc(-c3ccc4oc5c(-c6cccc(-c7ccc8c9ccccc9c9ccccc9c8c7)c6)nc(-c6cccc(-c7ccccc7)c6)nc5c4c3)c2)cc1]

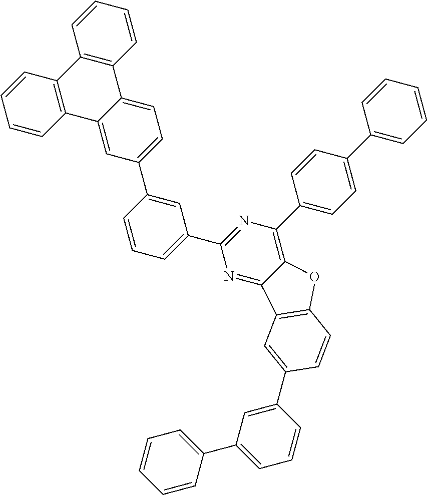 [SMILES: c1ccc(-c2ccc(-c3nc(-c4cccc(-c5ccc6c7ccccc7c7ccccc7c6c5)c4)nc4c3oc3ccc(-c5cccc(-c6ccccc6)c5)cc34)cc2)cc1]

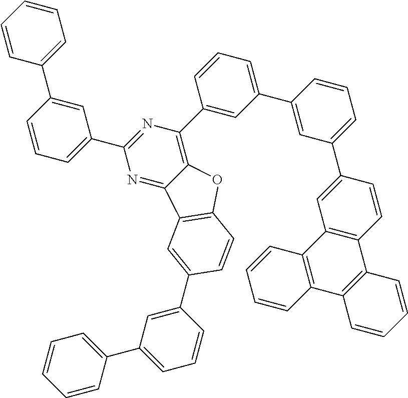 [SMILES: c1ccc(-c2cccc(-c3ccc4oc5c(-c6cccc(-c7cccc(-c8ccc9c%10ccccc%10c%10ccccc%10c9c8)c7)c6)nc(-c6cccc(-c7ccccc7)c6)nc5c4c3)c2)cc1]

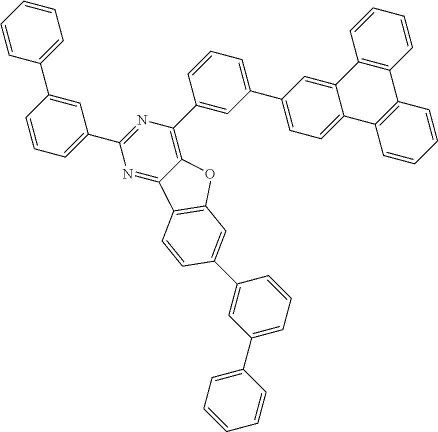 [SMILES: c1ccc(-c2cccc(-c3ccc4c(c3)oc3c(-c5cccc(-c6ccc7c8ccccc8c8ccccc8c7c6)c5)nc(-c5cccc(-c6ccccc6)c5)nc34)c2)cc1]

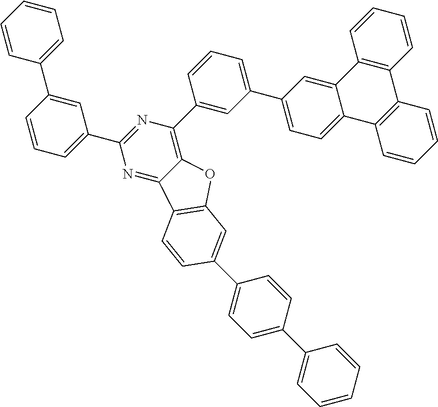 [SMILES: c1ccc(-c2ccc(-c3ccc4c(c3)oc3c(-c5cccc(-c6ccc7c8ccccc8c8ccccc8c7c6)c5)nc(-c5cccc(-c6ccccc6)c5)nc34)cc2)cc1]

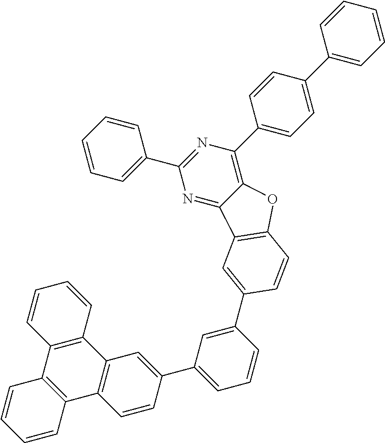 [SMILES: c1ccc(-c2ccc(-c3nc(-c4ccccc4)nc4c3oc3ccc(-c5cccc(-c6ccc7c8ccccc8c8ccccc8c7c6)c5)cc34)cc2)cc1]

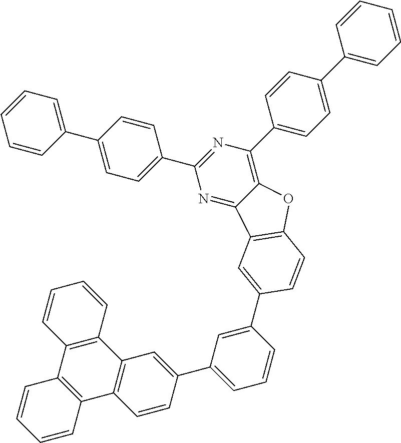 [SMILES: c1ccc(-c2ccc(-c3nc(-c4ccc(-c5ccccc5)cc4)c4oc5ccc(-c6cccc(-c7ccc8c9ccccc9c9ccccc9c8c7)c6)cc5c4n3)cc2)cc1]

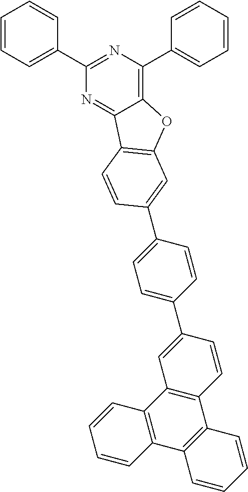 [SMILES: c1ccc(-c2nc(-c3ccccc3)c3oc4cc(-c5ccc(-c6ccc7c8ccccc8c8ccccc8c7c6)cc5)ccc4c3n2)cc1]

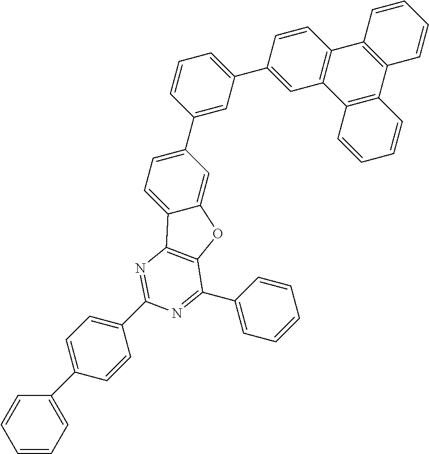 [SMILES: c1ccc(-c2ccc(-c3nc(-c4ccccc4)c4oc5cc(-c6cccc(-c7ccc8c9ccccc9c9ccccc9c8c7)c6)ccc5c4n3)cc2)cc1]

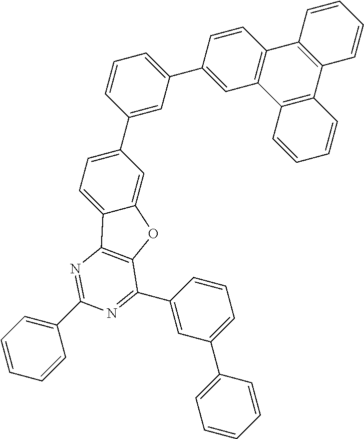 [SMILES: c1ccc(-c2cccc(-c3nc(-c4ccccc4)nc4c3oc3cc(-c5cccc(-c6ccc7c8ccccc8c8ccccc8c7c6)c5)ccc34)c2)cc1]

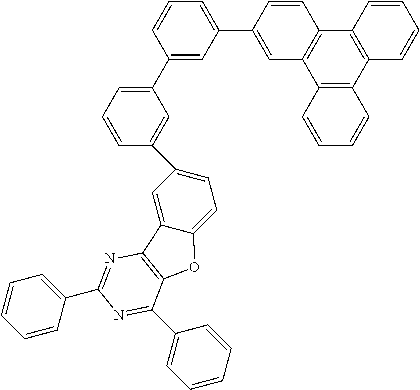 [SMILES: c1ccc(-c2nc(-c3ccccc3)c3oc4ccc(-c5cccc(-c6cccc(-c7ccc8c9ccccc9c9ccccc9c8c7)c6)c5)cc4c3n2)cc1]

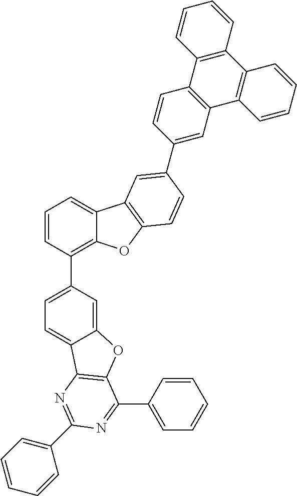 [SMILES: c1ccc(-c2nc(-c3ccccc3)c3oc4cc(-c5cccc6c5oc5ccc(-c7ccc8c9ccccc9c9ccccc9c8c7)cc56)ccc4c3n2)cc1]

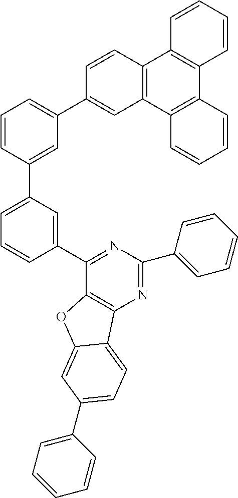 [SMILES: c1ccc(-c2ccc3c(c2)oc2c(-c4cccc(-c5cccc(-c6ccc7c8ccccc8c8ccccc8c7c6)c5)c4)nc(-c4ccccc4)nc23)cc1]

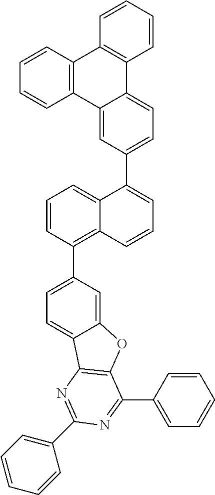 [SMILES: c1ccc(-c2nc(-c3ccccc3)c3oc4cc(-c5cccc6c(-c7ccc8c9ccccc9c9ccccc9c8c7)cccc56)ccc4c3n2)cc1]

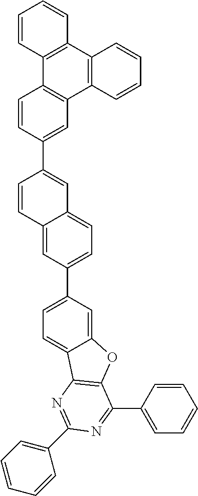 [SMILES: c1ccc(-c2nc(-c3ccccc3)c3oc4cc(-c5ccc6cc(-c7ccc8c9ccccc9c9ccccc9c8c7)ccc6c5)ccc4c3n2)cc1]

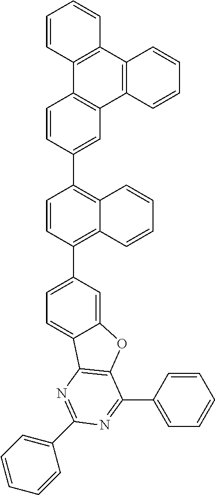 [SMILES: c1ccc(-c2nc(-c3ccccc3)c3oc4cc(-c5ccc(-c6ccc7c8ccccc8c8ccccc8c7c6)c6ccccc56)ccc4c3n2)cc1]

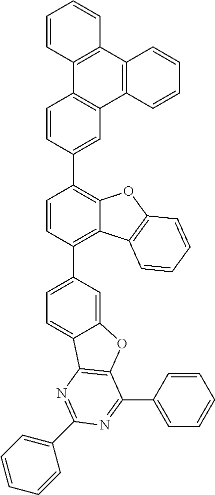 [SMILES: c1ccc(-c2nc(-c3ccccc3)c3oc4cc(-c5ccc(-c6ccc7c8ccccc8c8ccccc8c7c6)c6oc7ccccc7c56)ccc4c3n2)cc1]

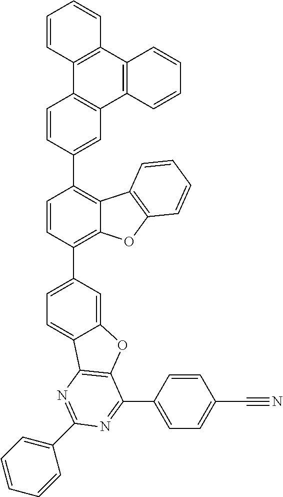 [SMILES: N#Cc1ccc(-c2nc(-c3ccccc3)nc3c2oc2cc(-c4ccc(-c5ccc6c7ccccc7c7ccccc7c6c5)c5c4oc4ccccc45)ccc23)cc1]

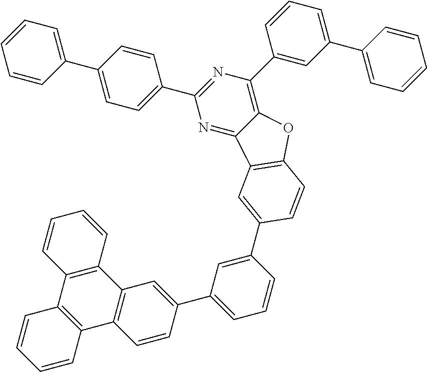 [SMILES: c1ccc(-c2ccc(-c3nc(-c4cccc(-c5ccccc5)c4)c4oc5ccc(-c6cccc(-c7ccc8c9ccccc9c9ccccc9c8c7)c6)cc5c4n3)cc2)cc1]

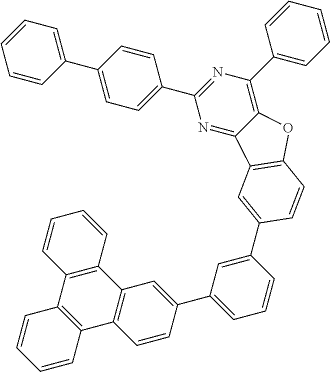 [SMILES: c1ccc(-c2ccc(-c3nc(-c4ccccc4)c4oc5ccc(-c6cccc(-c7ccc8c9ccccc9c9ccccc9c8c7)c6)cc5c4n3)cc2)cc1]

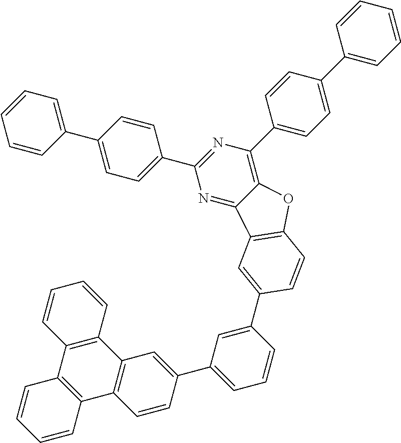 [SMILES: c1ccc(-c2ccc(-c3nc(-c4ccc(-c5ccccc5)cc4)c4oc5ccc(-c6cccc(-c7ccc8c9ccccc9c9ccccc9c8c7)c6)cc5c4n3)cc2)cc1]

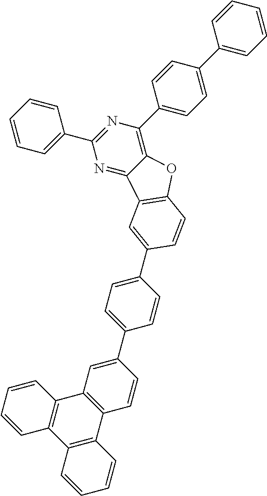 [SMILES: c1ccc(-c2ccc(-c3nc(-c4ccccc4)nc4c3oc3ccc(-c5ccc(-c6ccc7c8ccccc8c8ccccc8c7c6)cc5)cc34)cc2)cc1]

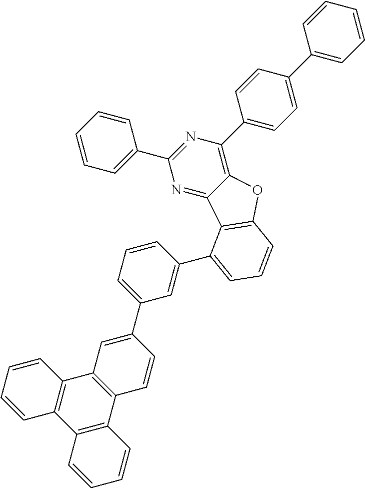 [SMILES: c1ccc(-c2ccc(-c3nc(-c4ccccc4)nc4c3oc3cccc(-c5cccc(-c6ccc7c8ccccc8c8ccccc8c7c6)c5)c34)cc2)cc1]

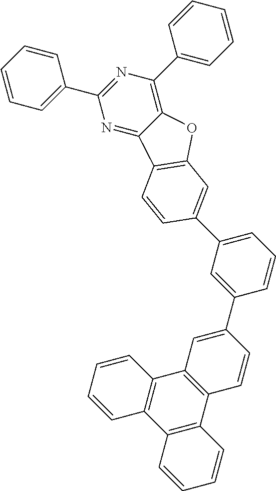 [SMILES: c1ccc(-c2nc(-c3ccccc3)c3oc4cc(-c5cccc(-c6ccc7c8ccccc8c8ccccc8c7c6)c5)ccc4c3n2)cc1]

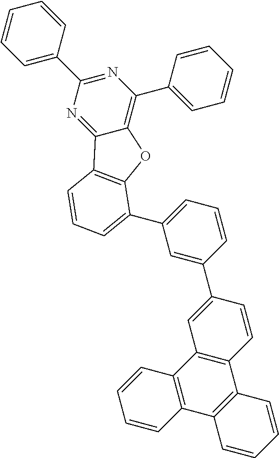 [SMILES: c1ccc(-c2nc(-c3ccccc3)c3oc4c(-c5cccc(-c6ccc7c8ccccc8c8ccccc8c7c6)c5)cccc4c3n2)cc1]

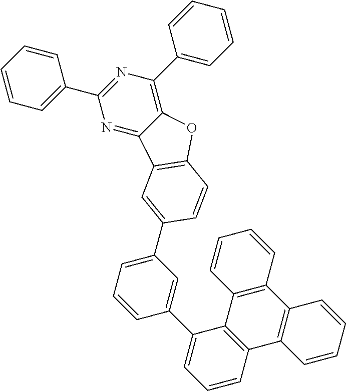 [SMILES: c1ccc(-c2nc(-c3ccccc3)c3oc4ccc(-c5cccc(-c6cccc7c8ccccc8c8ccccc8c67)c5)cc4c3n2)cc1]

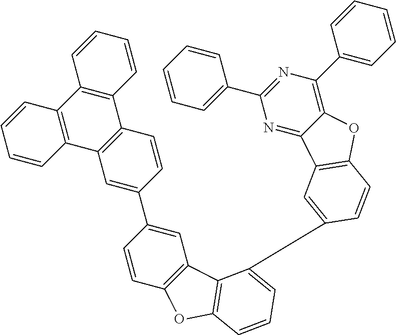 [SMILES: c1ccc(-c2nc(-c3ccccc3)c3oc4ccc(-c5cccc6oc7ccc(-c8ccc9c%10ccccc%10c%10ccccc%10c9c8)cc7c56)cc4c3n2)cc1]

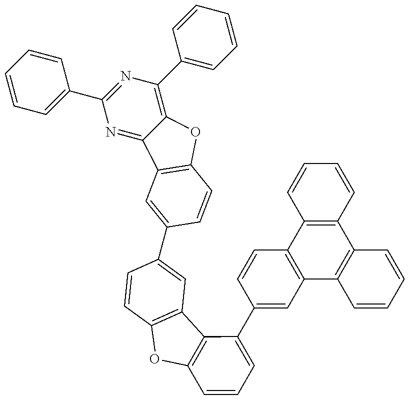 [SMILES: c1ccc(-c2nc(-c3ccccc3)c3oc4ccc(-c5ccc6oc7cccc(-c8ccc9c%10ccccc%10c%10ccccc%10c9c8)c7c6c5)cc4c3n2)cc1]

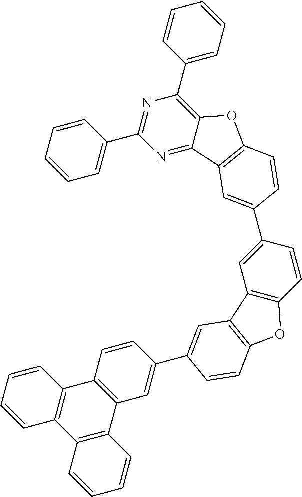 [SMILES: c1ccc(-c2nc(-c3ccccc3)c3oc4ccc(-c5ccc6oc7ccc(-c8ccc9c%10ccccc%10c%10ccccc%10c9c8)cc7c6c5)cc4c3n2)cc1]

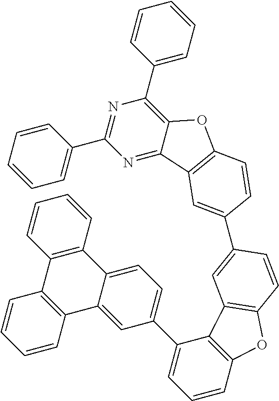 [SMILES: c1ccc(-c2nc(-c3ccccc3)c3oc4ccc(-c5ccc6oc7cccc(-c8ccc9c%10ccccc%10c%10ccccc%10c9c8)c7c6c5)cc4c3n2)cc1]

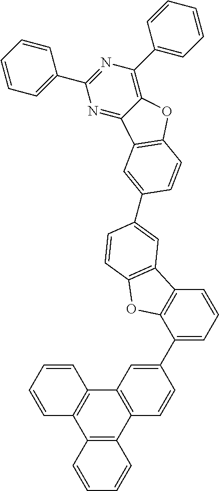 [SMILES: c1ccc(-c2nc(-c3ccccc3)c3oc4ccc(-c5ccc6oc7c(-c8ccc9c%10ccccc%10c%10ccccc%10c9c8)cccc7c6c5)cc4c3n2)cc1]

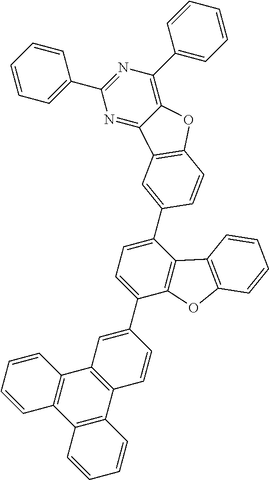 [SMILES: c1ccc(-c2nc(-c3ccccc3)c3oc4ccc(-c5ccc(-c6ccc7c8ccccc8c8ccccc8c7c6)c6oc7ccccc7c56)cc4c3n2)cc1]

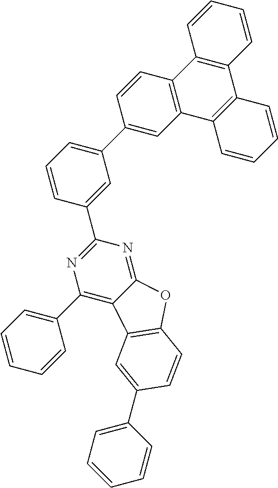 [SMILES: c1ccc(-c2ccc3oc4nc(-c5cccc(-c6ccc7c8ccccc8c8ccccc8c7c6)c5)nc(-c5ccccc5)c4c3c2)cc1]

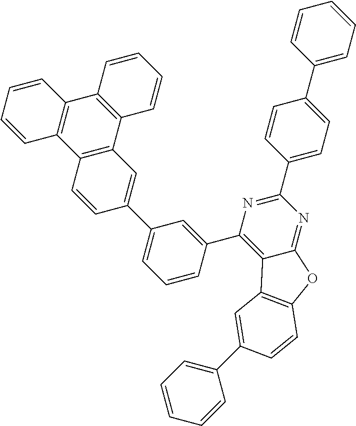 [SMILES: c1ccc(-c2ccc(-c3nc(-c4cccc(-c5ccc6c7ccccc7c7ccccc7c6c5)c4)c4c(n3)oc3ccc(-c5ccccc5)cc34)cc2)cc1]

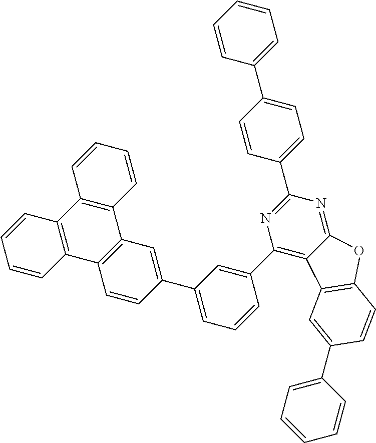 [SMILES: c1ccc(-c2ccc(-c3nc(-c4cccc(-c5ccc6c7ccccc7c7ccccc7c6c5)c4)c4c(n3)oc3ccc(-c5ccccc5)cc34)cc2)cc1]

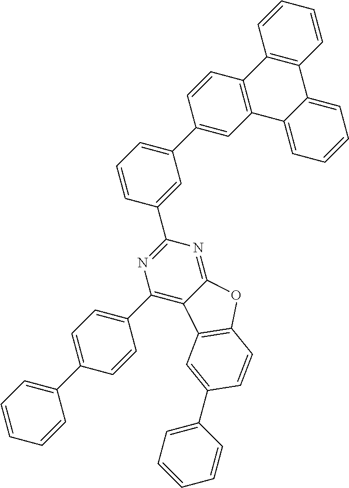 [SMILES: c1ccc(-c2ccc(-c3nc(-c4cccc(-c5ccc6c7ccccc7c7ccccc7c6c5)c4)nc4oc5ccc(-c6ccccc6)cc5c34)cc2)cc1]

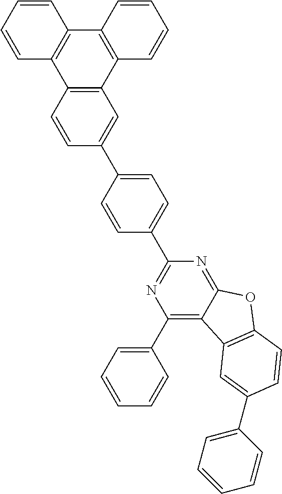 [SMILES: c1ccc(-c2ccc3oc4nc(-c5ccc(-c6ccc7c8ccccc8c8ccccc8c7c6)cc5)nc(-c5ccccc5)c4c3c2)cc1]

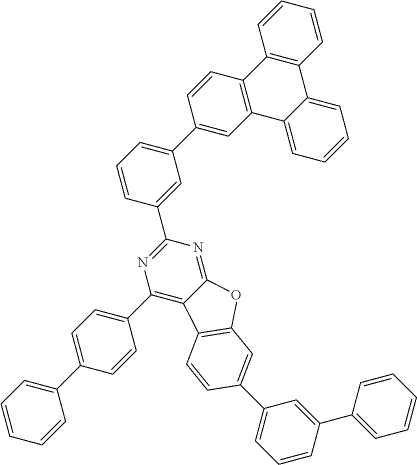 [SMILES: c1ccc(-c2ccc(-c3nc(-c4cccc(-c5ccc6c7ccccc7c7ccccc7c6c5)c4)nc4oc5cc(-c6cccc(-c7ccccc7)c6)ccc5c34)cc2)cc1]

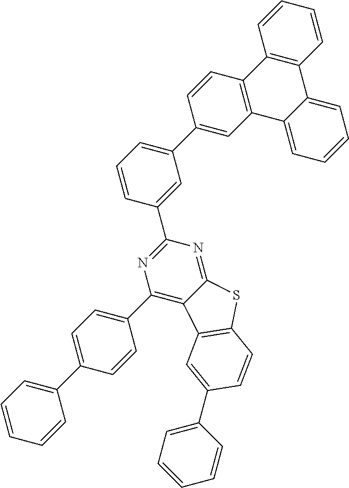 [SMILES: c1ccc(-c2ccc(-c3nc(-c4cccc(-c5ccc6c7ccccc7c7ccccc7c6c5)c4)nc4sc5ccc(-c6ccccc6)cc5c34)cc2)cc1]

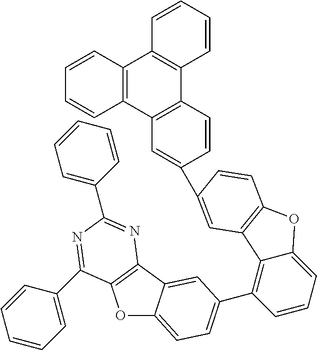 [SMILES: c1ccc(-c2nc(-c3ccccc3)c3oc4ccc(-c5cccc6oc7ccc(-c8ccc9c%10ccccc%10c%10ccccc%10c9c8)cc7c56)cc4c3n2)cc1]

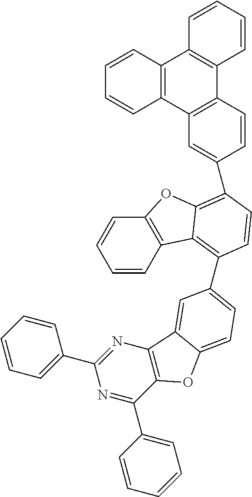 [SMILES: c1ccc(-c2nc(-c3ccccc3)c3oc4ccc(-c5ccc(-c6ccc7c8ccccc8c8ccccc8c7c6)c6oc7ccccc7c56)cc4c3n2)cc1]

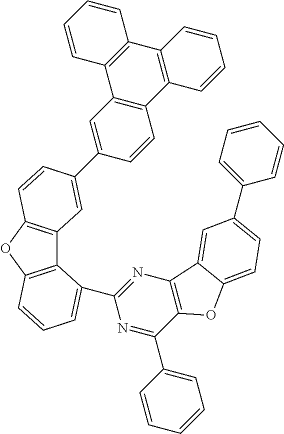 [SMILES: c1ccc(-c2ccc3oc4c(-c5ccccc5)nc(-c5cccc6oc7ccc(-c8ccc9c%10ccccc%10c%10ccccc%10c9c8)cc7c56)nc4c3c2)cc1]

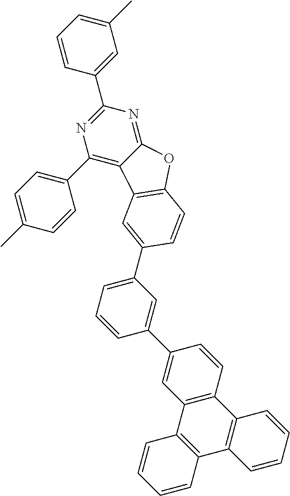 [SMILES: Cc1ccc(-c2nc(-c3cccc(C)c3)nc3oc4ccc(-c5cccc(-c6ccc7c8ccccc8c8ccccc8c7c6)c5)cc4c23)cc1]

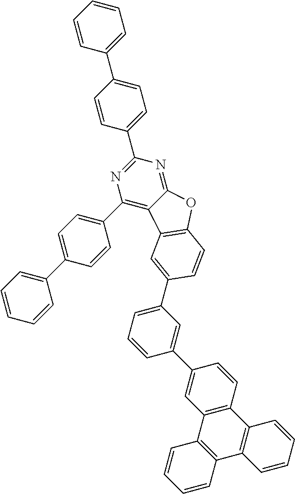 [SMILES: c1ccc(-c2ccc(-c3nc(-c4ccc(-c5ccccc5)cc4)c4c(n3)oc3ccc(-c5cccc(-c6ccc7c8ccccc8c8ccccc8c7c6)c5)cc34)cc2)cc1]

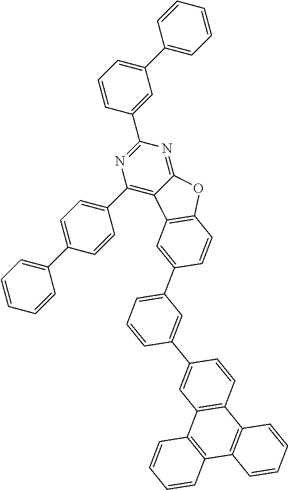 [SMILES: c1ccc(-c2ccc(-c3nc(-c4cccc(-c5ccccc5)c4)nc4oc5ccc(-c6cccc(-c7ccc8c9ccccc9c9ccccc9c8c7)c6)cc5c34)cc2)cc1]

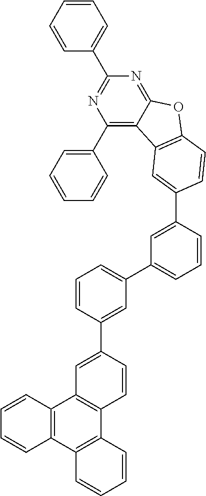 [SMILES: c1ccc(-c2nc(-c3ccccc3)c3c(n2)oc2ccc(-c4cccc(-c5cccc(-c6ccc7c8ccccc8c8ccccc8c7c6)c5)c4)cc23)cc1]

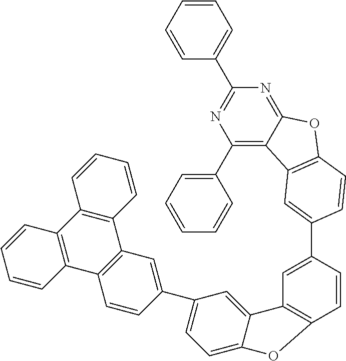 [SMILES: c1ccc(-c2nc(-c3ccccc3)c3c(n2)oc2ccc(-c4ccc5oc6ccc(-c7ccc8c9ccccc9c9ccccc9c8c7)cc6c5c4)cc23)cc1]

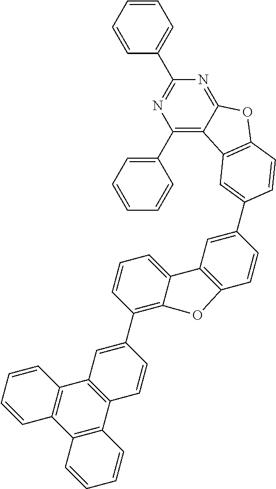 [SMILES: c1ccc(-c2nc(-c3ccccc3)c3c(n2)oc2ccc(-c4ccc5oc6c(-c7ccc8c9ccccc9c9ccccc9c8c7)cccc6c5c4)cc23)cc1]

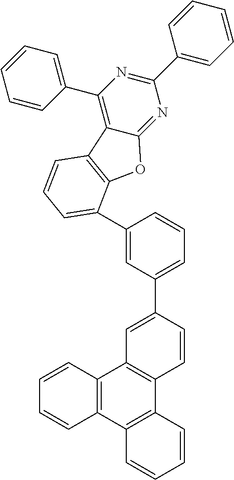 [SMILES: c1ccc(-c2nc(-c3ccccc3)c3c(n2)oc2c(-c4cccc(-c5ccc6c7ccccc7c7ccccc7c6c5)c4)cccc23)cc1]

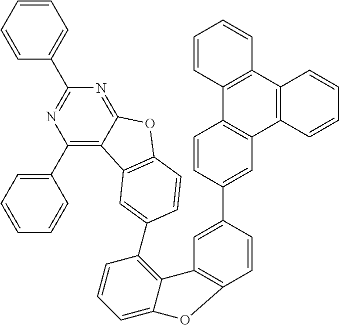 [SMILES: c1ccc(-c2nc(-c3ccccc3)c3c(n2)oc2ccc(-c4cccc5oc6ccc(-c7ccc8c9ccccc9c9ccccc9c8c7)cc6c45)cc23)cc1]

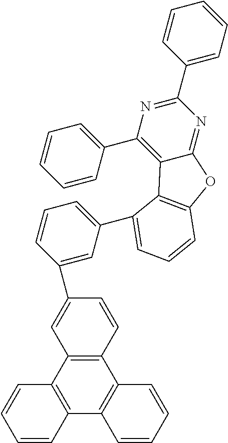 [SMILES: c1ccc(-c2nc(-c3ccccc3)c3c(n2)oc2cccc(-c4cccc(-c5ccc6c7ccccc7c7ccccc7c6c5)c4)c23)cc1]

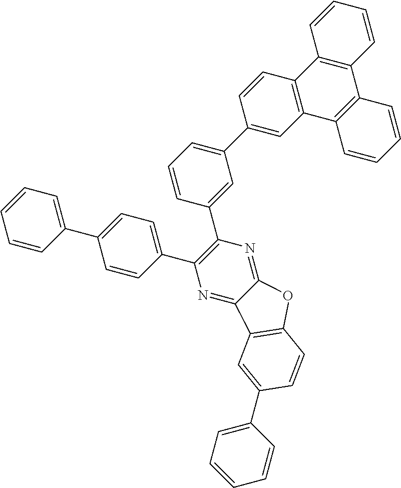 [SMILES: c1ccc(-c2ccc(-c3nc4c(nc3-c3cccc(-c5ccc6c7ccccc7c7ccccc7c6c5)c3)oc3ccc(-c5ccccc5)cc34)cc2)cc1]

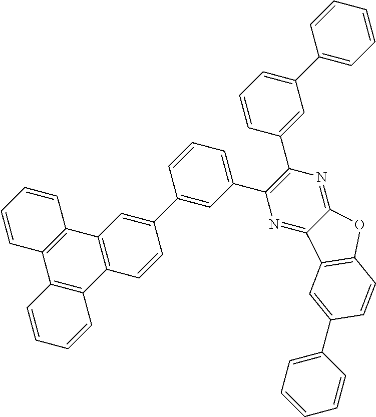 [SMILES: c1ccc(-c2cccc(-c3nc4oc5ccc(-c6ccccc6)cc5c4nc3-c3cccc(-c4ccc5c6ccccc6c6ccccc6c5c4)c3)c2)cc1]

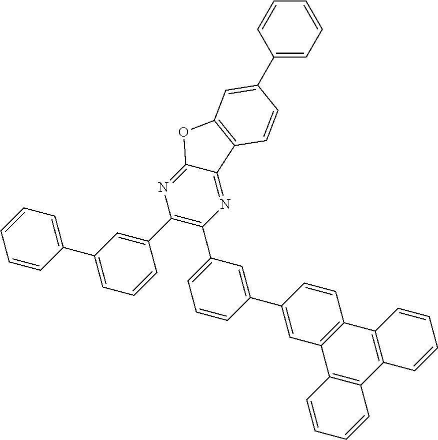 [SMILES: c1ccc(-c2cccc(-c3nc4oc5cc(-c6ccccc6)ccc5c4nc3-c3cccc(-c4ccc5c6ccccc6c6ccccc6c5c4)c3)c2)cc1]

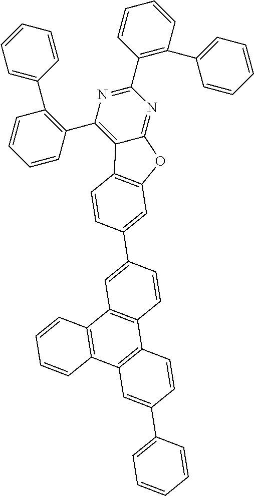 [SMILES: c1ccc(-c2ccc3c4ccc(-c5ccc6c(c5)oc5nc(-c7ccccc7-c7ccccc7)nc(-c7ccccc7-c7ccccc7)c56)cc4c4ccccc4c3c2)cc1]

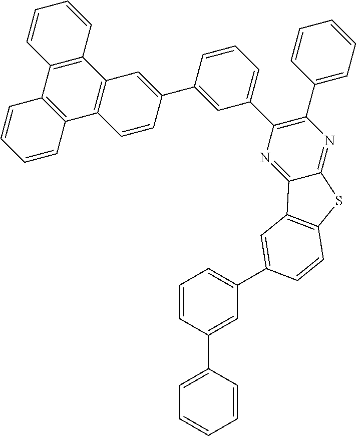 [SMILES: c1ccc(-c2cccc(-c3ccc4sc5nc(-c6ccccc6)c(-c6cccc(-c7ccc8c9ccccc9c9ccccc9c8c7)c6)nc5c4c3)c2)cc1]

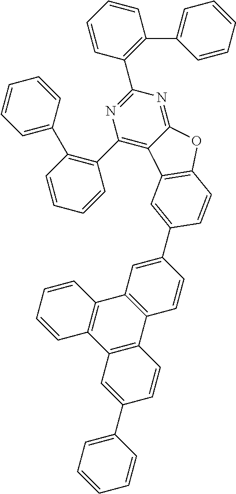 [SMILES: c1ccc(-c2ccc3c4ccc(-c5ccc6oc7nc(-c8ccccc8-c8ccccc8)nc(-c8ccccc8-c8ccccc8)c7c6c5)cc4c4ccccc4c3c2)cc1]

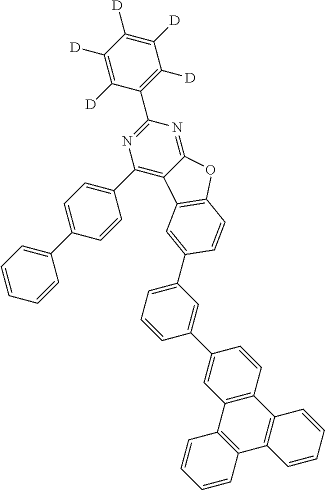 [SMILES: [2H]c1c([2H])c([2H])c(-c2nc(-c3ccc(-c4ccccc4)cc3)c3c(n2)oc2ccc(-c4cccc(-c5ccc6c7ccccc7c7ccccc7c6c5)c4)cc23)c([2H])c1[2H]]

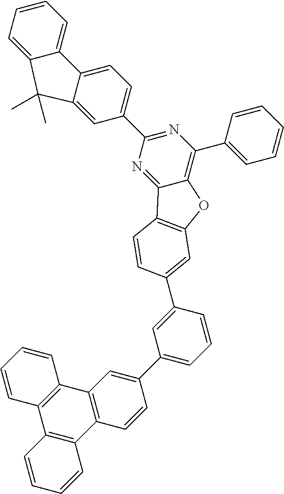 [SMILES: CC1(C)c2ccccc2-c2ccc(-c3nc(-c4ccccc4)c4oc5cc(-c6cccc(-c7ccc8c9ccccc9c9ccccc9c8c7)c6)ccc5c4n3)cc21]

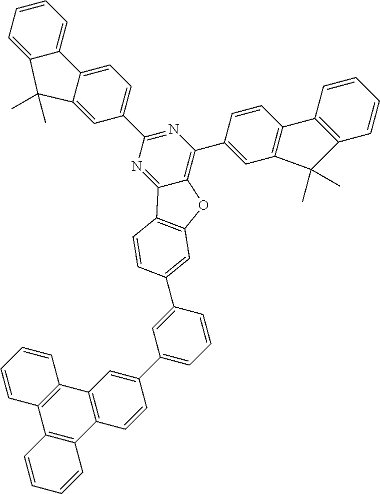 [SMILES: CC1(C)c2ccccc2-c2ccc(-c3nc(-c4ccc5c(c4)C(C)(C)c4ccccc4-5)c4oc5cc(-c6cccc(-c7ccc8c9ccccc9c9ccccc9c8c7)c6)ccc5c4n3)cc21]

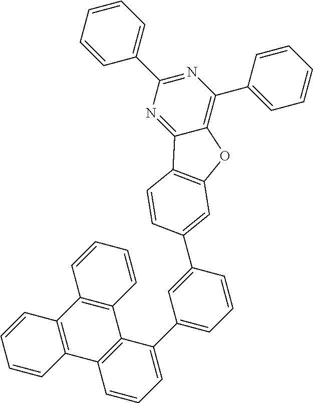 [SMILES: c1ccc(-c2nc(-c3ccccc3)c3oc4cc(-c5cccc(-c6cccc7c8ccccc8c8ccccc8c67)c5)ccc4c3n2)cc1]

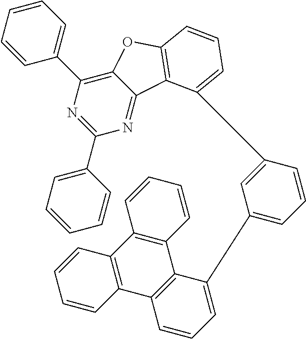 [SMILES: c1ccc(-c2nc(-c3ccccc3)c3oc4cccc(-c5cccc(-c6cccc7c8ccccc8c8ccccc8c67)c5)c4c3n2)cc1]

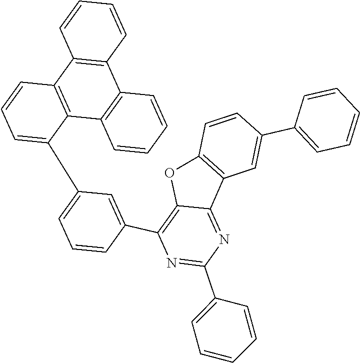 [SMILES: c1ccc(-c2ccc3oc4c(-c5cccc(-c6cccc7c8ccccc8c8ccccc8c67)c5)nc(-c5ccccc5)nc4c3c2)cc1]

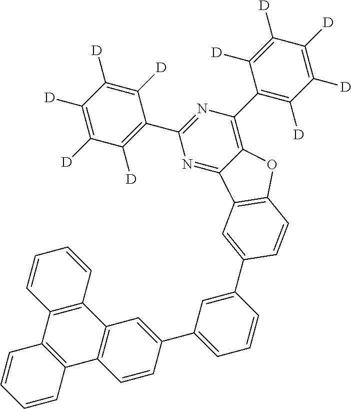 [SMILES: [2H]c1c([2H])c([2H])c(-c2nc(-c3c([2H])c([2H])c([2H])c([2H])c3[2H])c3oc4ccc(-c5cccc(-c6ccc7c8ccccc8c8ccccc8c7c6)c5)cc4c3n2)c([2H])c1[2H]]

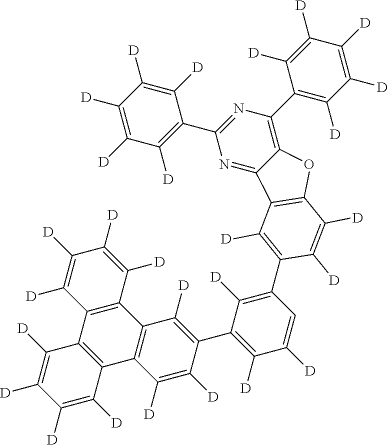 [SMILES: [2H]c1cc(-c2c([2H])c([2H])c3oc4c(-c5c([2H])c([2H])c([2H])c([2H])c5[2H])nc(-c5c([2H])c([2H])c([2H])c([2H])c5[2H])nc4c3c2[2H])c([2H])c(-c2c([2H])c([2H])c3c4c([2H])c([2H])c([2H])c([2H])c4c4c([2H])c([2H])c([2H])c([2H])c4c3c2[2H])c1[2H]]

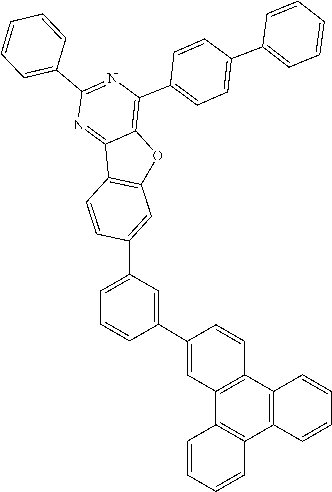 [SMILES: c1ccc(-c2ccc(-c3nc(-c4ccccc4)nc4c3oc3cc(-c5cccc(-c6ccc7c8ccccc8c8ccccc8c7c6)c5)ccc34)cc2)cc1]

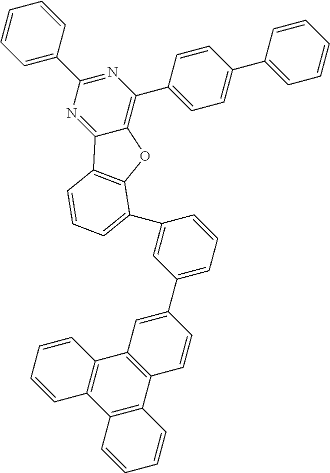 [SMILES: c1ccc(-c2ccc(-c3nc(-c4ccccc4)nc4c3oc3c(-c5cccc(-c6ccc7c8ccccc8c8ccccc8c7c6)c5)cccc34)cc2)cc1]

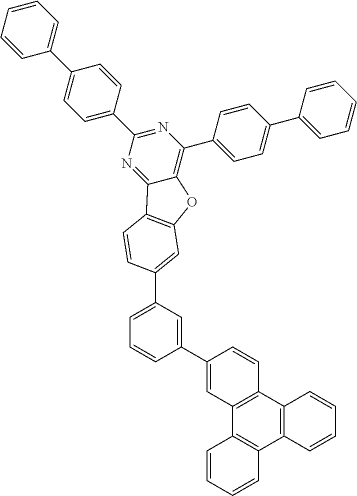 [SMILES: c1ccc(-c2ccc(-c3nc(-c4ccc(-c5ccccc5)cc4)c4oc5cc(-c6cccc(-c7ccc8c9ccccc9c9ccccc9c8c7)c6)ccc5c4n3)cc2)cc1]

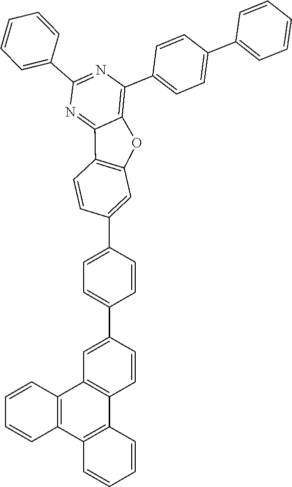 [SMILES: c1ccc(-c2ccc(-c3nc(-c4ccccc4)nc4c3oc3cc(-c5ccc(-c6ccc7c8ccccc8c8ccccc8c7c6)cc5)ccc34)cc2)cc1]

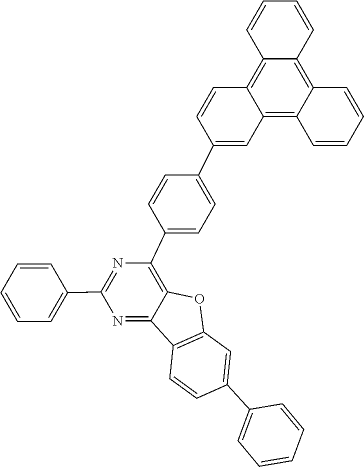 [SMILES: c1ccc(-c2ccc3c(c2)oc2c(-c4ccc(-c5ccc6c7ccccc7c7ccccc7c6c5)cc4)nc(-c4ccccc4)nc23)cc1]

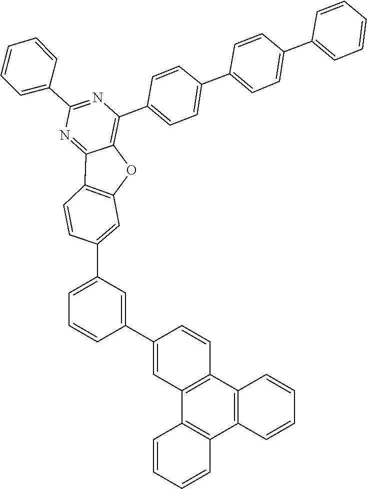 [SMILES: c1ccc(-c2ccc(-c3ccc(-c4nc(-c5ccccc5)nc5c4oc4cc(-c6cccc(-c7ccc8c9ccccc9c9ccccc9c8c7)c6)ccc45)cc3)cc2)cc1]

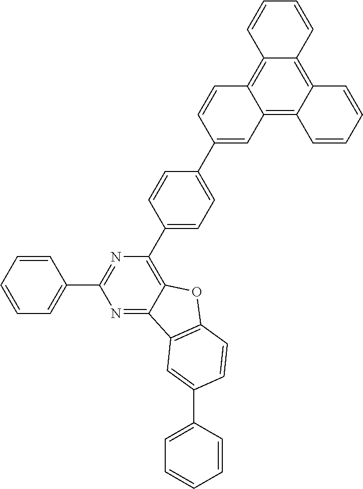 [SMILES: c1ccc(-c2ccc3oc4c(-c5ccc(-c6ccc7c8ccccc8c8ccccc8c7c6)cc5)nc(-c5ccccc5)nc4c3c2)cc1]

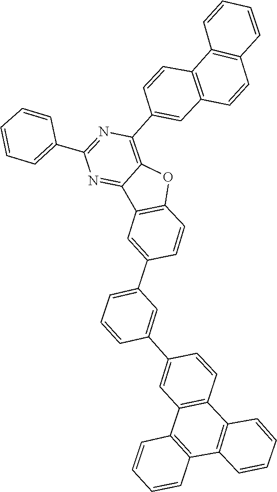 [SMILES: c1ccc(-c2nc(-c3ccc4c(ccc5ccccc54)c3)c3oc4ccc(-c5cccc(-c6ccc7c8ccccc8c8ccccc8c7c6)c5)cc4c3n2)cc1]

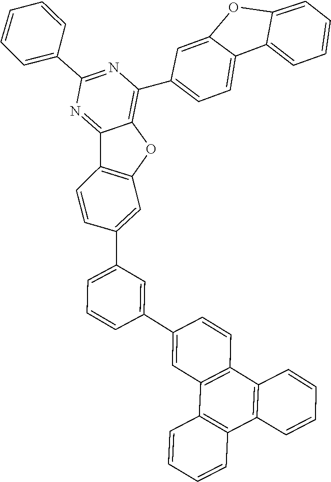 [SMILES: c1ccc(-c2nc(-c3ccc4c(c3)oc3ccccc34)c3oc4cc(-c5cccc(-c6ccc7c8ccccc8c8ccccc8c7c6)c5)ccc4c3n2)cc1]

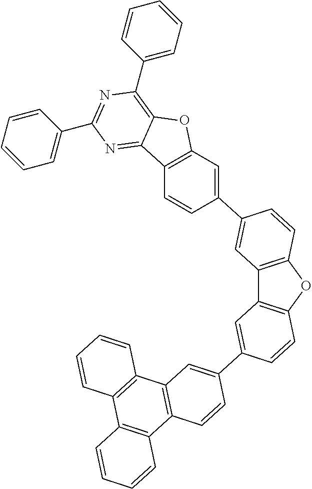 [SMILES: c1ccc(-c2nc(-c3ccccc3)c3oc4cc(-c5ccc6oc7ccc(-c8ccc9c%10ccccc%10c%10ccccc%10c9c8)cc7c6c5)ccc4c3n2)cc1]

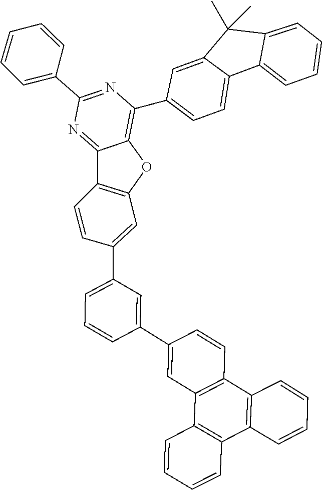 [SMILES: CC1(C)c2ccccc2-c2ccc(-c3nc(-c4ccccc4)nc4c3oc3cc(-c5cccc(-c6ccc7c8ccccc8c8ccccc8c7c6)c5)ccc34)cc21]

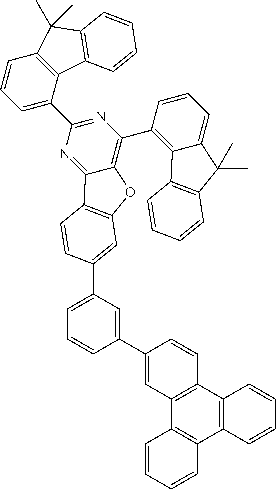 [SMILES: CC1(C)c2ccccc2-c2c(-c3nc(-c4cccc5c4-c4ccccc4C5(C)C)c4oc5cc(-c6cccc(-c7ccc8c9ccccc9c9ccccc9c8c7)c6)ccc5c4n3)cccc21]

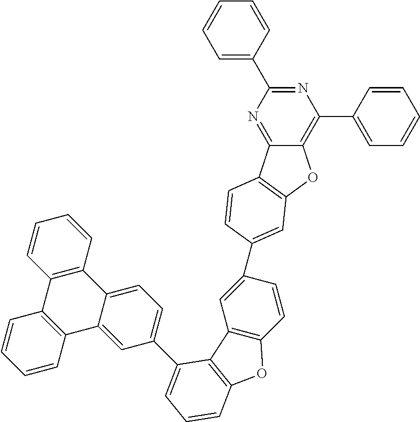 [SMILES: c1ccc(-c2nc(-c3ccccc3)c3oc4cc(-c5ccc6oc7cccc(-c8ccc9c%10ccccc%10c%10ccccc%10c9c8)c7c6c5)ccc4c3n2)cc1]

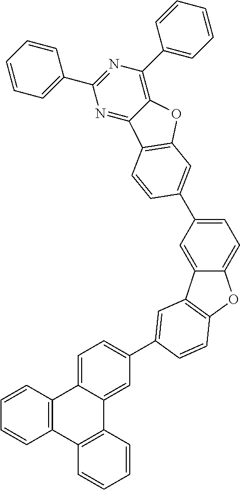 [SMILES: c1ccc(-c2nc(-c3ccccc3)c3oc4cc(-c5ccc6oc7ccc(-c8ccc9c%10ccccc%10c%10ccccc%10c9c8)cc7c6c5)ccc4c3n2)cc1]

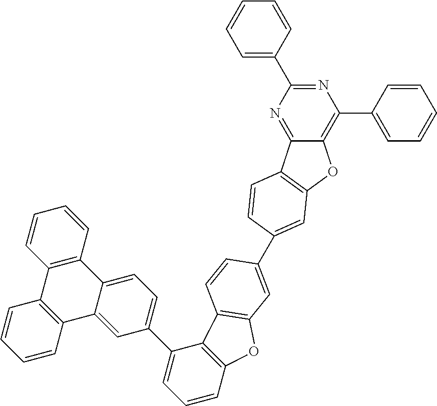 [SMILES: c1ccc(-c2nc(-c3ccccc3)c3oc4cc(-c5ccc6c(c5)oc5cccc(-c7ccc8c9ccccc9c9ccccc9c8c7)c56)ccc4c3n2)cc1]

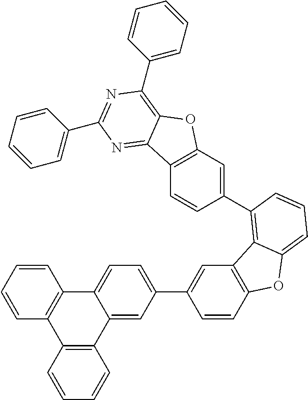 [SMILES: c1ccc(-c2nc(-c3ccccc3)c3oc4cc(-c5cccc6oc7ccc(-c8ccc9c%10ccccc%10c%10ccccc%10c9c8)cc7c56)ccc4c3n2)cc1]

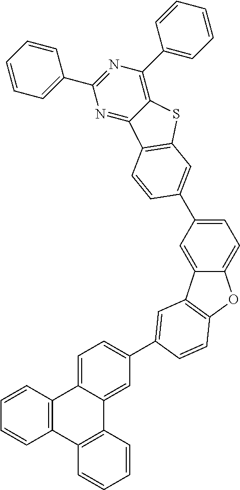 [SMILES: c1ccc(-c2nc(-c3ccccc3)c3sc4cc(-c5ccc6oc7ccc(-c8ccc9c%10ccccc%10c%10ccccc%10c9c8)cc7c6c5)ccc4c3n2)cc1]

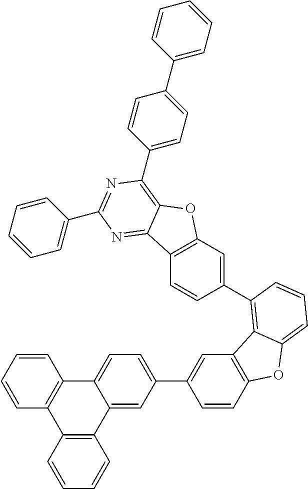 [SMILES: c1ccc(-c2ccc(-c3nc(-c4ccccc4)nc4c3oc3cc(-c5cccc6oc7ccc(-c8ccc9c%10ccccc%10c%10ccccc%10c9c8)cc7c56)ccc34)cc2)cc1]

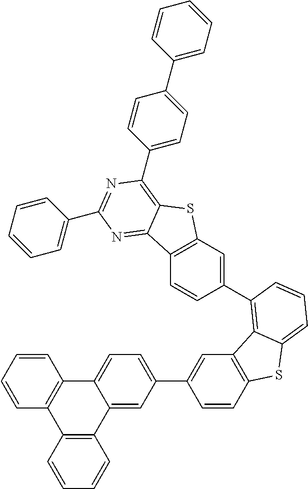 [SMILES: c1ccc(-c2ccc(-c3nc(-c4ccccc4)nc4c3sc3cc(-c5cccc6sc7ccc(-c8ccc9c%10ccccc%10c%10ccccc%10c9c8)cc7c56)ccc34)cc2)cc1]

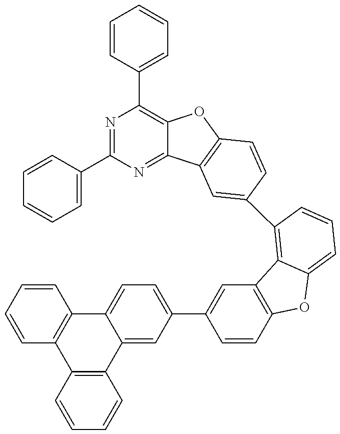 [SMILES: c1ccc(-c2nc(-c3ccccc3)c3oc4ccc(-c5cccc6oc7ccc(-c8ccc9c%10ccccc%10c%10ccccc%10c9c8)cc7c56)cc4c3n2)cc1]

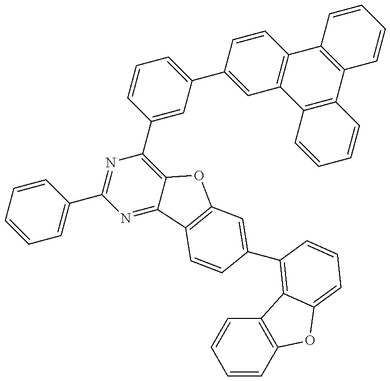 [SMILES: c1ccc(-c2nc(-c3cccc(-c4ccc5c6ccccc6c6ccccc6c5c4)c3)c3oc4cc(-c5cccc6oc7ccccc7c56)ccc4c3n2)cc1]

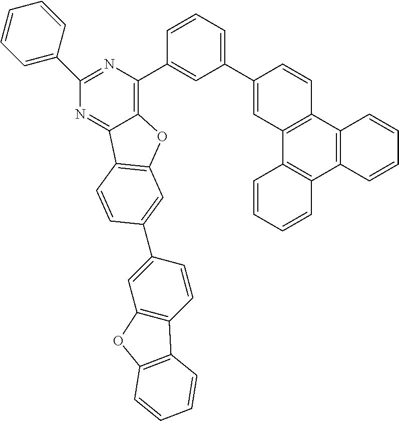 [SMILES: c1ccc(-c2nc(-c3cccc(-c4ccc5c6ccccc6c6ccccc6c5c4)c3)c3oc4cc(-c5ccc6c(c5)oc5ccccc56)ccc4c3n2)cc1]

Further examples of compounds of the formula (1) are described in the examples section.

Particularly suitable compounds of the formula (1) that are preferably used in combination with at least one compound of the formula (2) in the electroluminescent device of the invention are the compounds E1 to E27:

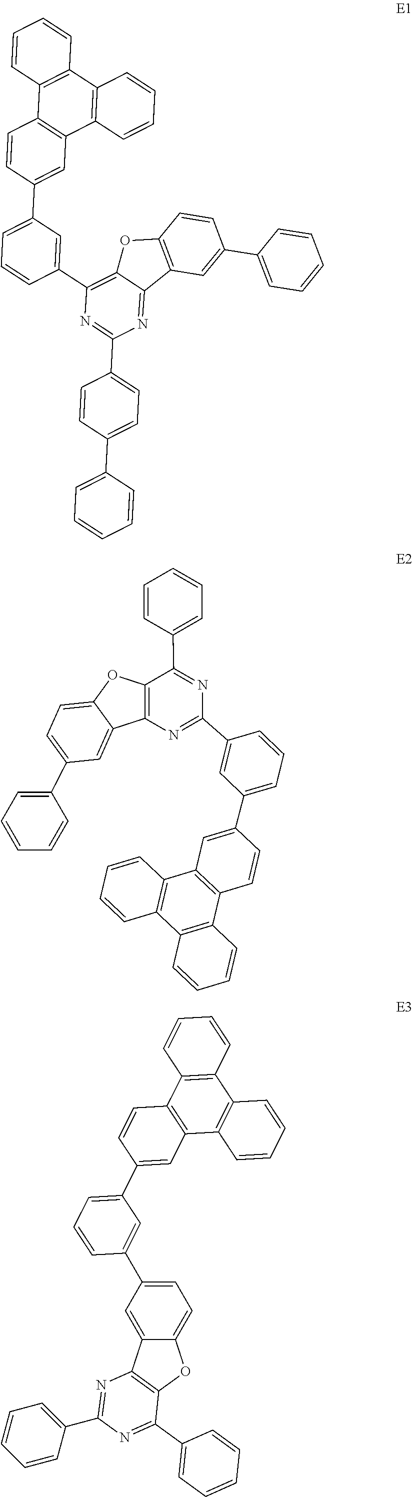

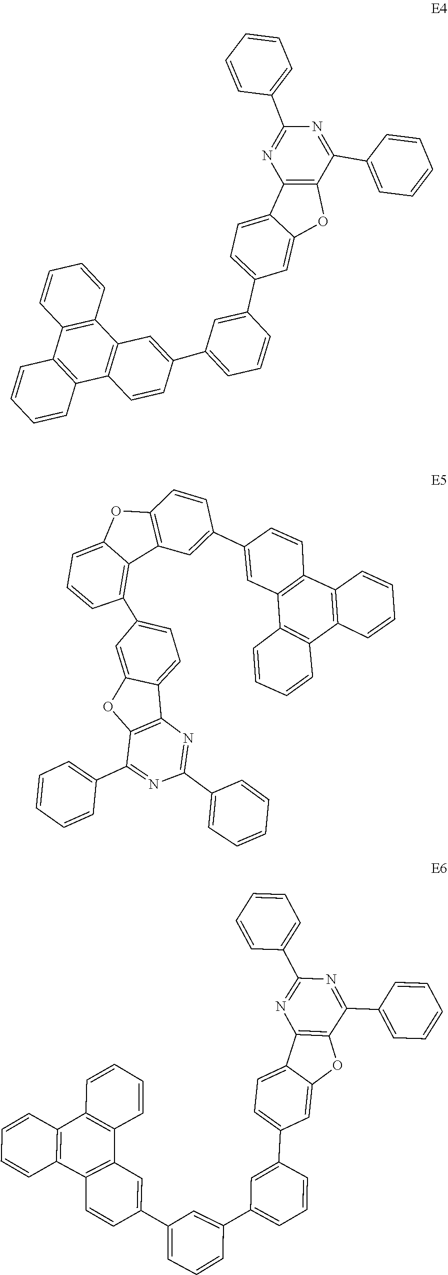 [SMILES: c1ccc(-c2nc(-c3ccccc3)c3oc4cc(-c5cccc(-c6ccc7c8ccccc8c8ccccc8c7c6)c5)ccc4c3n2)cc1 ; c1ccc(-c2nc(-c3ccccc3)c3oc4cc(-c5cccc6oc7ccc(-c8ccc9c%10ccccc%10c%10ccccc%10c9c8)cc7c56)ccc4c3n2)cc1 ; c1ccc(-c2nc(-c3ccccc3)c3oc4cc(-c5cccc(-c6cccc(-c7ccc8c9ccccc9c9ccccc9c8c7)c6)c5)ccc4c3n2)cc1]

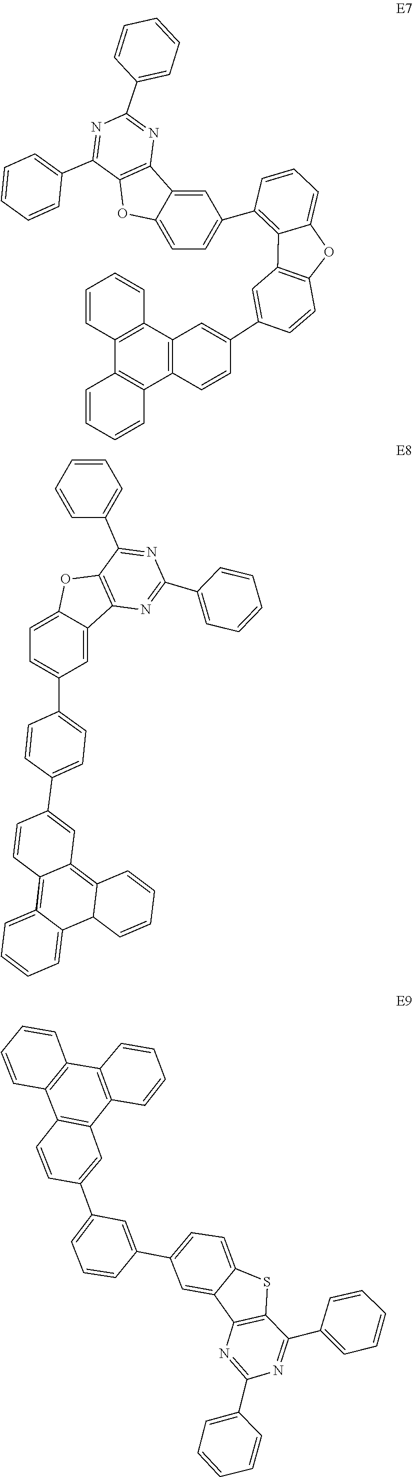

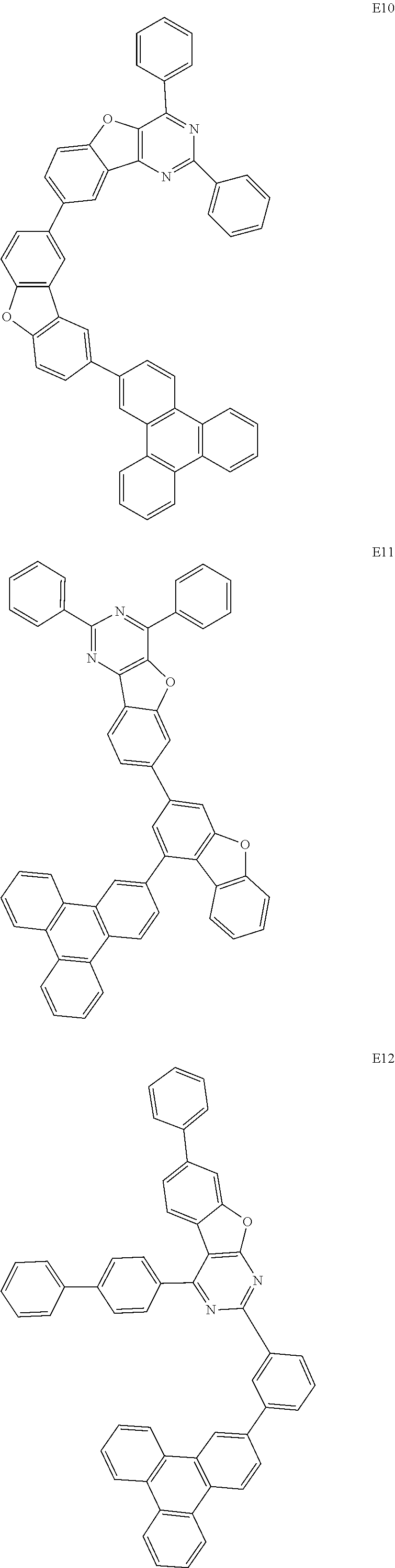 [SMILES: c1ccc(-c2nc(-c3ccccc3)c3oc4ccc(-c5ccc6oc7ccc(-c8ccc9c%10ccccc%10c%10ccccc%10c9c8)cc7c6c5)cc4c3n2)cc1 ; c1ccc(-c2nc(-c3ccccc3)c3oc4cc(-c5cc(-c6ccc7c8ccccc8c8ccccc8c7c6)c6c(c5)oc5ccccc56)ccc4c3n2)cc1 ; c1ccc(-c2ccc(-c3nc(-c4cccc(-c5ccc6c7ccccc7c7ccccc7c6c5)c4)nc4oc5cc(-c6ccccc6)ccc5c34)cc2)cc1]

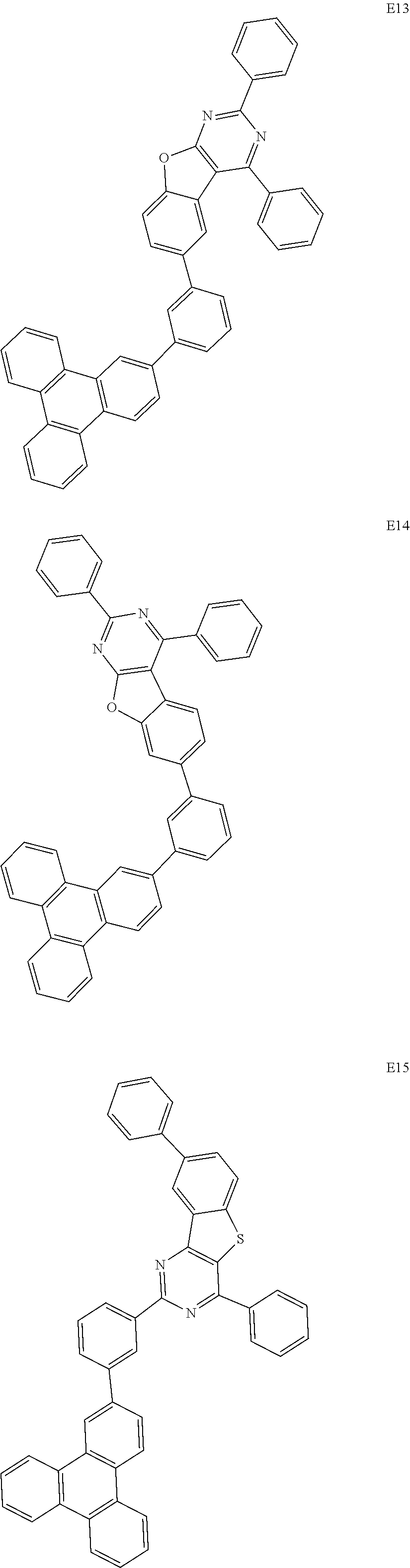 [SMILES: c1ccc(-c2nc(-c3ccccc3)c3c(n2)oc2ccc(-c4cccc(-c5ccc6c7ccccc7c7ccccc7c6c5)c4)cc23)cc1 ; c1ccc(-c2nc(-c3ccccc3)c3c(n2)oc2cc(-c4cccc(-c5ccc6c7ccccc7c7ccccc7c6c5)c4)ccc23)cc1 ; c1ccc(-c2ccc3sc4c(-c5ccccc5)nc(-c5cccc(-c6ccc7c8ccccc8c8ccccc8c7c6)c5)nc4c3c2)cc1]

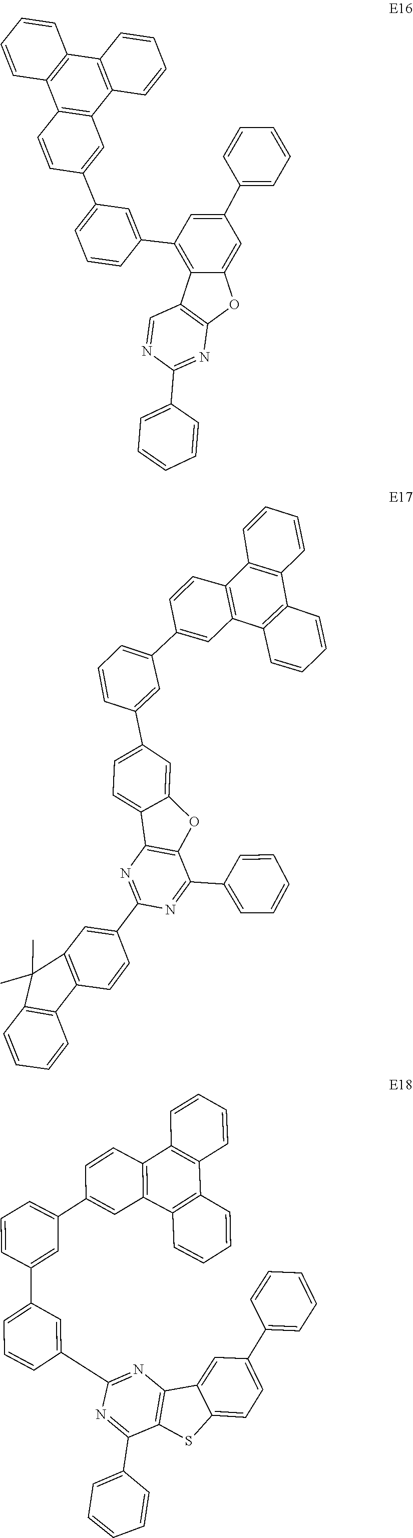 [SMILES: c1ccc(-c2cc(-c3cccc(-c4ccc5c6ccccc6c6ccccc6c5c4)c3)c3c(c2)oc2nc(-c4ccccc4)ncc23)cc1 ; CC1(C)c2ccccc2-c2ccc(-c3nc(-c4ccccc4)c4oc5cc(-c6cccc(-c7ccc8c9ccccc9c9ccccc9c8c7)c6)ccc5c4n3)cc21 ; c1ccc(-c2ccc3sc4c(-c5ccccc5)nc(-c5cccc(-c6cccc(-c7ccc8c9ccccc9c9ccccc9c8c7)c6)c5)nc4c3c2)cc1]

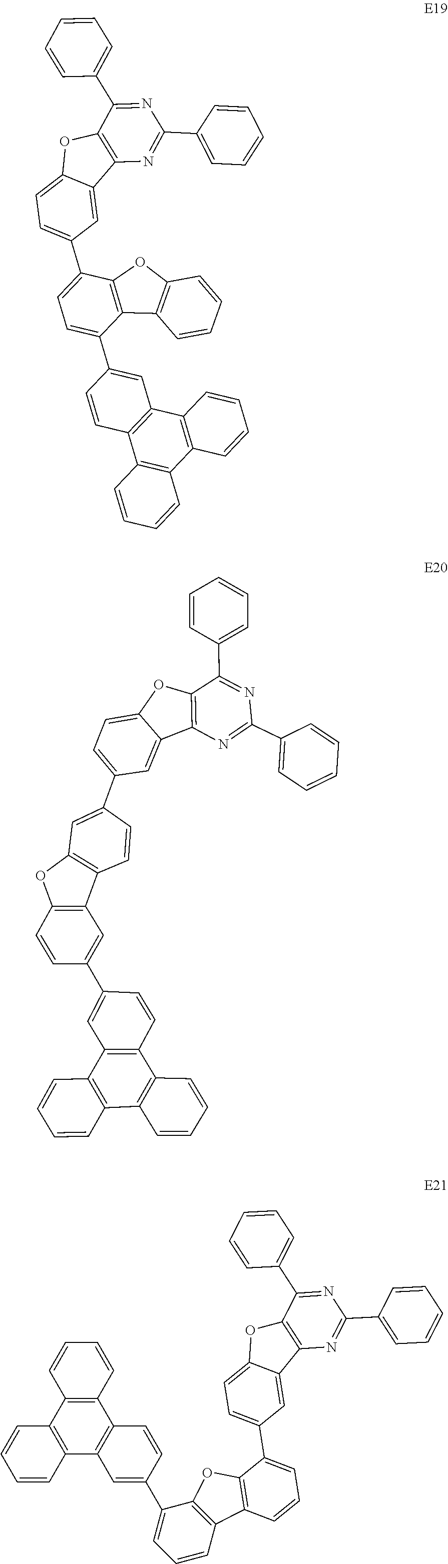 [SMILES: c1ccc(-c2nc(-c3ccccc3)c3oc4ccc(-c5ccc(-c6ccc7c8ccccc8c8ccccc8c7c6)c6c5oc5ccccc56)cc4c3n2)cc1 ; c1ccc(-c2nc(-c3ccccc3)c3oc4ccc(-c5ccc6c(c5)oc5ccc(-c7ccc8c9ccccc9c9ccccc9c8c7)cc56)cc4c3n2)cc1 ; c1ccc(-c2nc(-c3ccccc3)c3oc4ccc(-c5cccc6c5oc5c(-c7ccc8c9ccccc9c9ccccc9c8c7)cccc56)cc4c3n2)cc1]

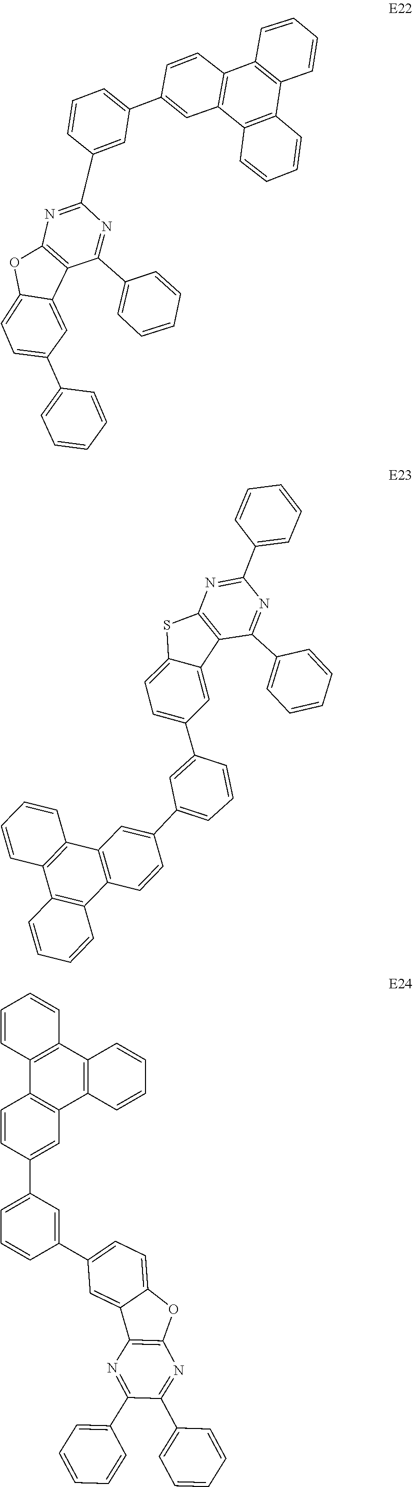

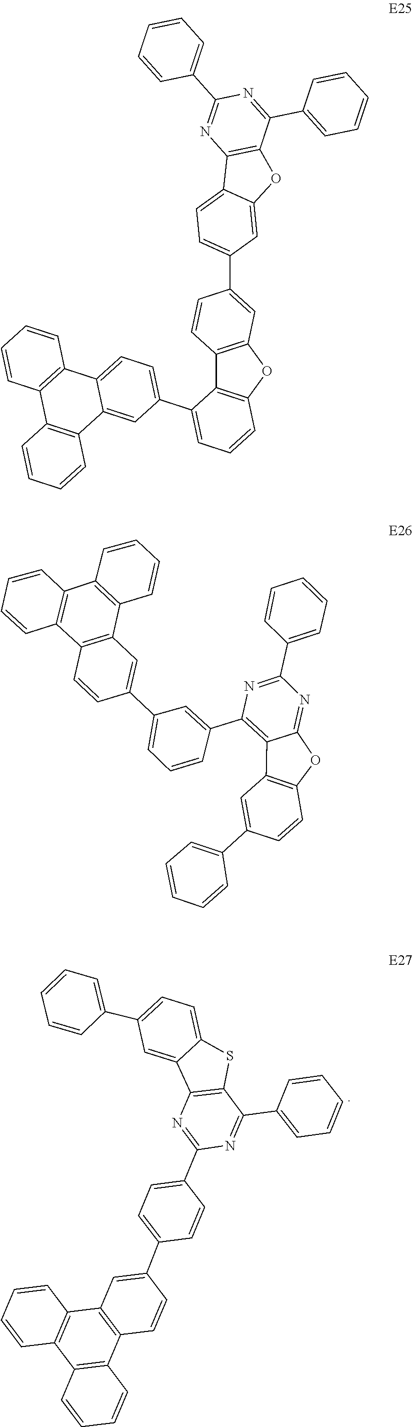 [SMILES: c1ccc(-c2nc(-c3ccccc3)c3oc4cc(-c5ccc6c(c5)oc5cccc(-c7ccc8c9ccccc9c9ccccc9c8c7)c56)ccc4c3n2)cc1 ; c1ccc(-c2ccc3oc4nc(-c5ccccc5)nc(-c5cccc(-c6ccc7c8ccccc8c8ccccc8c7c6)c5)c4c3c2)cc1 ; c1ccc(-c2ccc3sc4c(-c5ccccc5)nc(-c5ccc(-c6ccc7c8ccccc8c8ccccc8c7c6)cc5)nc4c3c2)cc1]

The preparation of the compounds of the formula (1) or of the preferred compounds from table 1 and of the compounds E1 to E27 is known to those skilled in the art. The compounds may be prepared by synthesis steps known to the person skilled in the art, for example halogenation, preferably bromination, and a subsequent organometallic coupling reaction, for example Suzuki coupling, Heck coupling or Hartwig-Buchwald coupling.

The preparation of precursors for compounds of the formula (1) may be carried out for example according to the following scheme 1, wherein V, m and R #have one of the definitions described or described as preferable above.

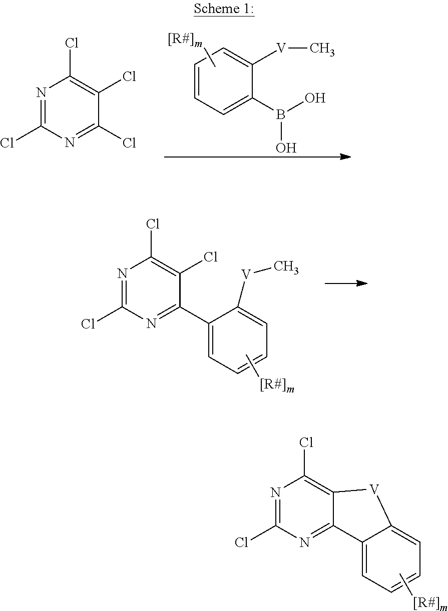

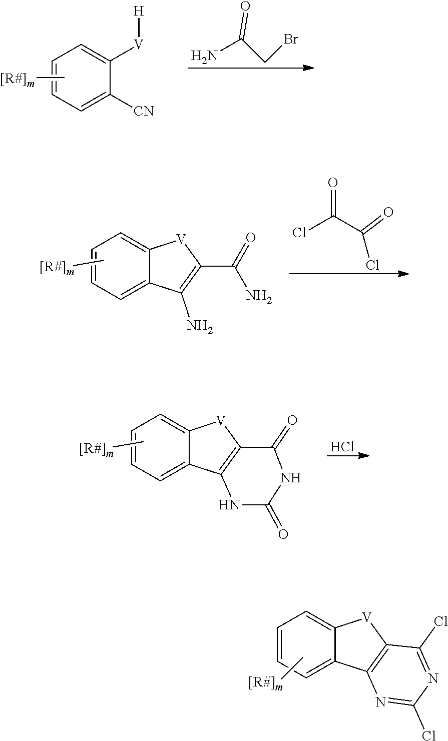

The preparation of compounds of the formula (1) may be carried out according to the following schemes 2 and 3, wherein Ar₂, L, R*, V, m and R #have one of the definitions described or described as preferable above and n represents 0.

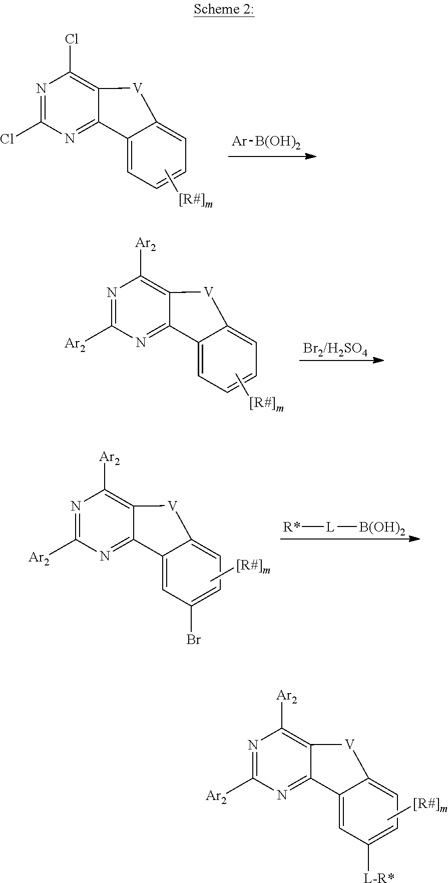

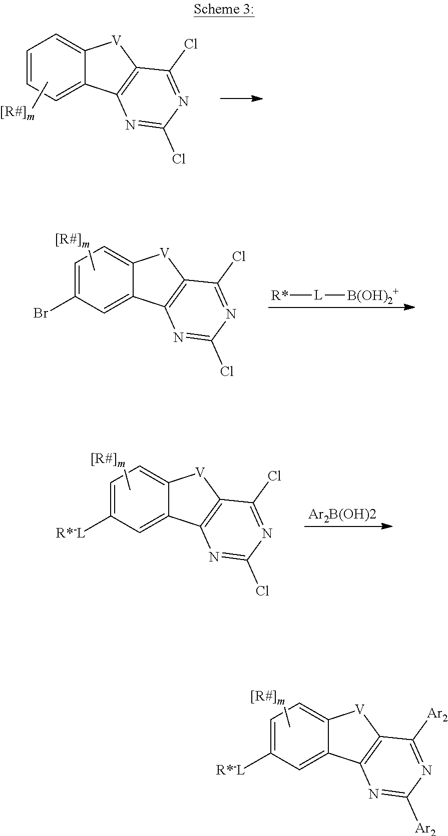

The preparation of compounds of the formula (1) may be carried out according to the following scheme 4, wherein n in each case represents 1, L in each case represents a phenylene group, m represents 0 and Ar₂, R* and L have one of the definitions described or described as preferable above.

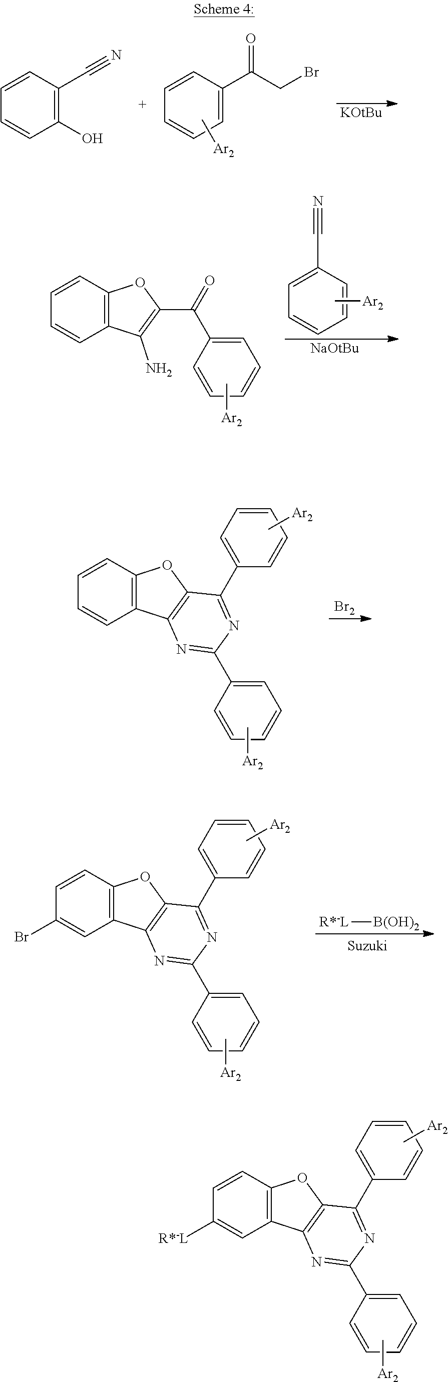

There follows a description of the host material 2 and its preferred embodiments that is/are present in the device of the invention. The preferred embodiments of the host material 1 of the formula (1) are also applicable to the mixture and/or formulation of the invention.

Host material 2 is at least one compound of the formula (2),

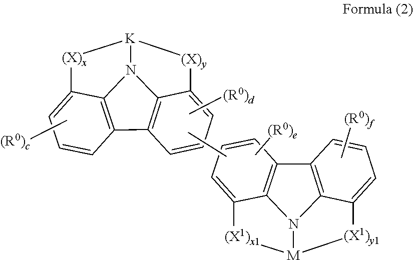

where the symbols and indices used are as follows:
K, M are each independently an unsubstituted or partially or completely deuterated or R*-monosubstituted aromatic ring system having 6 to 40 ring atoms when x and y are 0 and when x₁ and y₁ are 0, or
K, M each independently together with X or X¹ form a heteroaromatic ring system having 14 to 40 ring atoms, as soon as the value of x, x1, y and/or y1 is 1;
x, x1 are each independently at each occurrence 0 or 1;
y, y1 are each independently at each occurrence 0 or 1;
X and X¹ are each independently at each occurrence a bond or C(R⁺)₂;
R⁰ is independently at each occurrence an unsubstituted or partially or completely deuterated aromatic ring system having 6 to 18 ring atoms;
R⁺ is independently at each occurrence a straight-chain or branched alkyl group having 1 to 4 carbon atoms and
c, d, e and f are independently 0 or 1.

One embodiment of the invention comprises selecting for the device according to the invention compounds of the formula (2) as described above which are used in the light-emitting layer with compounds of the formula (1) as described or described as preferable above or with the compounds from table 1 or the compounds E1 to E27.

A preferred embodiment of the device according to the invention comprises using as host material 2 compounds of the formula (2) in which x, y, x1 and y1 are 0. Compounds of the formula (2) in which x, x1, y and y1 are at each occurrence 0 may be represented by the following formula (2a),

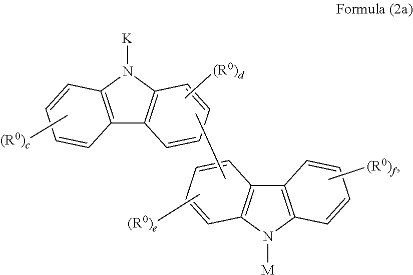

wherein R⁰, c, d, e and f are as defined above or hereinafter and
K and M are each independently an unsubstituted or partially or completely deuterated or R*-monosubstituted aromatic ring system having 6 to 40 ring atoms.

In preferred compounds of the formula (2a) the sum of the indices c+d+e+f is preferably 0 or 1 and R⁰ is as defined as preferable above or hereinafter.

In compounds of the formula (2) or (2a) R⁰ is independently at each occurrence preferably an unsubstituted aromatic ring system having 6 to 18 ring atoms, preferably 6 to 18 carbon atoms. R⁰ is independently at each occurrence preferably phenyl, 1,3-biphenyl, 1,4-biphenyl, naphthyl or triphenylenyl. R⁰ is independently at each occurrence particularly preferably phenyl.

In compounds of the formula (2) or (2a) the indices c, d, e and f are particularly preferably 0.

In compounds of the formula (2) or (2a) K and M are independently at each occurrence preferably an unsubstituted or partially deuterated or R*-monosubstituted aromatic ring system having 6 to 40 ring atoms as described above. K and M in compounds of the formula (2) or (2a) are independently at each occurrence particularly preferably phenyl, deuterated phenyl, 1,3-biphenyl, 1,4-biphenyl, terphenyl, partially deuterated terphenyl, quaterphenyl, naphthyl, fluorenyl, 9,9-diphenylfluorenyl, bispirofluorenyl or triphenylenyl.

The invention accordingly further provides an organic electroluminescent device as described or described as preferable above, wherein the at least one compound of the formula (2) corresponds to a compound of the formula (2a) or to a preferred embodiment of the compound of the formula (2a).

A preferred embodiment of the device according to the invention comprises using as host material 2 compounds of the formula (2) in which x1 and y1 are 0, x and y are 0 or 1 and the sum of x and y is 1 or 2. Compounds of the formula (2) in which x1 and y1 are 0, x and y are 0 or 1 and the sum of x and y is 1 or 2 may be represented by the following formula (2b),

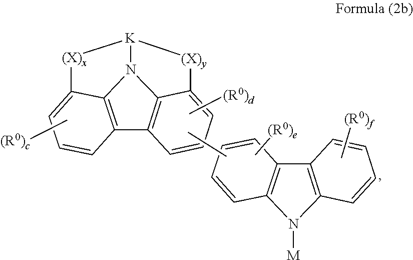

wherein X, x, y, R⁰, c, d, e and f are as defined above or hereinafter,
M is an unsubstituted or partially or completely deuterated or R*-monosubstituted aromatic ring system having 6 to 40 ring atoms and
K together with X forms a heteroaromatic ring system having 14 to 40 ring atoms as soon as the value of x or y is 1 or both values x and y are 1.

In preferred compounds of the formula (2b) the sum of the indices c+d+e+f is preferably 0, 1 or 2 and R⁰ is as defined as described or described as preferable above.

In compounds of the formula (2) or (2b) the indices c, d, e and f are particularly preferably 0 or 1. In compounds of the formula (2) or (2b) the indices c, d, e and f are very particularly preferably 0. In compounds of the formula (2) or (2b) the indices c, d, e and f are very particularly preferably 1. In compounds of the formula (2) or (2b) the indices c, d, e and f are very particularly preferably 2.

In compounds of the formula (2) or (2b) K preferably forms a heteroaromatic ring system when the sum of x+y is 1 or 2. In compounds of the formula (2) or (2b) X is preferably a direct bond or C(CH₃)₂.

Preferred compounds of the formula (2) or (2b) may be represented by the formulae (2b-1) to (2b-6),

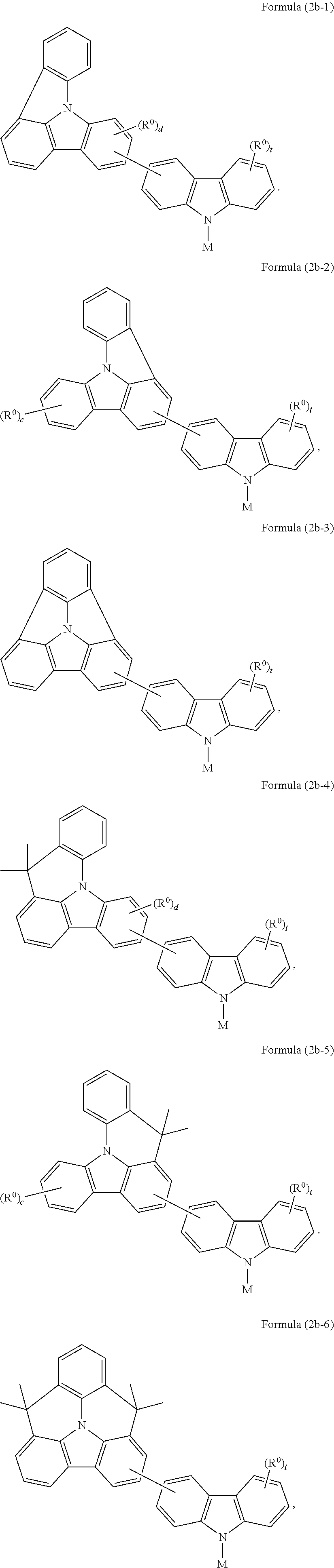

wherein M, R⁰, c, d, e and f are defined as described or described as preferable above.

In compounds of the formulae (2), (2b), (2b-1), (2b-2), (2b-3), (2b-4, (2b-5) or (2b-6) M is preferably an unsubstituted or partially deuterated or R*-monosubstituted aromatic ring system having 6 to 40 ring atoms as described above. M in compounds of the formulae (2), (2b), (2b-1), (2b-2), (2b-3), (2b-4, (2b-5) or (2b-6)) is particularly preferably phenyl, deuterated phenyl, 1,3-biphenyl, 1,4-biphenyl, terphenyl, partially deuterated terphenyl, quaterphenyl, naphthyl, fluorenyl, 9,9-diphenylfluorenyl, bispirofluorenyl or triphenylenyl.

In compounds of the formulae (2b-1), (2b-2), (2b-3), (2b-4, (2b-5) or (2b-6)) the indices c, d, e and f are preferably 0 or 1.

The invention accordingly further provides an organic electroluminescent device as described or described as preferable above, wherein the at least one compound of the formula (2) corresponds to a compound of the formula (2b), (2b-1), (2b-2), (2b-3), (2b-4), (2b-5) or (2b-6) or to a preferred embodiment of these compounds.

A preferred embodiment of the device according to the invention comprises using as host material 2 compounds of the formula (2) in which c and f are 0 or 1, d and e are 0 and x, x1, y and y1 independently at each occurrence represent 0 or 1 but the sum of x and y is at least 1 and the sum of x1 and y1 is at least 1. Such compounds of the formula (2) as described above may preferably be represented by the following formula (2c),

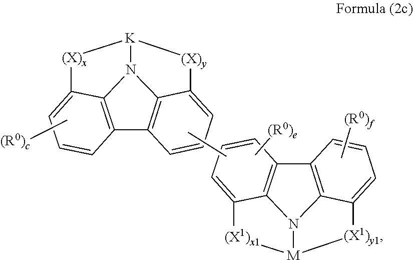

wherein X and X¹ are as defined above or hereinafter,
K and M each independently together with X or X¹ form a heteroaromatic ring system having 14 to 40 ring atoms,
x, x1, y and/or y1 are 0 or 1 and the sum of x and y is at least 1 and the sum of x1 and y1 is at least 1.

In preferred compounds of the formula (2c) the sum of x and y is 1 or 2 and the sum of x1 and y1 is 1. In particularly preferred compounds of the formula (2c) the sum of x and y is 1 and the sum of x1 and y1 is in each case 1.

In compounds of the formula (2) or (2c) K and M thus preferably form a heteroaromatic ring system. In compounds of the formula (2) or (2c) X and X¹ are preferably a direct bond or C(CH₃)₂.

Preferred compounds of the formula (2) or (2c) may be represented by the formulae (2c-1) to (2c-8),

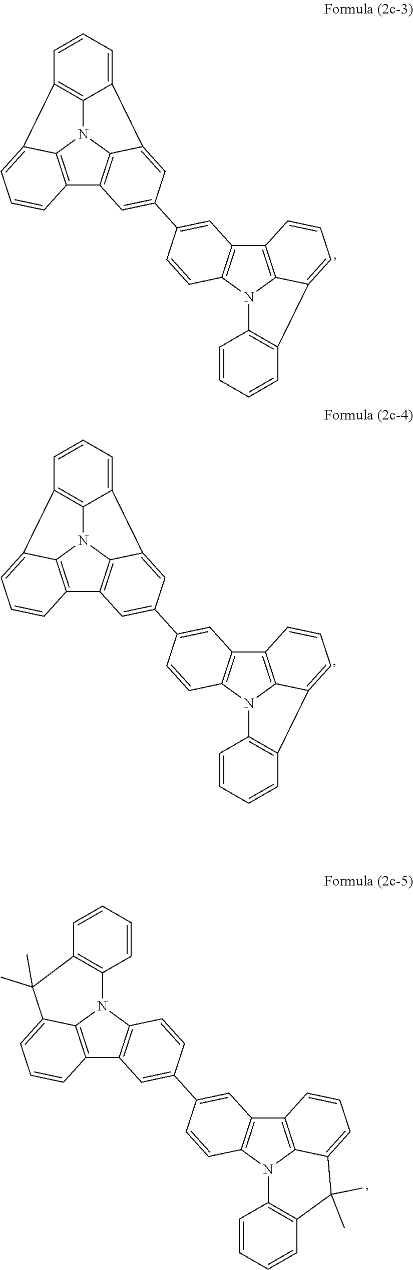

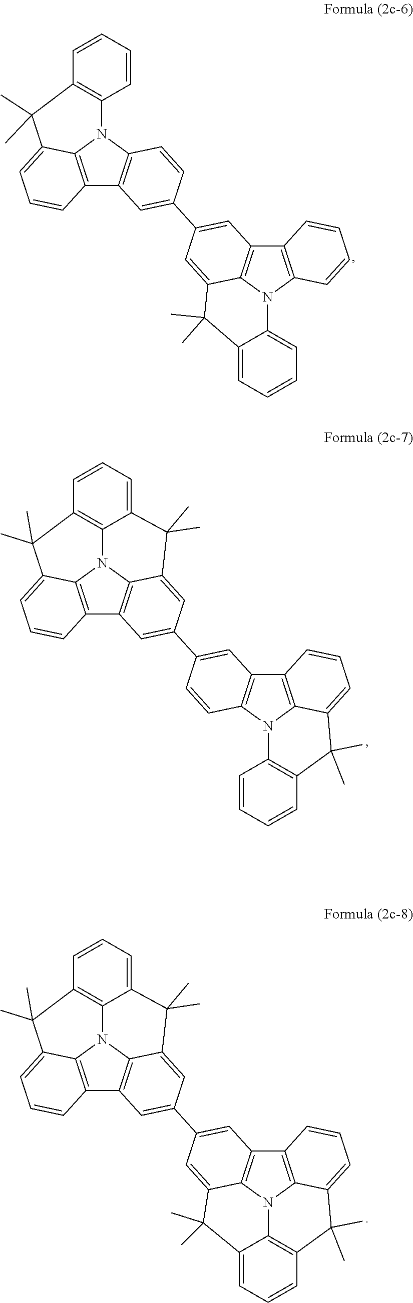

Preferred compounds of the formula (2c) also include the compounds H9, H11, H12, H13, H14, H15, H19 and H20 as described hereinafter.

The invention accordingly further provides an organic electroluminescent device as described or described as preferable above, wherein the at least one compound of the formula (2) corresponds to a compound of the formulae (2c), (2c-1), (2c-2), (2c-3), (2c-4, (2c-5), (2c-6), (2c-7) or (2c-8).

In a preferred embodiment of the compounds of the formulae (2), (2a), (2b), (2b-1), (2b-2), (2b-3), (2b-4, (2b-5) or (2b-6) the carbazole and the bridged carbazole are bonded to one another in the 3-position in each case.

In a preferred embodiment of the compounds of the formula (2c) the two bridged carbazoles are bonded to one another in the 3-position in each case.

Examples of suitable host materials of the formulae (2), (2a), (2b), (2b-1), (2b-2), (2b-3), (2b-4, (2b-5) and (2c), that are selected in accordance with the invention and are preferably used in combination with at least one compound of the formula (1) in the electroluminescent device of the invention are the structures given below in table 2.

TABLE 2

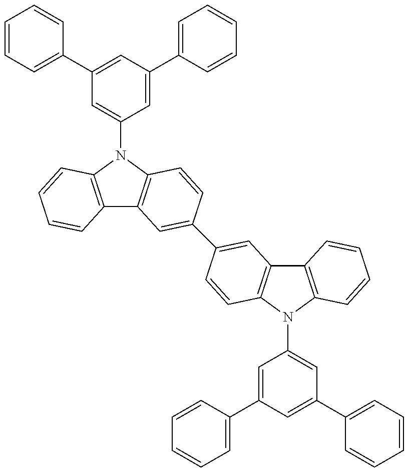 [SMILES: c1ccc(-c2cc(-c3ccccc3)cc(-n3c4ccccc4c4cc(-c5ccc6c(c5)c5ccccc5n6-c5cc(-c6ccccc6)cc(-c6ccccc6)c5)ccc43)c2)cc1]

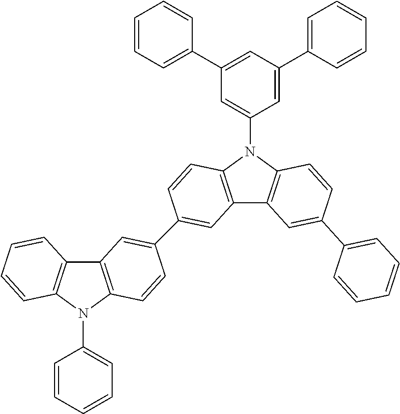 [SMILES: c1ccc(-c2cc(-c3ccccc3)cc(-n3c4ccc(-c5ccccc5)cc4c4cc(-c5ccc6c(c5)c5ccccc5n6-c5ccccc5)ccc43)c2)cc1]

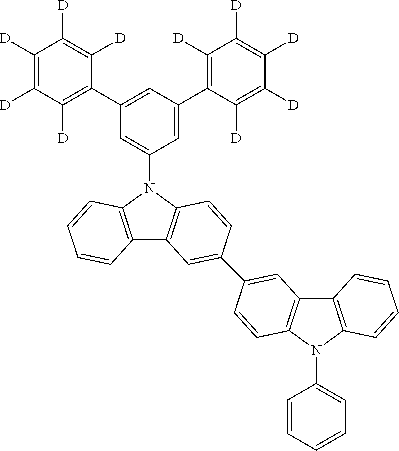 [SMILES: [2H]c1c([2H])c([2H])c(-c2cc(-c3c([2H])c([2H])c([2H])c([2H])c3[2H])cc(-n3c4ccccc4c4cc(-c5ccc6c(c5)c5ccccc5n6-c5ccccc5)ccc43)c2)c([2H])c1[2H]]

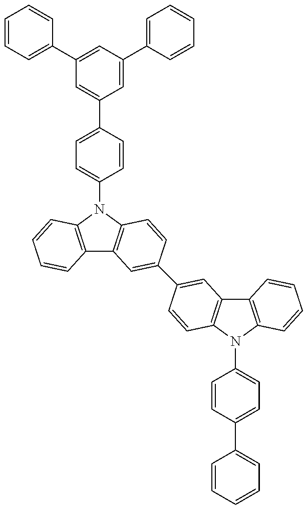 [SMILES: c1ccc(-c2ccc(-n3c4ccccc4c4cc(-c5ccc6c(c5)c5ccccc5n6-c5ccc(-c6cc(-c7ccccc7)cc(-c7ccccc7)c6)cc5)ccc43)cc2)cc1]

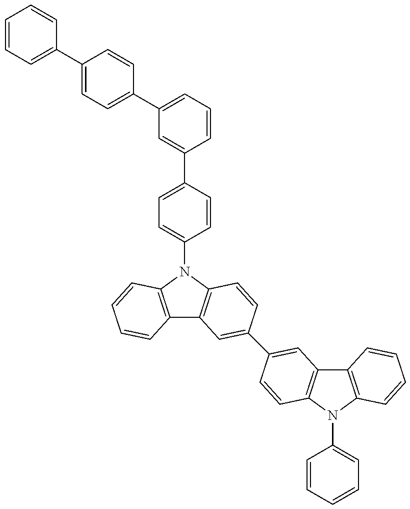 [SMILES: c1ccc(-c2ccc(-c3cccc(-c4ccc(-n5c6ccccc6c6cc(-c7ccc8c(c7)c7ccccc7n8-c7ccccc7)ccc65)cc4)c3)cc2)cc1]

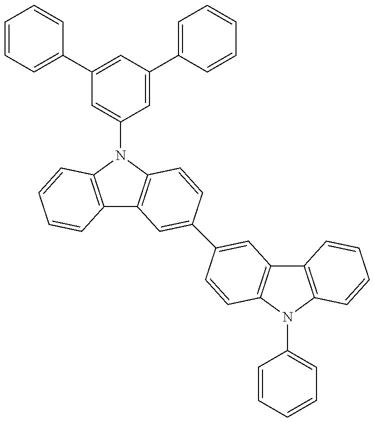 [SMILES: c1ccc(-c2cc(-c3ccccc3)cc(-n3c4ccccc4c4cc(-c5ccc6c(c5)c5ccccc5n6-c5ccccc5)ccc43)c2)cc1]

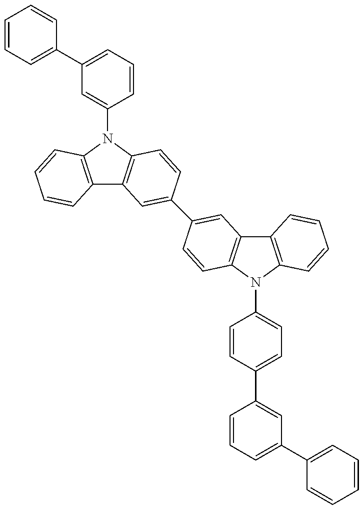 [SMILES: c1ccc(-c2cccc(-c3ccc(-n4c5ccccc5c5cc(-c6ccc7c(c6)c6ccccc6n7-c6cccc(-c7ccccc7)c6)ccc54)cc3)c2)cc1]

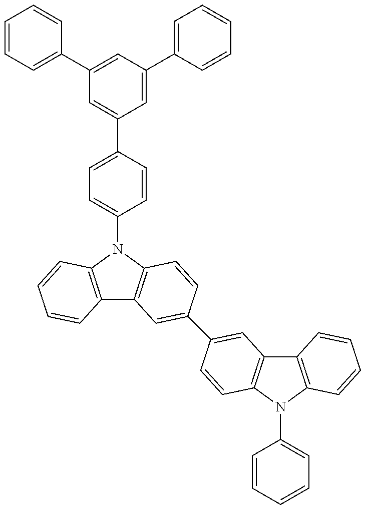 [SMILES: c1ccc(-c2cc(-c3ccccc3)cc(-c3ccc(-n4c5ccccc5c5cc(-c6ccc7c(c6)c6ccccc6n7-c6ccccc6)ccc54)cc3)c2)cc1]

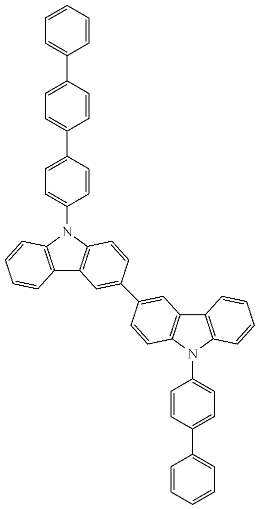 [SMILES: c1ccc(-c2ccc(-c3ccc(-n4c5ccccc5c5cc(-c6ccc7c(c6)c6ccccc6n7-c6ccc(-c7ccccc7)cc6)ccc54)cc3)cc2)cc1]

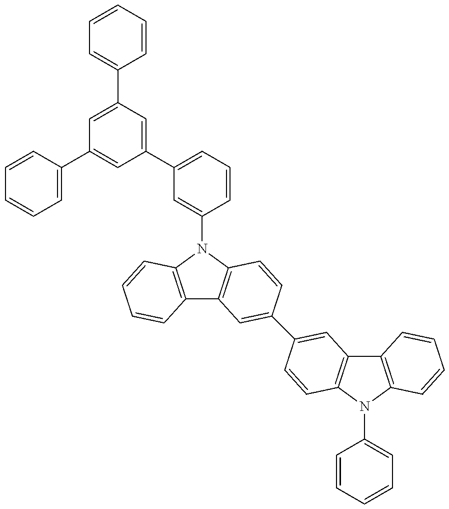 [SMILES: c1ccc(-c2cc(-c3ccccc3)cc(-c3cccc(-n4c5ccccc5c5cc(-c6ccc7c(c6)c6ccccc6n7-c6ccccc6)ccc54)c3)c2)cc1]

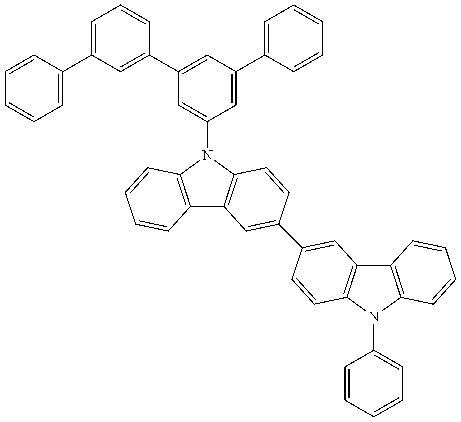 [SMILES: c1ccc(-c2cccc(-c3cc(-c4ccccc4)cc(-n4c5ccccc5c5cc(-c6ccc7c(c6)c6ccccc6n7-c6ccccc6)ccc54)c3)c2)cc1]

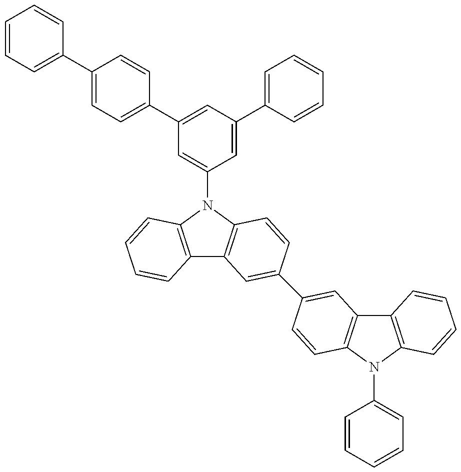 [SMILES: c1ccc(-c2ccc(-c3cc(-c4ccccc4)cc(-n4c5ccccc5c5cc(-c6ccc7c(c6)c6ccccc6n7-c6ccccc6)ccc54)c3)cc2)cc1]

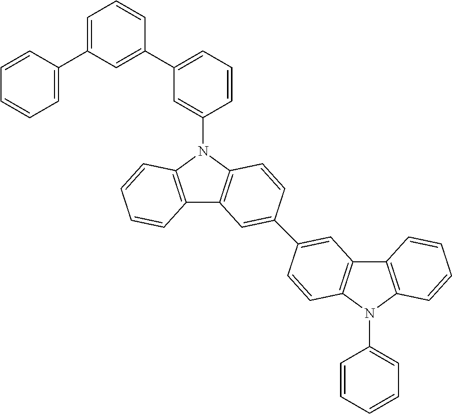 [SMILES: c1ccc(-c2cccc(-c3cccc(-n4c5ccccc5c5cc(-c6ccc7c(c6)c6ccccc6n7-c6ccccc6)ccc54)c3)c2)cc1]

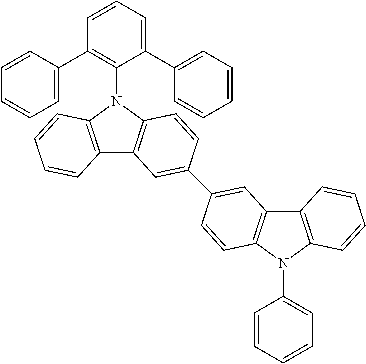 [SMILES: c1ccc(-c2cccc(-c3ccccc3)c2-n2c3ccccc3c3cc(-c4ccc5c(c4)c4ccccc4n5-c4ccccc4)ccc32)cc1]

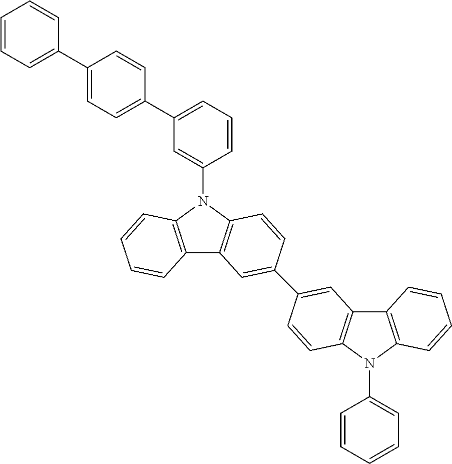 [SMILES: c1ccc(-c2ccc(-c3cccc(-n4c5ccccc5c5cc(-c6ccc7c(c6)c6ccccc6n7-c6ccccc6)ccc54)c3)cc2)cc1]

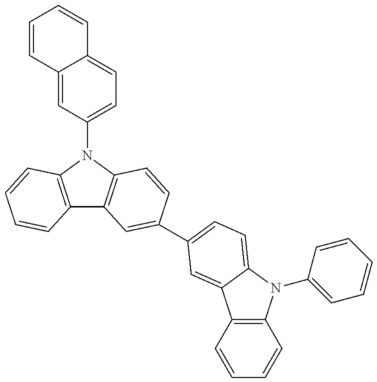 [SMILES: c1ccc(-n2c3ccccc3c3cc(-c4ccc5c(c4)c4ccccc4n5-c4ccc5ccccc5c4)ccc32)cc1]

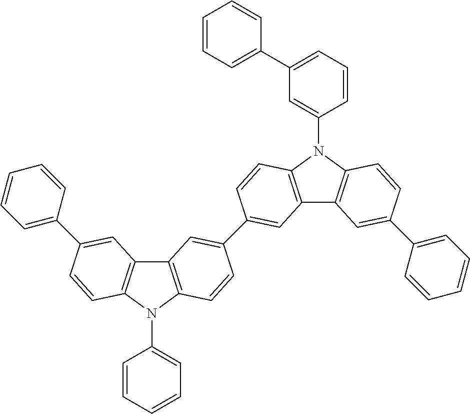 [SMILES: c1ccc(-c2cccc(-n3c4ccc(-c5ccccc5)cc4c4cc(-c5ccc6c(c5)c5cc(-c7ccccc7)ccc5n6-c5ccccc5)ccc43)c2)cc1]

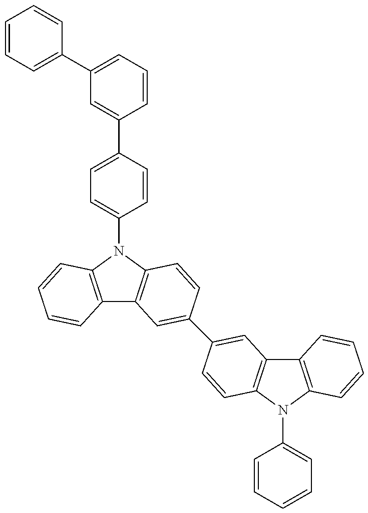 [SMILES: c1ccc(-c2cccc(-c3ccc(-n4c5ccccc5c5cc(-c6ccc7c(c6)c6ccccc6n7-c6ccccc6)ccc54)cc3)c2)cc1]

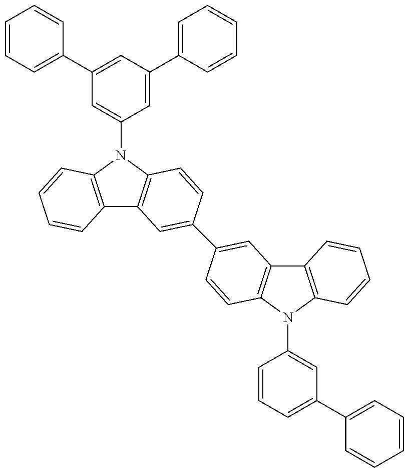 [SMILES: c1ccc(-c2cccc(-n3c4ccccc4c4cc(-c5ccc6c(c5)c5ccccc5n6-c5cc(-c6ccccc6)cc(-c6ccccc6)c5)ccc43)c2)cc1]

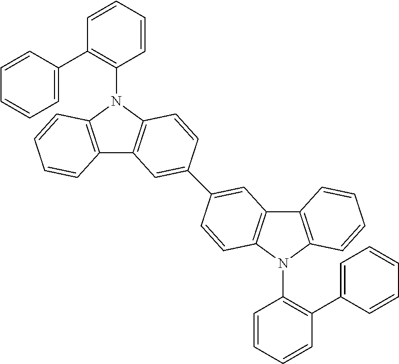 [SMILES: c1ccc(-c2ccccc2-n2c3ccccc3c3cc(-c4ccc5c(c4)c4ccccc4n5-c4ccccc4-c4ccccc4)ccc32)cc1]

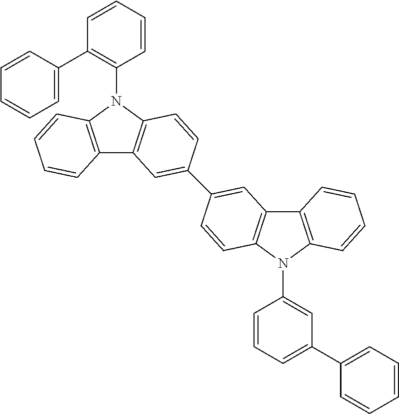 [SMILES: c1ccc(-c2cccc(-n3c4ccccc4c4cc(-c5ccc6c(c5)c5ccccc5n6-c5ccccc5-c5ccccc5)ccc43)c2)cc1]

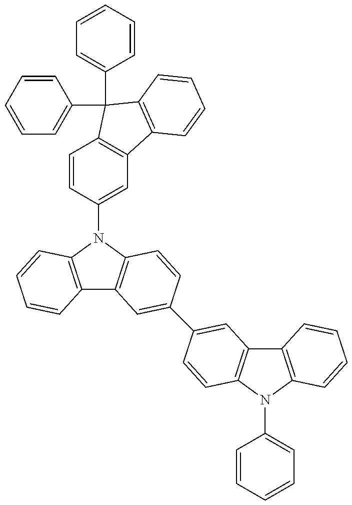 [SMILES: c1ccc(-n2c3ccccc3c3cc(-c4ccc5c(c4)c4ccccc4n5-c4ccc5c(c4)-c4ccccc4C5(c4ccccc4)c4ccccc4)ccc32)cc1]

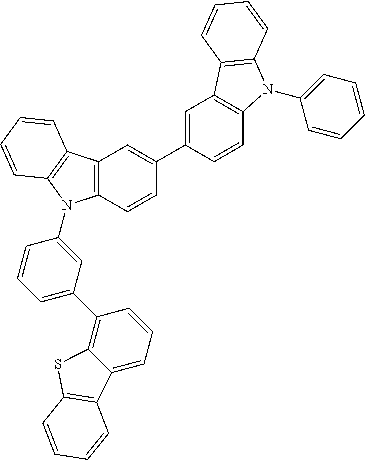 [SMILES: c1ccc(-n2c3ccccc3c3cc(-c4ccc5c(c4)c4ccccc4n5-c4cccc(-c5cccc6c5sc5ccccc56)c4)ccc32)cc1]

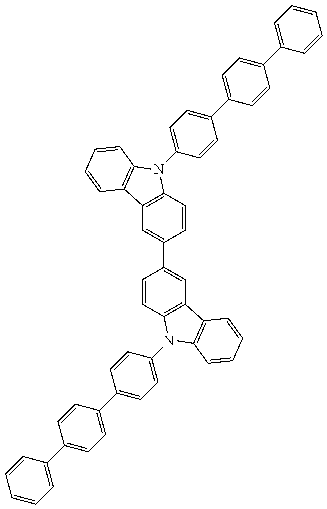 [SMILES: c1ccc(-c2ccc(-c3ccc(-n4c5ccccc5c5cc(-c6ccc7c(c6)c6ccccc6n7-c6ccc(-c7ccc(-c8ccccc8)cc7)cc6)ccc54)cc3)cc2)cc1]

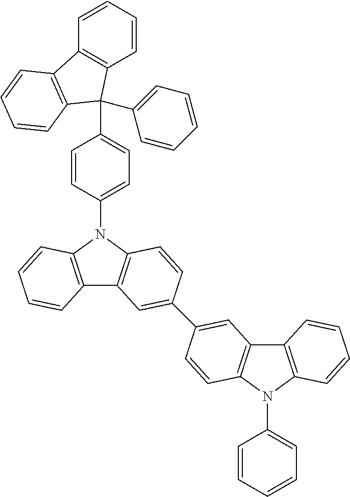 [SMILES: c1ccc(-n2c3ccccc3c3cc(-c4ccc5c(c4)c4ccccc4n5-c4ccc(C5(c6ccccc6)c6ccccc6-c6ccccc65)cc4)ccc32)cc1]

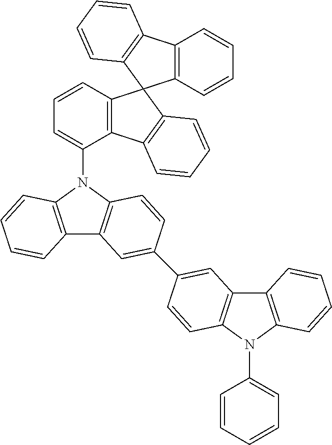 [SMILES: c1ccc(-n2c3ccccc3c3cc(-c4ccc5c(c4)c4ccccc4n5-c4cccc5c4-c4ccccc4C54c5ccccc5-c5ccccc54)ccc32)cc1]

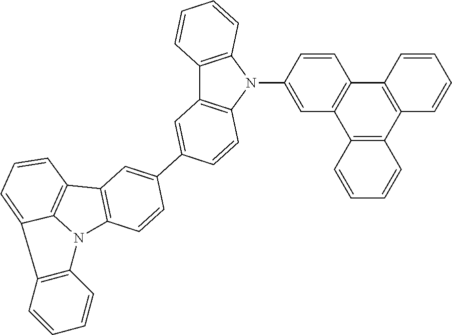 [SMILES: c1ccc2c(c1)c1ccccc1c1cc(-n3c4ccccc4c4cc(-c5ccc6c(c5)c5cccc7c8ccccc8n6c75)ccc43)ccc21]

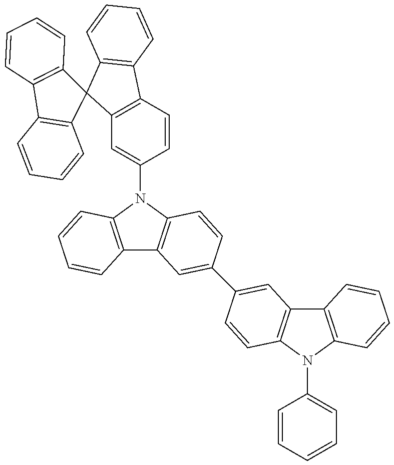 [SMILES: c1ccc(-n2c3ccccc3c3cc(-c4ccc5c(c4)c4ccccc4n5-c4ccc5c(c4)C4(c6ccccc6-c6ccccc64)c4ccccc4-5)ccc32)cc1]

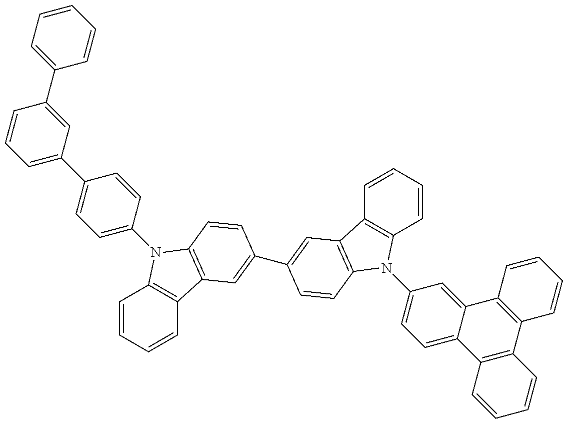 [SMILES: c1ccc(-c2cccc(-c3ccc(-n4c5ccccc5c5cc(-c6ccc7c(c6)c6ccccc6n7-c6ccc7c8ccccc8c8ccccc8c7c6)ccc54)cc3)c2)cc1]

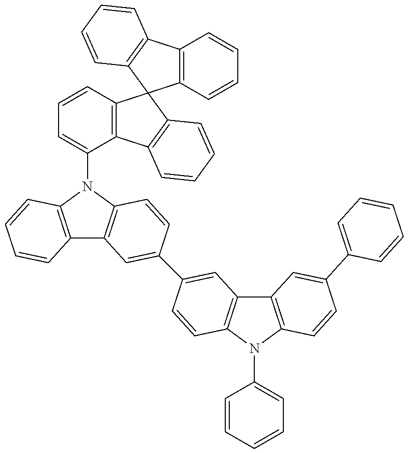 [SMILES: c1ccc(-c2ccc3c(c2)c2cc(-c4ccc5c(c4)c4ccccc4n5-c4cccc5c4-c4ccccc4C54c5ccccc5-c5ccccc54)ccc2n3-c2ccccc2)cc1]

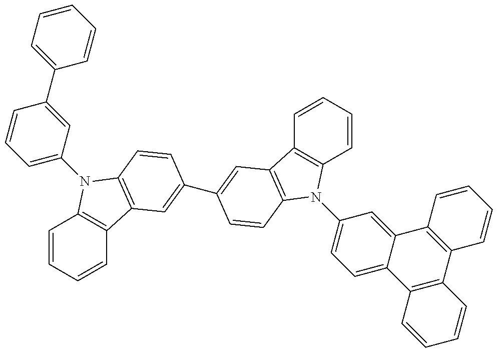 [SMILES: c1ccc(-c2cccc(-n3c4ccccc4c4cc(-c5ccc6c(c5)c5ccccc5n6-c5ccc6c7ccccc7c7ccccc7c6c5)ccc43)c2)cc1]

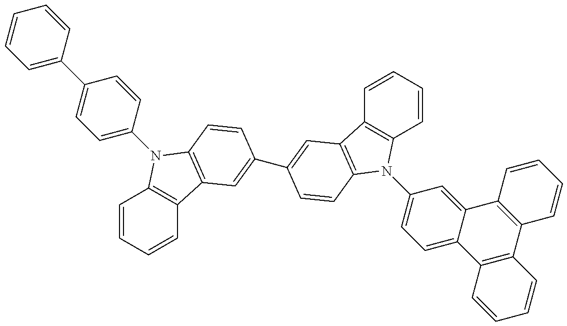 [SMILES: c1ccc(-c2ccc(-n3c4ccccc4c4cc(-c5ccc6c(c5)c5ccccc5n6-c5ccc6c7ccccc7c7ccccc7c6c5)ccc43)cc2)cc1]

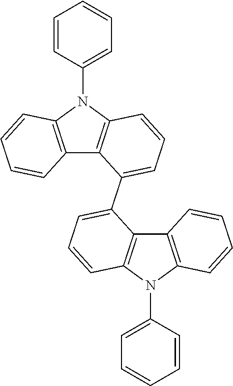 [SMILES: c1ccc(-n2c3ccccc3c3c(-c4cccc5c4c4ccccc4n5-c4ccccc4)cccc32)cc1]

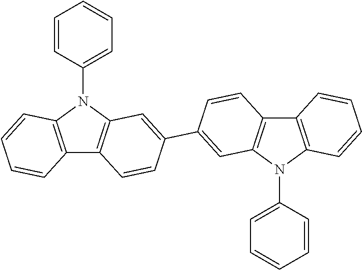 [SMILES: c1ccc(-n2c3ccccc3c3ccc(-c4ccc5c6ccccc6n(-c6ccccc6)c5c4)cc32)cc1]

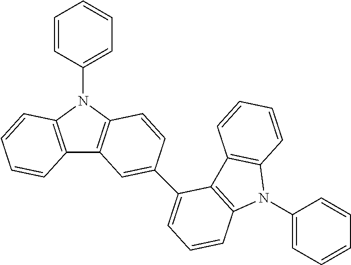 [SMILES: c1ccc(-n2c3ccccc3c3cc(-c4cccc5c4c4ccccc4n5-c4ccccc4)ccc32)cc1]

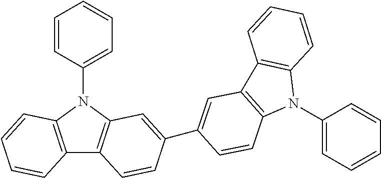 [SMILES: c1ccc(-n2c3ccccc3c3cc(-c4ccc5c6ccccc6n(-c6ccccc6)c5c4)ccc32)cc1]

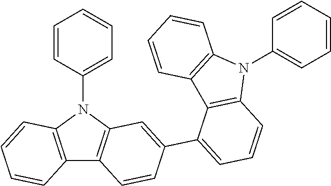 [SMILES: c1ccc(-n2c3ccccc3c3ccc(-c4cccc5c4c4ccccc4n5-c4ccccc4)cc32)cc1]

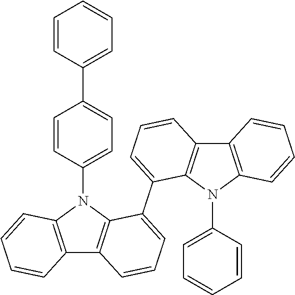 [SMILES: c1ccc(-c2ccc(-n3c4ccccc4c4cccc(-c5cccc6c7ccccc7n(-c7ccccc7)c56)c43)cc2)cc1]

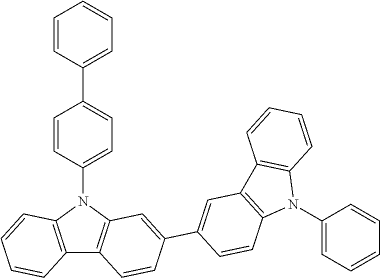 [SMILES: c1ccc(-c2ccc(-n3c4ccccc4c4ccc(-c5ccc6c(c5)c5ccccc5n6-c5ccccc5)cc43)cc2)cc1]

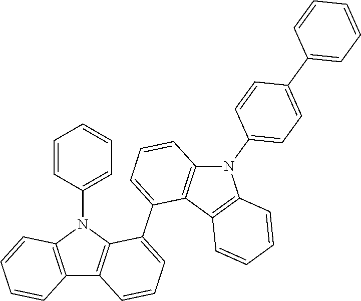 [SMILES: c1ccc(-c2ccc(-n3c4ccccc4c4c(-c5cccc6c7ccccc7n(-c7ccccc7)c56)cccc43)cc2)cc1]

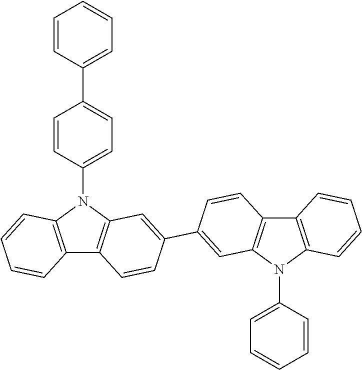 [SMILES: c1ccc(-c2ccc(-n3c4ccccc4c4ccc(-c5ccc6c7ccccc7n(-c7ccccc7)c6c5)cc43)cc2)cc1]

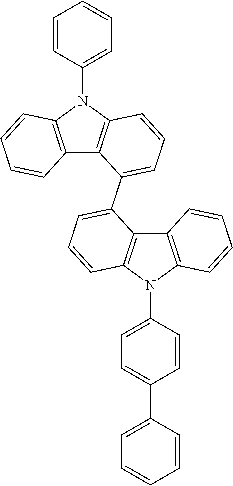 [SMILES: c1ccc(-c2ccc(-n3c4ccccc4c4c(-c5cccc6c5c5ccccc5n6-c5ccccc5)cccc43)cc2)cc1]

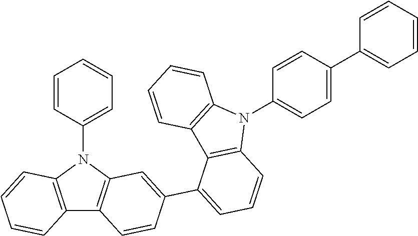 [SMILES: c1ccc(-c2ccc(-n3c4ccccc4c4c(-c5ccc6c7ccccc7n(-c7ccccc7)c6c5)cccc43)cc2)cc1]

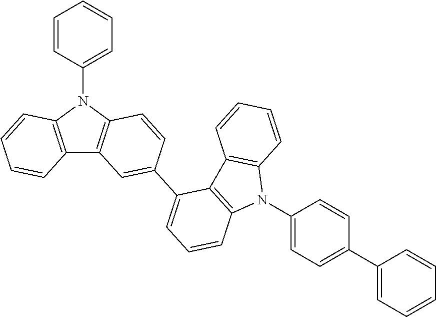 [SMILES: c1ccc(-c2ccc(-n3c4ccccc4c4c(-c5ccc6c(c5)c5ccccc5n6-c5ccccc5)cccc43)cc2)cc1]

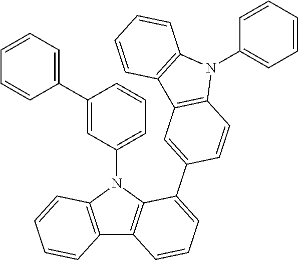 [SMILES: c1ccc(-c2cccc(-n3c4ccccc4c4cccc(-c5ccc6c(c5)c5ccccc5n6-c5ccccc5)c43)c2)cc1]

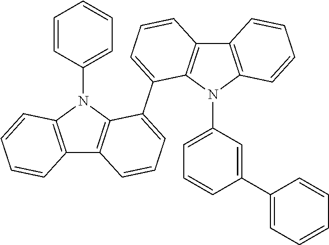 [SMILES: c1ccc(-c2cccc(-n3c4ccccc4c4cccc(-c5cccc6c7ccccc7n(-c7ccccc7)c56)c43)c2)cc1]

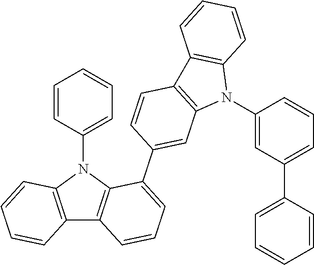 [SMILES: c1ccc(-c2cccc(-n3c4ccccc4c4ccc(-c5cccc6c7ccccc7n(-c7ccccc7)c56)cc43)c2)cc1]

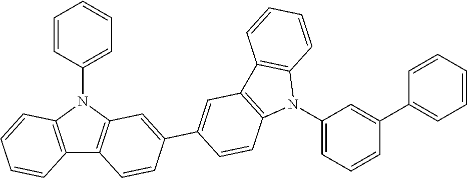 [SMILES: c1ccc(-c2cccc(-n3c4ccccc4c4cc(-c5ccc6c7ccccc7n(-c7ccccc7)c6c5)ccc43)c2)cc1]

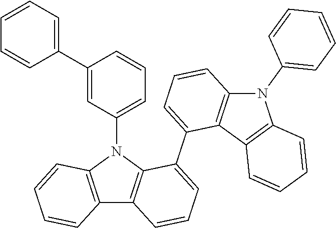 [SMILES: c1ccc(-c2cccc(-n3c4ccccc4c4cccc(-c5cccc6c5c5ccccc5n6-c5ccccc5)c43)c2)cc1]

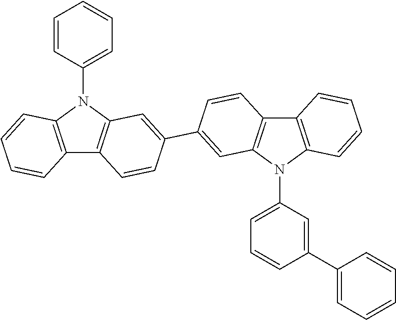 [SMILES: c1ccc(-c2cccc(-n3c4ccccc4c4ccc(-c5ccc6c7ccccc7n(-c7ccccc7)c6c5)cc43)c2)cc1]

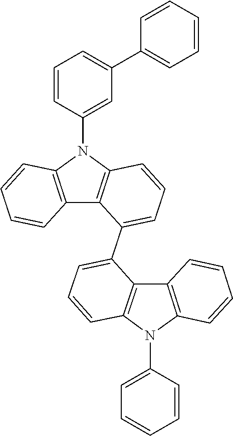 [SMILES: c1ccc(-c2cccc(-n3c4ccccc4c4c(-c5cccc6c5c5ccccc5n6-c5ccccc5)cccc43)c2)cc1]

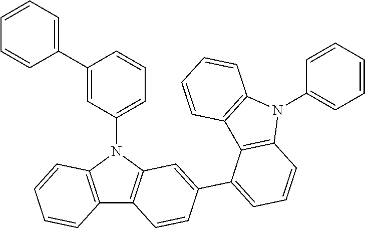 [SMILES: c1ccc(-c2cccc(-n3c4ccccc4c4ccc(-c5cccc6c5c5ccccc5n6-c5ccccc5)cc43)c2)cc1]

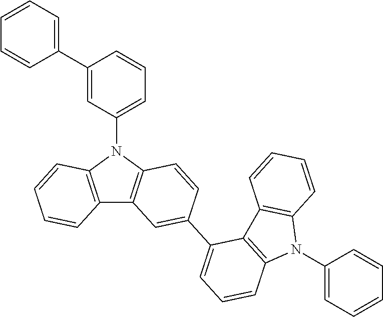 [SMILES: c1ccc(-c2cccc(-n3c4ccccc4c4cc(-c5cccc6c5c5ccccc5n6-c5ccccc5)ccc43)c2)cc1]

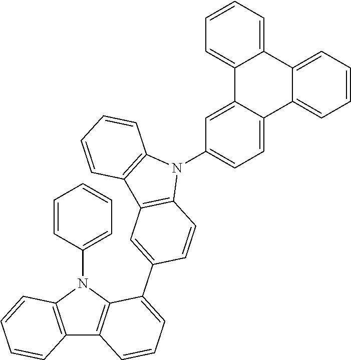 [SMILES: c1ccc(-n2c3ccccc3c3cccc(-c4ccc5c(c4)c4ccccc4n5-c4ccc5c6ccccc6c6ccccc6c5c4)c32)cc1]

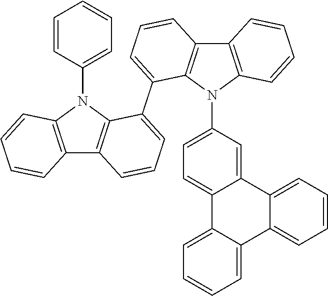 [SMILES: c1ccc(-n2c3ccccc3c3cccc(-c4cccc5c6ccccc6n(-c6ccc7c8ccccc8c8ccccc8c7c6)c45)c32)cc1]

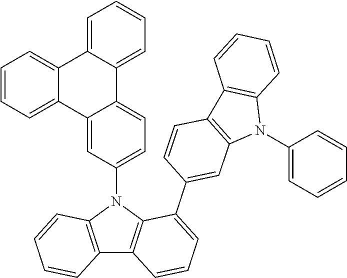 [SMILES: c1ccc(-n2c3ccccc3c3ccc(-c4cccc5c6ccccc6n(-c6ccc7c8ccccc8c8ccccc8c7c6)c45)cc32)cc1]

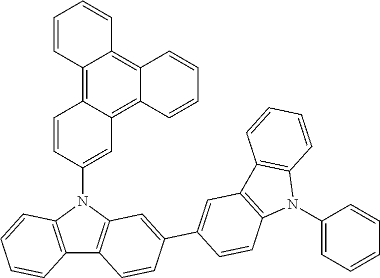 [SMILES: c1ccc(-n2c3ccccc3c3cc(-c4ccc5c6ccccc6n(-c6ccc7c8ccccc8c8ccccc8c7c6)c5c4)ccc32)cc1]

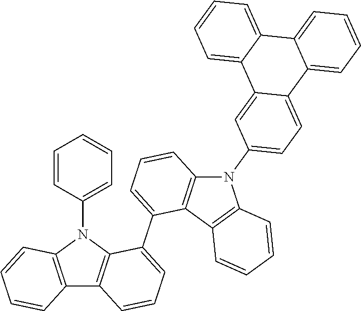 [SMILES: c1ccc(-n2c3ccccc3c3cccc(-c4cccc5c4c4ccccc4n5-c4ccc5c6ccccc6c6ccccc6c5c4)c32)cc1]

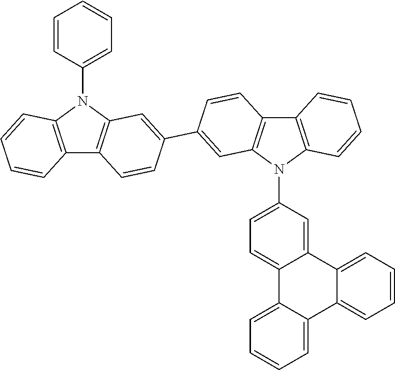 [SMILES: c1ccc(-n2c3ccccc3c3ccc(-c4ccc5c6ccccc6n(-c6ccc7c8ccccc8c8ccccc8c7c6)c5c4)cc32)cc1]

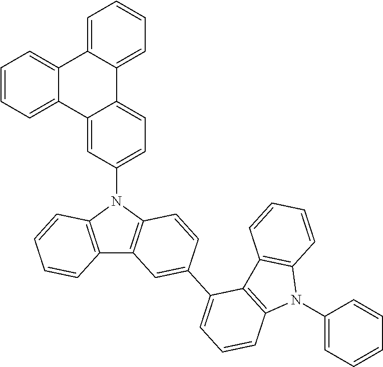 [SMILES: c1ccc(-n2c3ccccc3c3c(-c4ccc5c(c4)c4ccccc4n5-c4ccc5c6ccccc6c6ccccc6c5c4)cccc32)cc1]

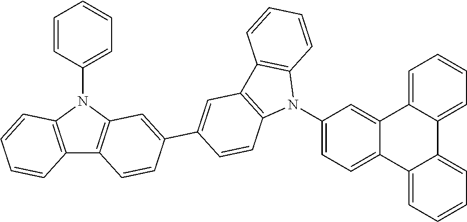 [SMILES: c1ccc(-n2c3ccccc3c3ccc(-c4ccc5c(c4)c4ccccc4n5-c4ccc5c6ccccc6c6ccccc6c5c4)cc32)cc1]

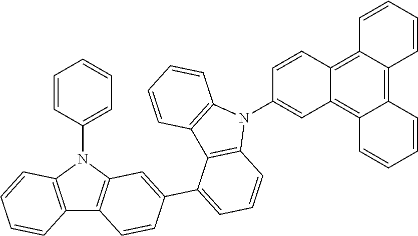 [SMILES: c1ccc(-n2c3ccccc3c3ccc(-c4cccc5c4c4ccccc4n5-c4ccc5c6ccccc6c6ccccc6c5c4)cc32)cc1]

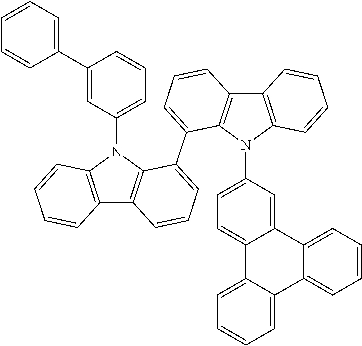 [SMILES: c1ccc(-c2cccc(-n3c4ccccc4c4cccc(-c5cccc6c7ccccc7n(-c7ccc8c9ccccc9c9ccccc9c8c7)c56)c43)c2)cc1]

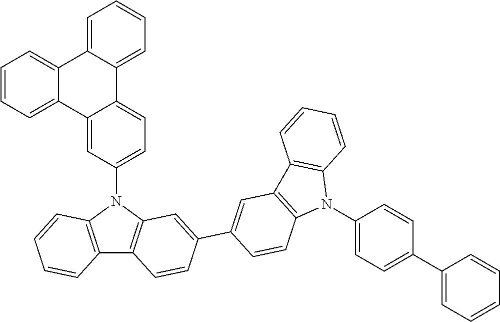 [SMILES: c1ccc(-c2ccc(-n3c4ccccc4c4cc(-c5ccc6c7ccccc7n(-c7ccc8c9ccccc9c9ccccc9c8c7)c6c5)ccc43)cc2)cc1]

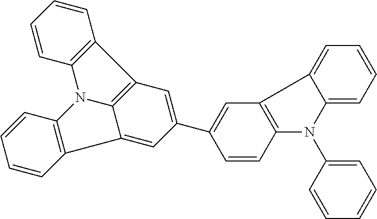 [SMILES: c1ccc(-n2c3ccccc3c3cc(-c4cc5c6ccccc6n6c7ccccc7c(c4)c56)ccc32)cc1]

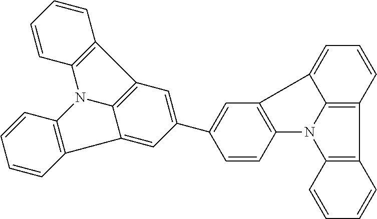 [SMILES: c1ccc2c(c1)c1cccc3c4cc(-c5cc6c7ccccc7n7c8ccccc8c(c5)c67)ccc4n2c13]

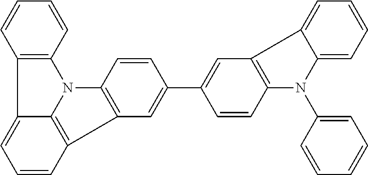 [SMILES: c1ccc(-n2c3ccccc3c3cc(-c4ccc5c(c4)c4cccc6c7ccccc7n5c64)ccc32)cc1]

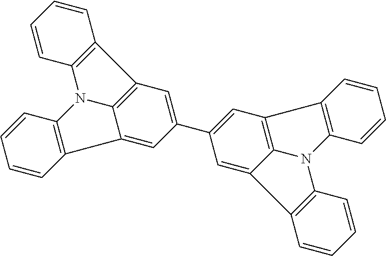 [SMILES: c1ccc2c(c1)c1cc(-c3cc4c5ccccc5n5c6ccccc6c(c3)c45)cc3c4ccccc4n2c13]

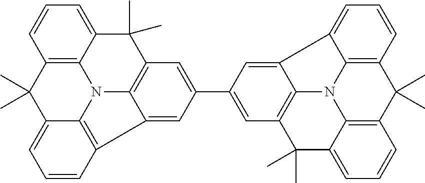

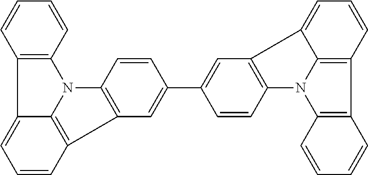 [SMILES: c1ccc2c(c1)c1cccc3c4cc(-c5ccc6c(c5)c5cccc7c8ccccc8n6c75)ccc4n2c13]

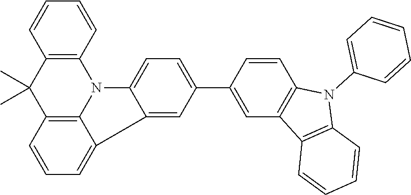 [SMILES: CC1(C)c2ccccc2-n2c3ccc(-c4ccc5c(c4)c4ccccc4n5-c4ccccc4)cc3c3cccc1c32]

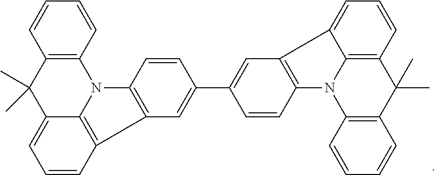

Particularly suitable compounds of the formula (2) that are preferably used in combination with at least one compound of the formula (1) in the electroluminescent device of the invention are the compounds H1 to H27:

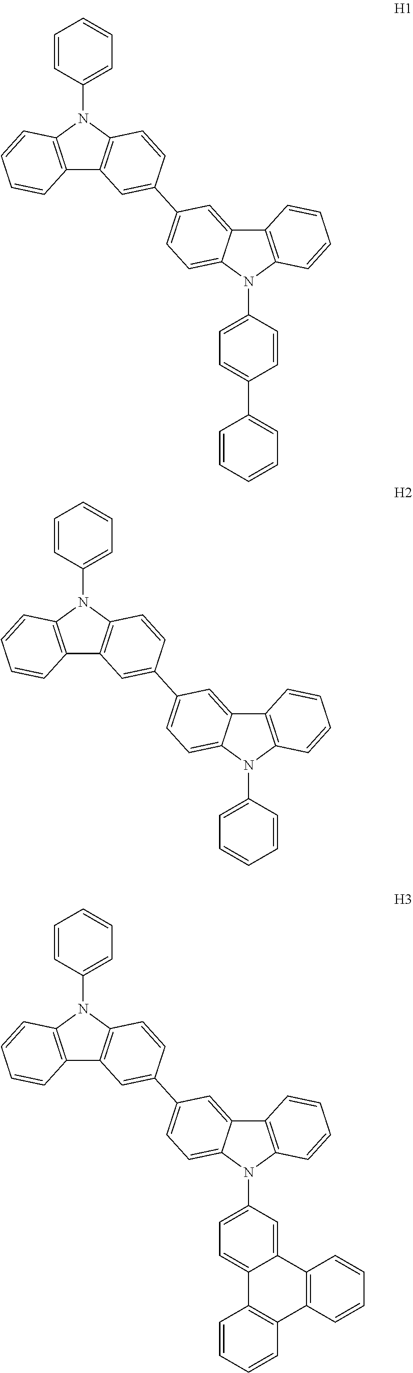 [SMILES: c1ccc(-c2ccc(-n3c4ccccc4c4cc(-c5ccc6c(c5)c5ccccc5n6-c5ccccc5)ccc43)cc2)cc1 ; c1ccc(-n2c3ccccc3c3cc(-c4ccc5c(c4)c4ccccc4n5-c4ccccc4)ccc32)cc1 ; c1ccc(-n2c3ccccc3c3cc(-c4ccc5c(c4)c4ccccc4n5-c4ccc5c6ccccc6c6ccccc6c5c4)ccc32)cc1]

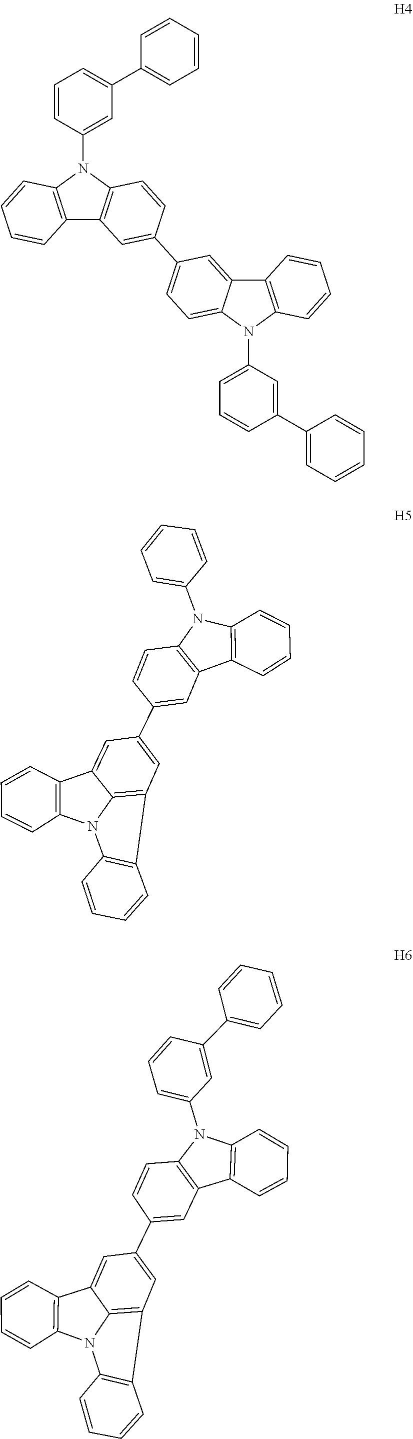 [SMILES: c1ccc(-c2cccc(-n3c4ccccc4c4cc(-c5ccc6c(c5)c5ccccc5n6-c5cccc(-c6ccccc6)c5)ccc43)c2)cc1 ; c1ccc(-n2c3ccccc3c3cc(-c4cc5c6ccccc6n6c7ccccc7c(c4)c56)ccc32)cc1 ; c1ccc(-c2cccc(-n3c4ccccc4c4cc(-c5cc6c7ccccc7n7c8ccccc8c(c5)c67)ccc43)c2)cc1]

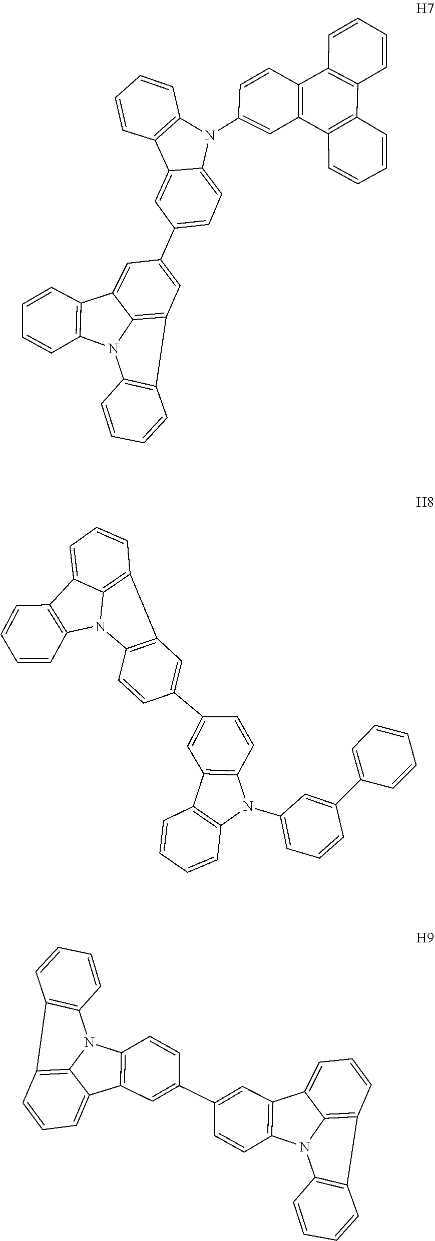 [SMILES: c1ccc2c(c1)c1ccccc1c1cc(-n3c4ccccc4c4cc(-c5cc6c7ccccc7n7c8ccccc8c(c5)c67)ccc43)ccc21 ; c1ccc(-c2cccc(-n3c4ccccc4c4cc(-c5ccc6c(c5)c5cccc7c8ccccc8n6c75)ccc43)c2)cc1 ; c1ccc2c(c1)c1cccc3c4cc(-c5ccc6c(c5)c5cccc7c8ccccc8n6c75)ccc4n2c13]

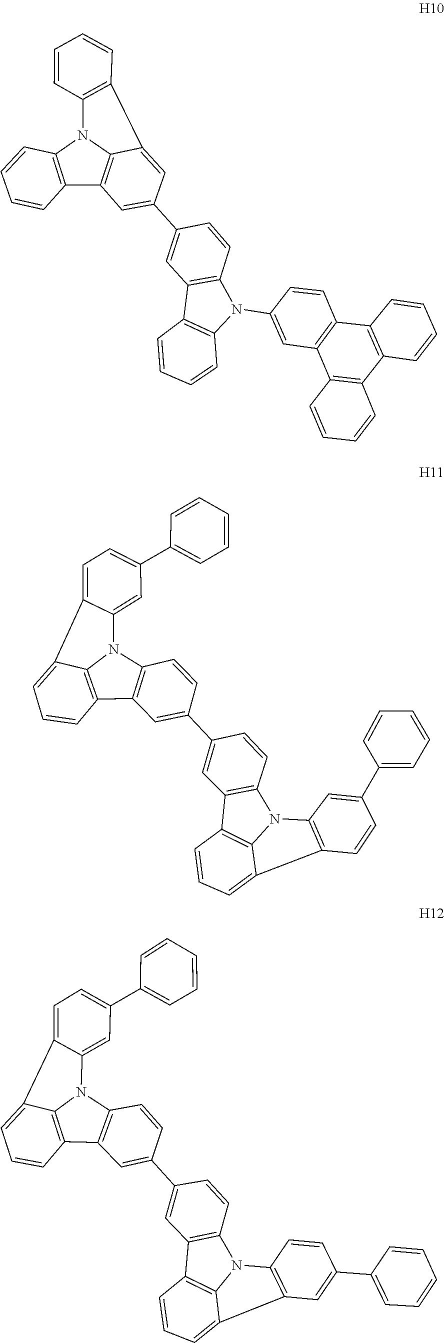 [SMILES: c1ccc2c(c1)c1ccccc1c1cc(-n3c4ccccc4c4cc(-c5cc6c7ccccc7n7c8ccccc8c(c5)c67)ccc43)ccc21 ; c1ccc(-c2ccc3c4cccc5c6cc(-c7ccc8c(c7)c7cccc9c%10ccc(-c%11ccccc%11)cc%10n8c79)ccc6n(c3c2)c54)cc1 ; c1ccc(-c2ccc3c(c2)c2cccc4c5cc(-c6ccc7c(c6)c6cccc8c9ccc(-c%10ccccc%10)cc9n7c68)ccc5n3c24)cc1]

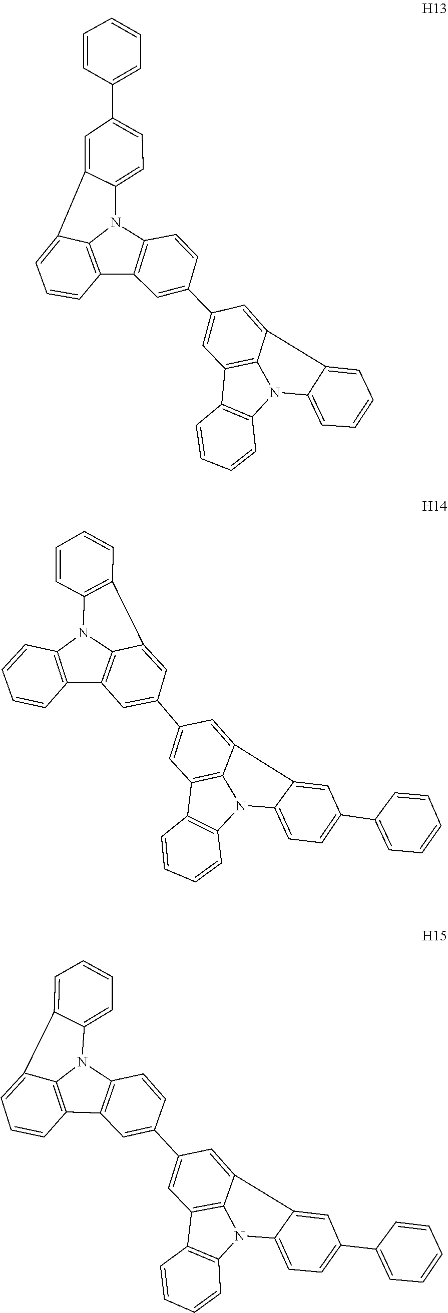 [SMILES: c1ccc(-c2ccc3c(c2)c2cccc4c5cc(-c6cc7c8ccccc8n8c9ccccc9c(c6)c78)ccc5n3c24)cc1 ; c1ccc(-c2ccc3c(c2)c2cc(-c4cc5c6ccccc6n6c7ccccc7c(c4)c56)cc4c5ccccc5n3c42)cc1 ; c1ccc(-c2ccc3c(c2)c2cc(-c4ccc5c(c4)c4cccc6c7ccccc7n5c64)cc4c5ccccc5n3c42)cc1]

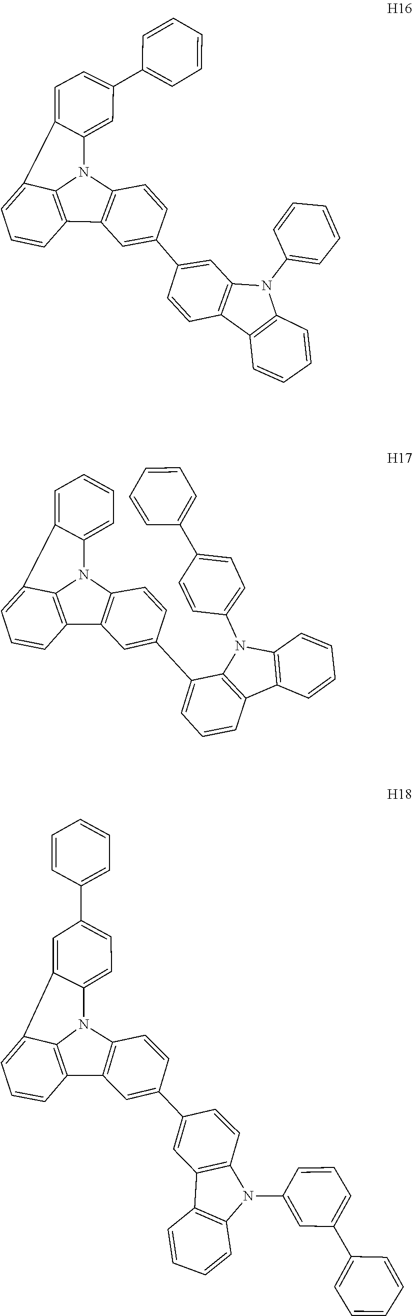 [SMILES: c1ccc(-c2ccc3c4cccc5c6cc(-c7ccc8c9ccccc9n(-c9ccccc9)c8c7)ccc6n(c3c2)c54)cc1 ; c1ccc(-c2ccc(-n3c4ccccc4c4cccc(-c5ccc6c(c5)c5cccc7c8ccccc8n6c75)c43)cc2)cc1 ; c1ccc(-c2cccc(-n3c4ccccc4c4cc(-c5ccc6c(c5)c5cccc7c8cc(-c9ccccc9)ccc8n6c75)ccc43)c2)cc1]

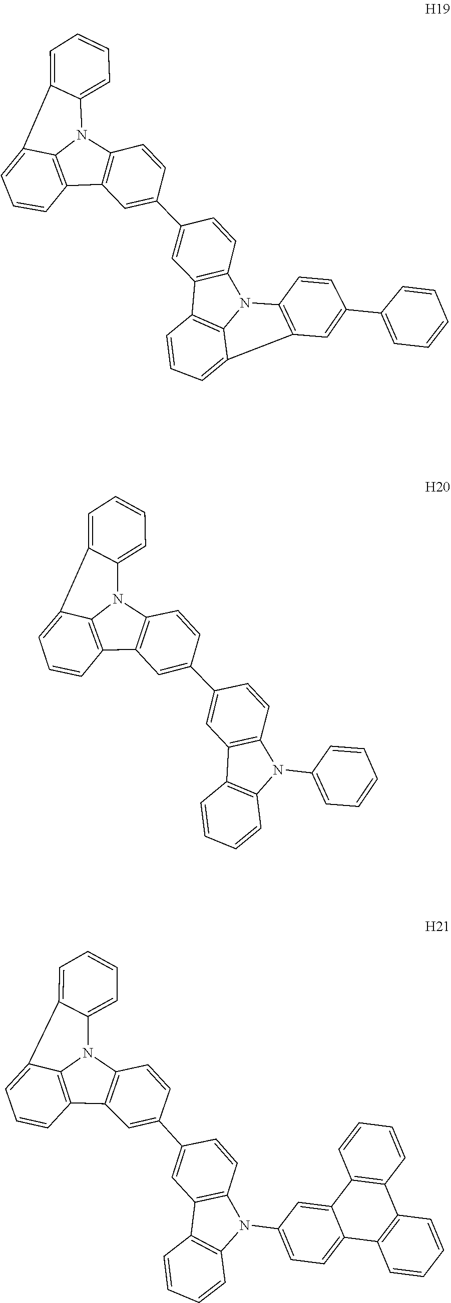 [SMILES: c1ccc(-c2ccc3c(c2)c2cccc4c5cc(-c6ccc7c(c6)c6cccc8c9ccccc9n7c86)ccc5n3c24)cc1 ; c1ccc(-n2c3ccccc3c3cc(-c4ccc5c(c4)c4cccc6c7ccccc7n5c64)ccc32)cc1 ; c1ccc2c(c1)c1ccccc1c1cc(-n3c4ccccc4c4cc(-c5ccc6c(c5)c5cccc7c8ccccc8n6c75)ccc43)ccc21]

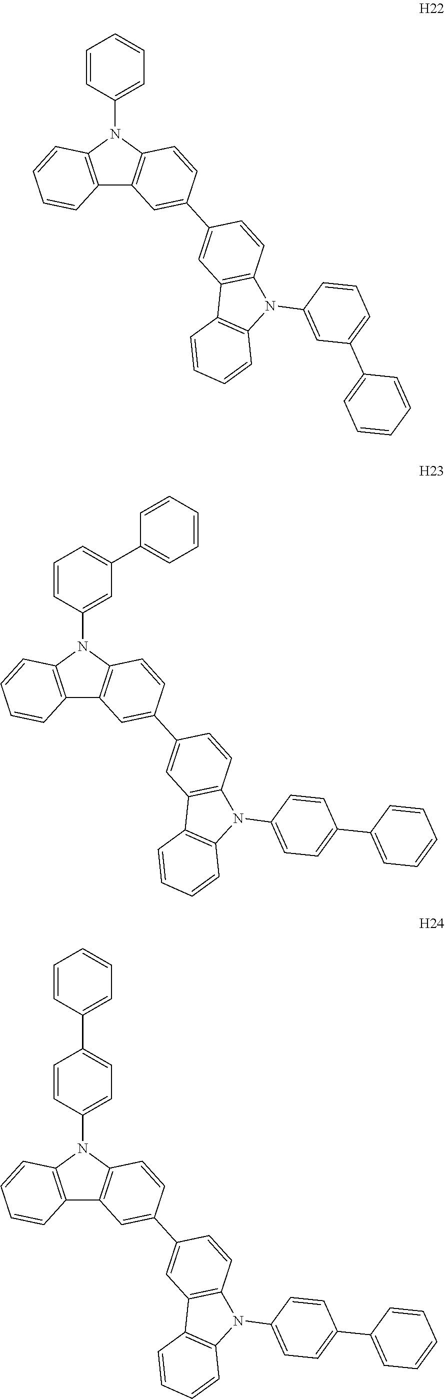 [SMILES: c1ccc(-c2cccc(-n3c4ccccc4c4cc(-c5ccc6c(c5)c5ccccc5n6-c5ccccc5)ccc43)c2)cc1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccc(-c6ccccc6)cc5)ccc43)cc2)cc1]

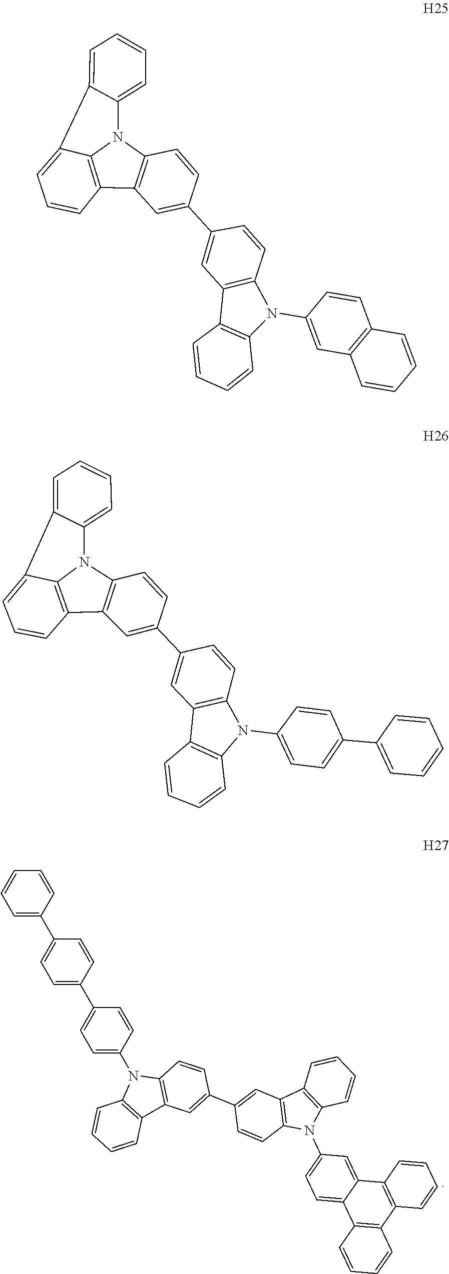 [SMILES: c1ccc2cc(-n3c4ccccc4c4cc(-c5ccc6c(c5)c5cccc7c8ccccc8n6c75)ccc43)ccc2c1 ; c1ccc(-c2ccc(-n3c4ccccc4c4cc(-c5ccc6c(c5)c5cccc7c8ccccc8n6c75)ccc43)cc2)cc1 ; c1ccc(-c2ccc(-c3ccc(-n4c5ccccc5c5cc(-c6ccc7c(c6)c6ccccc6n7-c6ccc7c8ccccc8c8ccccc8c7c6)ccc54)cc3)cc2)cc1]

The preparation of the compounds of the formula (2) or of the preferred compounds of the formulae (2), (2a), (2b), (2b-1), (2b-2), (2b-3), (2b-4, (2b-5) and (2c), and of the compounds of the table 2 and H1 to H27 is known to those skilled in the art. The compounds may be prepared by synthesis steps known to the person skilled in the art, for example halogenation, preferably bromination, and a subsequent organometallic coupling reaction, for example Suzuki coupling, Heck coupling or Hartwig-Buchwald coupling. Some of the compounds of the formula (2) are commercially available.

The aforementioned host materials of the formula (1) and the embodiments thereof that are described as preferred or the compounds from table 1 and the compounds E1 to E27 can be combined as desired in the device of the invention with the host materials of the formulae (2), (2a), (2b), (2), (2a), (2b), (2b-1), (2b-2), (2b-3), (2b-4, (2b-5), (2c), (2c-1), (2c-2), (2c-3), (2c-4), (2c-5), (2c-6), (2c-7) and (2c-8) mentioned and the embodiments thereof that are described as preferred or the compounds from table 2 or the compounds H1 to H27.

Aforementioned specific combinations of host materials of the formula (1) with host materials of the formula (2) are preferred as described above. Preferred combinations of host materials are likewise described hereinafter.

The invention likewise further provides mixtures comprising at least one compound of the formula (1) and at least one compound of the formula (2),

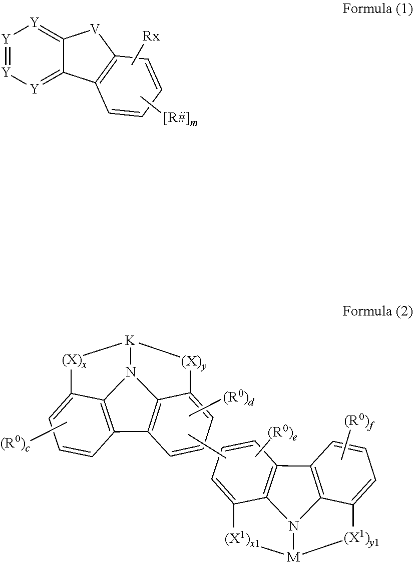

where the symbols and indices used are as follows:
Y is independently at each occurrence N, [L]ₙ-Ar₂ or [L]-R*, wherein precisely two Y are N and are separated by at least one group [L]-R* or L]ₙ-Ar₂;
V is O or S;
Rx is [L]ₙ-Ar₂ or [L]-R*;
R* is a triphenylenyl group which may be substituted with precisely one substituent R^{#}and/or may be substituted with one or more radicals R;
with the proviso that the substituent [L]-R* occurs precisely once in compounds of the formula (1);
n is 0 or 1;
m is 0 or 1;
L is independently at each occurrence identical or different and represents an arylene group having 6 to 20 carbon atoms, a divalent dibenzofuran group or a divalent dibenzothiophene group, each of which may be substituted with one or more radicals R;
Ar₂ is identical or different at each occurrence and represents an aromatic ring system which has 6 to 30 ring atoms and may be substituted by one or more radicals R;
R is identical or different at each occurrence and selected from D, F, CN, a straight-chain alkyl group having 1 to 20 carbon atoms or a branched or cyclic alkyl group having 3 to 20 carbon atoms, wherein one or more nonadjacent CH₂ groups may be replaced by R²C═CR², O or S and wherein one or more hydrogen atoms may be replaced by D, F, or CN;
R #is an aryl group having 6 to 20 carbon atoms which may be substituted with one or more radicals R;
R² is identical or different at each occurrence and selected from the group consisting of H, D, F, CN, a straight-chain alkyl group having 1 to 20 carbon atoms or a branched or cyclic alkyl group having 3 to 20 carbon atoms, wherein one or more nonadjacent CH₂ groups may be replaced by O or S and wherein one or more hydrogen atoms may be replaced by D, F, or CN;
K, M are each independently an unsubstituted or partially or completely deuterated or R*-monosubstituted aromatic ring system having 6 to 40 ring atoms when x and y are 0 and when x₁ and y₁ are 0, or
K, M each independently together with X or X¹ form a heteroaromatic ring system having 14 to 40 ring atoms, as soon as the value of x, x1, y and/or y1 is 1;
x, x1 are each independently at each occurrence 0 or 1;
y, y1 are each independently at each occurrence 0 or 1;
X and X¹ are each independently at each occurrence a bond or C(R⁺)₂;
R⁰ is independently at each occurrence an unsubstituted or partially or completely deuterated aromatic ring system having 6 to 18 ring atoms;
R⁺ is independently at each occurrence a straight-chain or branched alkyl group having 1 to 4 carbon atoms; and
c, d, e and f are independently 0 or 1.

The foregoing concerning the host materials of the formulae (1) and (2) and also the preferred embodiments thereof and the combination thereof are correspondingly also applicable to the mixture according to the invention.

Particularly preferred mixtures of the host materials of the formula (1) with the host materials of the formula (2) for the device of the invention are obtained by combination of the compounds E1 to E27 with the compounds from table 2.

Very particularly preferred mixtures of the host materials of the formula (1) with the host materials of the formula (2) for the device of the invention are obtained by combination of the compounds E1 to E27 with the compounds H1 to H27, as shown hereinafter in table 3.

TABLE 3

| | | | | | | | | |
|---|---|---|---|---|---|---|---|---|
| M1 | E1 | H1 | M2 | E2 | H1 | M3 | E3 | H1 |
| M4 | E4 | H1 | M5 | E5 | H1 | M6 | E6 | H1 |
| M7 | E7 | H1 | M8 | E8 | H1 | M9 | E9 | H1 |
| M10 | E10 | H1 | M11 | E11 | H1 | M12 | E12 | H1 |
| M13 | E13 | H1 | M14 | E14 | H1 | M15 | E15 | H1 |
| M16 | E16 | H1 | M17 | E17 | H1 | M18 | E18 | H1 |
| M19 | E19 | H1 | M20 | E20 | H1 | M21 | E21 | H1 |
| M22 | E22 | H1 | M23 | E23 | H1 | M24 | E24 | H1 |
| M25 | E25 | H1 | M26 | E26 | H1 | M27 | E27 | H1 |
| M28 | E1 | H2 | M29 | E2 | H2 | M30 | E3 | H2 |
| M31 | E4 | H2 | M32 | E5 | H2 | M33 | E6 | H2 |
| M34 | E7 | H2 | M35 | E8 | H2 | M36 | E9 | H2 |
| M37 | E10 | H2 | M38 | E11 | H2 | M39 | E12 | H2 |
| M40 | E13 | H2 | M41 | E14 | H2 | M42 | E15 | H2 |
| M43 | E16 | H2 | M44 | E17 | H2 | M45 | E18 | H2 |
| M46 | E19 | H2 | M47 | E20 | H2 | M48 | E21 | H2 |
| M49 | E22 | H2 | M50 | E23 | H2 | M51 | E24 | H2 |
| M52 | E25 | H2 | M53 | E26 | H2 | M54 | E27 | H2 |
| M55 | E1 | H3 | M56 | E2 | H3 | M57 | E3 | H3 |
| M58 | E4 | H3 | M59 | E5 | H3 | M60 | E6 | H3 |
| M61 | E7 | H3 | M62 | E8 | H3 | M63 | E9 | H3 |
| M64 | E10 | H3 | M65 | E11 | H3 | M66 | E12 | H3 |
| M67 | E13 | H3 | M68 | E14 | H3 | M69 | E15 | H3 |
| M70 | E16 | H3 | M71 | E17 | H3 | M72 | E18 | H3 |
| M73 | E19 | H3 | M74 | E20 | H3 | M75 | E21 | H3 |
| M76 | E22 | H3 | M77 | E23 | H3 | M78 | E24 | H3 |
| M79 | E25 | H3 | M80 | E26 | H3 | M81 | E27 | H3 |
| M82 | E1 | H4 | M83 | E2 | H4 | M84 | E3 | H4 |
| M85 | E4 | H4 | M86 | E5 | H4 | M87 | E6 | H4 |
| M88 | E7 | H4 | M89 | E8 | H4 | M90 | E9 | H4 |
| M91 | E10 | H4 | M92 | E11 | H4 | M93 | E12 | H4 |
| M94 | E13 | H4 | M95 | E14 | H4 | M96 | E15 | H4 |
| M97 | E16 | H4 | M98 | E17 | H4 | M99 | E18 | H4 |
| M100 | E19 | H4 | M101 | E20 | H4 | M102 | E21 | H4 |
| M103 | E22 | H4 | M104 | E23 | H4 | M105 | E24 | H4 |
| M106 | E25 | H4 | M107 | E26 | H4 | M108 | E27 | H4 |
| M109 | E1 | H5 | M110 | E2 | H5 | M111 | E3 | H5 |
| M112 | E4 | H5 | M113 | E5 | H5 | M114 | E6 | H5 |
| M115 | E7 | H5 | M116 | E8 | H5 | M117 | E9 | H5 |
| M118 | E10 | H5 | M119 | E11 | H5 | M120 | E12 | H5 |
| M121 | E13 | H5 | M122 | E14 | H5 | M123 | E15 | H5 |
| M124 | E16 | H5 | M125 | E17 | H5 | M126 | E18 | H5 |
| M127 | E19 | H5 | M128 | E20 | H5 | M129 | E21 | H5 |
| M130 | E22 | H5 | M131 | E23 | H5 | M132 | E24 | H5 |
| M133 | E25 | H5 | M134 | E26 | H5 | M135 | E27 | H5 |
| M136 | E1 | H6 | M137 | E2 | H6 | M138 | E3 | H6 |
| M139 | E4 | H6 | M140 | E5 | H6 | M141 | E6 | H6 |
| M142 | E7 | H6 | M143 | E8 | H6 | M144 | E9 | H6 |
| M145 | E10 | H6 | M146 | E11 | H6 | M147 | E12 | H6 |
| M148 | E13 | H6 | M149 | E14 | H6 | M150 | E15 | H6 |
| M151 | E16 | H6 | M152 | E17 | H6 | M153 | E18 | H6 |
| M154 | E19 | H6 | M155 | E20 | H6 | M156 | E21 | H6 |
| M157 | E22 | H6 | M158 | E23 | H6 | M159 | E24 | H6 |
| M160 | E25 | H6 | M161 | E26 | H6 | M162 | E27 | H6 |
| M163 | E1 | H7 | M164 | E2 | H7 | M165 | E3 | H7 |
| M166 | E4 | H7 | M167 | E5 | H7 | M168 | E6 | H7 |
| M169 | E7 | H7 | M170 | E8 | H7 | M171 | E9 | H7 |
| M172 | E10 | H7 | M173 | E11 | H7 | M174 | E12 | H7 |
| M175 | E13 | H7 | M176 | E14 | H7 | M177 | E15 | H7 |
| M178 | E16 | H7 | M179 | E17 | H7 | M180 | E18 | H7 |
| M181 | E19 | H7 | M182 | E20 | H7 | M183 | E21 | H7 |
| M184 | E22 | H7 | M185 | E23 | H7 | M186 | E24 | H7 |
| M187 | E25 | H7 | M188 | E26 | H7 | M189 | E27 | H7 |
| M190 | E1 | H8 | M191 | E2 | H8 | M192 | E3 | H8 |
| M193 | E4 | H8 | M194 | E5 | H8 | M195 | E6 | H8 |
| M196 | E7 | H8 | M197 | E8 | H8 | M198 | E9 | H8 |
| M199 | E10 | H8 | M200 | E11 | H8 | M201 | E12 | H8 |
| M202 | E13 | H8 | M203 | E14 | H8 | M204 | E15 | H8 |
| M205 | E16 | H8 | M206 | E17 | H8 | M207 | E18 | H8 |
| M208 | E19 | H8 | M209 | E20 | H8 | M210 | E21 | H8 |
| M211 | E22 | H8 | M212 | E23 | H8 | M213 | E24 | H8 |
| M214 | E25 | H8 | M215 | E26 | H8 | M216 | E27 | H8 |
| M217 | E1 | H9 | M218 | E2 | H9 | M219 | E3 | H9 |
| M220 | E4 | H9 | M221 | E5 | H9 | M222 | E6 | H9 |
| M223 | E7 | H9 | M224 | E8 | H9 | M225 | E9 | H9 |
| M226 | E10 | H9 | M227 | E11 | H9 | M228 | E12 | H9 |
| M229 | E13 | H9 | M230 | E14 | H9 | M231 | E15 | H9 |
| M232 | E16 | H9 | M233 | E17 | H9 | M234 | E18 | H9 |
| M235 | E19 | H9 | M236 | E20 | H9 | M237 | E21 | H9 |
| M238 | E22 | H9 | M239 | E23 | H9 | M240 | E24 | H9 |
| M241 | E25 | H9 | M242 | E26 | H9 | M243 | E27 | H9 |
| M244 | E1 | H10 | M245 | E2 | H10 | M246 | E3 | H10 |
| M247 | E4 | H10 | M248 | E5 | H10 | M249 | E6 | H10 |
| M250 | E7 | H10 | M251 | E8 | H10 | M252 | E9 | H10 |
| M253 | E10 | H10 | M254 | E11 | H10 | M255 | E12 | H10 |
| M256 | E13 | H10 | M257 | E14 | H10 | M258 | E15 | H10 |
| M259 | E16 | H10 | M260 | E17 | H10 | M261 | E18 | H10 |
| M262 | E19 | H10 | M263 | E20 | H10 | M264 | E21 | H10 |
| M265 | E22 | H10 | M266 | E23 | H10 | M267 | E24 | H10 |
| M268 | E25 | H10 | M269 | E26 | H10 | M270 | E27 | H10 |
| M271 | E1 | H11 | M272 | E2 | H11 | M273 | E3 | H11 |
| M274 | E4 | H11 | M275 | E5 | H1 | M276 | E6 | H11 |
| M277 | E7 | H11 | M278 | E8 | H11 | M279 | E9 | H11 |
| M280 | E10 | H11 | M281 | E11 | H11 | M282 | E12 | H11 |
| M283 | E13 | H11 | M284 | E14 | H11 | M285 | E15 | H11 |
| M286 | E16 | H11 | M287 | E17 | H1 | M288 | E18 | H11 |
| M289 | E19 | H11 | M290 | E20 | H11 | M291 | E21 | H11 |
| M292 | E22 | H11 | M293 | E23 | H11 | M294 | E24 | H11 |
| M295 | E25 | H11 | M296 | E26 | H11 | M297 | E27 | H11 |
| M298 | E1 | H12 | M299 | E2 | H12 | M300 | E3 | H12 |
| M301 | E4 | H12 | M302 | E5 | H12 | M303 | E6 | H12 |
| M304 | E7 | H12 | M305 | E8 | H12 | M306 | E9 | H12 |
| M307 | E10 | H12 | M308 | E11 | H12 | M309 | E12 | H12 |
| M310 | E13 | H12 | M311 | E14 | H12 | M312 | E15 | H12 |
| M313 | E16 | H12 | M314 | E17 | H12 | M315 | E18 | H12 |
| M316 | E19 | H12 | M317 | E20 | H12 | M318 | E21 | H12 |
| M319 | E22 | H12 | M320 | E23 | H12 | M321 | E24 | H12 |
| M322 | E25 | H12 | M323 | E26 | H12 | M324 | E27 | H12 |
| M325 | E1 | H13 | M326 | E2 | H13 | M327 | E3 | H13 |
| M328 | E4 | H13 | M329 | E5 | H13 | M330 | E6 | H13 |
| M331 | E7 | H13 | M332 | E8 | H13 | M333 | E9 | H13 |
| M334 | E10 | H13 | M335 | E11 | H13 | M336 | E12 | H13 |
| M337 | E13 | H13 | M338 | E14 | H13 | M339 | E15 | H13 |
| M340 | E16 | H13 | M341 | E17 | H13 | M342 | E18 | H13 |
| M343 | E19 | H13 | M344 | E20 | H13 | M345 | E21 | H13 |
| M346 | E22 | H13 | M347 | E23 | H13 | M348 | E24 | H13 |
| M349 | E25 | H13 | M350 | E26 | H13 | M351 | E27 | H13 |
| M352 | E1 | H14 | M353 | E2 | H14 | M354 | E3 | H14 |
| M355 | E4 | H14 | M356 | E5 | H14 | M357 | E6 | H14 |
| M358 | E7 | H14 | M359 | E8 | H14 | M360 | E9 | H14 |
| M361 | E10 | H14 | M362 | E11 | H14 | M363 | E12 | H14 |
| M364 | E13 | H14 | M365 | E14 | H14 | M366 | E15 | H14 |
| M367 | E16 | H14 | M368 | E17 | H14 | M369 | E18 | H14 |
| M370 | E19 | H14 | M371 | E20 | H14 | M372 | E21 | H14 |
| M373 | E22 | H14 | M374 | E23 | H14 | M375 | E24 | H14 |
| M376 | E25 | H14 | M377 | E26 | H14 | M378 | E27 | H14 |
| M379 | E1 | H15 | M380 | E2 | H15 | M381 | E3 | H15 |
| M382 | E4 | H15 | M383 | E5 | H15 | M384 | E6 | H15 |
| M385 | E7 | H15 | M386 | E8 | H15 | M387 | E9 | H15 |
| M388 | E10 | H15 | M389 | E11 | H15 | M390 | E12 | H15 |
| M391 | E13 | H15 | M392 | E14 | H15 | M393 | E15 | H15 |
| M394 | E16 | H15 | M395 | E17 | H15 | M396 | E18 | H15 |
| M397 | E19 | H15 | M398 | E20 | H15 | M399 | E21 | H15 |
| M400 | E22 | H15 | M401 | E23 | H15 | M402 | E24 | H15 |
| M403 | E25 | H15 | M404 | E26 | H15 | M405 | E27 | H15 |
| M406 | E1 | H16 | M407 | E2 | H16 | M408 | E3 | H16 |
| M409 | E4 | H16 | M410 | E5 | H16 | M411 | E6 | H16 |
| M412 | E7 | H16 | M413 | E8 | H16 | M414 | E9 | H16 |
| M415 | E10 | H16 | M416 | E11 | H16 | M417 | E12 | H16 |
| M418 | E13 | H16 | M419 | E14 | H16 | M420 | E15 | H16 |
| M421 | E16 | H16 | M422 | E17 | H16 | M423 | E18 | H16 |
| M424 | E19 | H16 | M425 | E20 | H16 | M426 | E21 | H16 |
| M427 | E22 | H16 | M428 | E23 | H16 | M429 | E24 | H16 |
| M430 | E25 | H16 | M431 | E26 | H16 | M432 | E27 | H16 |
| M433 | E1 | H17 | M434 | E2 | H17 | M435 | E3 | H17 |
| M436 | E4 | H17 | M437 | E5 | H17 | M438 | E6 | H17 |
| M439 | E7 | H17 | M440 | E8 | H17 | M441 | E9 | H17 |
| M442 | E10 | H17 | M443 | E11 | H17 | M444 | E12 | H17 |
| M445 | E13 | H17 | M446 | E14 | H17 | M447 | E15 | H17 |
| M448 | E16 | H17 | M449 | E17 | H17 | M450 | E18 | H17 |
| M451 | E19 | H17 | M452 | E20 | H17 | M453 | E21 | H17 |
| M454 | E22 | H17 | M455 | E23 | H17 | M456 | E24 | H17 |
| M457 | E25 | H17 | M458 | E26 | H17 | M459 | E27 | H17 |
| M460 | E1 | H18 | M461 | E2 | H18 | M462 | E3 | H18 |
| M463 | E4 | H18 | M464 | E5 | H18 | M465 | E6 | H18 |
| M466 | E7 | H18 | M467 | E8 | H18 | M468 | E9 | H18 |
| M469 | E10 | H18 | M470 | E11 | H18 | M471 | E12 | H18 |
| M472 | E13 | H18 | M473 | E14 | H18 | M474 | E15 | H18 |
| M475 | E16 | H18 | M476 | E17 | H18 | M477 | E18 | H18 |
| M478 | E19 | H18 | M479 | E20 | H18 | M480 | E21 | H18 |
| M481 | E22 | H18 | M482 | E23 | H18 | M483 | E24 | H18 |
| M484 | E25 | H18 | M485 | E26 | H18 | M486 | E27 | H18 |
| M487 | E1 | H19 | M488 | E2 | H19 | M489 | E3 | H19 |
| M490 | E4 | H19 | M491 | E5 | H19 | M492 | E6 | H19 |
| M493 | E7 | H19 | M494 | E8 | H19 | M495 | E9 | H19 |
| M496 | E10 | H19 | M497 | E11 | H19 | M498 | E12 | H19 |
| M499 | E13 | H19 | M500 | E14 | H19 | M501 | E15 | H19 |
| M502 | E16 | H19 | M503 | E17 | H19 | M504 | E18 | H19 |
| M505 | E19 | H19 | M506 | E20 | H19 | M507 | E21 | H19 |
| M508 | E22 | H19 | M509 | E23 | H19 | M510 | E24 | H19 |
| M511 | E25 | H19 | M512 | E26 | H19 | M513 | E27 | H19 |
| M514 | E1 | H20 | M515 | E2 | H20 | M516 | E3 | H20 |
| M517 | E4 | H20 | M518 | E5 | H20 | M519 | E6 | H20 |
| M520 | E7 | H20 | M521 | E8 | H20 | M522 | E9 | H20 |
| M523 | E10 | H20 | M524 | E11 | H20 | M525 | E12 | H20 |
| M526 | E13 | H20 | M527 | E14 | H20 | M528 | E15 | H20 |
| M529 | E16 | H20 | M530 | E17 | H20 | M531 | E18 | H20 |
| M532 | E19 | H20 | M533 | E20 | H20 | M534 | E21 | H20 |
| M535 | E22 | H20 | M536 | E23 | H20 | M537 | E24 | H20 |
| M538 | E25 | H20 | M539 | E26 | H20 | M540 | E27 | H20 |
| M541 | E1 | H21 | M542 | E2 | H21 | M543 | E3 | H21 |
| M544 | E4 | H21 | M545 | E5 | H21 | M546 | E6 | H21 |
| M547 | E7 | H21 | M548 | E8 | H21 | M549 | E9 | H21 |
| M550 | E10 | H21 | M551 | E11 | H21 | M552 | E12 | H21 |
| M553 | E13 | H21 | M554 | E14 | H21 | M555 | E15 | H21 |
| M556 | E16 | H21 | M557 | E17 | H21 | M558 | E18 | H21 |
| M559 | E19 | H21 | M560 | E20 | H21 | M561 | E21 | H21 |
| M562 | E22 | H21 | M563 | E23 | H21 | M564 | E24 | H21 |
| M565 | E25 | H21 | M566 | E26 | H21 | M567 | E27 | H21 |
| M568 | E1 | H22 | M569 | E2 | H22 | M570 | E3 | H22 |
| M571 | E4 | H22 | M572 | E5 | H22 | M573 | E6 | H22 |
| M574 | E7 | H22 | M575 | E8 | H22 | M576 | E9 | H22 |
| M577 | E10 | H22 | M578 | E11 | H22 | M579 | E12 | H22 |
| M580 | E13 | H22 | M581 | E14 | H22 | M582 | E15 | H22 |
| M583 | E16 | H22 | M584 | E17 | H22 | M585 | E18 | H22 |
| M586 | E19 | H22 | M587 | E20 | H22 | M588 | E21 | H22 |
| M589 | E22 | H22 | M590 | E23 | H22 | M591 | E24 | H22 |
| M592 | E25 | H22 | M593 | E26 | H22 | M594 | E27 | H22 |
| M595 | E1 | H23 | M596 | E2 | H23 | M597 | E3 | H23 |
| M598 | E4 | H23 | M599 | E5 | H23 | M600 | E6 | H23 |
| M601 | E7 | H23 | M602 | E8 | H23 | M603 | E9 | H23 |
| M604 | E10 | H23 | M605 | E11 | H23 | M606 | E12 | H23 |
| M607 | E13 | H23 | M608 | E14 | H23 | M609 | E15 | H23 |
| M610 | E16 | H23 | M611 | E17 | H23 | M612 | E18 | H23 |
| M613 | E19 | H23 | M614 | E20 | H23 | M615 | E21 | H23 |
| M616 | E22 | H23 | M617 | E23 | H23 | M618 | E24 | H23 |
| M619 | E25 | H23 | M620 | E26 | H23 | M621 | E27 | H23 |
| M622 | E1 | H24 | M623 | E2 | H24 | M624 | E3 | H24 |
| M625 | E4 | H24 | M626 | E5 | H24 | M627 | E6 | H24 |
| M628 | E7 | H24 | M629 | E8 | H24 | M630 | E9 | H24 |
| M631 | E10 | H24 | M632 | E11 | H24 | M633 | E12 | H24 |
| M634 | E13 | H24 | M635 | E14 | H24 | M636 | E15 | H24 |
| M637 | E16 | H24 | M638 | E17 | H24 | M639 | E18 | H24 |
| M640 | E19 | H24 | M641 | E20 | H24 | M642 | E21 | H24 |
| M643 | E22 | H24 | M644 | E23 | H24 | M645 | E24 | H24 |
| M646 | E25 | H24 | M647 | E26 | H24 | M648 | E27 | H24 |
| M649 | E1 | H25 | M650 | E2 | H25 | M651 | E3 | H25 |
| M652 | E4 | H25 | M653 | E5 | H25 | M654 | E6 | H25 |
| M655 | E7 | H25 | M656 | E8 | H25 | M657 | E9 | H25 |
| M658 | E10 | H25 | M659 | E11 | H25 | M660 | E12 | H25 |
| M661 | E13 | H25 | M662 | E14 | H25 | M663 | E15 | H25 |
| M664 | E16 | H25 | M665 | E17 | H25 | M666 | E18 | H25 |
| M667 | E19 | H25 | M668 | E20 | H25 | M669 | E21 | H25 |
| M670 | E22 | H25 | M671 | E23 | H25 | M672 | E24 | H25 |
| M673 | E25 | H25 | M674 | E26 | H25 | M675 | E27 | H25 |
| M676 | E1 | H26 | M677 | E2 | H26 | M678 | E3 | H26 |
| M679 | E4 | H26 | M680 | E5 | H26 | M681 | E6 | H26 |
| M682 | E7 | H26 | M683 | E8 | H26 | M684 | E9 | H26 |
| M685 | E10 | H26 | M686 | E11 | H26 | M687 | E12 | H26 |
| M688 | E13 | H26 | M689 | E14 | H26 | M690 | E15 | H26 |
| M691 | E16 | H26 | M692 | E17 | H26 | M693 | E18 | H26 |
| M694 | E19 | H26 | M695 | E20 | H26 | M696 | E21 | H26 |
| M697 | E22 | H26 | M698 | E23 | H26 | M699 | E24 | H26 |
| M700 | E25 | H26 | M701 | E26 | H26 | M702 | E27 | H26 |
| M703 | E1 | H27 | M704 | E2 | H27 | M705 | E3 | H27 |
| M706 | E4 | H27 | M707 | E5 | H27 | M708 | E6 | H27 |
| M709 | E7 | H27 | M710 | E8 | H27 | M711 | E9 | H27 |
| M712 | E10 | H27 | M713 | E11 | H27 | M714 | E12 | H27 |
| M715 | E13 | H27 | M716 | E14 | H27 | M717 | E15 | H27 |
| M718 | E16 | H27 | M719 | E17 | H27 | M720 | E18 | H27 |
| M721 | E19 | H27 | M722 | E20 | H27 | M723 | E21 | H27 |
| M724 | E22 | H27 | M725 | E23 | H27 | M726 | E24 | H27 |
| M727 | E25 | H27 | M728 | E26 | H27 | M729 | E27 | H27 |

concentration of the electron-transporting host material of the formula (1) as described or described as preferable above in the mixture of the invention or in the light-emitting layer of the device of the invention is in the range from 5% by weight to 90% by weight, preferably in the range from 10% by weight to 85% by weight, more preferably in the range from 20% by weight to 85% by weight, even more preferably in the range from 30% by weight to 80% by weight, very especially preferably in the range from 20% by weight to 60% by weight and most preferably in the range from 30% by weight to 50% by weight, based on the overall mixture or based on the overall composition of the light-emitting layer.

The concentration of the hole-transporting host material of the formula (2) as described or described as preferable above in the mixture of the invention or in the light-emitting layer of the device of the invention is in the range from 10% by weight to 95% by weight, preferably in the range from 15% by weight to 90% by weight, more preferably in the range from 15% by weight to 80% by weight, even more preferably in the range from 20% by weight to 70% by weight, very especially preferably in the range from 40% by weight to 80% by weight and most preferably in the range from 50% by weight to 70% by weight, based on the overall mixture or based on the overall composition of the light-emitting layer.

The present invention also relates to a mixture which, as well as the aforementioned host materials 1 and 2, as described or described as preferable above, especially mixtures M1 to M729, also contains at least one phosphorescent emitter.

The present invention also relates to an organic electroluminescent device as described or described as preferable above, wherein the light-emitting layer, as well as the aforementioned host materials 1 and 2, as described or described as preferable above, especially the material combinations M1 to M729, also comprises at least one phosphorescent emitter.

The term “phosphorescent emitters” typically encompasses compounds where the light is emitted through a spin-forbidden transition from an excited state having higher spin multiplicity, i.e. a spin state >1, for example through a transition from a triplet state or a state having an even higher spin quantum number, for example a quintet state. This is preferably understood to mean a transition from a triplet state.

Suitable phosphorescent emitters (=triplet emitters) are especially compounds which, when suitably excited, emit light, preferably in the visible region, and also contain at least one atom of atomic number greater than 20, preferably greater than 38 and less than 84, more preferably greater than 56 and less than 80, especially a metal having this atomic number. Preferred phosphorescence emitters used are compounds containing copper, molybdenum, tungsten, rhenium, ruthenium, osmium, rhodium, iridium, palladium, platinum, silver, gold or europium, especially compounds containing iridium or platinum. In the context of the present invention, all luminescent compounds containing the abovementioned metals are regarded as phosphorescent emitters.

In general, all phosphorescent complexes as used for phosphorescent OLEDs according to the prior art and as known to those skilled in the art in the field of organic electroluminescent devices are suitable.

Preferred phosphorescent emitters according to the present invention conform to the formula (3),

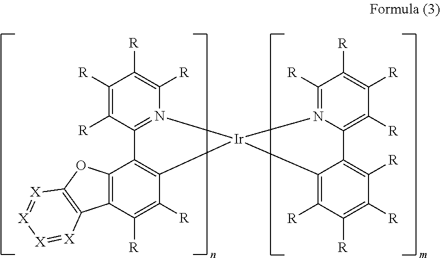

where the symbols and indices for this formula (3) are defined as follows:
n+m is 3, n is 1 or 2, m is 2 or 1,
X is N or CR,
R is H, D, or a branched or linear alkyl group having 1 to 10 carbon atoms or a partly or fully deuterated branched or linear alkyl group having 1 to 10 carbon atoms or a cycloalkyl group which has 4 to 7 carbon atoms and may be partly or fully substituted by deuterium.

The invention accordingly further provides an organic electroluminescent device as described or described as preferable above, characterized in that the light-emitting layer, as well as the host materials 1 and 2, comprises at least one phosphorescent emitter conforming to the formula (3) as described above.

In emitters of the formula (3), n is preferably 1 and m is preferably 2.

In emitters of the formula (3), preferably, one X is selected from N and the other X are CR.

In emitters of the formula (3) at least one R is preferably different from H. In emitters of the formula (3) preferably two R are different from H and have one of the other definitions given above for the emitters of the formula (3).

Preferred phosphorescent emitters according to the present invention conform to the formulae (I), (II) and (III)

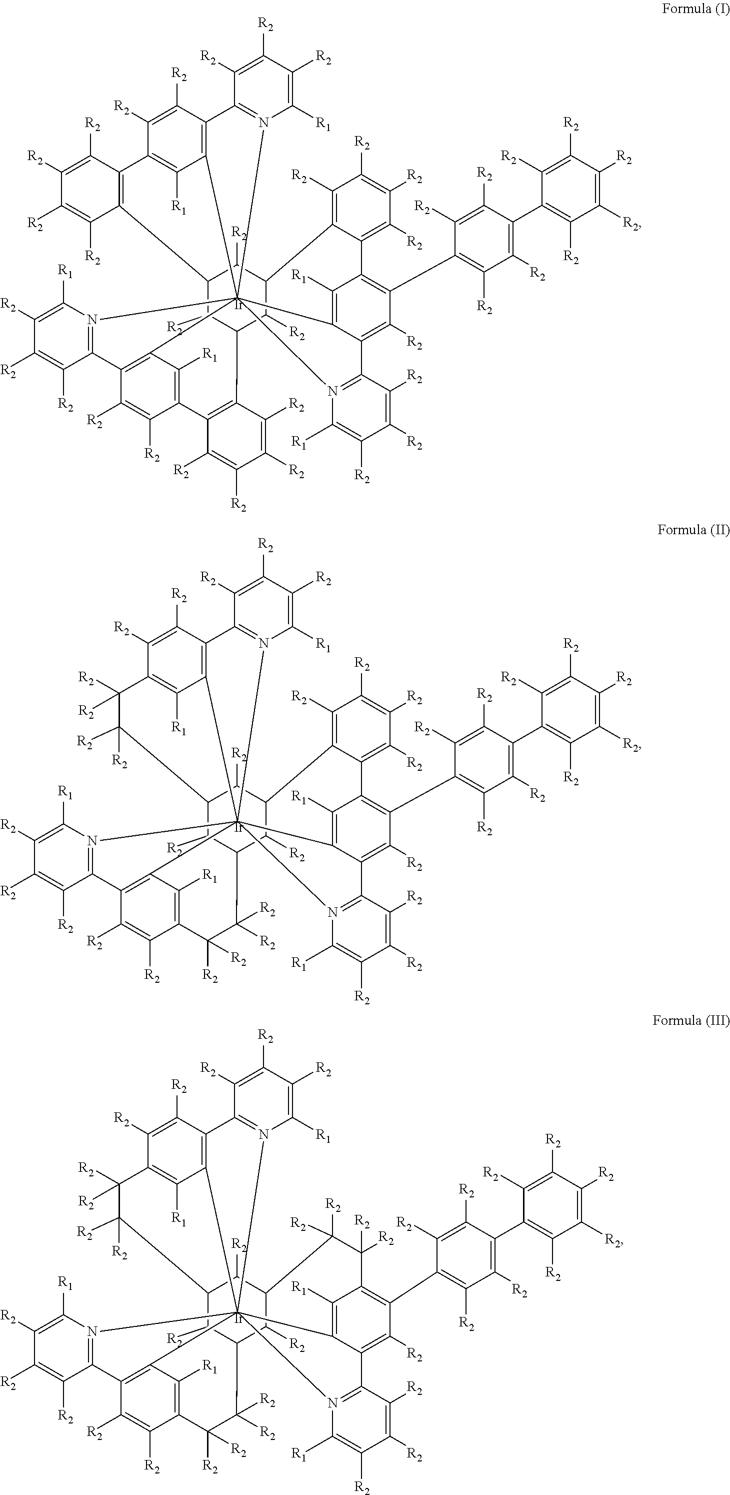

where the symbols and indices for these formulae (I), (II) and (III) are defined as follows: R₁ is H or D, R₂ is H, D, or a branched or linear alkyl group having 1 to 10 carbon atoms or a partly or fully deuterated branched or linear alkyl group having 1 to 10 carbon atoms or a cycloalkyl group which has 4 to 10 carbon atoms and may be partly or fully substituted by deuterium.

Preferred phosphorescent emitters according to the present invention conform to the formulae (IV), (V) and (VI)

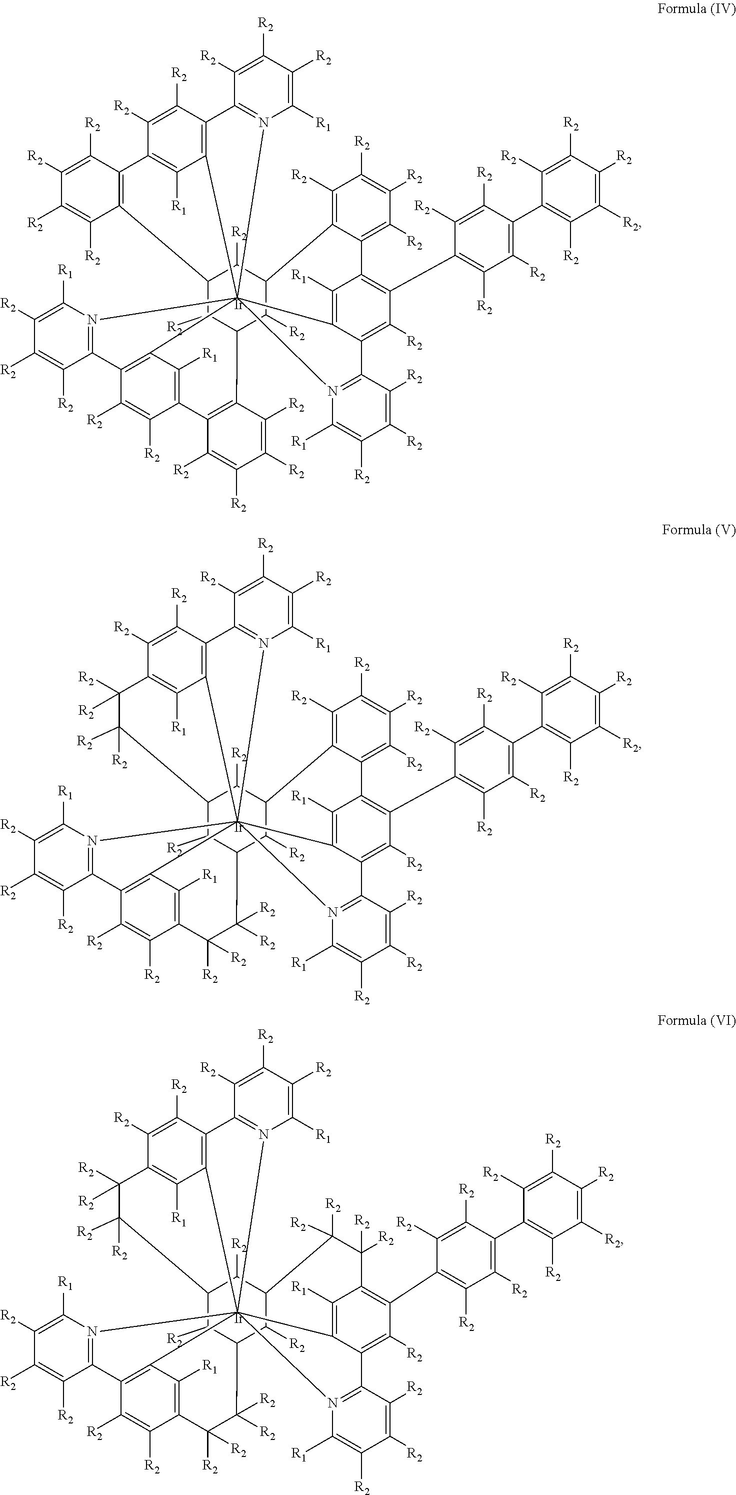

where the symbols and indices for these formulae (IV), (V and (VI) are defined as follows: R₁ is H or D, R₂ is H, D, F or a branched or linear alkyl group having 1 to 10 carbon atoms or a partly or fully deuterated branched or linear alkyl group having 1 to 10 carbon atoms or a cycloalkyl group which has 4 to 10 carbon atoms and may be partly or fully substituted by deuterium.

Preferred examples of phosphorescent emitters are listed in table 4 below.

TABLE 4

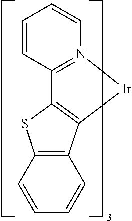

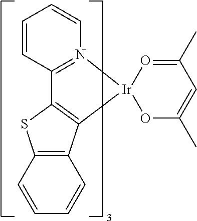

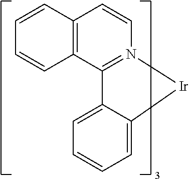

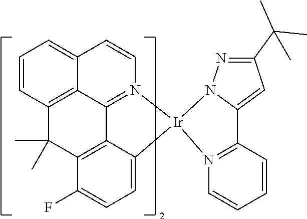

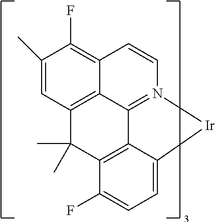

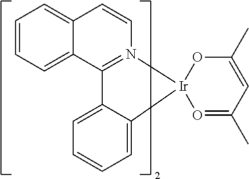

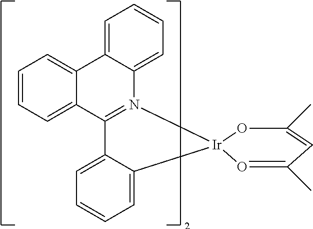

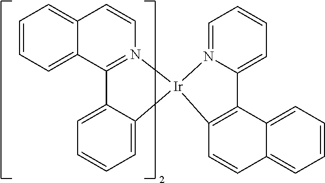

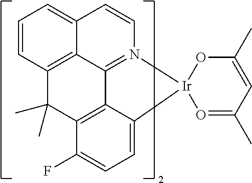

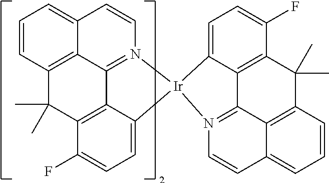

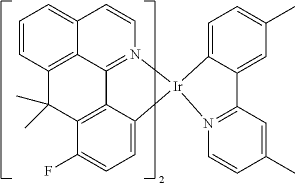

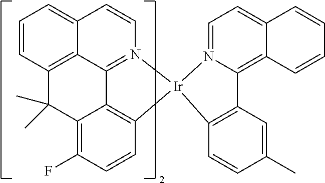

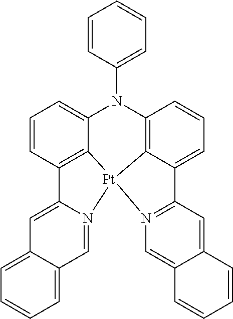

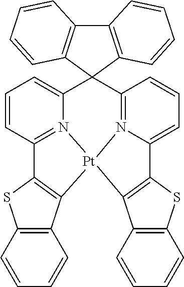

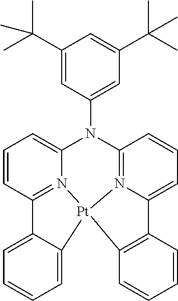

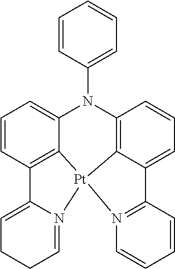

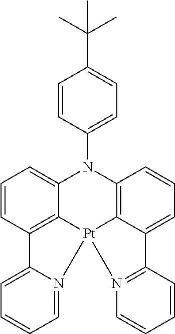

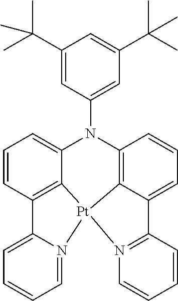

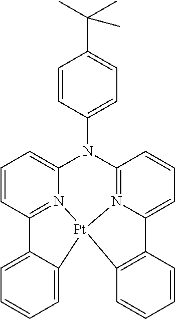

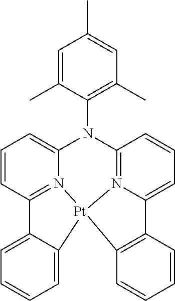

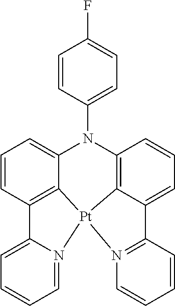

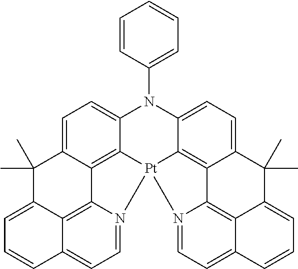

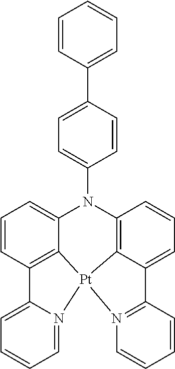

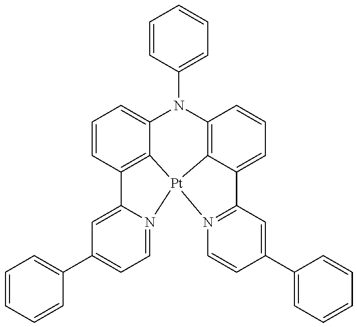

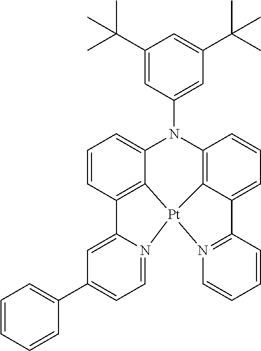

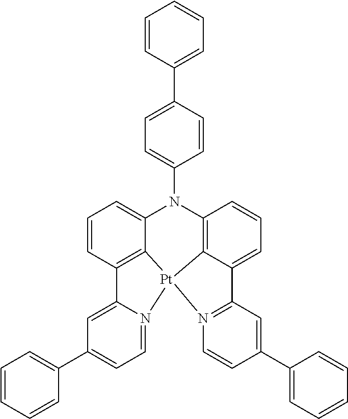

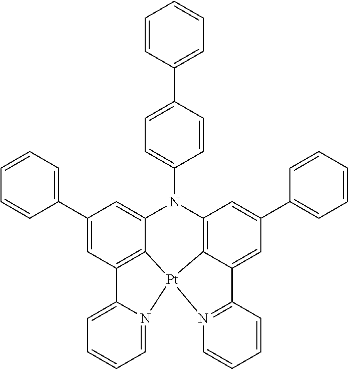

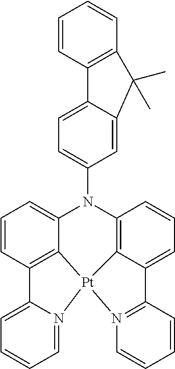

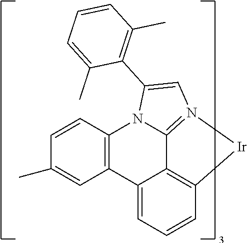

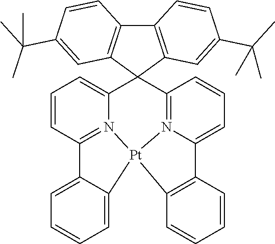

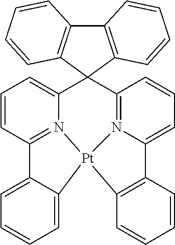

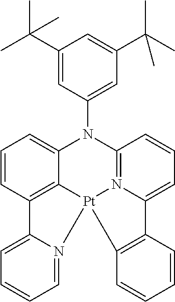

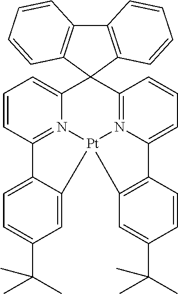

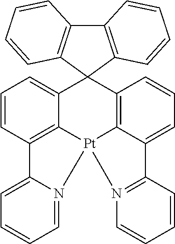

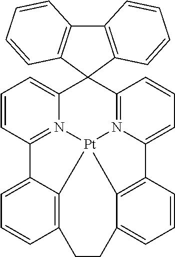

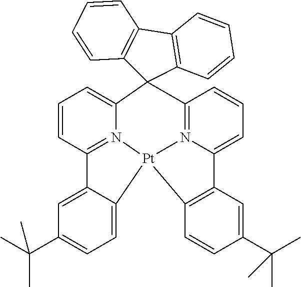

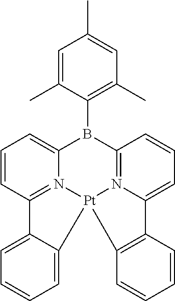

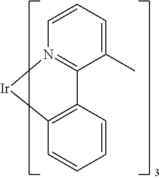

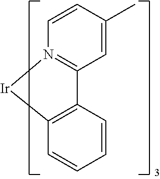

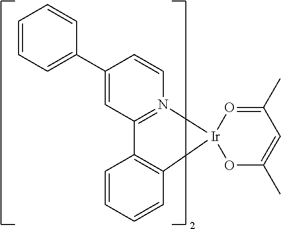

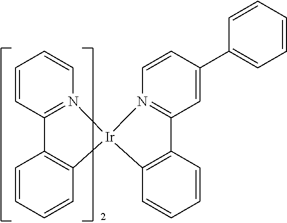

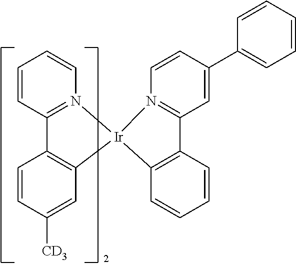

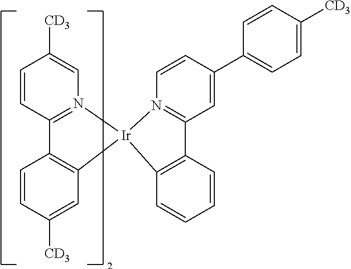

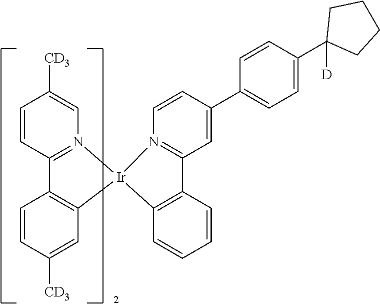

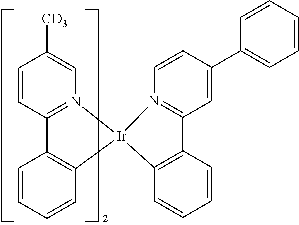

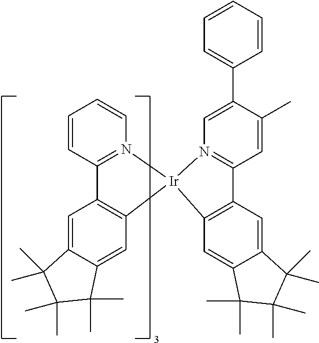

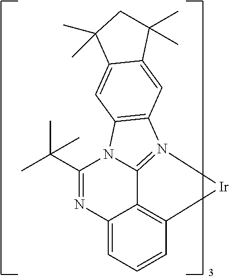

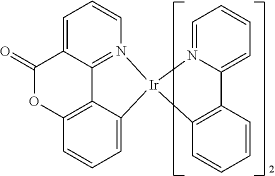

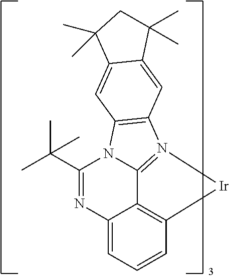

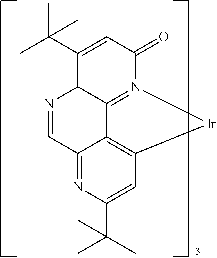

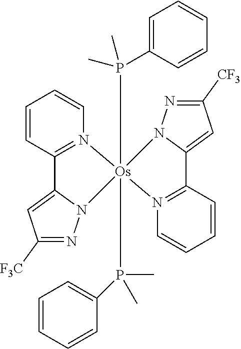

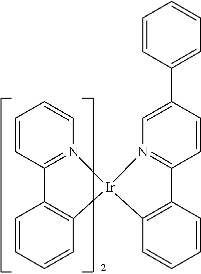

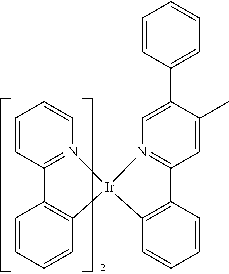

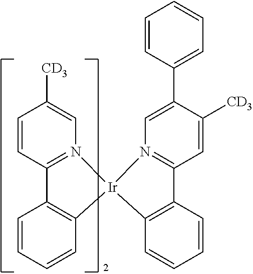

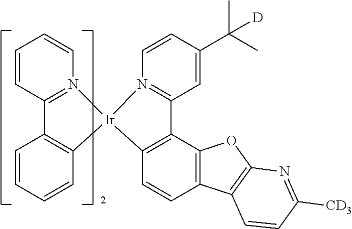

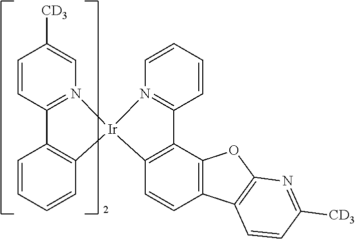

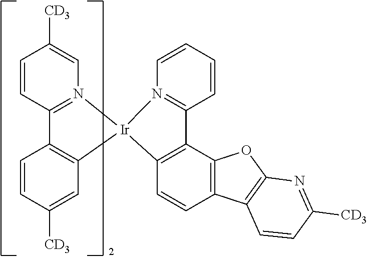

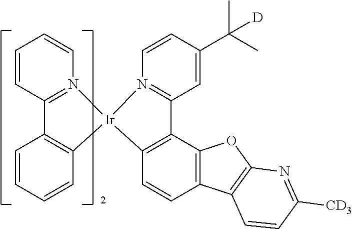

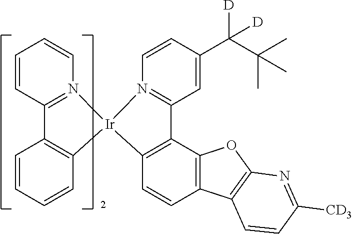

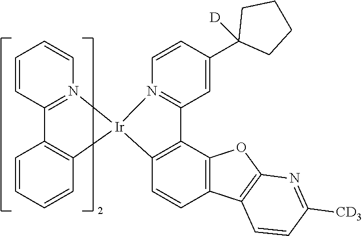

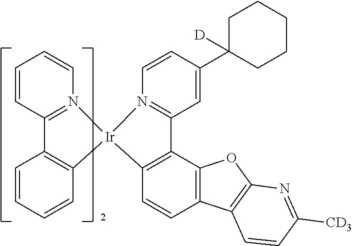

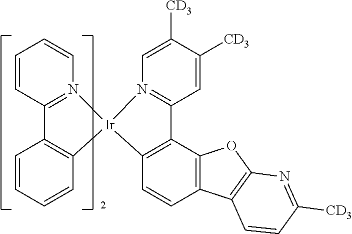

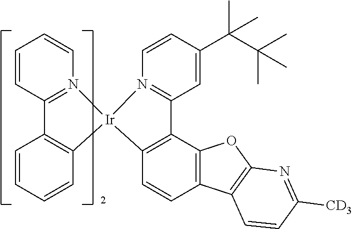

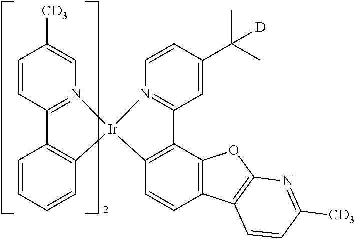

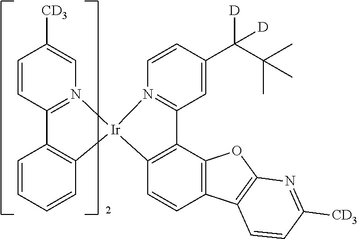

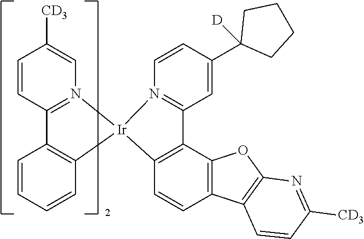

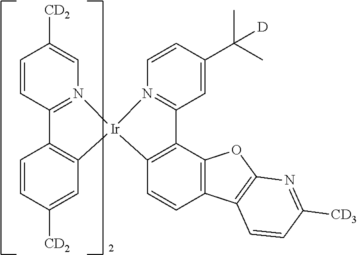

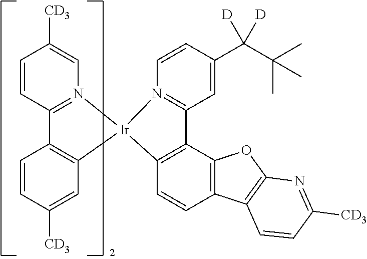

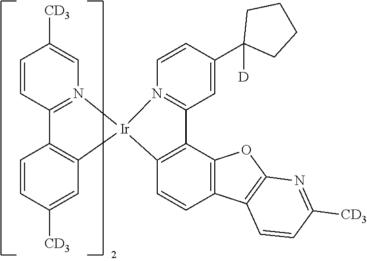

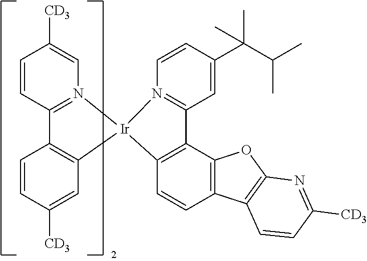

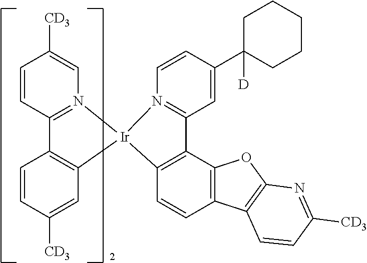

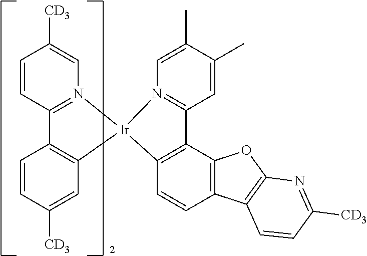

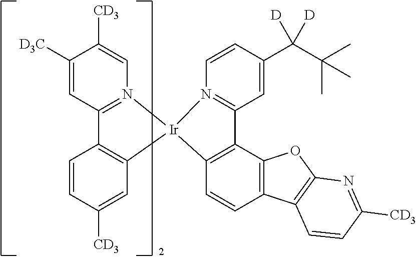

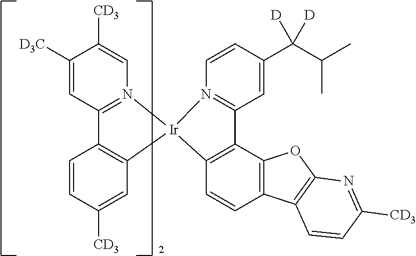

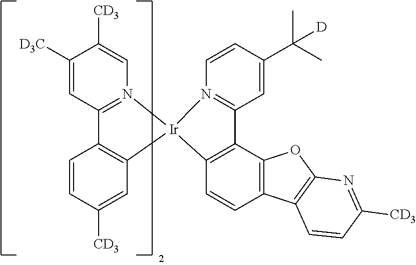

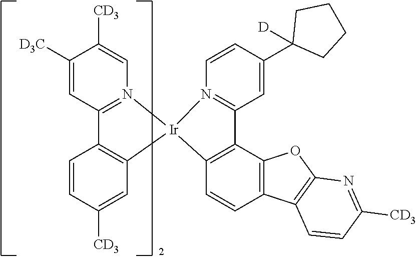

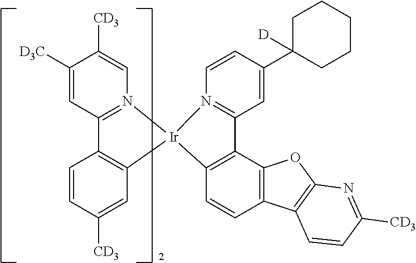

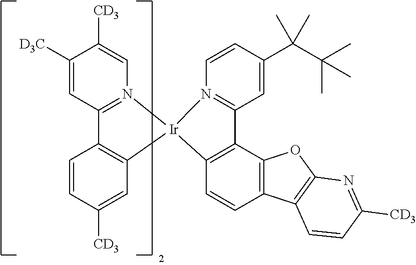

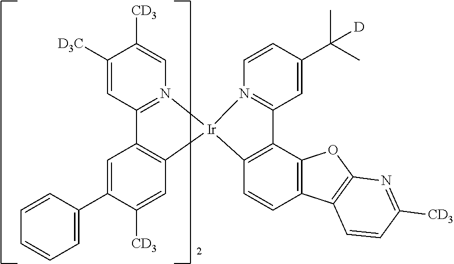

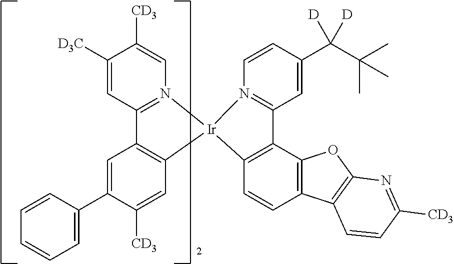

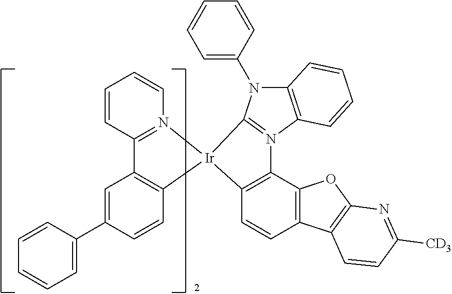

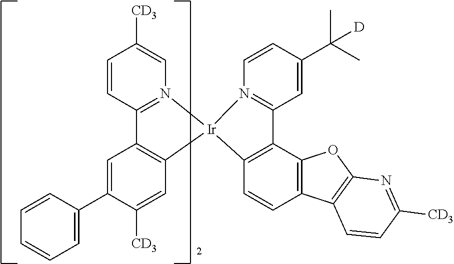

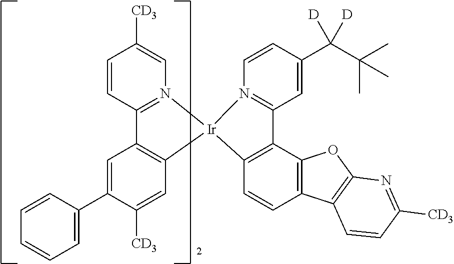

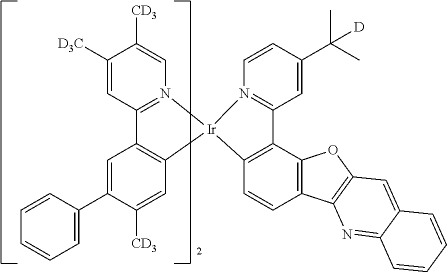

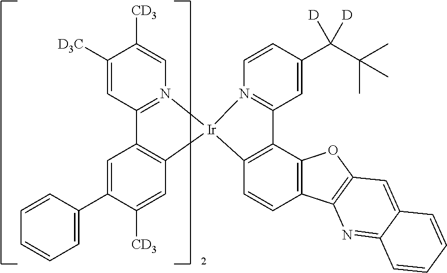

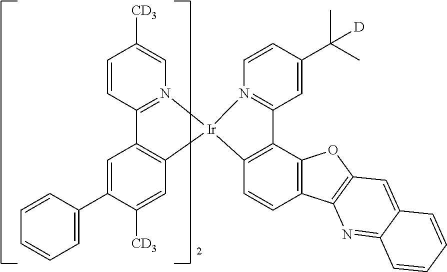

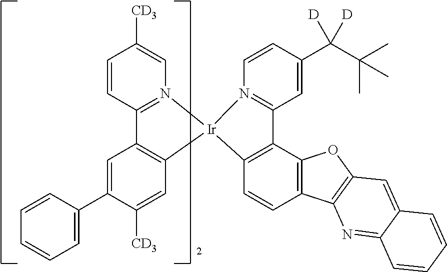

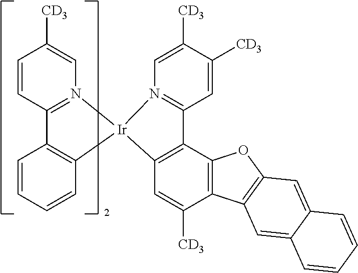

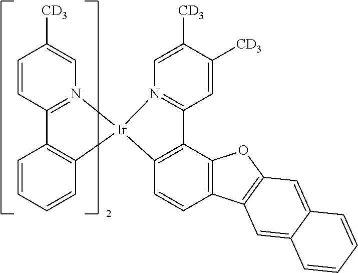

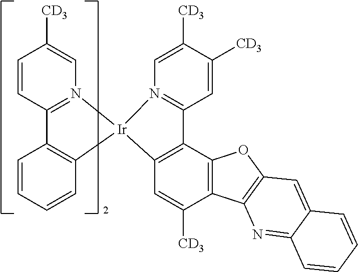

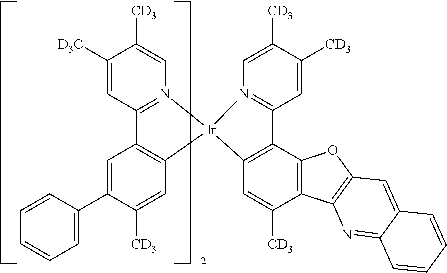

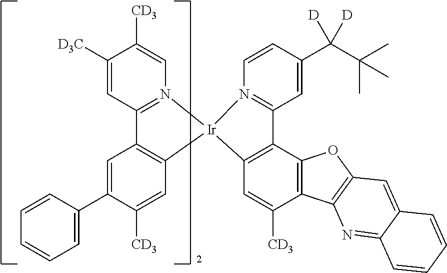

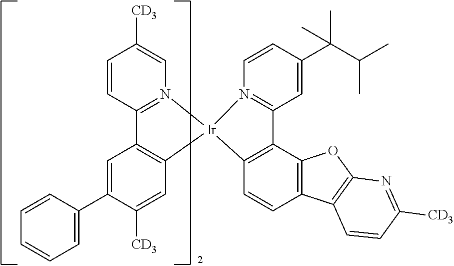

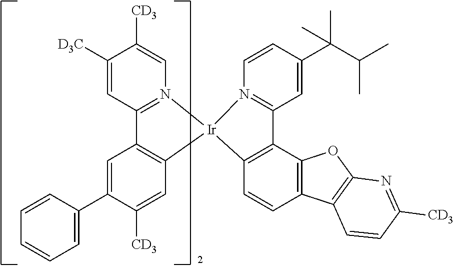

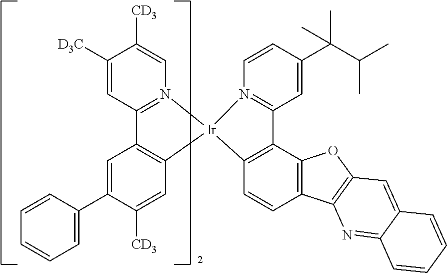

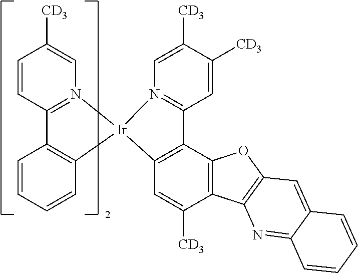

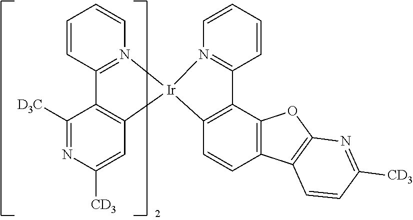

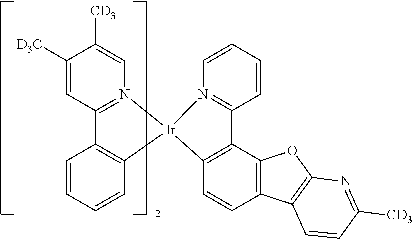

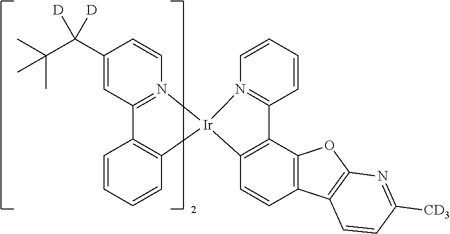

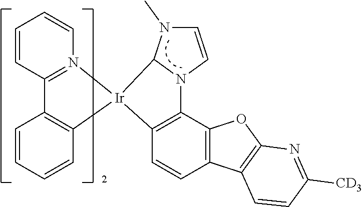

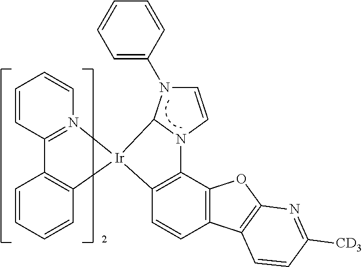

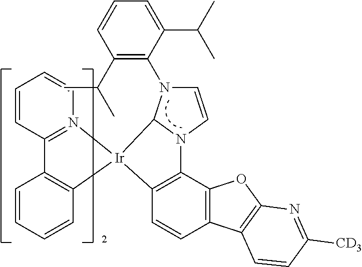

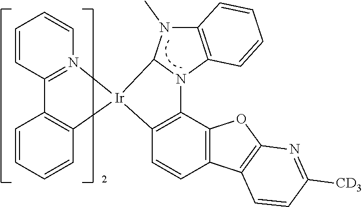

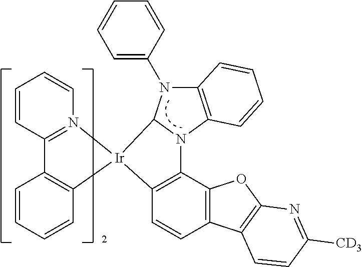

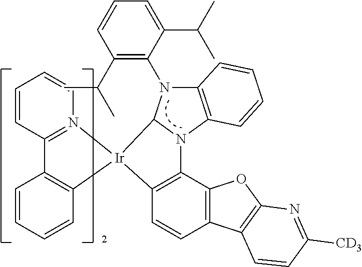

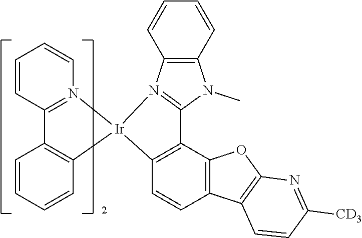

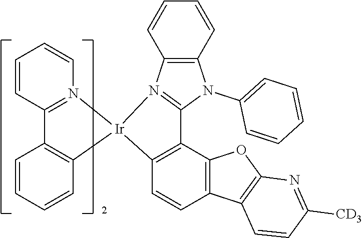

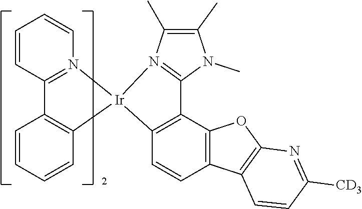

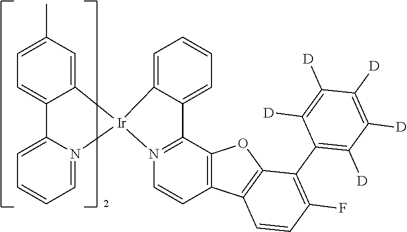

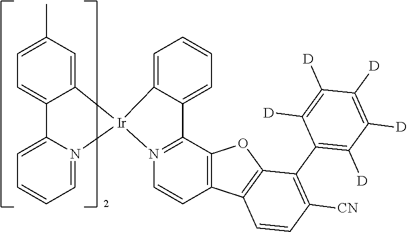

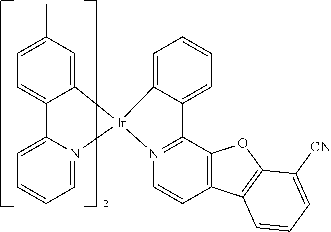

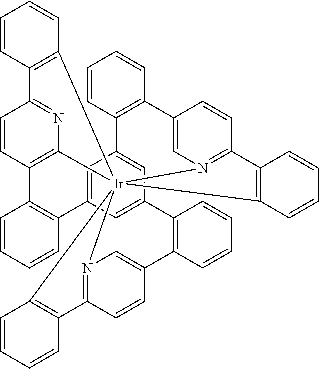

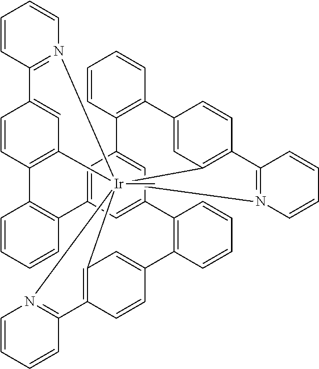

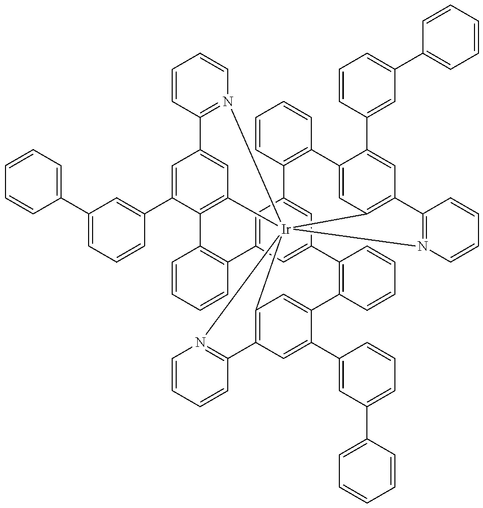

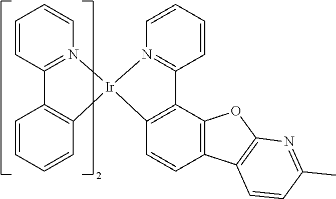

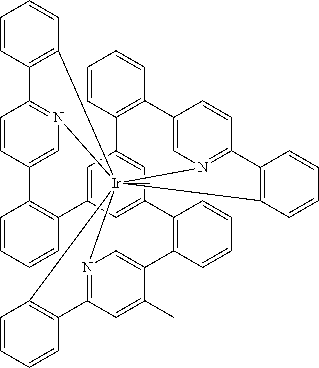

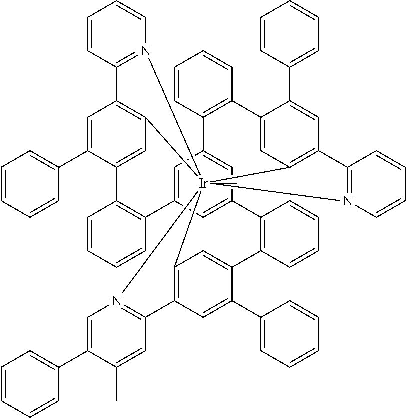

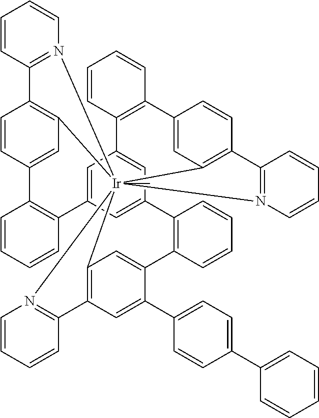

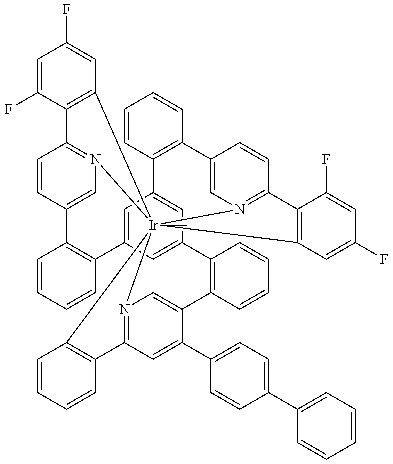

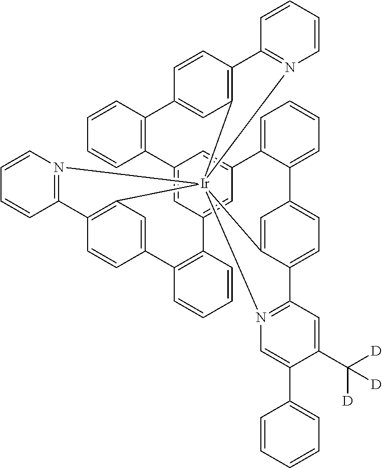

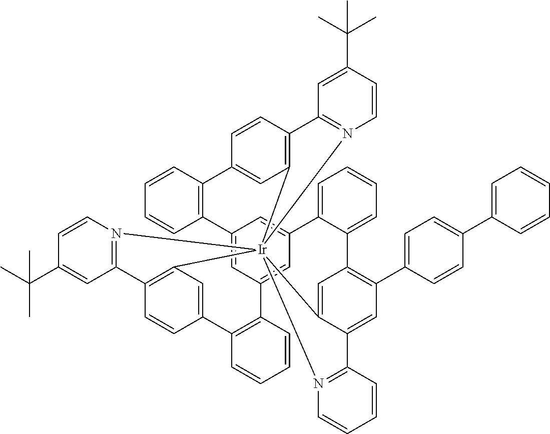

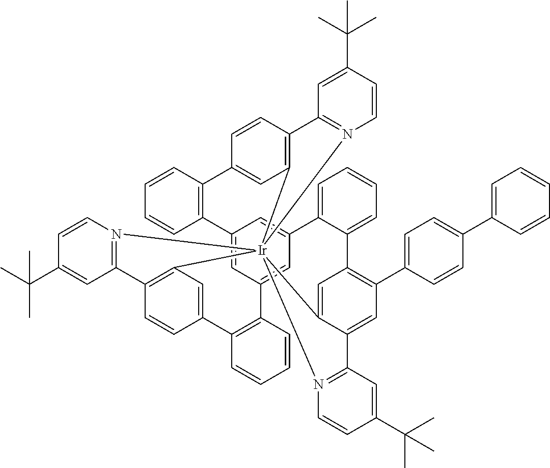

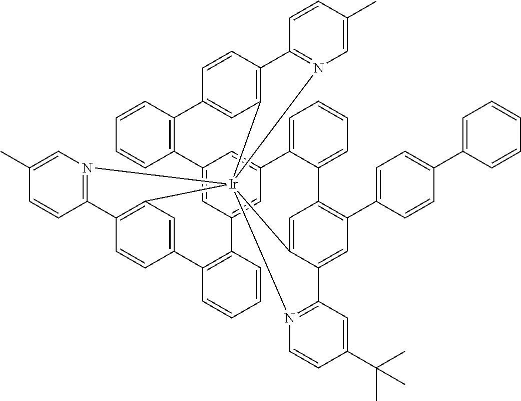

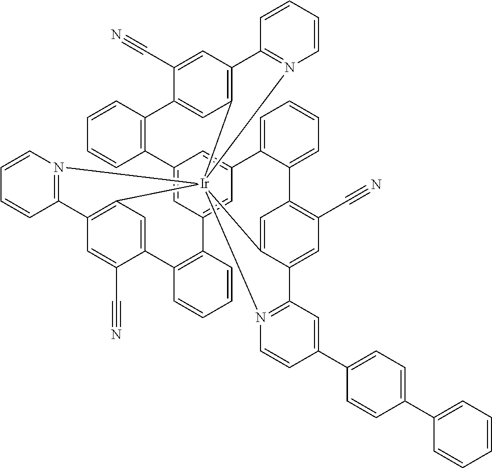

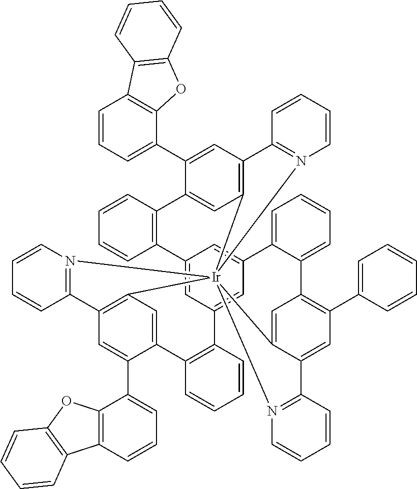

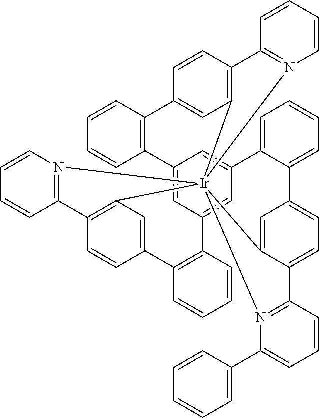

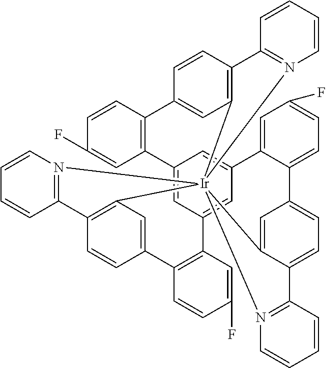

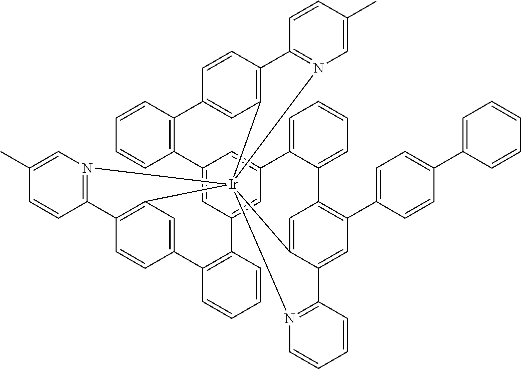

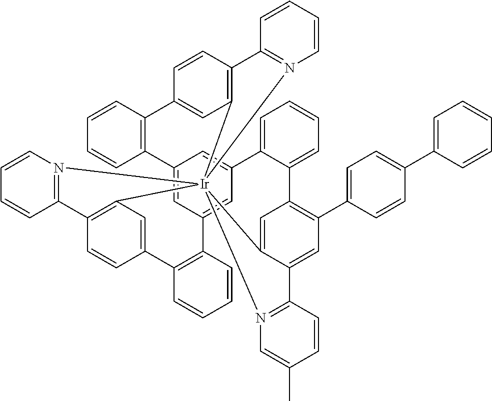

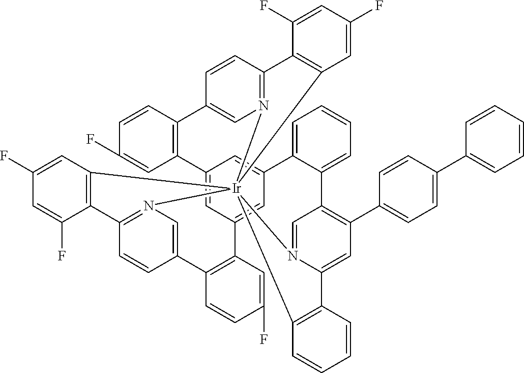

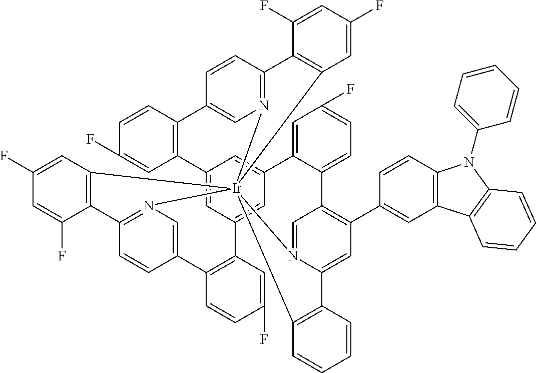

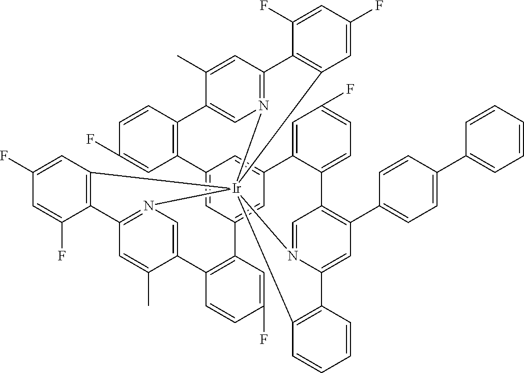

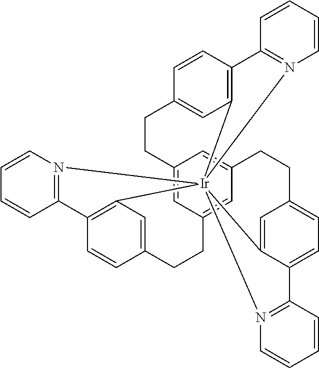

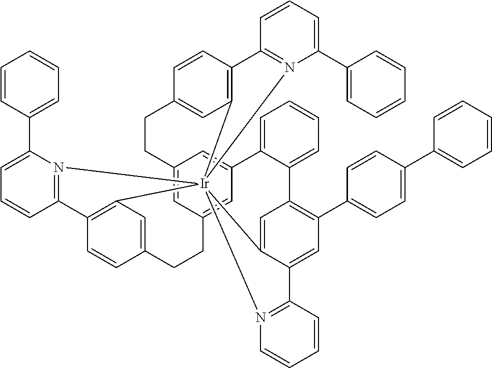

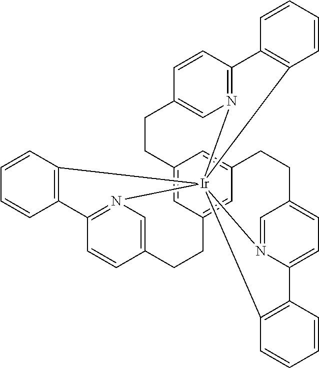

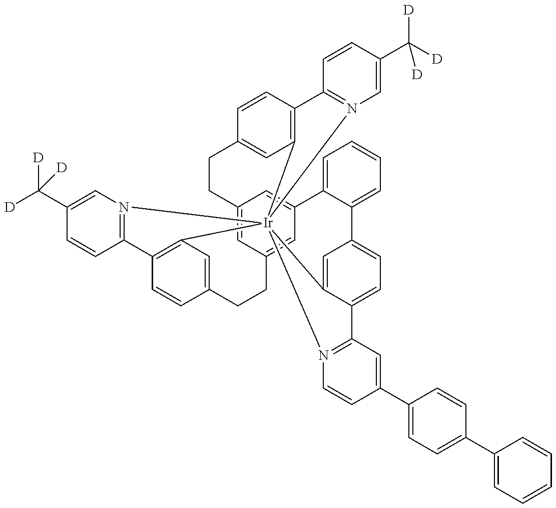

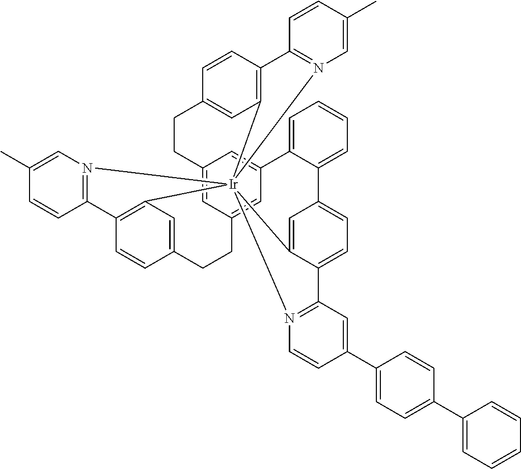

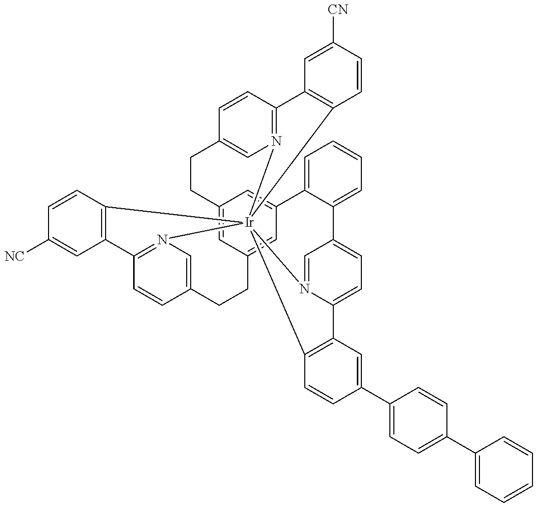

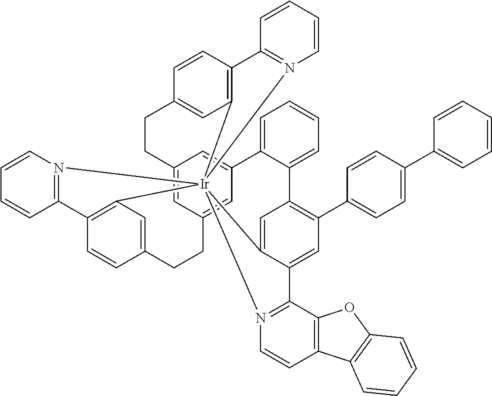

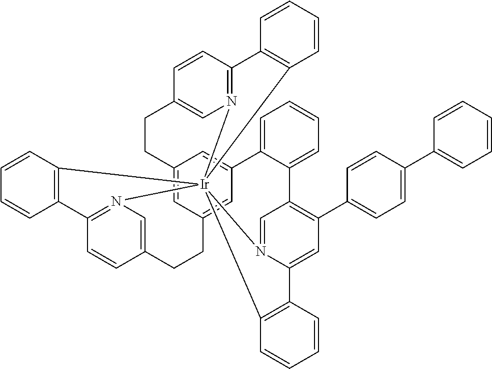

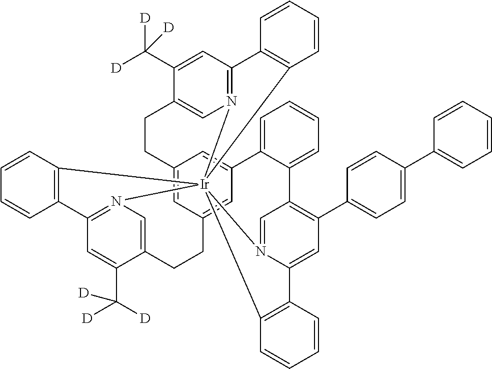

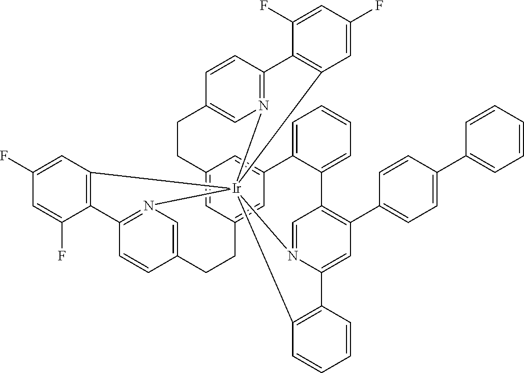

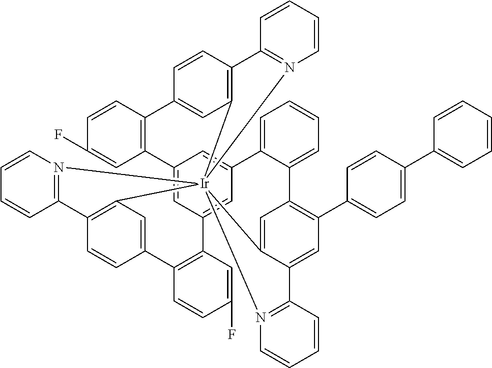

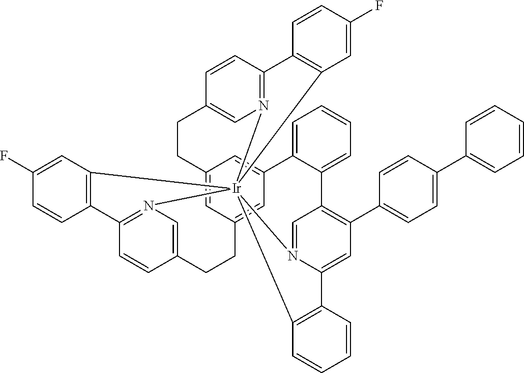

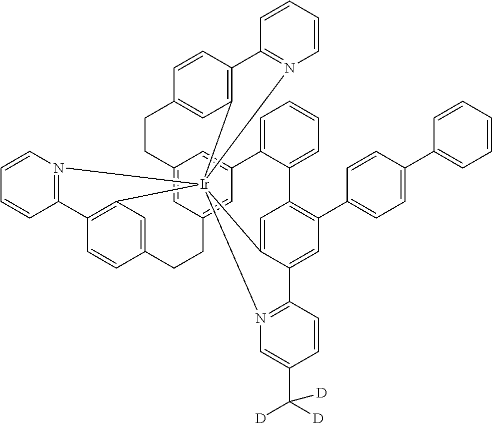

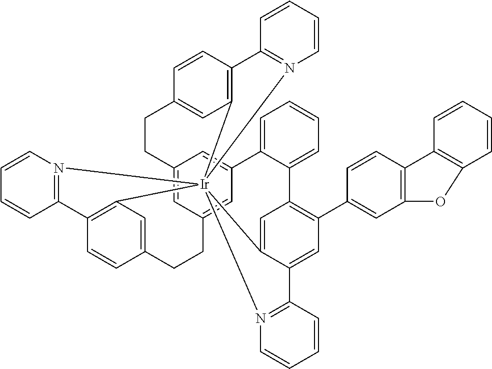

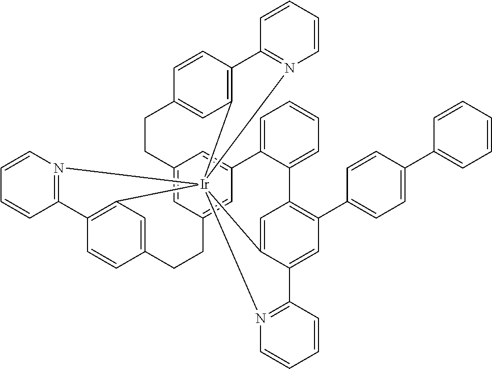

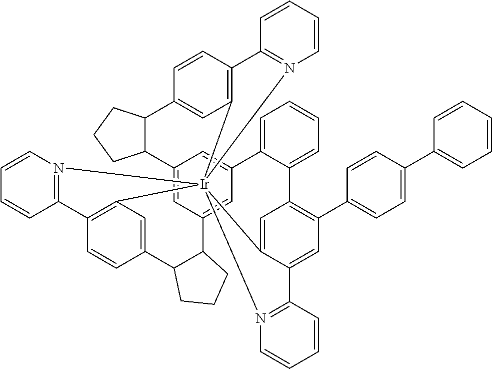

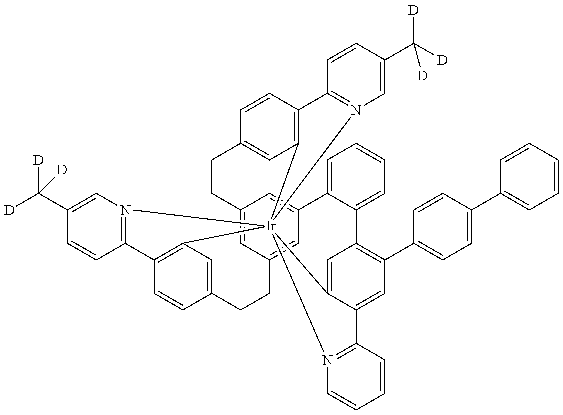

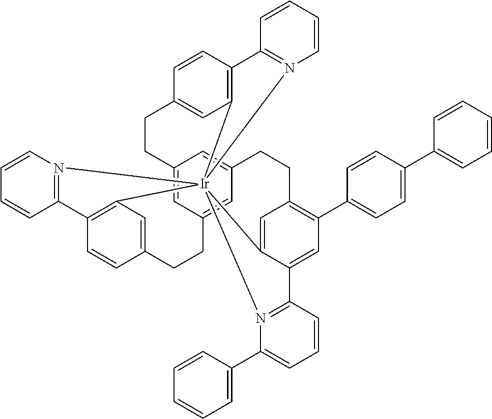

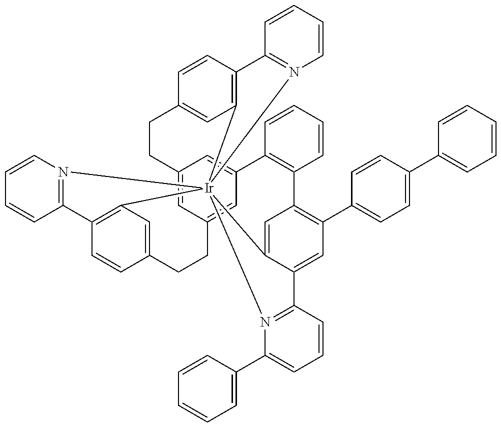

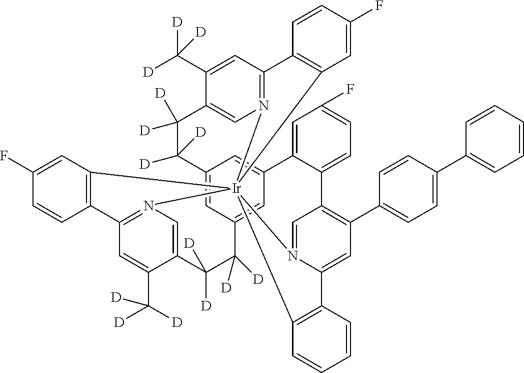

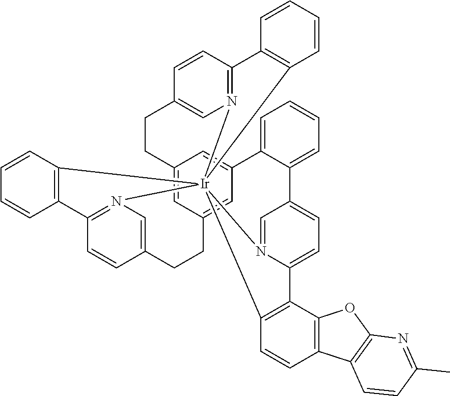

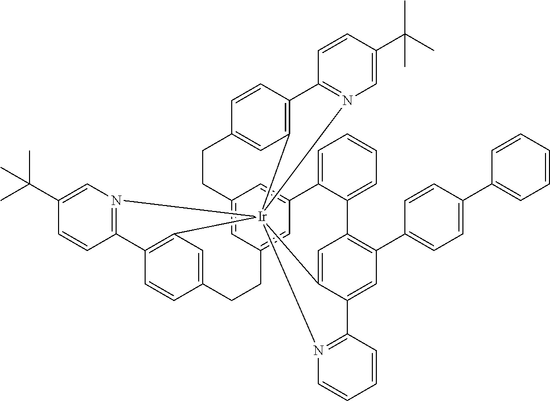

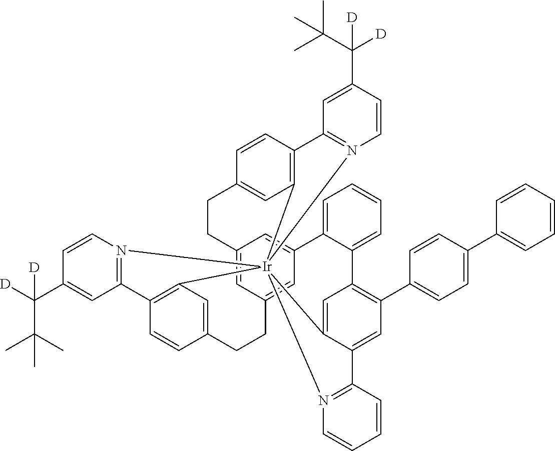

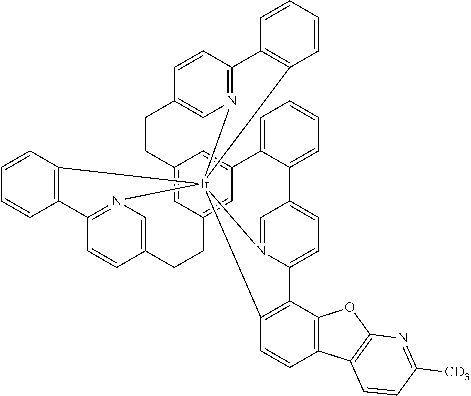

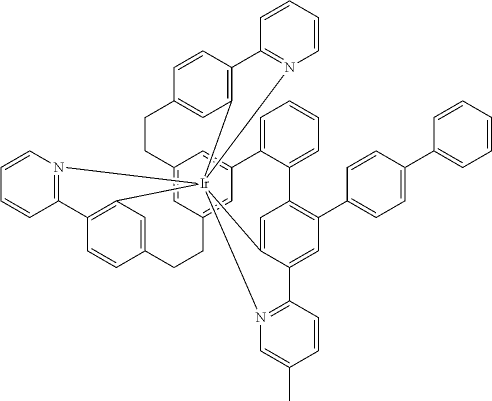

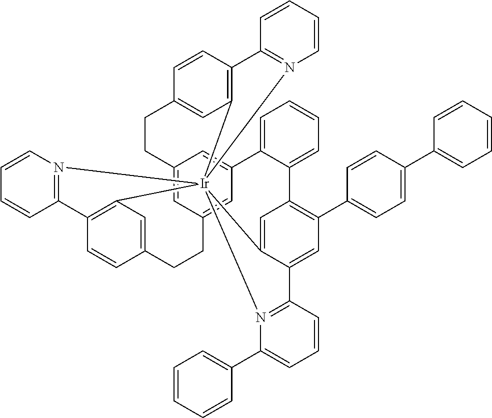

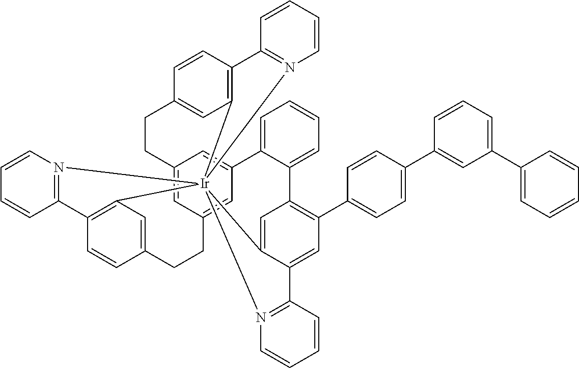

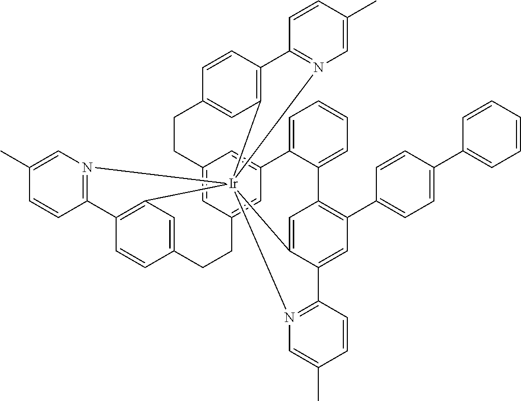

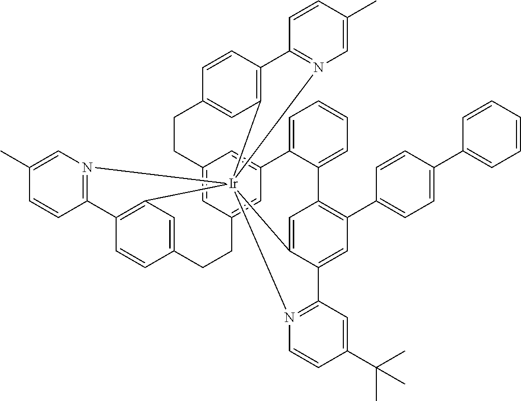

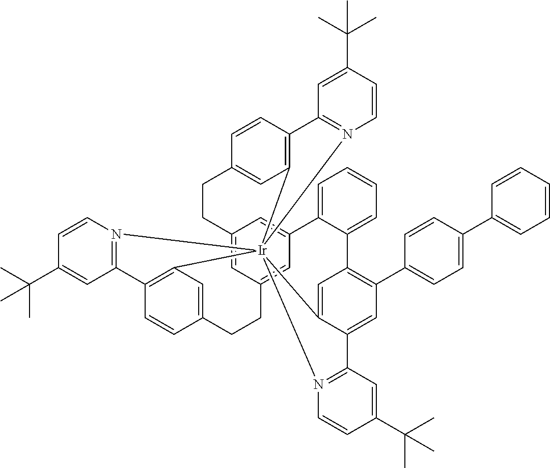

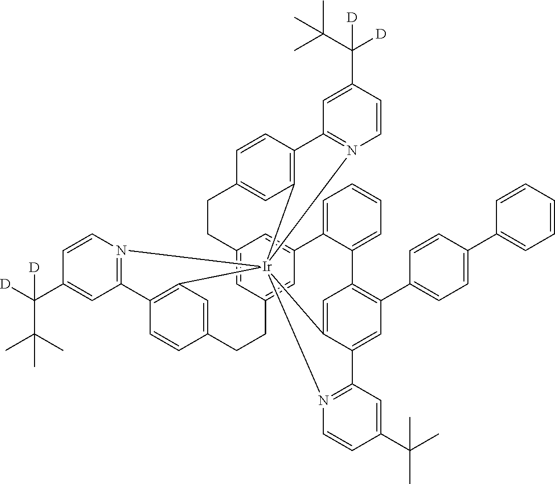

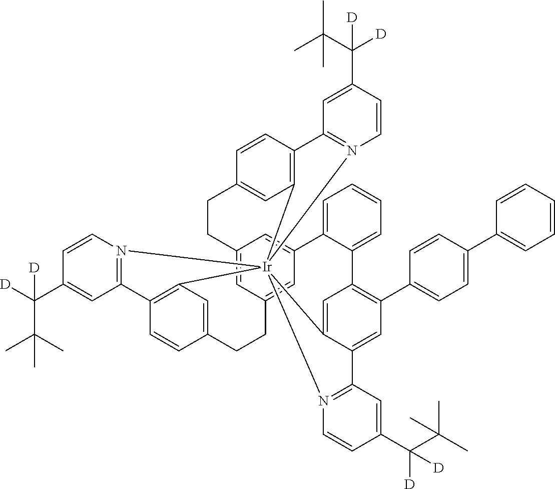

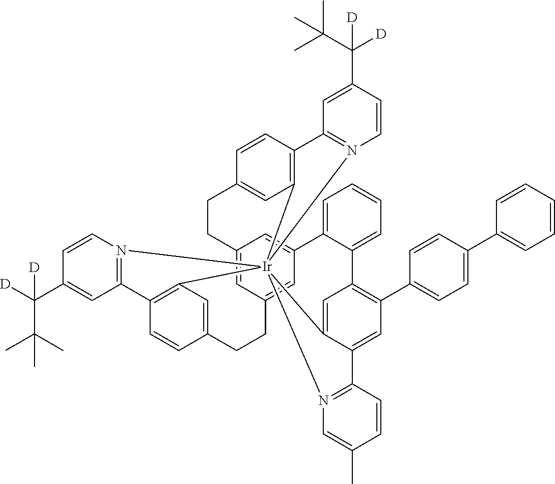

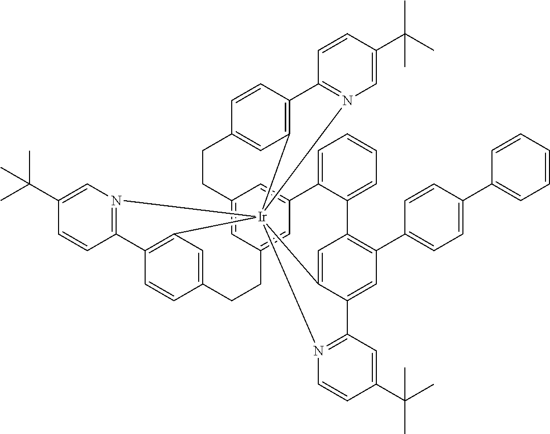

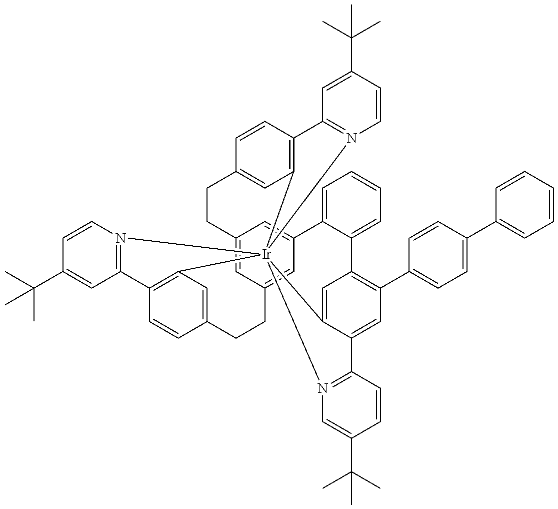

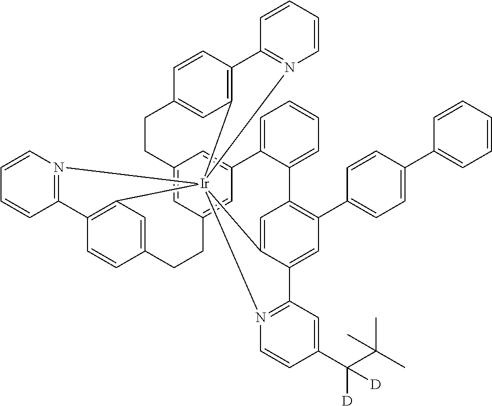

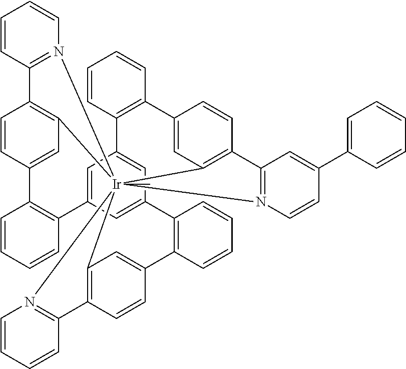

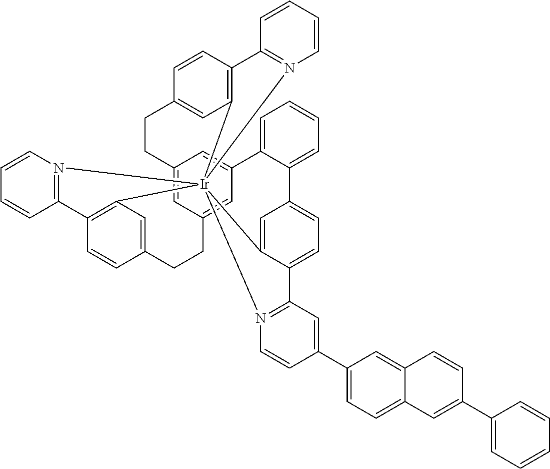

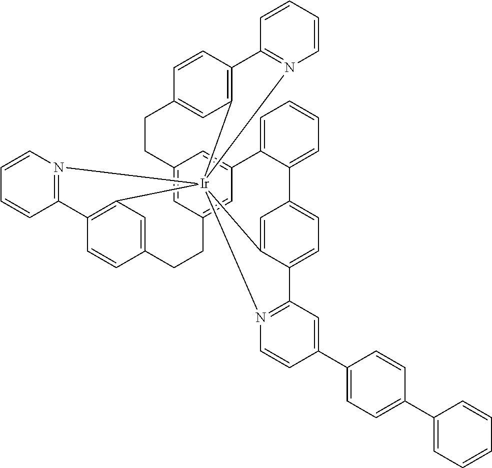

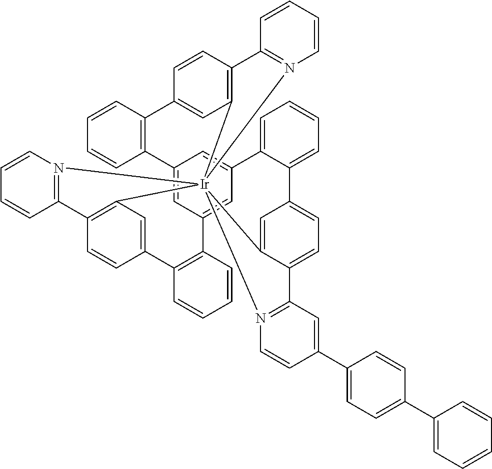

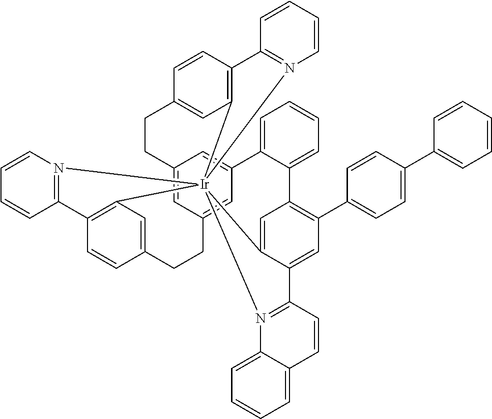

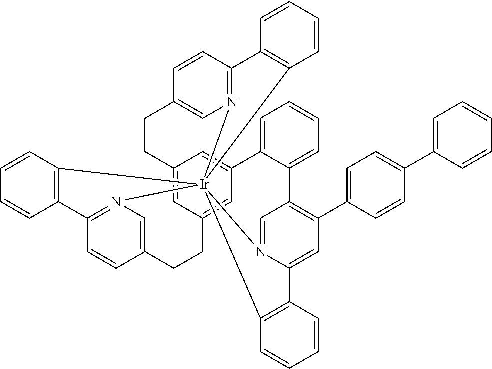

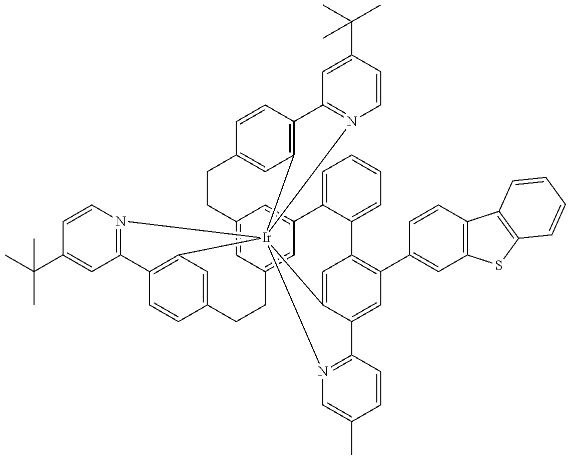

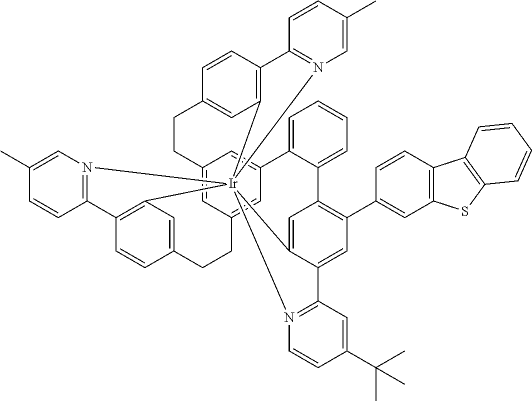

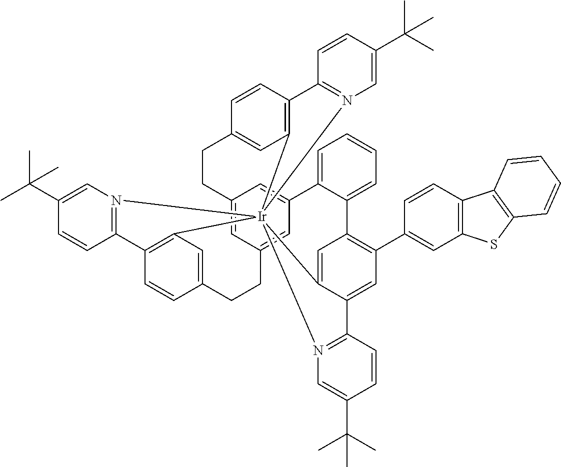

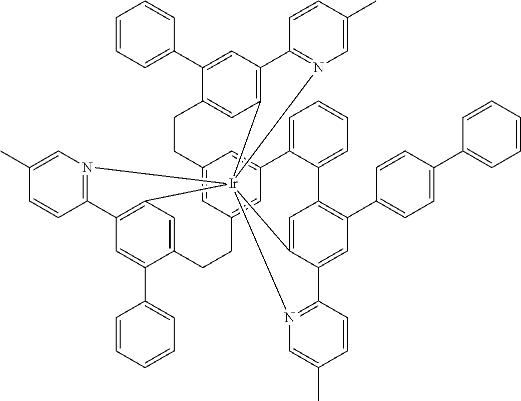

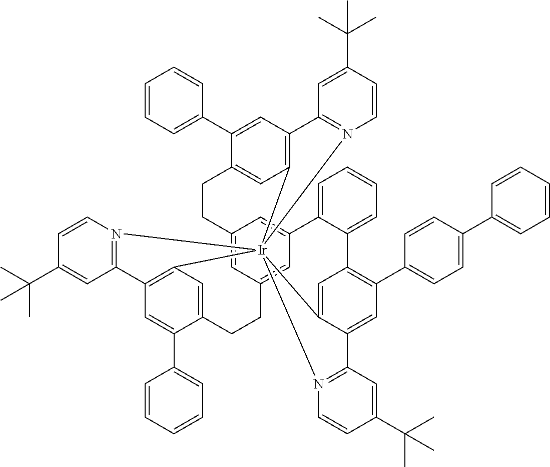

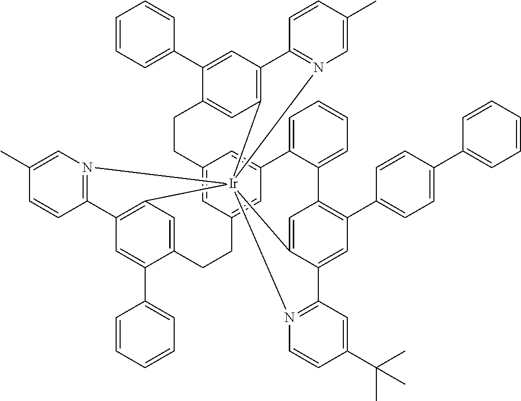

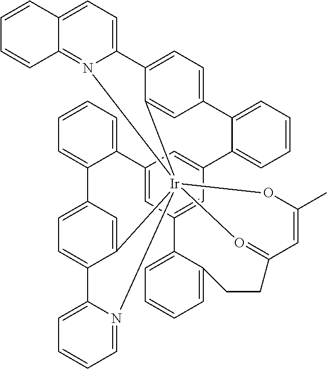

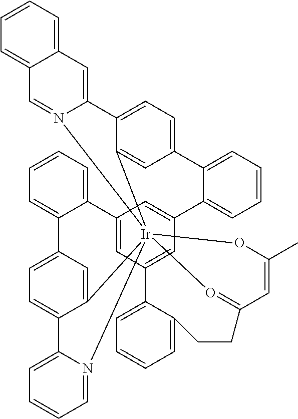

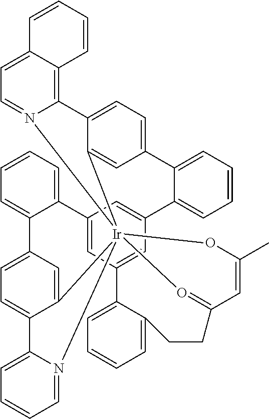

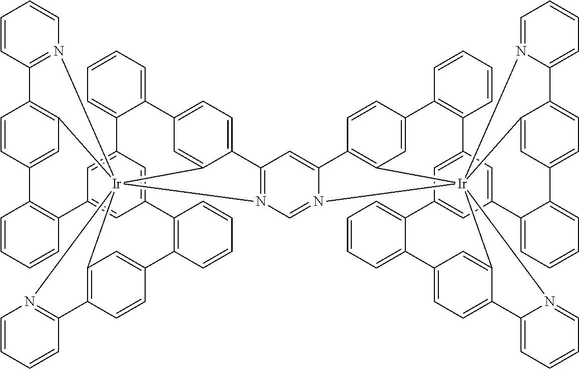

/
=)

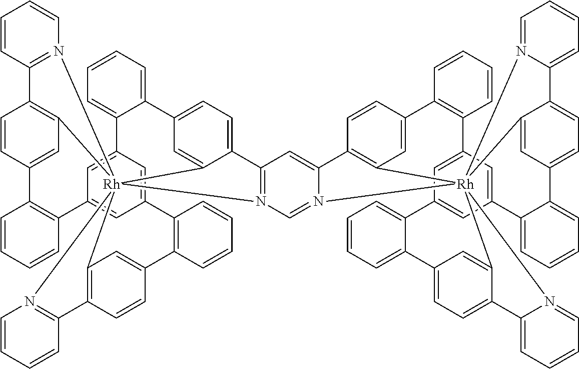

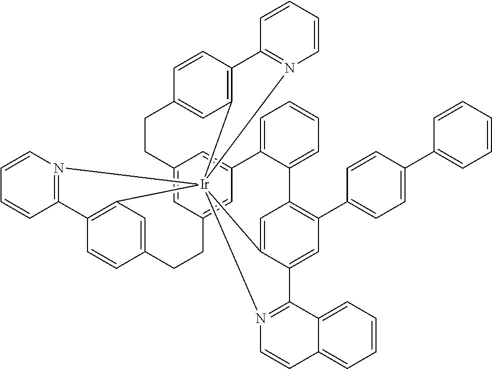

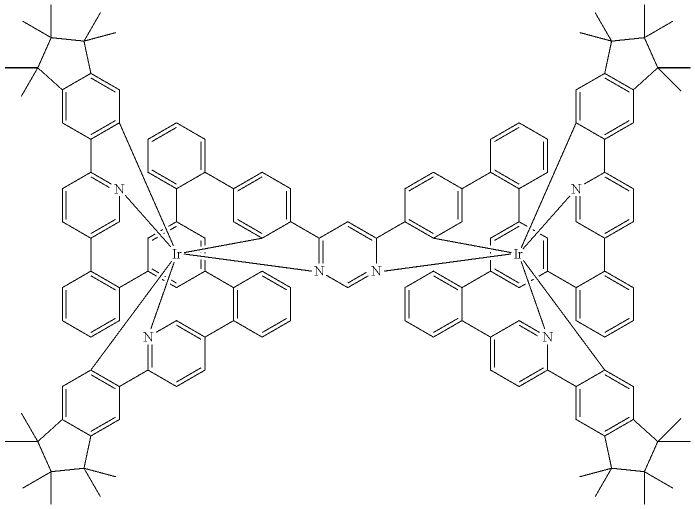

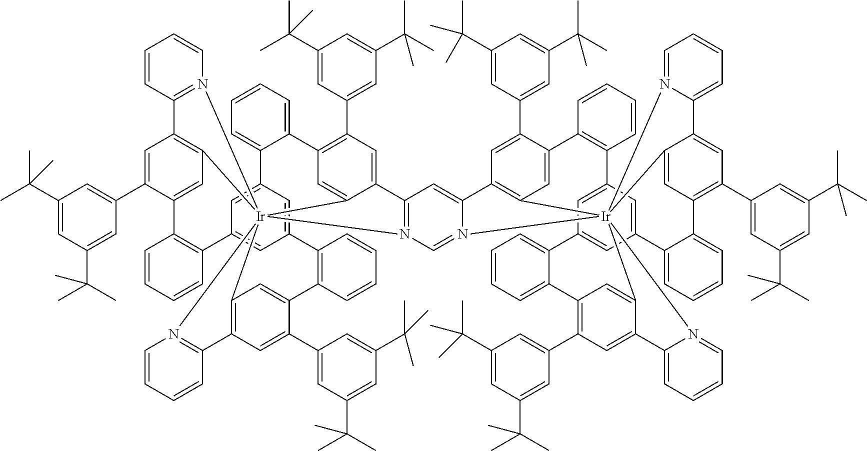

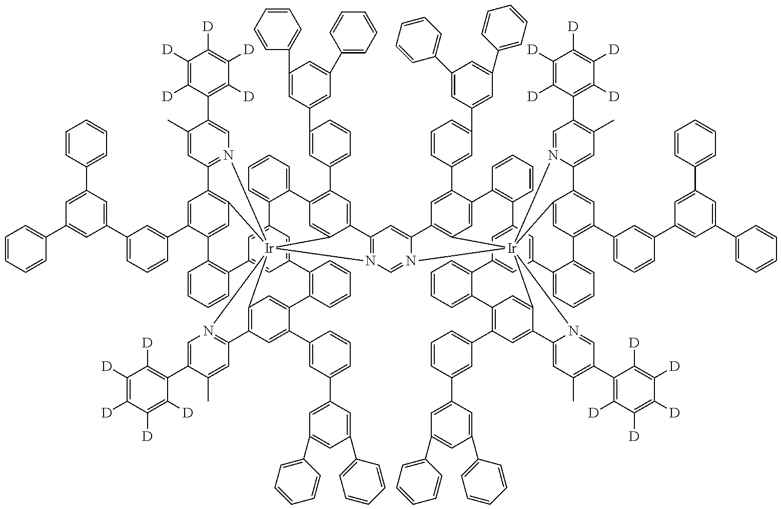

In the mixtures of the invention or in the light-emitting layer of the device of the invention, any mixture selected from the sum of the mixtures M1 to M729 is preferably combined with a compound of the formula (3) or a compound of the formulae (I) to (VI) or a compound from table 4.

The light-emitting layer in the organic electroluminescent device of the invention, comprising at least one phosphorescent emitter, is preferably an infrared-emitting or yellow-, orange-, red-, green-, blue- or ultraviolet-emitting layer, more preferably a yellow- or green-emitting layer and most preferably a green-emitting layer.

A yellow-emitting layer is understood here to mean a layer having a photoluminescence maximum within the range from 540 to 570 nm. An orange-emitting layer is understood to mean a layer having a photoluminescence maximum within the range from 570 to 600 nm. A red-emitting layer is understood to mean a layer having a photoluminescence maximum within the range from 600 to 750 nm. A green-emitting layer is understood to mean a layer having a photoluminescence maximum within the range from 490 to 540 nm. A blue-emitting layer is understood to mean a layer having a photoluminescence maximum within the range from 440 to 490 nm. The photoluminescence maximum of the layer is determined here by measuring the photoluminescence spectrum of the layer having a layer thickness of 50 nm at room temperature, said layer having the inventive combination of the host materials of the formulae (1) and (2) and the appropriate emitter. The photoluminescence spectrum of the layer is recorded, for example, with a commercial photoluminescence spectrometer.

The photoluminescence spectrum of the emitter chosen is generally measured in oxygen-free solution, 10⁻⁵ molar, at room temperature, a suitable solvent being any in which the chosen emitter dissolves in the concentration mentioned. Particularly suitable solvents are typically toluene or 2-methyl-THF, but also dichloromethane. Measurement is effected with a commercial photoluminescence spectrometer. The triplet energy T1 in eV is determined from the photoluminescence spectra of the emitters. Initially the peak maximum Plmax. (in nm) of the photoluminescence spectrum is determined. The peak maximum Plmax. (in nm) is then converted into eV according to: E(T1 in eV)=1240/E(T1 in nm)=1240/PLmax. (in nm).

Preferred phosphorescent emitters are accordingly yellow emitters, preferably of the formula (3), of the formulae (I) to (VI) or from table 4, the triplet energy T1 of which is preferably ˜2.3 eV to ˜2.1 eV.

Preferred phosphorescent emitters are accordingly green emitters, preferably of the formula (3), of the formulae (I) to (VI) or from table 4, the triplet energy T1 of which is preferably ˜2.5 eV to ˜2.3 eV.

Particularly preferred phosphorescent emitters are accordingly green emitters, preferably of the formula (3), of the formulae (I) to (VI) or from table 4 as described above, the triplet energy T₁ of which is preferably ˜2.5 eV to ˜2.3 eV.

Most preferably, green emitters, preferably of the formula (3), of the formulae (I) to (VI) or from table 4, as described above, are selected for the composition of the invention or emitting layer of the invention.

It is also possible for fluorescent emitters to be present in the light-emitting layer of the device of the invention.

Preferred fluorescent emitters are selected from the class of the arylamines. An arylamine or an aromatic amine in the context of this invention is understood to mean a compound containing three substituted or unsubstituted aromatic or heteroaromatic ring systems bonded directly to the nitrogen.

In a further preferred embodiment of the invention, the at least one light-emitting layer of the organic electroluminescent device, as well as the host materials 1 and 2, as described or described as preferable above, may comprise further host materials or matrix materials called mixed matrix systems. The mixed matrix systems preferably comprise three or four different matrix materials, more preferably three different matrix materials (in other words, one further matrix component in addition to the host materials 1 and 2, as described above). Particularly suitable matrix materials which can be used in combination as matrix component in a mixed matrix system are selected from wide-band gap materials, bipolar host materials, electron transport materials (ETM) and hole transport materials (HTM).

A wide-band gap material is understood herein to mean a material within the scope of the disclosure of U.S. Pat. No. 7,294,849 which is characterized by a band gap of at least 3.5 eV, the band gap being understood to mean the gap between the HOMO and LUMO energy of a material.

Preferably, the mixed matrix system is optimized for an emitter of the formula (3), the formulae (I) to (VI), or from table 4.

In one embodiment of the present invention, the mixture does not comprise any further constituents, i.e. functional materials, aside from the constituents of electron-transporting host material of the formula (1) and hole-transporting host material of the formula (2). These are material mixtures that are used as such for production of the light-emitting layer. These mixtures are also referred to as premix systems that are used as the sole material source in the vapour deposition of the host materials for the light-emitting layer and have a constant mixing ratio in the vapour deposition. In this way, it is possible in a simple and rapid manner to achieve the vapour deposition of a layer with homogeneous distribution of the components without the need for precise actuation of a multitude of material sources.

In an alternative embodiment of the present invention, the mixture also comprises the phosphorescent emitter, as described above, in addition to the constituents of electron-transporting host material of the formula (1) and hole-transporting host material of the formula (2). In the case of a suitable mixing ratio in the vapour deposition, this mixture may also be used as the sole material source, as described above.

The components or constituents of the light-emitting layer of the device of the invention may thus be processed by vapour deposition or from solution. The material combination of host materials 1 and 2, as described or described as preferable above, optionally with the phosphorescent emitter, as described or described as preferable above, is provided for this purpose in a formulation containing at least one solvent. These formulations may, for example, be solutions, dispersions or emulsions. For this purpose, it may be preferable to use mixtures of two or more solvents.

The present invention therefore further provides a formulation comprising an inventive mixture of host materials 1 and 2, as described above, optionally in combination with a phosphorescent emitter, as described or described as preferable above, and at least one solvent.

Suitable and preferred solvents are, for example, toluene, anisole, o-, m- or p-xylene, methyl benzoate, mesitylene, tetralin, veratrole, THF, methyl-THF, THP, chlorobenzene, dioxane, phenoxytoluene, especially 3-phenoxytoluene, (−)-fenchone, 1,2,3,5-tetramethylbenzene, 1,2,4,5-tetramethylbenzene, 1-methylnaphthalene, 2-methylbenzothiazole, 2-phenoxyethanol, 2-pyrrolidinone, 3-methylanisole, 4-methylanisole, 3,4-dimethylanisole, 3,5-dimethylanisole, acetophenone, α-terpineol, benzothiazole, butyl benzoate, cumene, cyclohexanol, cyclohexanone, cyclohexylbenzene, decalin, dodecylbenzene, ethyl benzoate, indane, methyl benzoate, NMP, p-cymene, phenetole, 1,4-diisopropylbenzene, dibenzyl ether, diethylene glycol butyl methyl ether, triethylene glycol butyl methyl ether, diethylene glycol dibutyl ether, triethylene glycol dimethyl ether, diethylene glycol monobutyl ether, tripropylene glycol dimethyl ether, tetraethylene glycol dimethyl ether, 2-isopropylnaphthalene, pentylbenzene, hexylbenzene, heptylbenzene, octylbenzene, 1,1-bis(3,4-dimethylphenyl)ethane, hexamethylindane or mixtures of these solvents.

The formulation here may also comprise at least one further organic or inorganic compound which is likewise used in the light-emitting layer of the device of the invention, especially a further emitting compound and/or a further matrix material. Suitable emitting compounds and further matrix materials have already been detailed above.

The light-emitting layer in the device of the invention, according to the preferred embodiments and the emitting compound, contains preferably between 99.9% and 1% by volume, further preferably between 99% and 10% by volume, especially preferably between 98% and 60% by volume, very especially preferably between 97% and 80% by volume, of matrix material composed of at least one compound of the formula (1) and at least one compound of the formula (2) according to the preferred embodiments, based on the overall composition of emitter and matrix material. Correspondingly, the light-emitting layer in the device of the invention preferably contains between 0.1% and 99% by volume, further preferably between 1% and 90% by volume, more preferably between 2% and 40% by volume, most preferably between 3% and 20% by volume, of the emitter based on the overall composition of the light-emitting layer composed of emitter and matrix material. If the compounds are processed from solution, preference is given to using the corresponding amounts in % by weight rather than the above-specified amounts in % by volume.

The light-emitting layer in the device of the invention, according to the preferred embodiments and the emitting compound, preferably contains the matrix material of the formula (1) and the matrix material of the formula (2) in a percentage by volume ratio between 3:1 and 1:3, preferably between 1:2.5 and 1:1, more preferably between 1:2 and 1:1. If the compounds are processed from solution, preference is given to using the corresponding ratio in % by weight rather than the above-specified ratio in % by volume.

The present invention also relates to an organic electroluminescent device as described or described as preferable above, wherein the organic layer comprises a hole injection layer (HIL) and/or a hole transport layer (HTL), the hole-injecting material and hole-transporting material of which is a monoamine that does not contain a carbazole unit. The hole-injecting material and hole-transporting material preferably comprises a monoamine containing a fluorenyl or bispirofluorenyl group, but no carbazole unit.

Preferred monoamines which are used in accordance with the invention in the organic layer of the device of the invention may be described by the formula (4)

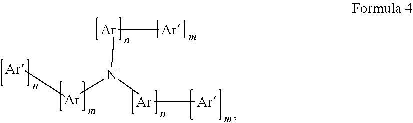

where the symbols and indices for this formula (4) are defined as follows:
Ar and Ar′ are independently at each occurrence an aromatic ring system having 6 to 40 ring atoms or a heteroaromatic ring system having 7 to 40 ring atoms, where carbazole units in the heteroaromatic ring system are excluded;
n is independently at each occurrence 0 or 1;
m is independently at each occurrence 0 or 1.

Preferably at least one Ar′ in formula (4) is a group of the following formulae (4a) or (4b)

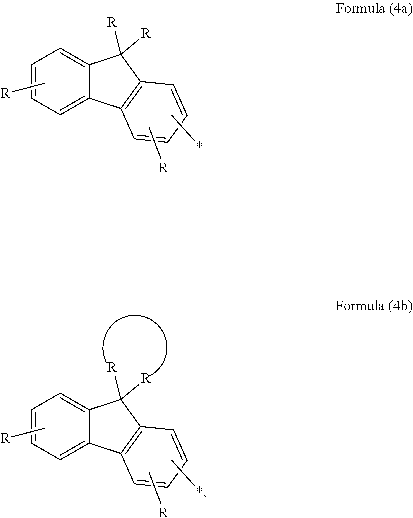

where R in formulae (4a) and (4b) is identical or different at each occurrence and is selected from H, D, F, CN, a straight-chain alkyl group having 1 to 20 carbon atoms or a branched or cyclic alkyl group having 3 to 20 carbon atoms, where one or more nonadjacent CH₂ groups may be replaced by R²C═CR², O or S and where one or more hydrogen atoms may be replaced by D, F, or CN and where two R may form a cyclic or polycyclic ring and * denotes the attachment to the remainder of the formula (4).

Preferred monoamines which are used in accordance with the invention in the organic layer of the device of the invention are described in table 5.

TABLE 5

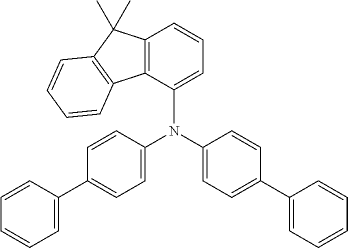 [SMILES: CC1(C)c2ccccc2-c2c(N(c3ccc(-c4ccccc4)cc3)c3ccc(-c4ccccc4)cc3)cccc21]

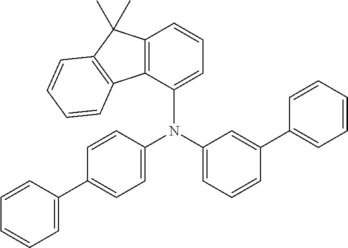 [SMILES: CC1(C)c2ccccc2-c2c(N(c3ccc(-c4ccccc4)cc3)c3cccc(-c4ccccc4)c3)cccc21]

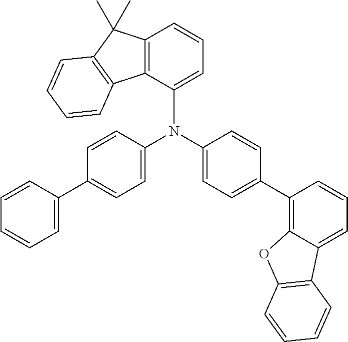 [SMILES: CC1(C)c2ccccc2-c2c(N(c3ccc(-c4ccccc4)cc3)c3ccc(-c4cccc5c4oc4ccccc45)cc3)cccc21]

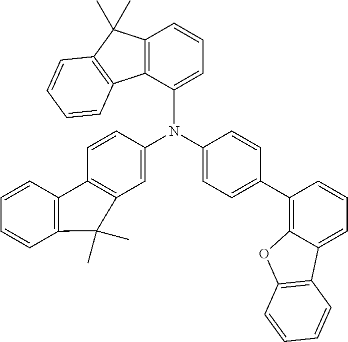 [SMILES: CC1(C)c2ccccc2-c2ccc(N(c3ccc(-c4cccc5c4oc4ccccc45)cc3)c3cccc4c3-c3ccccc3C4(C)C)cc21]

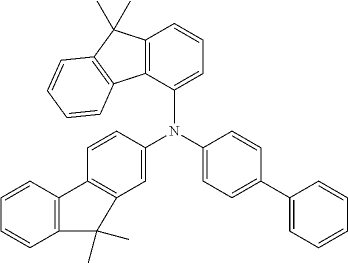 [SMILES: CC1(C)c2ccccc2-c2ccc(N(c3ccc(-c4ccccc4)cc3)c3cccc4c3-c3ccccc3C4(C)C)cc21]

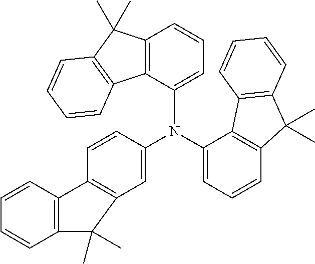 [SMILES: CC1(C)c2ccccc2-c2ccc(N(c3cccc4c3-c3ccccc3C4(C)C)c3cccc4c3-c3ccccc3C4(C)C)cc21]

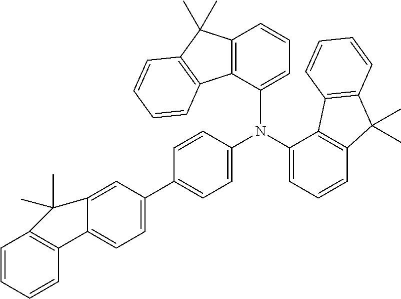 [SMILES: CC1(C)c2ccccc2-c2ccc(-c3ccc(N(c4cccc5c4-c4ccccc4C5(C)C)c4cccc5c4-c4ccccc4C5(C)C)cc3)cc21]

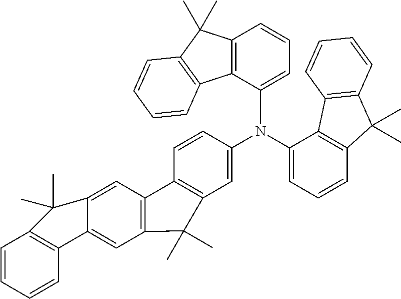 [SMILES: CC1(C)c2ccccc2-c2cc3c(cc21)-c1ccc(N(c2cccc4c2-c2ccccc2C4(C)C)c2cccc4c2-c2ccccc2C4(C)C)cc1C3(C)C]

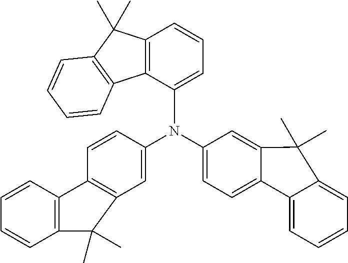 [SMILES: CC1(C)c2ccccc2-c2ccc(N(c3ccc4c(c3)C(C)(C)c3ccccc3-4)c3cccc4c3-c3ccccc3C4(C)C)cc21]

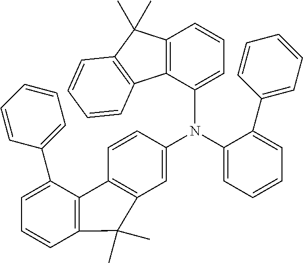 [SMILES: CC1(C)c2cc(N(c3ccccc3-c3ccccc3)c3cccc4c3-c3ccccc3C4(C)C)ccc2-c2c(-c3ccccc3)cccc21]

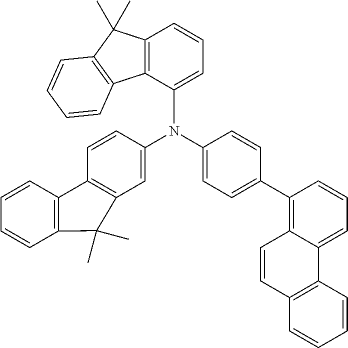 [SMILES: CC1(C)c2ccccc2-c2ccc(N(c3ccc(-c4cccc5c4ccc4ccccc45)cc3)c3cccc4c3-c3ccccc3C4(C)C)cc21]

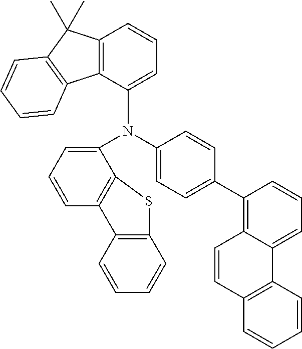 [SMILES: CC1(C)c2ccccc2-c2c(N(c3ccc(-c4cccc5c4ccc4ccccc45)cc3)c3cccc4c3sc3ccccc34)cccc21]

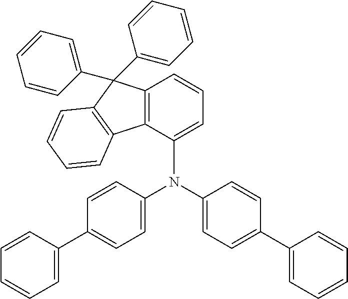 [SMILES: c1ccc(-c2ccc(N(c3ccc(-c4ccccc4)cc3)c3cccc4c3-c3ccccc3C4(c3ccccc3)c3ccccc3)cc2)cc1]

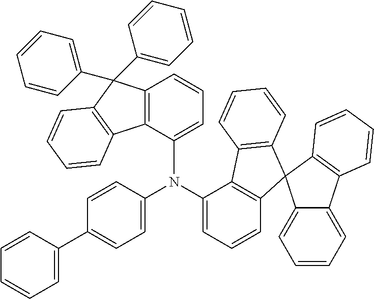 [SMILES: c1ccc(-c2ccc(N(c3cccc4c3-c3ccccc3C4(c3ccccc3)c3ccccc3)c3cccc4c3-c3ccccc3C43c4ccccc4-c4ccccc43)cc2)cc1]

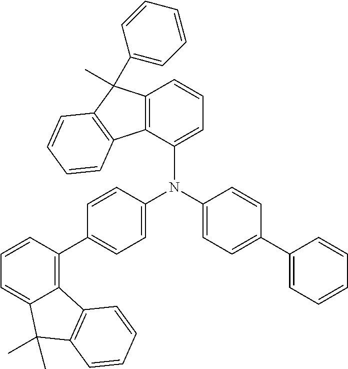 [SMILES: CC1(C)c2ccccc2-c2c(-c3ccc(N(c4ccc(-c5ccccc5)cc4)c4cccc5c4-c4ccccc4C5(C)c4ccccc4)cc3)cccc21]

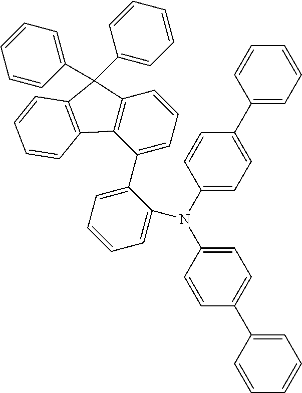 [SMILES: c1ccc(-c2ccc(N(c3ccc(-c4ccccc4)cc3)c3ccccc3-c3cccc4c3-c3ccccc3C4(c3ccccc3)c3ccccc3)cc2)cc1]

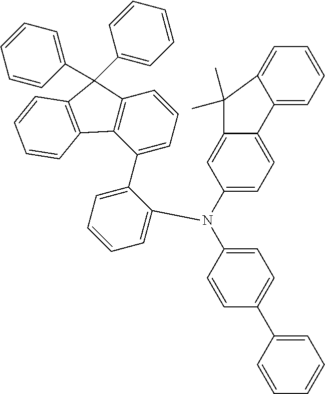 [SMILES: CC1(C)c2ccccc2-c2ccc(N(c3ccc(-c4ccccc4)cc3)c3ccccc3-c3cccc4c3-c3ccccc3C4(c3ccccc3)c3ccccc3)cc21]

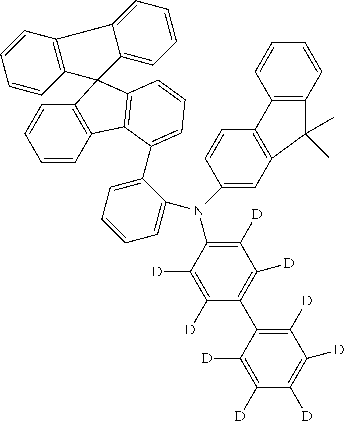 [SMILES: [2H]c1c([2H])c([2H])c(-c2c([2H])c([2H])c(N(c3ccc4c(c3)C(C)(C)c3ccccc3-4)c3ccccc3-c3cccc4c3-c3ccccc3C43c4ccccc4-c4ccccc43)c([2H])c2[2H])c([2H])c1[2H]]

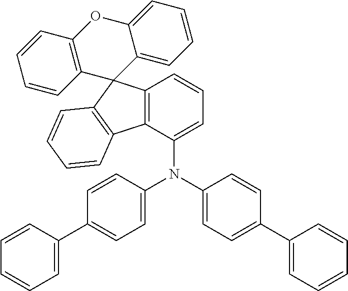 [SMILES: c1ccc(-c2ccc(N(c3ccc(-c4ccccc4)cc3)c3cccc4c3-c3ccccc3C43c4ccccc4Oc4ccccc43)cc2)cc1]

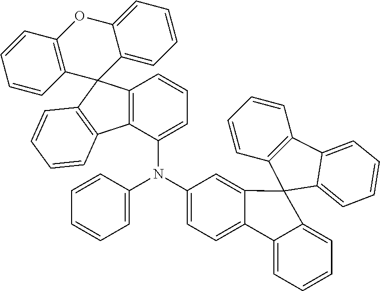 [SMILES: c1ccc(N(c2ccc3c(c2)C2(c4ccccc4-c4ccccc42)c2ccccc2-3)c2cccc3c2-c2ccccc2C32c3ccccc3Oc3ccccc32)cc1]

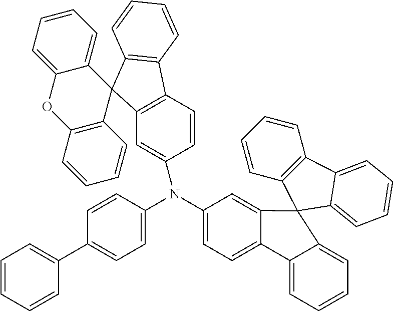 [SMILES: c1ccc(-c2ccc(N(c3ccc4c(c3)C3(c5ccccc5Oc5ccccc53)c3ccccc3-4)c3ccc4c(c3)C3(c5ccccc5-c5ccccc53)c3ccccc3-4)cc2)cc1]

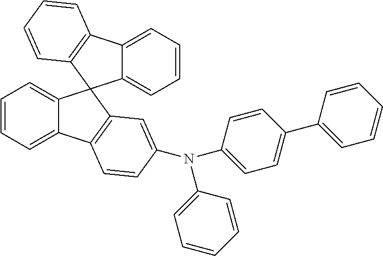 [SMILES: c1ccc(-c2ccc(N(c3ccccc3)c3ccc4c(c3)C3(c5ccccc5-c5ccccc53)c3ccccc3-4)cc2)cc1]

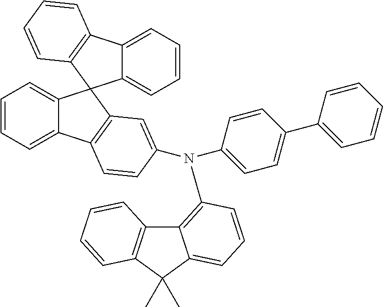 [SMILES: CC1(C)c2ccccc2-c2c(N(c3ccc(-c4ccccc4)cc3)c3ccc4c(c3)C3(c5ccccc5-c5ccccc53)c3ccccc3-4)cccc21]

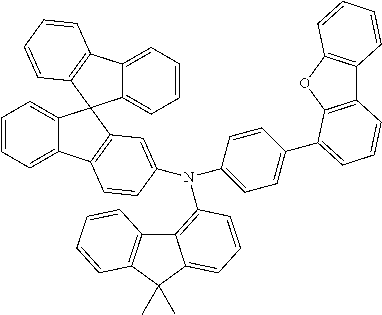 [SMILES: CC1(C)c2ccccc2-c2c(N(c3ccc(-c4cccc5c4oc4ccccc45)cc3)c3ccc4c(c3)C3(c5ccccc5-c5ccccc53)c3ccccc3-4)cccc21]

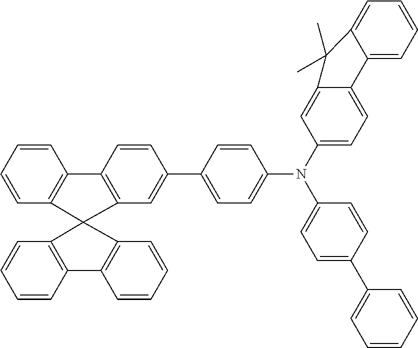 [SMILES: CC1(C)c2ccccc2-c2ccc(N(c3ccc(-c4ccccc4)cc3)c3ccc(-c4ccc5c(c4)C4(c6ccccc6-c6ccccc64)c4ccccc4-5)cc3)cc21]

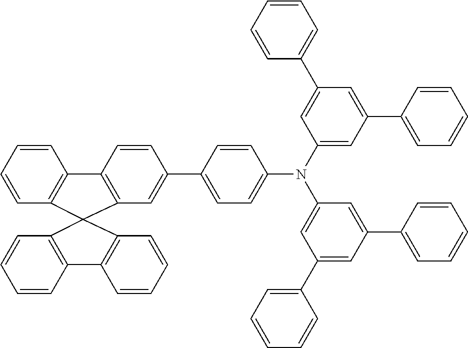 [SMILES: c1ccc(-c2cc(-c3ccccc3)cc(N(c3ccc(-c4ccc5c(c4)C4(c6ccccc6-c6ccccc64)c4ccccc4-5)cc3)c3cc(-c4ccccc4)cc(-c4ccccc4)c3)c2)cc1]

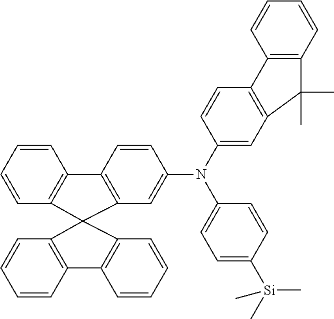 [SMILES: CC1(C)c2ccccc2-c2ccc(N(c3ccc([Si](C)(C)C)cc3)c3ccc4c(c3)C3(c5ccccc5-c5ccccc53)c3ccccc3-4)cc21]

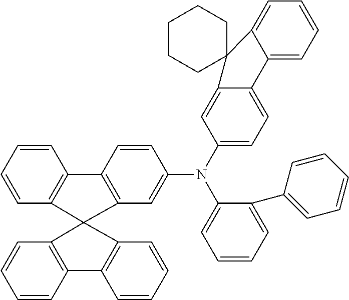 [SMILES: c1ccc(-c2ccccc2N(c2ccc3c(c2)C2(CCCCC2)c2ccccc2-3)c2ccc3c(c2)C2(c4ccccc4-c4ccccc42)c2ccccc2-3)cc1]

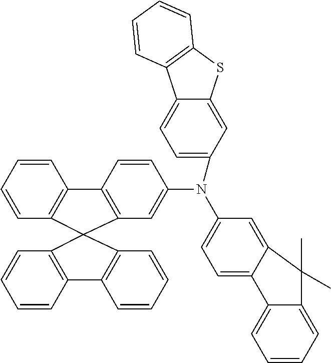 [SMILES: CC1(C)c2ccccc2-c2ccc(N(c3ccc4c(c3)C3(c5ccccc5-c5ccccc53)c3ccccc3-4)c3ccc4c(c3)sc3ccccc34)cc21]

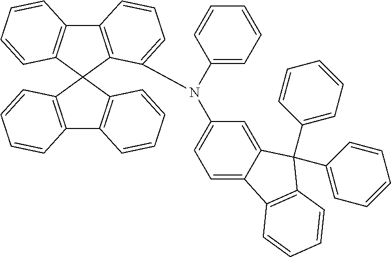 [SMILES: c1ccc(N(c2ccc3c(c2)C(c2ccccc2)(c2ccccc2)c2ccccc2-3)c2cccc3c2C2(c4ccccc4-c4ccccc42)c2ccccc2-3)cc1]

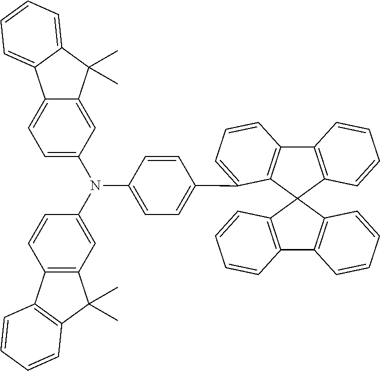 [SMILES: CC1(C)c2ccccc2-c2ccc(N(c3ccc(-c4cccc5c4C4(c6ccccc6-c6ccccc64)c4ccccc4-5)cc3)c3ccc4c(c3)C(C)(C)c3ccccc3-4)cc21]

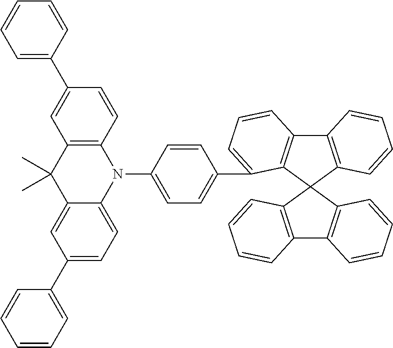 [SMILES: CC1(C)c2cc(-c3ccccc3)ccc2N(c2ccc(-c3cccc4c3C3(c5ccccc5-c5ccccc53)c3ccccc3-4)cc2)c2ccc(-c3ccccc3)cc21]

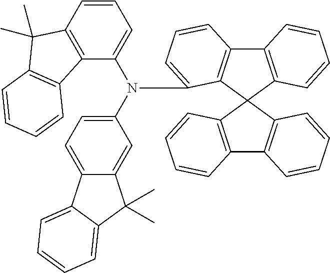 [SMILES: CC1(C)c2ccccc2-c2ccc(N(c3cccc4c3-c3ccccc3C4(C)C)c3cccc4c3C3(c5ccccc5-c5ccccc53)c3ccccc3-4)cc21]

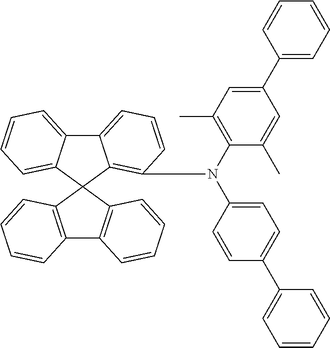 [SMILES: Cc1cc(-c2ccccc2)cc(C)c1N(c1ccc(-c2ccccc2)cc1)c1cccc2c1C1(c3ccccc3-c3ccccc31)c1ccccc1-2]

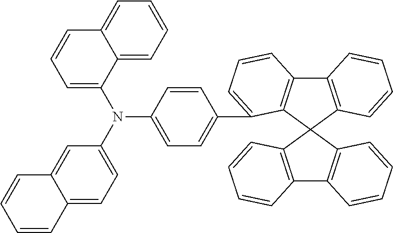 [SMILES: c1ccc2c(c1)-c1ccccc1C21c2ccccc2-c2cccc(-c3ccc(N(c4ccc5ccccc5c4)c4cccc5ccccc45)cc3)c21]

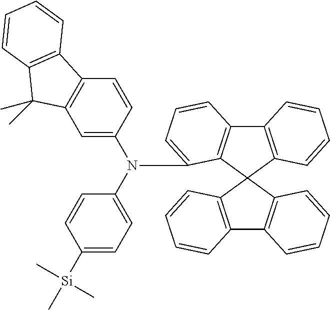 [SMILES: CC1(C)c2ccccc2-c2ccc(N(c3ccc([Si](C)(C)C)cc3)c3cccc4c3C3(c5ccccc5-c5ccccc53)c3ccccc3-4)cc21]

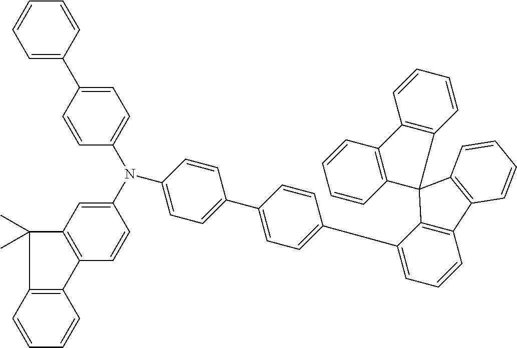 [SMILES: CC1(C)c2ccccc2-c2ccc(N(c3ccc(-c4ccccc4)cc3)c3ccc(-c4ccc(-c5cccc6c5C5(c7ccccc7-c7ccccc75)c5ccccc5-6)cc4)cc3)cc21]

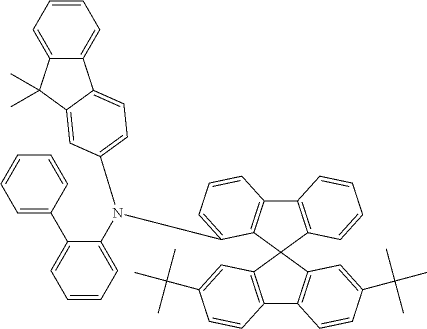 [SMILES: CC(C)(C)c1ccc2c(c1)C1(c3cc(C(C)(C)C)ccc3-2)c2ccccc2-c2cccc(N(c3ccc4c(c3)C(C)(C)c3ccccc3-4)c3ccccc3-c3ccccc3)c21]

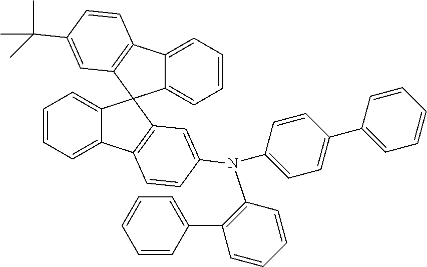 [SMILES: CC(C)(C)c1ccc2c(c1)C1(c3ccccc3-c3ccc(N(c4ccc(-c5ccccc5)cc4)c4ccccc4-c4ccccc4)cc31)c1ccccc1-2]

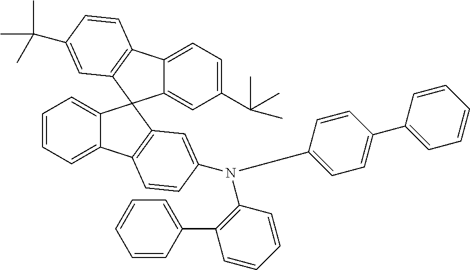 [SMILES: CC(C)(C)c1ccc2c(c1)C1(c3ccccc3-c3ccc(N(c4ccc(-c5ccccc5)cc4)c4ccccc4-c4ccccc4)cc31)c1cc(C(C)(C)C)ccc1-2]

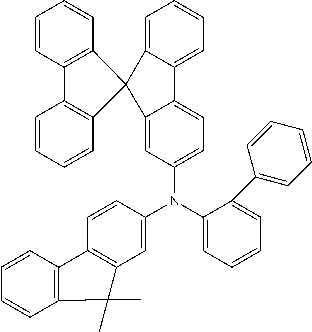 [SMILES: CC1(C)c2ccccc2-c2ccc(N(c3ccc4c(c3)C3(c5ccccc5-c5ccccc53)c3ccccc3-4)c3ccccc3-c3ccccc3)cc21]

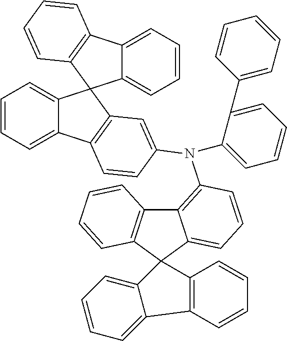 [SMILES: c1ccc(-c2ccccc2N(c2ccc3c(c2)C2(c4ccccc4-c4ccccc42)c2ccccc2-3)c2cccc3c2-c2ccccc2C32c3ccccc3-c3ccccc32)cc1]

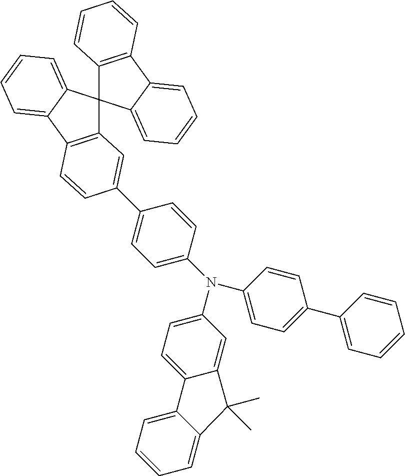 [SMILES: CC1(C)c2ccccc2-c2ccc(N(c3ccc(-c4ccccc4)cc3)c3ccc(-c4ccc5c(c4)C4(c6ccccc6-c6ccccc64)c4ccccc4-5)cc3)cc21]

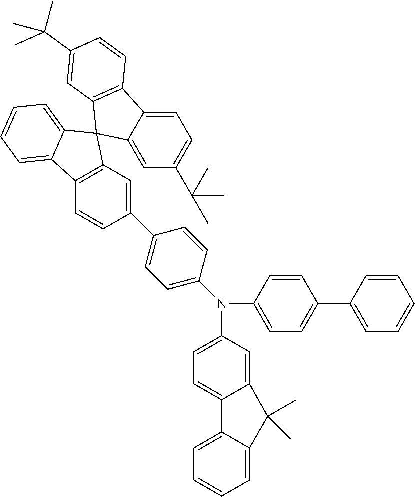 [SMILES: CC(C)(C)c1ccc2c(c1)C1(c3ccccc3-c3ccc(-c4ccc(N(c5ccc(-c6ccccc6)cc5)c5ccc6c(c5)C(C)(C)c5ccccc5-6)cc4)cc31)c1cc(C(C)(C)C)ccc1-2]

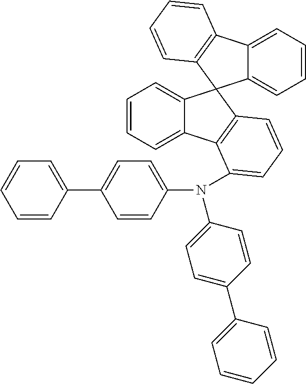 [SMILES: c1ccc(-c2ccc(N(c3ccc(-c4ccccc4)cc3)c3cccc4c3-c3ccccc3C43c4ccccc4-c4ccccc43)cc2)cc1]

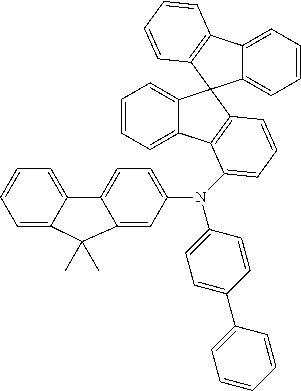 [SMILES: CC1(C)c2ccccc2-c2ccc(N(c3ccc(-c4ccccc4)cc3)c3cccc4c3-c3ccccc3C43c4ccccc4-c4ccccc43)cc21]

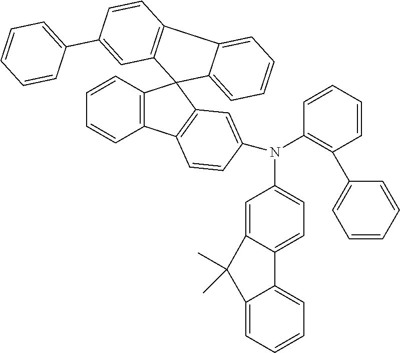 [SMILES: CC1(C)c2ccccc2-c2ccc(N(c3ccc4c(c3)C3(c5ccccc5-c5ccc(-c6ccccc6)cc53)c3ccccc3-4)c3ccccc3-c3ccccc3)cc21]

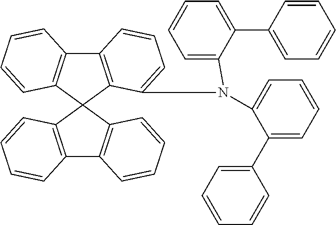 [SMILES: c1ccc(-c2ccccc2N(c2ccccc2-c2ccccc2)c2cccc3c2C2(c4ccccc4-c4ccccc42)c2ccccc2-3)cc1]

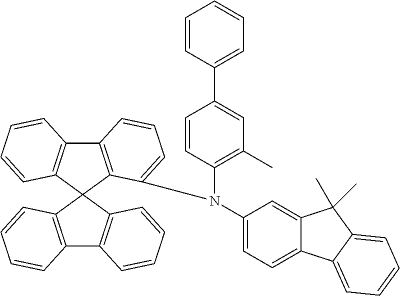 [SMILES: Cc1cc(-c2ccccc2)ccc1N(c1ccc2c(c1)C(C)(C)c1ccccc1-2)c1cccc2c1C1(c3ccccc3-c3ccccc31)c1ccccc1-2]

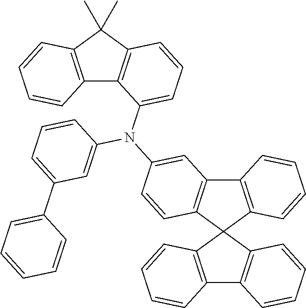 [SMILES: CC1(C)c2ccccc2-c2c(N(c3cccc(-c4ccccc4)c3)c3ccc4c(c3)-c3ccccc3C43c4ccccc4-c4ccccc43)cccc21]

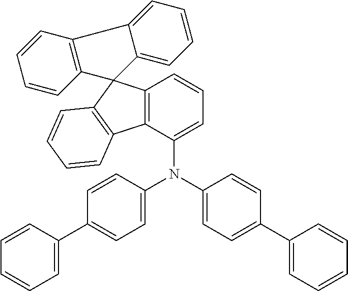 [SMILES: c1ccc(-c2ccc(N(c3ccc(-c4ccccc4)cc3)c3cccc4c3-c3ccccc3C43c4ccccc4-c4ccccc43)cc2)cc1]

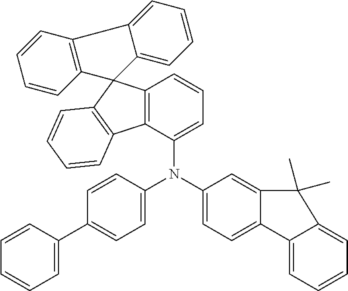 [SMILES: CC1(C)c2ccccc2-c2ccc(N(c3ccc(-c4ccccc4)cc3)c3cccc4c3-c3ccccc3C43c4ccccc4-c4ccccc43)cc21]

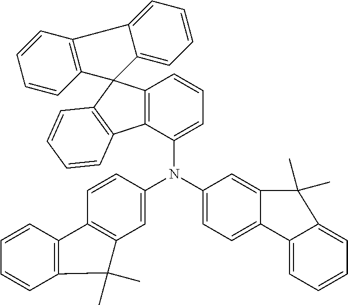 [SMILES: CC1(C)c2ccccc2-c2ccc(N(c3ccc4c(c3)C(C)(C)c3ccccc3-4)c3cccc4c3-c3ccccc3C43c4ccccc4-c4ccccc43)cc21]

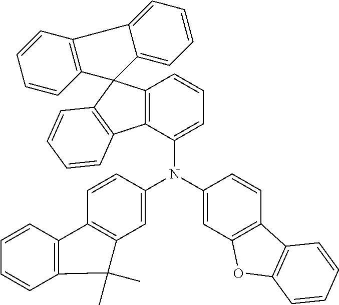 [SMILES: CC1(C)c2ccccc2-c2ccc(N(c3ccc4c(c3)oc3ccccc34)c3cccc4c3-c3ccccc3C43c4ccccc4-c4ccccc43)cc21]

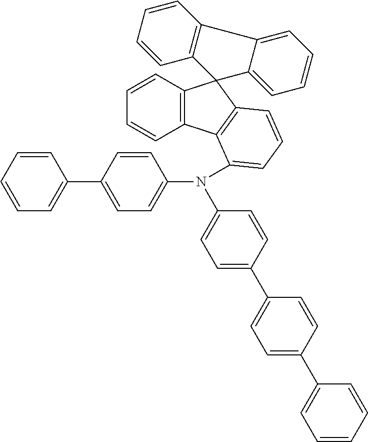 [SMILES: c1ccc(-c2ccc(-c3ccc(N(c4ccc(-c5ccccc5)cc4)c4cccc5c4-c4ccccc4C54c5ccccc5-c5ccccc54)cc3)cc2)cc1]

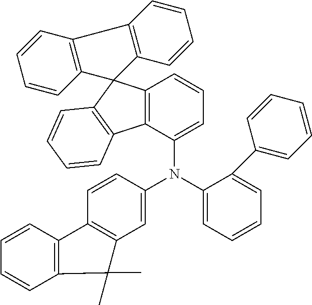 [SMILES: CC1(C)c2ccccc2-c2ccc(N(c3ccccc3-c3ccccc3)c3cccc4c3-c3ccccc3C43c4ccccc4-c4ccccc43)cc21]

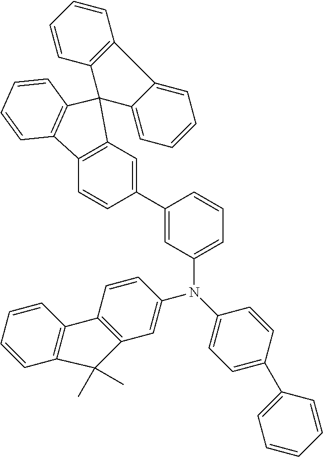 [SMILES: CC1(C)c2ccccc2-c2ccc(N(c3ccc(-c4ccccc4)cc3)c3cccc(-c4ccc5c(c4)C4(c6ccccc6-c6ccccc64)c4ccccc4-5)c3)cc21]

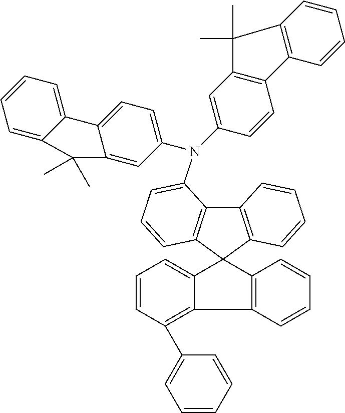 [SMILES: CC1(C)c2ccccc2-c2ccc(N(c3ccc4c(c3)C(C)(C)c3ccccc3-4)c3cccc4c3-c3ccccc3C43c4ccccc4-c4c(-c5ccccc5)cccc43)cc21]

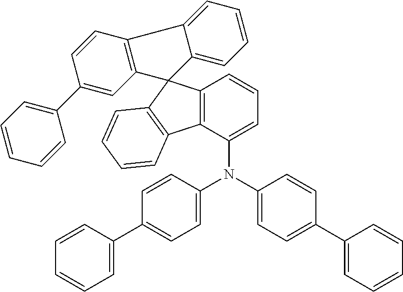 [SMILES: c1ccc(-c2ccc(N(c3ccc(-c4ccccc4)cc3)c3cccc4c3-c3ccccc3C43c4ccccc4-c4ccc(-c5ccccc5)cc43)cc2)cc1]

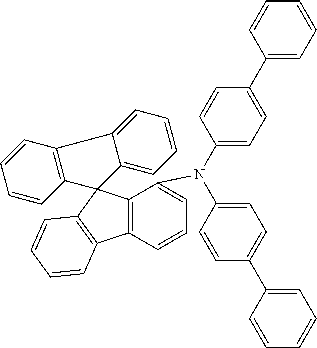 [SMILES: c1ccc(-c2ccc(N(c3ccc(-c4ccccc4)cc3)c3cccc4c3C3(c5ccccc5-c5ccccc53)c3ccccc3-4)cc2)cc1]

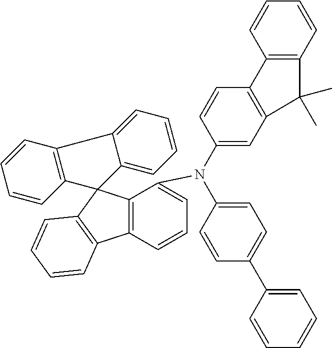 [SMILES: CC1(C)c2ccccc2-c2ccc(N(c3ccc(-c4ccccc4)cc3)c3cccc4c3C3(c5ccccc5-c5ccccc53)c3ccccc3-4)cc21]

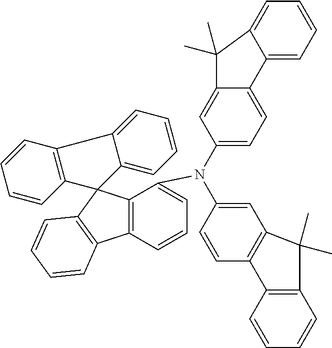 [SMILES: CC1(C)c2ccccc2-c2ccc(N(c3ccc4c(c3)C(C)(C)c3ccccc3-4)c3cccc4c3C3(c5ccccc5-c5ccccc53)c3ccccc3-4)cc21]

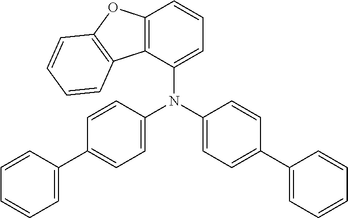 [SMILES: c1ccc(-c2ccc(N(c3ccc(-c4ccccc4)cc3)c3cccc4oc5ccccc5c34)cc2)cc1]

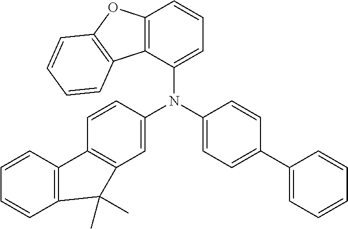 [SMILES: CC1(C)c2ccccc2-c2ccc(N(c3ccc(-c4ccccc4)cc3)c3cccc4oc5ccccc5c34)cc21]

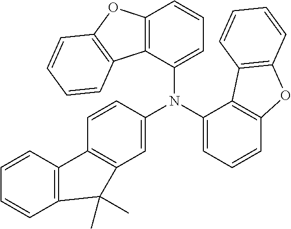 [SMILES: CC1(C)c2ccccc2-c2ccc(N(c3cccc4oc5ccccc5c34)c3cccc4oc5ccccc5c34)cc21]

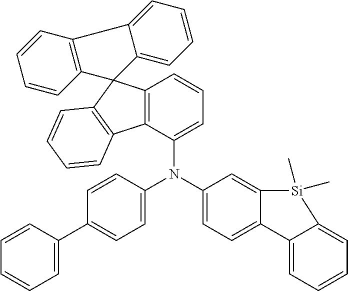 [SMILES: C[Si]1(C)c2ccccc2-c2ccc(N(c3ccc(-c4ccccc4)cc3)c3cccc4c3-c3ccccc3C43c4ccccc4-c4ccccc43)cc21]

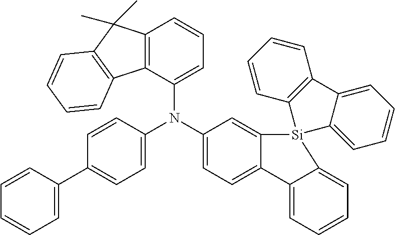 [SMILES: CC1(C)c2ccccc2-c2c(N(c3ccc(-c4ccccc4)cc3)c3ccc4c(c3)[Si]3(c5ccccc5-c5ccccc53)c3ccccc3-4)cccc21]

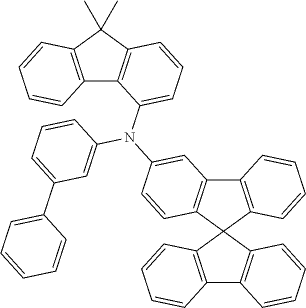 [SMILES: CC1(C)c2ccccc2-c2c(N(c3cccc(-c4ccccc4)c3)c3ccc4c(c3)-c3ccccc3C43c4ccccc4-c4ccccc43)cccc21]

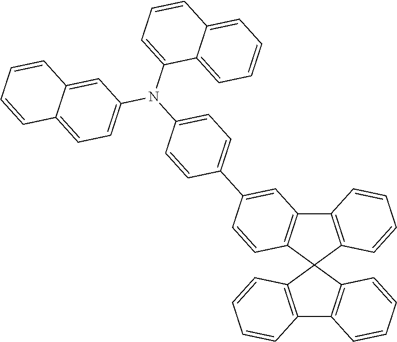 [SMILES: c1ccc2c(c1)-c1ccccc1C21c2ccccc2-c2cc(-c3ccc(N(c4ccc5ccccc5c4)c4cccc5ccccc45)cc3)ccc21]

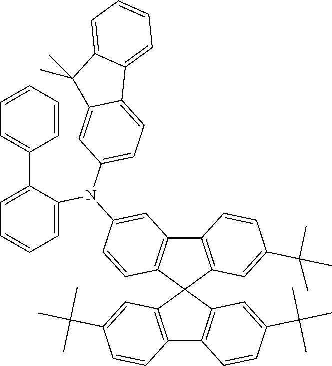 [SMILES: CC(C)(C)c1ccc2c(c1)C1(c3ccc(N(c4ccc5c(c4)C(C)(C)c4ccccc4-5)c4ccccc4-c4ccccc4)cc3-2)c2cc(C(C)(C)C)ccc2-c2ccc(C(C)(C)C)cc21]

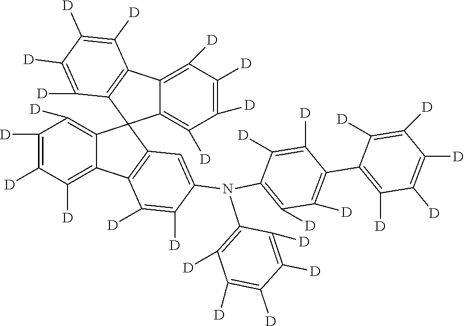 [SMILES: [2H]c1c(N(c2c([2H])c([2H])c([2H])c([2H])c2[2H])c2c([2H])c([2H])c(-c3c([2H])c([2H])c([2H])c([2H])c3[2H])c([2H])c2[2H])cc2c(c1[2H])-c1c([2H])c([2H])c([2H])c([2H])c1C21c2c([2H])c([2H])c([2H])c([2H])c2-c2c([2H])c([2H])c([2H])c([2H])c21]

Preferred hole transport materials further include in combination with the compounds of table 5 or as alternatives or compounds of the table 5 materials that may be used in a hole transport, hole injection or electron blocker layer, such as indenofluorenamine derivatives, hexaazatriphenylene derivatives, monobenzoindenofluorenamines, dibenzoindenofluorenamines, dihydroacridine derivatives.

The sequence of layers in the organic electroluminescent device of the invention is preferably as follows:

anode/hole injection layer/hole transport layer/emitting layer/electron transport layer/electron injection layer/cathode.

This sequence of the layers is a preferred sequence.

At the same time, it should be pointed out again that not all the layers mentioned need be present and/or that further layers may additionally be present.

The organic electroluminescent device of the invention may contain two or more emitting layers. At least one of the emitting layers is the light-emitting layer of the invention containing at least one compound of the formula (1) as host material 1 and at least one compound of the formula (2) as host material 2 as described above. It is particularly preferable when these emission layers in this case altogether exhibit a plurality of emission maxima between 380 nm and 750 nm, so that altogether white emission results.

Materials used for the electron transport layer may be any materials as used according to the prior art as electron transport materials in the electron transport layer. Especially suitable are aluminium complexes, for example Alq₃, zirconium complexes, for example Zrq₄, benzimidazole derivatives, triazine derivatives, pyrimidine derivatives, pyridine derivatives, pyrazine derivatives, quinoxaline derivatives, quinoline derivatives, oxadiazole derivatives, aromatic ketones, lactams, boranes, diazaphosphole derivatives and phosphine oxide derivatives.

Suitable cathodes of the device of the invention are metals having a low work function, metal alloys or multilayer structures composed of various metals, for example alkaline earth metals, alkali metals, main group metals or lanthanoids (e.g. Ca, Ba, Mg, Al, In, Yb, Sm, etc.). Additionally suitable are alloys composed of an alkali metal or alkaline earth metal and silver, for example an alloy composed of magnesium and silver. In the case of multilayer structures, in addition to the metals mentioned, it is also possible to use further metals having a relatively high work function, for example Ag or Al, in which case combinations of the metals such as Ca/Ag, Mg/Ag or Ba/Ag, for example, are generally used. It may also be preferable to introduce a thin interlayer of a material having a high dielectric constant between a metallic cathode and the organic semiconductor. Examples of useful materials for this purpose are alkali metal or alkaline earth metal fluorides, but also the corresponding oxides or carbonates (e.g. LiF, Li₂O, BaF₂, MgO, NaF, CsF, Cs₂CO₃, etc.). It is also possible to use lithium quinolinate (LiQ) for this purpose. The layer thickness of this layer is preferably between 0.5 and 5 nm.

Preferred anodes are materials having a high work function. Preferably, the anode has a work function of greater than 4.5 eV versus vacuum. Firstly, metals having a high redox potential are suitable for this purpose, for example Ag, Pt or Au. Secondly, metal/metal oxide electrodes (e.g. Al/Ni/NiOₓ, Al/PtOₓ) may also be preferred. For some applications, at least one of the electrodes has to be transparent or partly transparent in order to enable either the irradiation of the organic material (organic solar cell) or the emission of light (OLED, O-LASER). Preferred anode materials here are conductive mixed metal oxides. Particular preference is given to indium tin oxide (ITO) or indium zinc oxide (IZO). Preference is further given to conductive doped organic materials, especially conductive doped polymers. In addition, the anode may also consist of two or more layers, for example of an inner layer of ITO and an outer layer of a metal oxide, preferably tungsten oxide, molybdenum oxide or vanadium oxide.

The organic electroluminescent device of the invention, in the course of production, is appropriately (according to the application) structured, contact-connected and finally sealed, since the lifetime of the devices of the invention is shortened in the presence of water and/or air.

The production of the device of the invention is not restricted here. It is possible that one or more organic layers, including the light-emitting layer, are coated by a sublimation method. In this case, the materials are applied by vapour deposition in vacuum sublimation systems at an initial pressure of less than 10⁻⁵ mbar, preferably less than 10⁻⁶ mbar. In this case, however, it is also possible that the initial pressure is even lower, for example less than 10⁻⁷ mbar.

The organic electroluminescent device of the invention is preferably characterized in that one or more layers are coated by the OVPD (organic vapour phase deposition) method or with the aid of a carrier gas sublimation. In this case, the materials are applied at a pressure between 10⁻⁵ mbar and 1 bar. A special case of this method is the OVJP (organic vapour jet printing) method, in which the materials are applied directly by a nozzle and thus structured (for example M. S. Arnold et al., Appl. Phys. Lett. 2008, 92, 053301).

The organic electroluminescent device of the invention is further preferably characterized in that one or more organic layers comprising the composition of the invention are produced from solution, for example by spin-coating, or by any printing method, for example screen printing, flexographic printing, nozzle printing or offset printing, but more preferably LITI (light-induced thermal imaging, thermal transfer printing) or inkjet printing. For this purpose, soluble host materials 1 and 2 and phosphorescent emitters are needed. Processing from solution has the advantage that, for example, the light-emitting layer can be applied in a very simple and inexpensive manner. This technique is especially suitable for the mass production of organic electroluminescent devices.

In addition, hybrid methods are possible, in which, for example, one or more layers are applied from solution and one or more further layers are applied by vapour deposition.

These methods are known in general terms to those skilled in the art and can be applied to organic electroluminescent devices.

The invention therefore further provides a process for producing the organic electroluminescent device of the invention as described or described as preferable above, characterized in that the organic layer, preferably the light-emitting layer, the hole injection layer and/or hole transport layer is applied by gas phase deposition, especially by a sublimation method and/or by an OVPD (organic vapour phase deposition) method and/or with the aid of a carrier gas sublimation, or from solution, especially by spin-coating or by a printing method.

In the case of production by means of gas phase deposition, there are in principle two ways in which the organic layer, preferably the light-emitting layer, of the invention can be applied or vapour-deposited onto any substrate or the prior layer. Firstly, the materials used can each be initially charged in a material source and ultimately evaporated from the different material sources (“co-evaporation”). Secondly, the various materials can be premixed (premix systems) and the mixture can be initially charged in a single material source from which it is ultimately evaporated (“premix evaporation”). In this way, it is possible in a simple and rapid manner to achieve the vapour deposition of the light-emitting layer with homogeneous distribution of the components without the need for precise actuation of a multitude of material sources.

The invention accordingly further provides a process for producing the device of the invention, characterized in that the at least one compound of the formula (1) as described or described as preferable above and the at least one compound of the formula (2) as described or described as preferable above are deposited from the gas phase successively or simultaneously from at least two material sources, optionally with the at least one phosphorescent emitter as described or described as preferable above, and form the light-emitting layer.

In a preferred embodiment of the present invention, the light-emitting layer is applied by means of gas phase deposition, wherein the constituents of the composition are premixed and evaporated from a single material source.

The invention accordingly further provides a process for producing the device of the invention, characterized in that the at least one compound of the formula (1) and the at least one compound of the formula (2) are deposited from the gas phase as a mixture, successively or simultaneously with the at least one phosphorescent emitter, and form the light-emitting layer.

The invention further provides a process for producing the device of the invention, as described or described as preferable above, characterized in that the at least one compound of the formula (1) and the at least one compound of the formula (2), as described or described as preferable above, are applied from solution together with the at least one phosphorescent emitter in order to form the light-emitting layer.

The devices of the invention feature the following surprising advantages over the prior art:

The use of the described material combination of host materials 1 and 2, as described above, especially leads to an increase in the lifetime of the devices.

As apparent in the example given hereinafter, it is possible to determine by comparison of the data for OLEDs with combinations from the prior art that the inventive combinations of matrix materials in the EML lead to devices having a significantly increased lifetime, irrespective of the emitter concentration.

It should be pointed out that variations of the embodiments described in the present invention are covered by the scope of this invention. Any feature disclosed in the present invention may, unless this is explicitly ruled out, be exchanged for alternative features which serve the same purpose or an equivalent or similar purpose. Any feature disclosed in the present invention, unless stated otherwise, should therefore be considered as an example from a generic series or as an equivalent or similar feature.

All features of the present invention may be combined with one another in any manner, unless particular features and/or steps are mutually exclusive. This is especially true of preferred features of the present invention. Equally, features of non-essential combinations may be used separately (and not in combination).

The technical teaching disclosed with the present invention may be abstracted and combined with other examples.

The invention is illustrated in more detail by the examples which follow, without any intention of restricting it thereby.

### EXAMPLES

General Methods:

In all quantum-chemical calculations, the Gaussian16 (Rev. B.01) software package is used. The neutral singlet ground state is optimized at the B3LYP/6-31G(d) level. HOMO and LUMO values are determined at the B3LYP/6-31G(d) level for the B3LYP/6-31G(d)-optimized ground state energy. Then TD-DFT singlet and triplet excitations (vertical excitations) are calculated by the same method (B3LYP/6-31G(d)) and with the optimized ground state geometry. The standard settings for SCF and gradient convergence are used.

From the energy calculation, the HOMO is obtained as the last orbital occupied by two electrons (alpha occ. eigenvalues) and LUMO as the first unoccupied orbital (alpha virt. eigenvalues) in Hartree units, where HEh and LEh represent the HOMO energy in Hartree units and the LUMO energy in Hartree units respectively. This is used to determine the HOMO and LUMO value in electron volts, calibrated by cyclic voltammetry measurements, as follows:

HOMOcorr=0.90603*HOMO−0.84836

LUMOcorr=0.99687*LUMO−0.72445

The triplet level T1 of a material is defined as the relative excitation energy (in eV) of the triplet state having the lowest energy which is found by the quantum-chemical energy calculation.

The singlet level S1 of a material is defined as the relative excitation energy (in eV) of the singlet state having the second-lowest energy which is found by the quantum-chemical energy calculation.

The energetically lowest singlet state is referred to as S0.

The method described herein is independent of the software package used and always gives the same results. Examples of frequently utilized programs for this purpose are “Gaussian09” (Gaussian Inc.) and Q-Chem 4.1 (Q-Chem, Inc.). In the present case, the energies are calculated using the software package “Gaussian16 (Rev. B.01)”.

### Example 1: Production of the OLEDs

Pretreatment for production of the OLEDs: Glass plates coated with structured ITO (indium tin oxide) of thickness 50 nm are treated prior to coating, first with an oxygen plasma, followed by an argon plasma. These plasma-treated glass plates form the substrates to which the OLEDs are applied.

The OLEDs basically have the following layer structure: substrate/hole injection layer (HIL)/hole transport layer (HTL)/electron blocker layer (EBL)/emission layer (EML)/optional hole blocker layer (HBL)/electron transport layer (ETL)/optional electron injection layer (EIL) and finally a cathode. The cathode is formed by an aluminium layer of thickness 100 nm.

All materials are applied by thermal vapour deposition in a vacuum chamber. In this case, the emission layer always consists of at least one matrix material (host material), for the purposes of the invention at least two matrix materials and an emitting dopant (emitter) which is added to the matrix material(s) in a particular proportion by volume by co-evaporation. Analogously, the electron transport layer may also consist of a mixture of two materials.

The OLEDs are characterized in a standard manner. For this purpose, the electroluminescence spectra and current-voltage-luminance characteristics (IUL characteristics) are measured. EQE and current efficiency SE (in cd/A) are calculated therefrom. SE is calculated assuming Lambertian emission characteristics.

The lifetime LT is defined as the time after which the luminance drops from a starting luminance L0 (in cd/m²) to a certain proportion L1 (in cd/m²) in the course of operation with constant current density j0 in mA/cm². A figure of L1/L0=80% in table 7 means that the lifetime reported in the LT column corresponds to the time (in h) after which the luminance falls to 80% of its starting value (L0).

Use of Mixtures of the Invention in OLEDs

Examples V1 to V16 and B1 to B37 below (see tables 6 and 7) present the use of the inventive material combinations in OLEDs compared to material combinations from the prior art.

The construction of the OLEDs is apparent from table 6. The materials required for producing the OLEDs are shown in table 8 if not disclosed elsewhere. The device data of the OLEDs are listed in table 7.

Details reported in the form VG1:H2:TEG1 (33%:60%:7%) 30 nm indicate the presence of comparative material 1 in a proportion by volume of 33% as host material 1, the compound H2 as host material 2 in a proportion of 60% and TEG1 in a proportion of 7% in a 30 nm thick layer.

Examples V1 to V16 are comparative examples with an electron-transporting host according to the prior art or in V14 with the host H0. The examples B1 to B37 use inventive material combinations in the EML.

On comparison of the inventive examples with the corresponding comparative examples, it is clearly apparent that the inventive examples each show a distinct advantage in device lifetime.

TABLE 6

| | HIL | HTL | EBL | EML | HBL | ETL | EIL |
|---|---|---|---|---|---|---|---|
| Ex. | thickness | thickness | thickness | thickness | thickness | thickness | thickness |
| V1 | SpMA1: | SpMA1 | SpMA4 | VG1:H2:TEG1 | ST2 | ST2:LIQ | LiQ |
| | PD1 | 215 nm | 20 nm | (33%:60%:7%) | 10 nm | (50%:50%) | 1 nm |
| | (95%:5%) | | | 30 nm | | 30 nm | |
| | 20 nm | | | | | | |
| V2 | SpMA1: | SpMA1 | SpMA5 | VG1:H2:TEG1 | ST2 | ST2:LIQ | LiQ |
| | PD1 | 215 nm | 20 nm | (33%:60%:7%) | 10 nm | (50%:50%) | 1 nm |
| | (95%:5%) | | | 30 nm | | 30 nm | |
| | 20 nm | | | | | | |
| V3 | SpMA1: | SpMA1 | SpMA2 | VG1:H8:TEG1 | ST2 | ST2:LIQ | LiQ |
| | PD1 | 215 nm | 20 nm | (33%:60%:7%) | 10 nm | (50%:50%) | 1 nm |
| | (95%:5%) | | | 30 nm | | 30 nm | |
| | 20 nm | | | | | | |
| B1 | SpMA1: | SpMA1 | SpMA2 | E7:H2:TEG1 | ST2 | ST2:LIQ | LiQ |
| | PD1 | 215 nm | 20 nm | ((33%:60%:7%) | 10 nm | (50%:50%) | 1 nm |
| | (95%:5%) | | | 30 nm | | 30 nm | |
| | 20 nm | | | | | | |
| B2 | SpMA1: | SpMA1 | SpMA2 | E17:H2:TEG1 | ST2 | ST2:LIQ | LiQ |
| | PD1 | 215 nm | 20 nm | (33%:60%:7%) | 10 nm | (50%:50%) | 1 nm |
| | (95%:5%) | | | 30 nm | | 30 nm | |
| | 20 nm | | | | | | |
| B3 | SpMA1: | SpMA1 | SpMA2 | E13:H2:TEG1 | ST2 | ST2:LIQ | LiQ |
| | PD1 | 215 nm | 20 nm | (33%:60%:7%) | 10 nm | (50%:50%) | 1 nm |
| | (95%:5%) | | | 30 nm | | 30 nm | |
| | 20 nm | | | | | | |
| B4 | SpMA1: | SpMA1 | SpMA2 | E3:H2:TEG1 | ST2 | ST2:LIQ | LIQ |
| | PD1 | 215 nm | 20 nm | (33%:60%:7%) | 10 nm | (50%:50%) | 1 nm |
| | (95%:5%) | | | 30 nm | | 30 nm | |
| | 20 nm | | | | | | |
| B5 | SpMA1: | SpMA1 | SpMA2 | E4:H2:TEG1 | ST2 | ST2:LIQ | LiQ |
| | PD1 | 215 nm | 20 nm | (33%:60%:7%) | 10 nm | (50%:50%) | 1 nm |
| | (95%:5%) | | | 30 nm | | 30 nm | |
| | 20 nm | | | | | | |
| B6 | SpMA1: | SpMA1 | SpMA3 | E4:H2:TEG1 | ST2 | ST2:LIQ | LiQ |
| | PD1 | 215 nm | 20 nm | (33%:60%:7%) | 10 nm | (50%:50%) | 1 nm |
| | (95%:5%) | | | 30 nm | | 30 nm | |
| | 20 nm | | | | | | |
| B7 | SpMA1: | SpMA1 | SpMA2 | E4:H5:TEG1 | ST2 | ST2:LIQ | LiQ |
| | PD1 | 215 nm | 20 nm | (33%:60%:7%) | 10 nm | (50%:50%) | 1 nm |
| | (95%:5%) | | | 30 nm | | 30 nm | |
| | 20 nm | | | | | | |
| B8 | SpMA1: | SpMA1 | SpMA2 | E4:H7:TEG1 | ST2 | ST2:LIQ | LiQ |
| | PD1 | 215 nm | 20 nm | (33%:60%:7%) | 10 nm | (50%:50%) | 1 nm |
| | (95%:5%) | | | 30 nm | | 30 nm | |
| | 20 nm | | | | | | |
| B9 | SpMA1: | SpMA1 | SpMA2 | E4:H8:TEG1 | ST2 | ST2:LIQ | LiQ |
| | PD1 | 215 nm | 20 nm | (33%:60%:7%) | 10 nm | (50%:50%) | 1 nm |
| | (95%:5%) | | | 30 nm | | 30 nm | |
| | 20 nm | | | | | | |
| B10 | SpMA1: | SpMA1 | SpMA2 | E4:H8:TEG2 | ST3 | ST2:LIQ | LiQ |
| | PD1 | 215 nm | 20 nm | (33%:60%:7%) | 10 nm | (50%:50%) | 1 nm |
| | (95%:5%) | | | 30 nm | | 30 nm | |
| | 20 nm | | | | | | |
| B11 | SpMA1: | SpMA1 | SpMA2 | E4:H9:TEG2 | ST3 | ST2:LIQ | LiQ |
| | PD1 | 215 nm | 20 nm | (33%:60%:7%) | 10 nm | (50%:50%) | 1 nm |
| | (95%:5%) | | | 30 nm | | 30 nm | |
| | 20 nm | | | | | | |
| B12 | SpMA1: | SpMA1 | SpMA2 | E4:H8:TEG3 | ST3 | ST2:LIQ | LiQ |
| | PD1 | 215 nm | 20 nm | (33%:60%:7%) | 10 nm | (50%:50%) | 1 nm |
| | (95%:5%) | | | 30 nm | | 30 nm | |
| | 20 nm | | | | | | |
| B13 | SpMA1: | SpMA1 | SpMA2 | E4:H8:TEG3 | ST3 | E4:LiQ | LiQ |
| | PD1 | 215 nm | 20 nm | (33%:60%:7%) | 10 nm | (50%:50%) | 1 nm |
| | (95%:5%) | | | 30 nm | | 30 nm | |
| | 20 nm | | | | | | |
| V14 | SpMA1: | SpMA1 | SpMA2 | E4:H0:TEG3 | ST3 | E4:LiQ | LiQ |
| | PD1 | 215 nm | 20 nm | (33%:60%:7%) | 10 nm | (50%:50%) | 1 nm |
| | (95%:5%) | | | 30 nm | | 30 nm | |
| | 20 nm | | | | | | |
| V4 | SpMA1: | SpMA1 | SpMA2 | VG2:H8:TEG2 | ST2 | ST2:LIQ | LiQ |
| | PD1 | 200 nm | 20 nm | (33%:60%:7%) | 5 nm | (50%:50%) | 1 nm |
| | (95%:5%) | | | 30 nm | | 30 nm | |
| | 20 nm | | | | | | |
| B15 | SpMA1: | SpMA1 | SpMA2 | E2:H8:TEG2 | ST2 | ST2:LIQ | LiQ |
| | PD1 | 200 nm | 20 nm | (33%:60%:7%) | 5 nm | (50%:50%) | 1 nm |
| | (95%:5%) | | | 30 nm | | 30 nm | |
| | 20 nm | | | | | | |
| V5 | SpMA1: | SpMA1 | SpMA2 | VG3:H8:TEG2 | ST2 | ST2:LIQ | LiQ |
| | PD1 | 200 nm | 20 nm | (33%:60%:7%) | 5 nm | (50%:50%) | 1 nm |
| | (95%:5%) | | | 30 nm | | 30 nm | |
| | 20 nm | | | | | | |
| B16 | SpMA1: | SpMA1 | SpMA2 | E15:H8:TEG2 | ST2 | ST2:LIQ | LiQ |
| | PD1 | 200 nm | 20 nm | (33%:60%:7%) | 5 nm | (50%:50%) | 1 nm |
| | (95%:5%) | | | 30 nm | | 30 nm | |
| | 20 nm | | | | | | |
| V6 | SpMA1: | SpMA1 | SpMA2 | VG4:H8:TEG2 | ST2 | ST2:LIQ | LiQ |
| | PD1 | 200 nm | 20 nm | (33%:60%:7%) | 5 nm | (50%:50%) | 1 nm |
| | (95%:5%) | | | 30 nm | | 30 nm | |
| | 20 nm | | | | | | |
| B17 | SpMA1: | SpMA1 | SpMA2 | E18:H8:TEG2 | ST2 | ST2:LIQ | LiQ |
| | PD1 | 200 nm | 20 nm | (33%:60%:7%) | 5 nm | (50%:50%) | 1 nm |
| | (95%:5%) | | | 30 nm | | 30 nm | |
| | 20 nm | | | | | | |
| V7 | SpMA1: | SpMA1 | SpMA2 | VG5:H8:TEG2 | ST2 | ST2:LIQ | LiQ |
| | PD1 | 200 nm | 20 nm | (33%:60%:7%) | 5 nm | (50%:50%) | 1 nm |
| | (95%:5%) | | | 30 nm | | 30 nm | |
| | 20 nm | | | | | | |
| B18 | SpMA1: | SpMA1 | SpMA2 | E2:H8:TEG2 | ST2 | ST2:LIQ | LiQ |
| | PD1 | 200 nm | 20 nm | (33%:60%:7%) | 5 nm | (50%:50%) | 1 nm |
| | (95%:5%) | | | 30 nm | | 30 nm | |
| | 20 nm | | | | | | |
| V8 | SpMA1: | SpMA1 | SpMA2 | VG6:H8:TEG2 | ST2 | ST2:LIQ | LIQ |
| | PD1 | 200 nm | 20 nm | (44%:44%:12%) | 5 nm | (50%:50%) | 1 nm |
| | (95%:5%) | | | 40 nm | | 30 nm | |
| | 20 nm | | | | | | |
| V9 | SpMA1: | SpMA1 | SpMA2 | VG11:H8:TEG2 | ST2 | ST2:LIQ | LiQ |
| | PD1 | 200 nm | 20 nm | (44%:44%:12%) | 5 nm | (50%:50%) | 1 nm |
| | (95%:5%) | | | 40 nm | | 30 nm | |
| | 20 nm | | | | | | |
| V10 | SpMA1: | SpMA1 | SpMA2 | VG8:H8:TEG2 | ST2 | ST2:LIQ | LiQ |
| | PD1 | 200 nm | 20 nm | (44%:44%:12%) | 5 nm | (50%:50%) | 1 nm |
| | (95%:5%) | | | 40 nm | | 30 nm | |
| | 20 nm | | | | | | |
| V11 | SpMA1: | SpMA1 | SpMA2 | VG12:H8:TEG2 | ST2 | ST2:LIQ | LiQ |
| | PD1 | 200 nm | 20 nm | (44%:44%:12%) | 5 nm | (50%:50%) | 1 nm |
| | (95%:5%) | | | 40 nm | | 30 nm | |
| | 20 nm | | | | | | |
| V12 | SpMA1: | SpMA1 | SpMA2 | VG7:H8:TEG2 | ST2 | ST2:LIQ | LiQ |
| | PD1 | 200 nm | 20 nm | (33%:60%:7%) | 5 nm | (50%:50%) | 1 nm |
| | (95%:5%) | | | 30 nm | | 30 nm | |
| | 20 nm | | | | | | |
| B19 | SpMA1: | SpMA1 | SpMA2 | E3:H8:TEG2 | ST2 | ST2:LIQ | LiQ |
| | PD1 | 200 nm | 20 nm | (33%:60%:7%) | 5 nm | (50%:50%) | 1 nm |
| | (95%:5%) | | | 30 nm | | 30 nm | |
| | 20 nm | | | | | | |
| V13 | SpMA1: | SpMA1 | SpMA2 | VG8:H8:TEG2 | ST2 | ST2:LIQ | LiQ |
| | PD1 | 200 nm | 20 nm | (33%:60%:7%) | 5 nm | (50%:50%) | 1 nm |
| | (95%:5%) | | | 30 nm | | 30 nm | |
| | 20 nm | | | | | | |
| V15 | SpMA1: | SpMA1 | SpMA2 | VG9:H8:TEG2 | ST2 | ST2:LIQ | LiQ |
| | PD1 | 200 nm | 20 nm | (33%:60%:7%) | 5 nm | (50%:50%) | 1 nm |
| | (95%:5%) | | | 30 nm | | 30 nm | |
| | 20 nm | | | | | | |
| B20 | SpMA1: | SpMA1 | SpMA2 | E1:H8:TEG2 | ST2 | ST2:LIQ | LiQ |
| | PD1 | 200 nm | 20 nm | (33%:60%:7%) | 5 nm | (50%:50%) | 1 nm |
| | (95%:5%) | | | 30 nm | | 30 nm | |
| | 20 nm | | | | | | |
| V16 | SpMA1: | SpMA1 | SpMA2 | VG10:H8:TEG2 | ST2 | ST2:LIQ | LiQ |
| | PD1 | 200 nm | 20 nm | (33%:60%:7%) | 5 nm | (50%:50%) | 1 nm |
| | (95%:5%) | | | 30 nm | | 30 nm | |
| | 20 nm | | | | | | |
| B21 | SpMA1: | SpMA1 | SpMA2 | E27:H8:TEG2 | ST2 | ST2:LIQ | LiQ |
| | PD1 | 200 nm | 20 nm | (33%:60%:7%) | 5 nm | (50%:50%) | 1 nm |
| | (95%:5%) | | | 30 nm | | 30 nm | |
| | 20 nm | | | | | | |
| B22 | SpMA1: | SpMA1 | SpMA2 | E20:H8:TEG2 | ST2 | ST2:LIQ | LiQ |
| | PD1 | 200 nm | 20 nm | (33%:60%:7%) | 5 nm | (50%:50%) | 1 nm |
| | (95%:5%) | | | 30 nm | | 30 nm | |
| | 20 nm | | | | | | |
| B23 | SpMA1: | SpMA1 | SpMA2 | E21:H8:TEG2 | ST2 | ST2:LIQ | LiQ |
| | PD1 | 200 nm | 20 nm | (33%:60%:7%) | 5 nm | (50%:50%) | 1 nm |
| | (95%:5%) | | | 30 nm | | 30 nm | |
| | 20 nm | | | | | | |
| B24 | SpMA1: | SpMA1 | SpMA2 | E22:H8:TEG2 | ST2 | ST2:LIQ | LiQ |
| | PD1 | 200 nm | 20 nm | (33%:60%:7%) | 5 nm | (50%:50%) | 1 nm |
| | (95%:5%) | | | 30 nm | | 30 nm | |
| | 20 nm | | | | | | |
| B25 | SpMA1: | SpMA1 | SpMA2 | E15:H8:TEG2 | ST2 | ST2:LIQ | LiQ |
| | PD1 | 200 nm | 20 nm | (33%:60%:7%) | 5 nm | (50%:50%) | 1 nm |
| | (95%:5%) | | | 30 nm | | 30 nm | |
| | 20 nm | | | | | | |
| B26 | SpMA1: | SpMA1 | SpMA2 | E23:H8:TEG2 | ST2 | ST2:LIQ | LiQ |
| | PD1 | 200 nm | 20 nm | (33%:60%:7%) | 5 nm | (50%:50%) | 1 nm |
| | (95%:5%) | | | 30 nm | | 30 nm | |
| | 20 nm | | | | | | |
| B27 | SpMA1: | SpMA1 | SpMA2 | E24:H8:TEG2 | ST2 | ST2:LIQ | LiQ |
| | PD1 | 200 nm | 20 nm | (33%:60%:7%) | 5 nm | (50%:50%) | 1 nm |
| | (95%:5%) | | | 30 nm | | 30 nm | |
| | 20 nm | | | | | | |
| B28 | SpMA1: | SpMA1 | SpMA2 | E19:H8:TEG2 | ST2 | ST2:LIQ | LIQ |
| | PD1 | 200 nm | 20 nm | (33%:60%:7%) | 5 nm | (50%:50%) | 1 nm |
| | (95%:5%) | | | 30 nm | | 30 nm | |
| | 20 nm | | | | | | |
| B29 | SpMA1: | SpMA1 | SpMA2 | E6:H8:TEG2 | ST2 | ST2:LIQ | LiQ |
| | PD1 | 200 nm | 20 nm | (33%:60%:7%) | 5 nm | (50%:50%) | 1 nm |
| | (95%:5%) | | | 30 nm | | 30 nm | |
| | 20 nm | | | | | | |
| B30 | SpMA1: | SpMA1 | SpMA2 | E8:H8:TEG2 | ST2 | ST2:LIQ | LiQ |
| | PD1 | 200 nm | 20 nm | (33%:60%:7%) | 5 nm | (50%:50%) | 1 nm |
| | (95%:5%) | | | 30 nm | | 30 nm | |
| | 20 nm | | | | | | |
| B31 | SpMA1: | SpMA1 | SpMA2 | E9:H8:TEG2 | ST2 | ST2:LIQ | LiQ |
| | PD1 | 200 nm | 20 nm | (33%:60%:7%) | 5 nm | (50%:50%) | 1 nm |
| | (95%:5%) | | | 30 nm | | 30 nm | |
| | 20 nm | | | | | | |
| B32 | SpMA1: | SpMA1 | SpMA2 | E11:H8:TEG2 | ST2 | ST2:LIQ | LiQ |
| | PD1 | 200 nm | 20 nm | (33%:60%:7%) | 5 nm | (50%:50%) | 1 nm |
| | (95%:5%) | | | 30 nm | | 30 nm | |
| | 20 nm | | | | | | |
| B33 | SpMA1: | SpMA1 | SpMA2 | E11:H8:TEG2 | ST2 | ST2:LIQ | LIQ |
| | PD1 | 200 nm | 20 nm | (33%:60%:7%) | 5 nm | (50%:50%) | 1 nm |
| | (95%:5%) | | | 30 nm | | 30 nm | |
| | 20 nm | | | | | | |
| B34 | SpMA1: | SpMA1 | SpMA2 | E5:H8:TEG2 | ST2 | ST2:LIQ | LiQ |
| | PD1 | 200 nm | 20 nm | (33%:60%:7%) | 5 nm | (50%:50%) | 1 nm |
| | 95%:5%) | | | 30 nm | | 30 nm | |
| | 20 nm | | | | | | |
| B35 | SpMA1: | SpMA1 | SpMA2 | E25:H8:TEG2 | ST2 | ST2:LIQ | LIQ |
| | PD1 | 200 nm | 20 nm | (33%:60%:7%) | 5 nm | (50%:50%) | 1 nm |
| | (95%:5%) | | | 30 nm | | 30 nm | |
| | 20 nm | | | | | | |
| B36 | SpMA1: | SpMA1 | SpMA2 | E4:H3:TEG3 | ST2 | ST2:LIQ | LiQ |
| | PD1 | 200 nm | 20 nm | (33%:60%:7%) | 5 nm | (50%:50%) | 1 nm |
| | (95%:5%) | | | 30 nm | | 30 nm | |
| | 20 nm | | | | | | |
| B37 | SpMA1: | SpMA1 | SpMA2 | E5:H3:TEG3 | ST2 | ST2:LIQ | LiQ |
| | PD1 | 200 nm | 20 nm | (33%:60%:7%) | 5 nm | (50%:50%) | 1 nm |
| | (95%:5%) | | | 30 nm | | 30 nm | |
| | 20 nm | | | | | | |

TABLE 7
Data of the OLEDs

| | U1000 | SE1000 | EQE1000 | CIE x/y at | j0 | L1 | LT |
|---|---|---|---|---|---|---|---|
| Ex. | (M) | (cd/A) | (%) | 1000 cd/m2 | (mA/cm2) | (%) | (h) |
| V1 | 3.4 | 68 | 18.5 | 0.32/0.62 | 20 | 80 | 590 |
| V2 | 3.4 | 70 | 17 | 0.34/0.61 | 20 | 80 | 580 |
| V3 | 3.3 | 69 | 18 | 0.35/0.62 | 20 | 80 | 690 |
| B1 | 3.5 | 73 | 18 | 0.35/0.61 | 20 | 80 | 745 |
| B2 | 3.4 | 71 | 19 | 0.34/0.62 | 20 | 80 | 890 |
| B3 | 3.3 | 67 | 18 | 0.33/0.63 | 20 | 80 | 810 |
| B4 | 3.3 | 71 | 18 | 0.35/0.62 | 20 | 80 | 990 |
| B5 | 3.1 | 69 | 19 | 0.34/0.62 | 20 | 80 | 1040 |
| B6 | 3.2 | 67 | 19 | 0.33/0.63 | 20 | 80 | 1080 |
| B7 | 3.0 | 70 | 20 | 0.35/0.61 | 20 | 80 | 1170 |
| B8 | 3.0 | 72 | 20 | 0.35/0.63 | 20 | 80 | 1160 |
| B9 | 3.2 | 71 | 20 | 0.34/0.62 | 20 | 80 | 1180 |
| B10 | 3.1 | 69 | 20 | 0.34/0.62 | 20 | 80 | 1210 |
| B11 | 3.2 | 67 | 19 | 0.34/0.61 | 20 | 80 | 1190 |
| B12 | 3.1 | 68 | 21 | 0.34/0.61 | 20 | 80 | 1220 |
| B13 | 3.3 | 71 | 19 | 0.34/0.63 | 20 | 80 | 1090 |
| V14 | 3.6 | 72 | 17.8 | 0.35/0.61 | 20 | 80 | 650 |
| V4 | 3.4 | 66 | 17 | 0.33/0.63 | 20 | 80 | 500 |
| B15 | 3.2 | 70 | 18 | 0.35/0.61 | 20 | 80 | 880 |
| V5 | 3.3 | 72 | 17 | 0.35/0.63 | 20 | 80 | 520 |
| B16 | 3.2 | 74 | 19 | 0.33/0.63 | 20 | 80 | 740 |
| V6 | 3.3 | 67 | 17.5 | 0.35/0.62 | 20 | 80 | 510 |
| B17 | 3.2 | 70 | 19 | 0.35/0.61 | 20 | 80 | 780 |
| V7 | 3.4 | 68 | 16 | 0.33/0.64 | 20 | 80 | 440 |
| B18 | 3.2 | 70 | 18 | 0.35/0.61 | 20 | 80 | 880 |
| V8 | 3.5 | 67 | 17 | 0.35/0.62 | 20 | 80 | 330 |
| V9 | 3.4 | 68 | 16 | 0.33/0.64 | 20 | 80 | 410 |
| V10 | 3.3 | 67 | 17 | 0.35/0.62 | 20 | 80 | 420 |
| V11 | 3.5 | 68 | 16 | 0.33/0.64 | 20 | 80 | 500 |
| V12 | 3.3 | 70 | 17 | 0.35/0.62 | 20 | 80 | 610 |
| B19 | 3.2 | 73 | 19 | 0.35/0.61 | 20 | 80 | 870 |
| V13 | 3.5 | 64 | 16 | 0.34/0.61 | 20 | 80 | 410 |
| V15 | 3.6 | 71 | 16 | 0.34/0.61 | 20 | 80 | 510 |
| B20 | 3.2 | 61 | 18 | 0.34/0.61 | 20 | 80 | 715 |
| V16 | 3.6 | 71 | 16 | 0.34/0.61 | 20 | 80 | 495 |
| B21 | 3.2 | 74 | 19 | 0.33/0.63 | 20 | 80 | 680 |
| B22 | 3.2 | 67 | 19 | 0.35/0.62 | 20 | 80 | 870 |
| B23 | 3.3 | 69 | 18 | 0.35/0.61 | 20 | 80 | 830 |
| B24 | 3.3 | 72 | 17.5 | 0.35/0.61 | 20 | 80 | 800 |
| B25 | 3.1 | 74 | 17 | 0.35/0.61 | 20 | 80 | 720 |
| B26 | 3.4 | 73 | 18 | 0.35/0.61 | 20 | 80 | 930 |
| B27 | 3.3 | 67 | 18 | 0.33/0.63 | 20 | 80 | 750 |
| B28 | 3.3 | 70 | 18 | 0.33/0.63 | 20 | 80 | 840 |
| B29 | 3.3 | 73 | 19 | 0.35/0.62 | 20 | 80 | 870 |
| B30 | 3.1 | 73 | 18 | 0.35/0.61 | 20 | 80 | 980 |
| B31 | 3.2 | 73 | 19 | 0.35/0.62 | 20 | 80 | 990 |
| B32 | 3.4 | 73 | 18 | 0.34/0.61 | 20 | 80 | 945 |
| B33 | 3.3 | 73 | 19 | 0.35/0.63 | 20 | 80 | 985 |
| B34 | 3.2 | 71 | 18 | 0.34/0.61 | 20 | 80 | 935 |
| B35 | 3.3 | 72 | 18 | 0.35/0.63 | 20 | 80 | 960 |
| B36 | 3.3 | 74 | 19.5 | 0.35/0.61 | 20 | 80 | 1055 |
| B37 | 3.2 | 75 | 19.5 | 0.34/0.62 | 20 | 80 | 1115 |

TABLE 8
Structural formulae of the materials of the OLEDs used, if not already
described before:

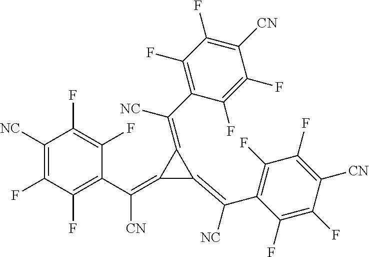 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F]

PD1 (1224447-88-4)

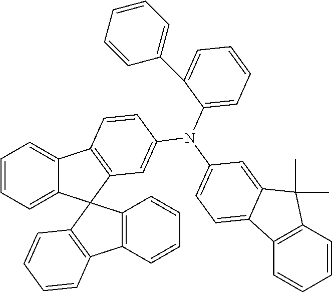 [SMILES: CC1(C)c2ccccc2-c2ccc(N(c3ccc4c(c3)C3(c5ccccc5-c5ccccc53)c3ccccc3-4)c3ccccc3-c3ccccc3)cc21]

SpMA1

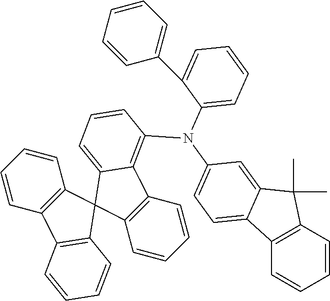 [SMILES: CC1(C)c2ccccc2-c2ccc(N(c3ccccc3-c3ccccc3)c3cccc4c3-c3ccccc3C43c4ccccc4-c4ccccc43)cc21]

SpMA2

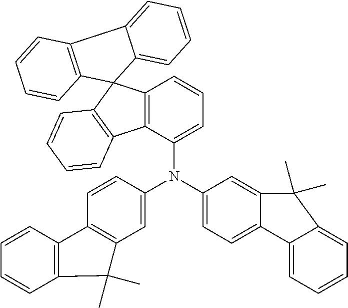 [SMILES: CC1(C)c2ccccc2-c2ccc(N(c3ccc4c(c3)C(C)(C)c3ccccc3-4)c3cccc4c3-c3ccccc3C43c4ccccc4-c4ccccc43)cc21]

SpMA3

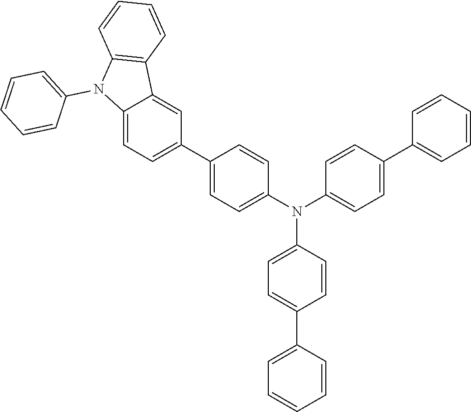 [SMILES: c1ccc(-c2ccc(N(c3ccc(-c4ccccc4)cc3)c3ccc(-c4ccc5c(c4)c4ccccc4n5-c4ccccc4)cc3)cc2)cc1]

SpMA4

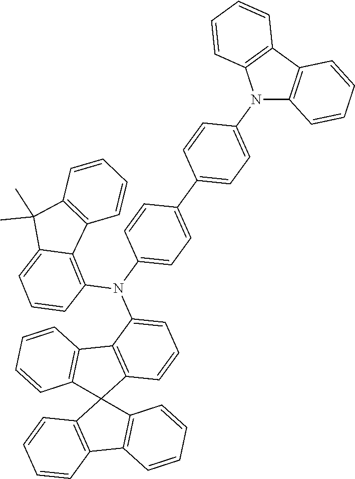 [SMILES: CC1(C)c2ccccc2-c2c(N(c3ccc(-c4ccc(-n5c6ccccc6c6ccccc65)cc4)cc3)c3cccc4c3-c3ccccc3C43c4ccccc4-c4ccccc43)cccc21]

SpMA5

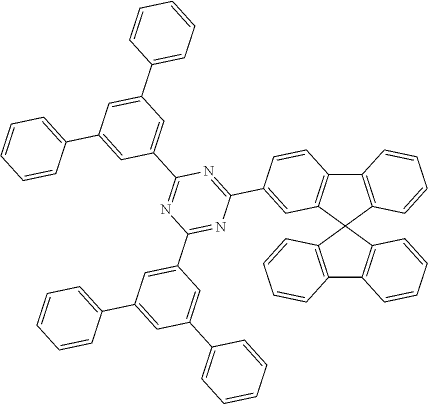 [SMILES: c1ccc(-c2cc(-c3ccccc3)cc(-c3nc(-c4cc(-c5ccccc5)cc(-c5ccccc5)c4)nc(-c4ccc5c(c4)C4(c6ccccc6-c6ccccc64)c4ccccc4-5)n3)c2)cc1]

ST2

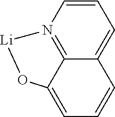

LiQ

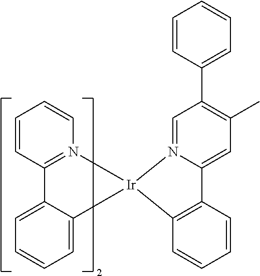

TEG1

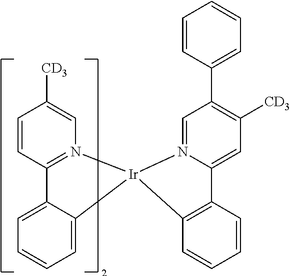

TEG2

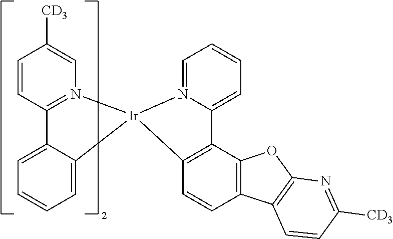

TEG3

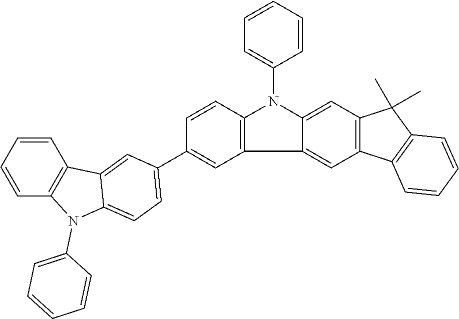 [SMILES: CC1(C)c2ccccc2-c2cc3c4cc(-c5ccc6c(c5)c5ccccc5n6-c5ccccc5)ccc4n(-c4ccccc4)c3cc21]

H0

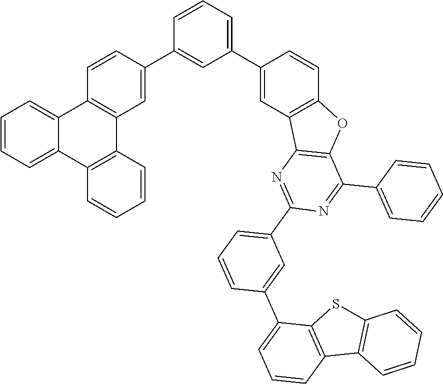 [SMILES: c1ccc(-c2nc(-c3cccc(-c4cccc5c4sc4ccccc45)c3)nc3c2oc2ccc(-c4cccc(-c5ccc6c7ccccc7c7ccccc7c6c5)c4)cc23)cc1]

VG1 [WO2018234932]

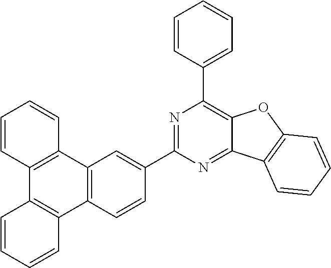 [SMILES: c1ccc(-c2nc(-c3ccc4c5ccccc5c5ccccc5c4c3)nc3c2oc2ccccc23)cc1]

VG2 [WO20067657]

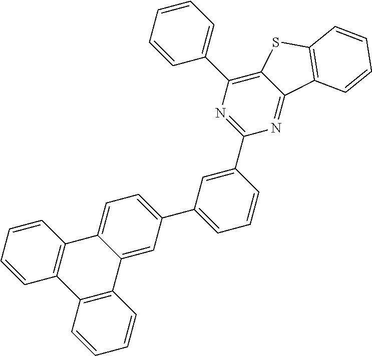 [SMILES: c1ccc(-c2nc(-c3cccc(-c4ccc5c6ccccc6c6ccccc6c5c4)c3)nc3c2sc2ccccc23)cc1]

VG3 [WO15105316]

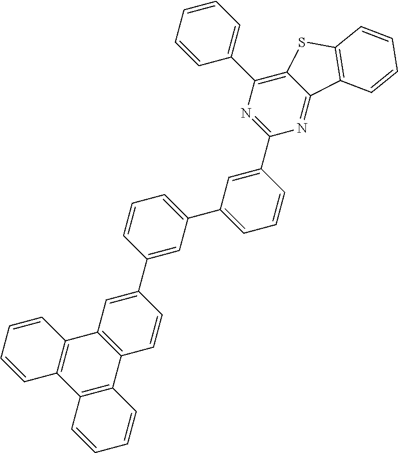 [SMILES: c1ccc(-c2nc(-c3cccc(-c4cccc(-c5ccc6c7ccccc7c7ccccc7c6c5)c4)c3)nc3c2sc2ccccc23)cc1]

VG4 [WO15105316]

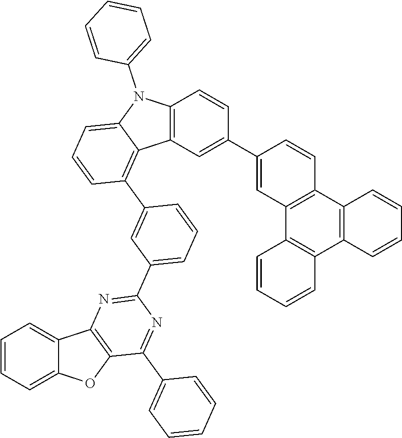 [SMILES: c1ccc(-c2nc(-c3cccc(-c4cccc5c4c4cc(-c6ccc7c8ccccc8c8ccccc8c7c6)ccc4n5-c4ccccc4)c3)nc3c2oc2ccccc23)cc1]

VG5 [US2016072078]

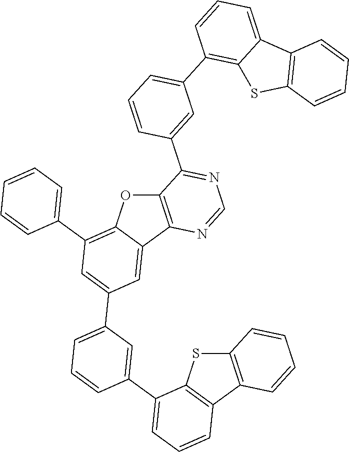 [SMILES: c1ccc(-c2cc(-c3cccc(-c4cccc5c4sc4ccccc45)c3)cc3c2oc2c(-c4cccc(-c5cccc6c5sc5ccccc56)c4)ncnc23)cc1]

VG6 [US2017186971]

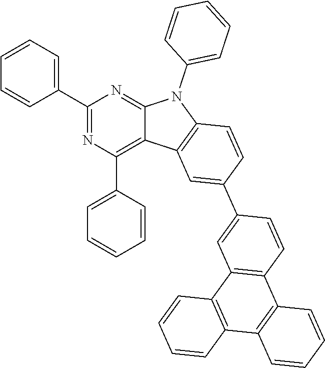 [SMILES: c1ccc(-c2nc(-c3ccccc3)c3c4cc(-c5ccc6c7ccccc7c7ccccc7c6c5)ccc4n(-c4ccccc4)c3n2)cc1]

VG7 [WO17186760]

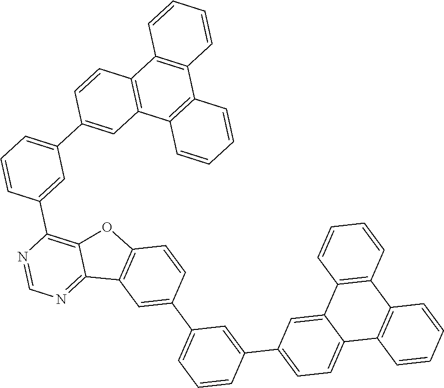 [SMILES: c1cc(-c2ccc3c4ccccc4c4ccccc4c3c2)cc(-c2ccc3oc4c(-c5cccc(-c6ccc7c8ccccc8c8ccccc8c7c6)c5)ncnc4c3c2)c1]

VG8 [US2020259099]

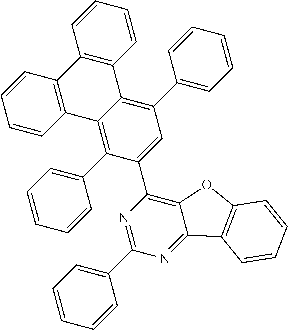 [SMILES: c1ccc(-c2nc(-c3cc(-c4ccccc4)c4c5ccccc5c5ccccc5c4c3-c3ccccc3)c3oc4ccccc4c3n2)cc1]

VG9 [WO18088665]

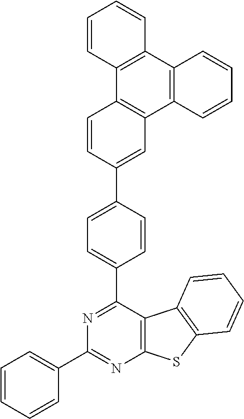 [SMILES: c1ccc(-c2nc(-c3ccc(-c4ccc5c6ccccc6c6ccccc6c5c4)cc3)c3c(n2)sc2ccccc23)cc1]

VG10 [US20172009039]

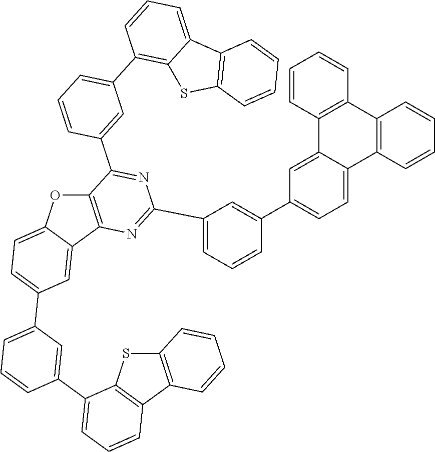 [SMILES: c1cc(-c2ccc3c4ccccc4c4ccccc4c3c2)cc(-c2nc(-c3cccc(-c4cccc5c4sc4ccccc45)c3)c3oc4ccc(-c5cccc(-c6cccc7c6sc6ccccc67)c5)cc4c3n2)c1]

VG11

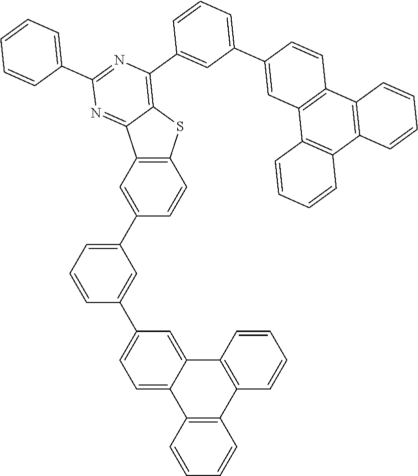 [SMILES: c1ccc(-c2nc(-c3cccc(-c4ccc5c6ccccc6c6ccccc6c5c4)c3)c3sc4ccc(-c5cccc(-c6ccc7c8ccccc8c8ccccc8c7c6)c5)cc4c3n2)cc1]

VG12

### Example 2: Synthesis of Host Materials and Precursors Thereof

The syntheses which follow, unless stated otherwise, are conducted under a protective gas atmosphere in dried solvents. The compounds of the invention can be prepared by means of synthesis methods known to those skilled in the art.

### a) 2,4-Diphenylbenzo[4,5]furo[3,2-d]pyrimidine

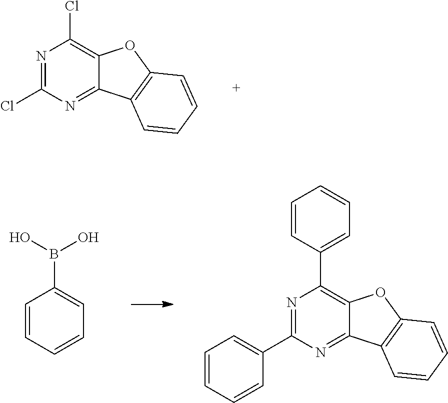 [SMILES: Clc1nc(Cl)c2oc3ccccc3c2n1 ; OB(O)c1ccccc1 ; c1ccc(-c2nc(-c3ccccc3)c3oc4ccccc4c3n2)cc1]

13 g (110.0 mmol) of phenylboronic acid, 13 g (55 mmol) of 2,4-dichlorobenzo[4,5]furo[3,2-d]pyrimidine and 21 g (210.0 mmol) of sodium carbonate are suspended in 500 ml of ethylene glycol diamine ether and 500 ml of water. To this suspension are added 913 mg (3.0 mmol) of tri-o-tolylphosphine and then 112 mg (0.5 mmol) of palladium(II) acetate, and the reaction mixture is heated under reflux for 16 h. After cooling, the organic phase is removed, filtered through silica gel and then concentrated to dryness. The residue is recrystallized from toluene and from dichloromethane/heptane. Yield: 15 g (47 mmol), 87% of theory.

The following compounds are prepared in an analogous manner:

| | Reactant 1 | Reactant 2 | Product | Yield |
|---|---|---|---|---|
| 1a | 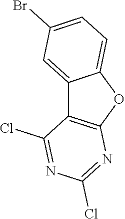 [SMILES: Clc1nc(Cl)c2c(n1)oc1ccc(Br)cc12] | 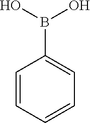 | 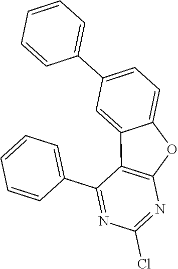 [SMILES: Clc1nc(-c2ccccc2)c2c(n1)oc1ccc(-c3ccccc3)cc12] | 63% |
| | 2201128-42-7 | | 2201128-42-7 | |
| 2a | 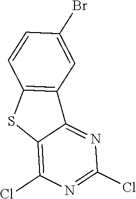 [SMILES: Clc1nc(Cl)c2sc3ccc(Br)cc3c2n1] | 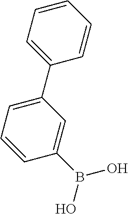 [SMILES: OB(O)c1cccc(-c2ccccc2)c1] | 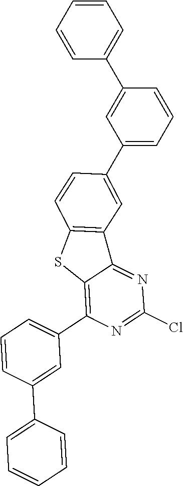 [SMILES: Clc1nc(-c2cccc(-c3ccccc3)c2)c2sc3ccc(-c4cccc(-c5ccccc5)c4)cc3c2n1] | 62% |
| | 2201128-35-8 | 5122-95-2 | | |
| 3a | 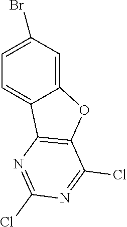 [SMILES: Clc1nc(Cl)c2oc3cc(Br)ccc3c2n1] | 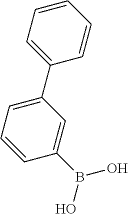 [SMILES: OB(O)c1cccc(-c2ccccc2)c1] | 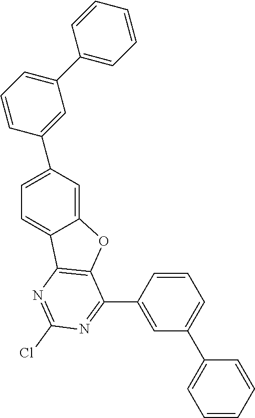 [SMILES: Clc1nc(-c2cccc(-c3ccccc3)c2)c2oc3cc(-c4cccc(-c5ccccc5)c4)ccc3c2n1] | 60% |
| | 2201128-38-1 | 5122-95-2 | | |
| 4a | 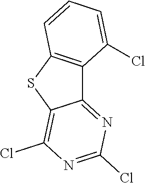 [SMILES: Clc1nc(Cl)c2sc3cccc(Cl)c3c2n1] | 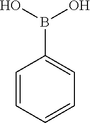 | 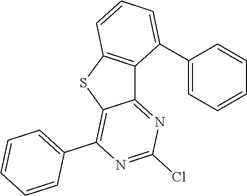 [SMILES: Clc1nc(-c2ccccc2)c2sc3cccc(-c4ccccc4)c3c2n1] | 57% |
| | 2303611-53-0 | | | |
| 5a | 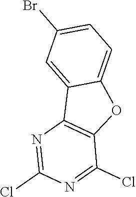 [SMILES: Clc1nc(Cl)c2oc3ccc(Br)cc3c2n1] | 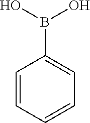 | 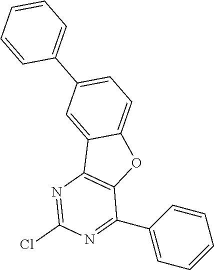 [SMILES: Clc1nc(-c2ccccc2)c2oc3ccc(-c4ccccc4)cc3c2n1] | 64% |
| | 1169560-03-5 | | | |
| 6a | 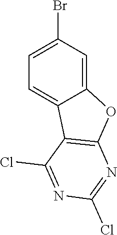 [SMILES: Clc1nc(Cl)c2c(n1)oc1cc(Br)ccc12] | 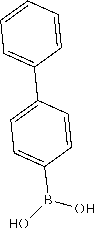 [SMILES: OB(O)c1ccc(-c2ccccc2)cc1] | 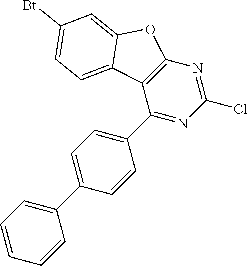 | 49% |
| | 2201128-41-6 | 5122-94-1 | | |
| 7a | 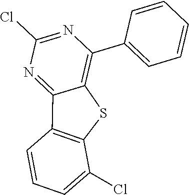 [SMILES: Clc1nc(-c2ccccc2)c2sc3c(Cl)cccc3c2n1] | 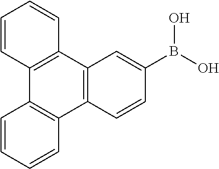 [SMILES: OB(O)c1ccc2c3ccccc3c3ccccc3c2c1] | 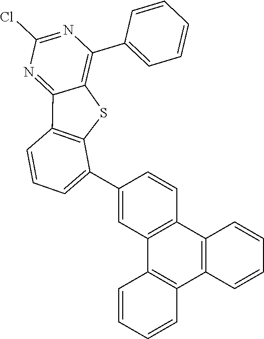 [SMILES: Clc1nc(-c2ccccc2)c2sc3c(-c4ccc5c6ccccc6c6ccccc6c5c4)cccc3c2n1] | 71% |
| | 2376837-27-1 | 654664-63-8 | | |
| 8a | 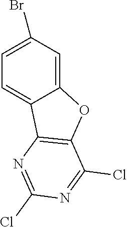 [SMILES: Clc1nc(Cl)c2oc3cc(Br)ccc3c2n1] | 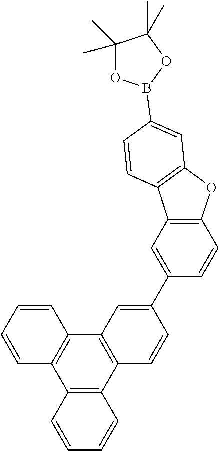 [SMILES: CC1(C)OB(c2ccc3c(c2)oc2ccc(-c4ccc5c6ccccc6c6ccccc6c5c4)cc23)OC1(C)C] | 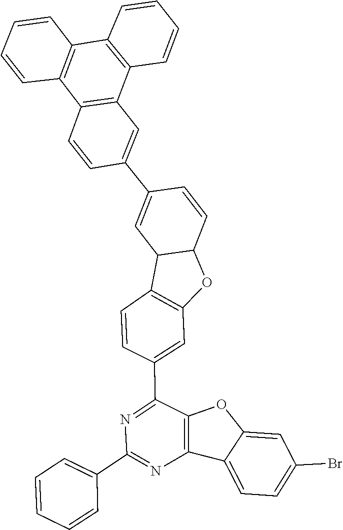 [SMILES: Brc1ccc2c(c1)oc1c(-c3ccc4c(c3)OC3C=CC(c5ccc6c7ccccc7c7ccccc7c6c5)=CC43)nc(-c3ccccc3)nc12] | 45% |
| | 2201128-38-1 | [2302041-79-6] | | |
| 9a | 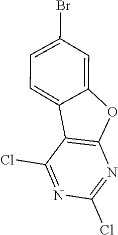 [SMILES: Clc1nc(Cl)c2c(n1)oc1cc(Br)ccc12] | 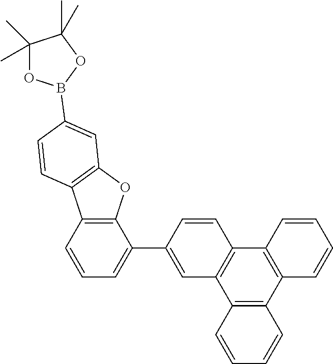 [SMILES: CC1(C)OB(c2ccc3c(c2)oc2c(-c4ccc5c6ccccc6c6ccccc6c5c4)cccc23)OC1(C)C] | 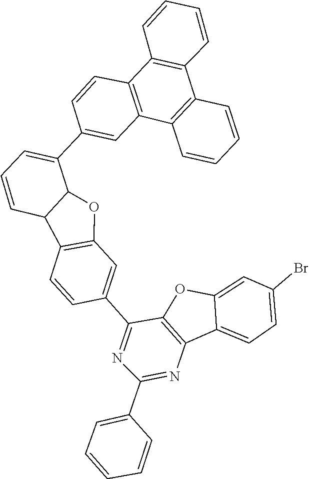 [SMILES: Brc1ccc2c(c1)oc1c(-c3ccc4c(c3)OC3C(c5ccc6c7ccccc7c7ccccc7c6c5)=CC=CC43)nc(-c3ccccc3)nc12] | 40% |
| | 2201128-41-6 | [2411555-09-2 ] | | |
| 10a | 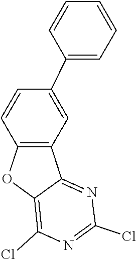 [SMILES: Clc1nc(Cl)c2oc3ccc(-c4ccccc4)cc3c2n1] | 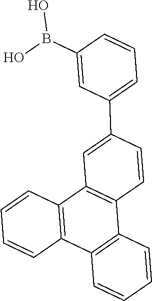 [SMILES: OB(O)c1cccc(-c2ccc3c4ccccc4c4ccccc4c3c2)c1] | 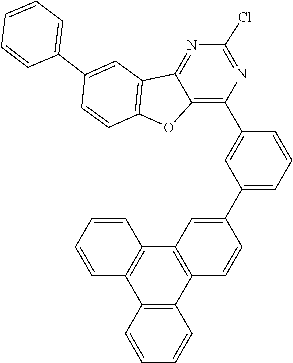 [SMILES: Clc1nc(-c2cccc(-c3ccc4c5ccccc5c5ccccc5c4c3)c2)c2oc3ccc(-c4ccccc4)cc3c2n1] | 77% |
| | 1835207-37-8 | 1235876-72-8 | | |
| 11a | 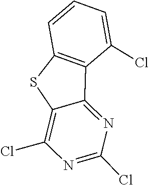 [SMILES: Clc1nc(Cl)c2sc3cccc(Cl)c3c2n1] | 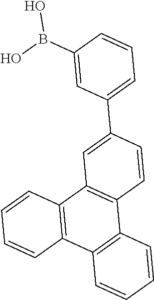 [SMILES: OB(O)c1cccc(-c2ccc3c4ccccc4c4ccccc4c3c2)c1] | 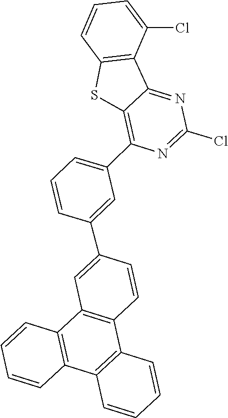 [SMILES: Clc1nc(-c2cccc(-c3ccc4c5ccccc5c5ccccc5c4c3)c2)c2sc3cccc(Cl)c3c2n1] | 66% |
| | 2303611-53-0 | 1235876-72-8 | | |
| 12a | 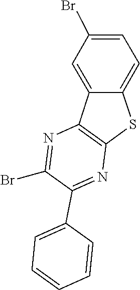 [SMILES: Brc1ccc2sc3nc(-c4ccccc4)c(Br)nc3c2c1] | 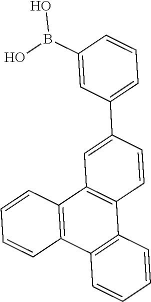 [SMILES: OB(O)c1cccc(-c2ccc3c4ccccc4c4ccccc4c3c2)c1] | 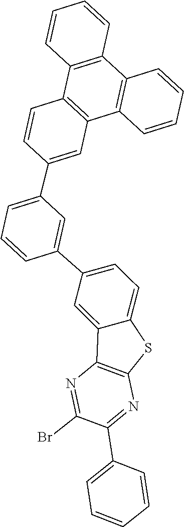 [SMILES: Brc1nc2c(nc1-c1ccccc1)sc1ccc(-c3cccc(-c4ccc5c6ccccc6c6ccccc6c5c4)c3)cc12] | 43% |
| | | 1235876-72-8 | | |
| 13a | 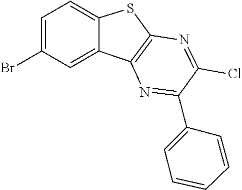 [SMILES: Clc1nc2sc3ccc(Br)cc3c2nc1-c1ccccc1] | 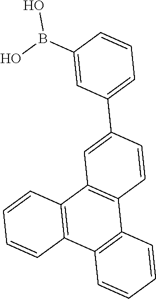 [SMILES: OB(O)c1cccc(-c2ccc3c4ccccc4c4ccccc4c3c2)c1] | 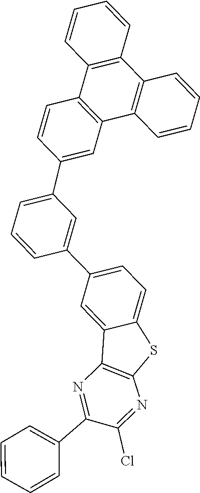 | 65% |
| | | 1235876-72-8 | | |
| 14a | 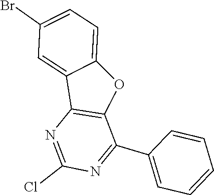 [SMILES: Clc1nc(-c2ccccc2)c2oc3ccc(Br)cc3c2n1] | 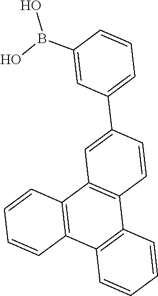 | 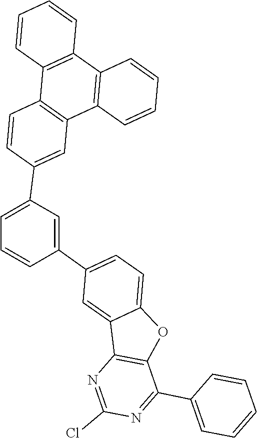 [SMILES: Clc1nc(-c2ccccc2)c2oc3ccc(-c4cccc(-c5ccc6c7ccccc7c7ccccc7c6c5)c4)cc3c2n1] | 69% |
| | 2217655-66-6 | 1235876-72-8 | | |
| 15a | 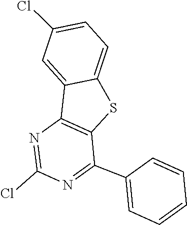 [SMILES: Clc1ccc2sc3c(-c4ccccc4)nc(Cl)nc3c2c1] | 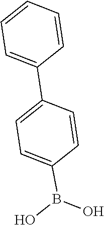 [SMILES: OB(O)c1ccc(-c2ccccc2)cc1] | 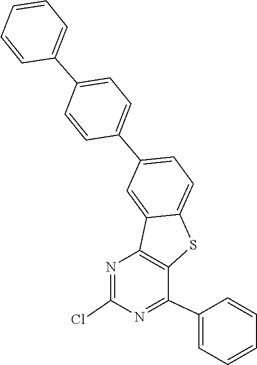 [SMILES: Clc1nc(-c2ccccc2)c2sc3ccc(-c4ccc(-c5ccccc5)cc4)cc3c2n1] | 62% |
| | 2376887-06-6 | 5122-94-1 | | |
| 16a | 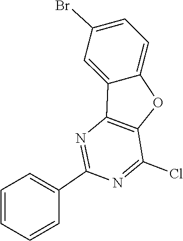 [SMILES: Clc1nc(-c2ccccc2)nc2c1oc1ccc(Br)cc12] | 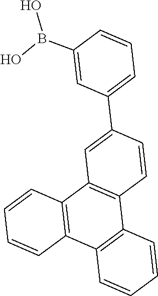 | 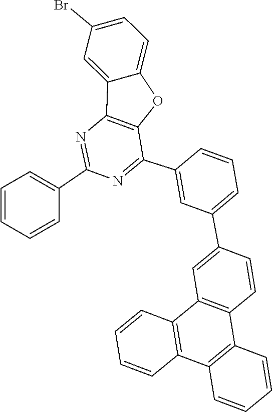 [SMILES: Brc1ccc2oc3c(-c4cccc(-c5ccc6c7ccccc7c7ccccc7c6c5)c4)nc(-c4ccccc4)nc3c2c1] | 64% |
| | 2219361-06-3 | 1235876-72-8 | | |
| 17a | 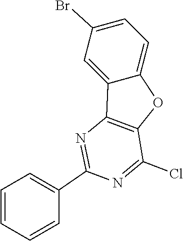 [SMILES: Clc1nc(-c2ccccc2)nc2c1oc1ccc(Br)cc12] | 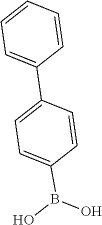 [SMILES: OB(O)c1ccc(-c2ccccc2)cc1] | 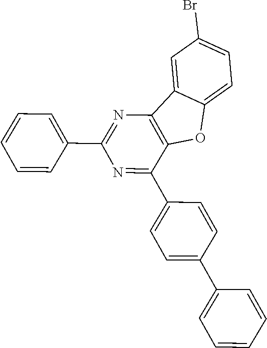 [SMILES: Brc1ccc2oc3c(-c4ccc(-c5ccccc5)cc4)nc(-c4ccccc4)nc3c2c1] | 58% |
| | 2219361-06-3 | 5122-94-1 | | |
| 18a | 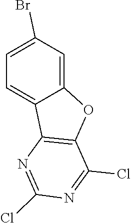 [SMILES: Clc1nc(Cl)c2oc3cc(Br)ccc3c2n1] | 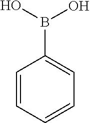 | 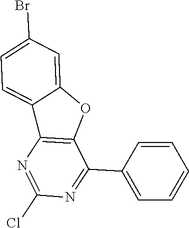 [SMILES: Clc1nc(-c2ccccc2)c2oc3cc(Br)ccc3c2n1] | 47% |
| | 2201128-28-1 | | | |
| 19a | 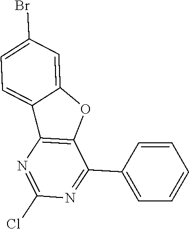 [SMILES: Clc1nc(-c2ccccc2)c2oc3cc(Br)ccc3c2n1] | 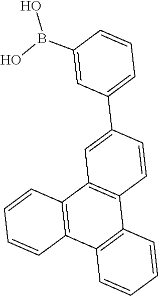 | 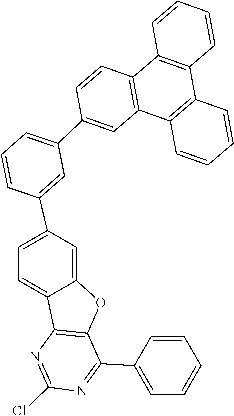 [SMILES: Clc1nc(-c2ccccc2)c2oc3cc(-c4cccc(-c5ccc6c7ccccc7c7ccccc7c6c5)c4)ccc3c2n1] | 53% |
| | | 1235876-72-8 | | |
| 20a | 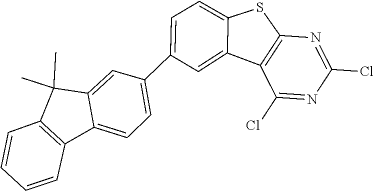 [SMILES: CC1(C)c2ccccc2-c2ccc(-c3ccc4sc5nc(Cl)nc(Cl)c5c4c3)cc21] | 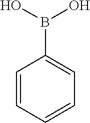 | 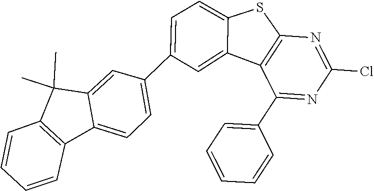 [SMILES: CC1(C)c2ccccc2-c2ccc(-c3ccc4sc5nc(Cl)nc(-c6ccccc6)c5c4c3)cc21] | 60% |
| | [2219361-27-8] | | | |
| 21a | 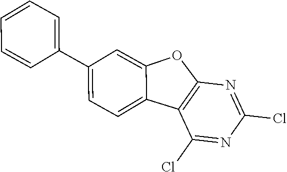 [SMILES: Clc1nc(Cl)c2c(n1)oc1cc(-c3ccccc3)ccc12] | 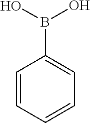 | 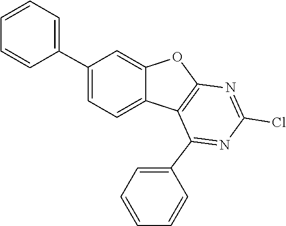 [SMILES: Clc1nc(-c2ccccc2)c2c(n1)oc1cc(-c3ccccc3)ccc12] | 59% |
| | [2201128-28-9] | | | |
| 22a | 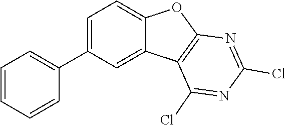 [SMILES: Clc1nc(Cl)c2c(n1)oc1ccc(-c3ccccc3)cc12] | 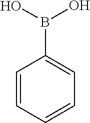 | 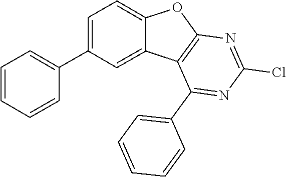 [SMILES: Clc1nc(-c2ccccc2)c2c(n1)oc1ccc(-c3ccccc3)cc12] | 61% |
| | [2201128-33-6] | | | |
| 23a | 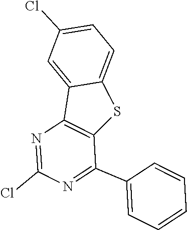 [SMILES: Clc1ccc2sc3c(-c4ccccc4)nc(Cl)nc3c2c1] | 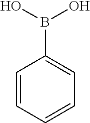 | 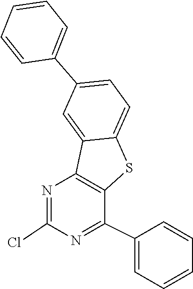 [SMILES: Clc1nc(-c2ccccc2)c2sc3ccc(-c4ccccc4)cc3c2n1] | 72% |
| | 2376887-06-6 | | | |
| 24a | 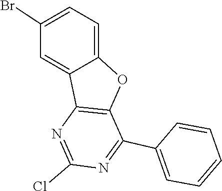 [SMILES: Clc1nc(-c2ccccc2)c2oc3ccc(Br)cc3c2n1] | 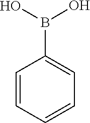 | 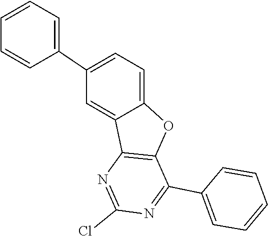 [SMILES: Clc1nc(-c2ccccc2)c2oc3ccc(-c4ccccc4)cc3c2n1] | 65% |
| | 2217655-66-6 | | | |
| 25a | 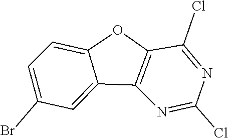 [SMILES: Clc1nc(Cl)c2oc3ccc(Br)cc3c2n1] | 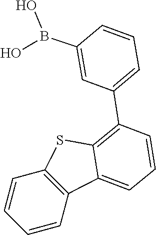 [SMILES: OB(O)c1cccc(-c2cccc3c2sc2ccccc23)c1] | 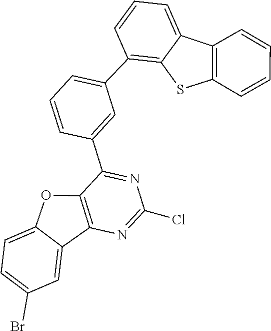 [SMILES: Clc1nc(-c2cccc(-c3cccc4c3sc3ccccc34)c2)c2oc3ccc(Br)cc3c2n1] | 61% |
| | [1169560-03-5] | [1307859-67-1] | | |
| 26a | 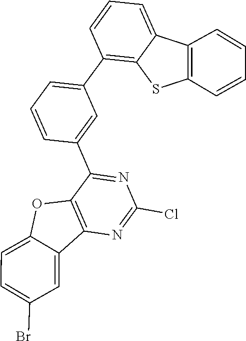 [SMILES: Clc1nc(-c2cccc(-c3cccc4c3sc3ccccc34)c2)c2oc3ccc(Br)cc3c2n1] | 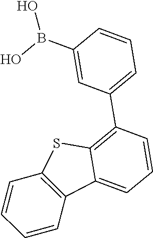 [SMILES: OB(O)c1cccc(-c2cccc3c2sc2ccccc23)c1] | 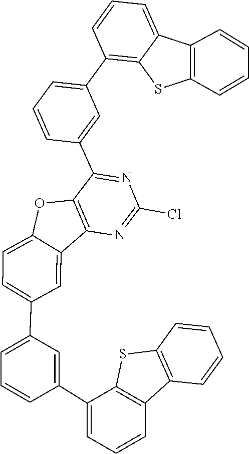 [SMILES: Clc1nc(-c2cccc(-c3cccc4c3sc3ccccc34)c2)c2oc3ccc(-c4cccc(-c5cccc6c5sc5ccccc56)c4)cc3c2n1] | 53% |
| | | [1307859-67-1] | | |
| 27a | 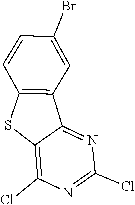 [SMILES: Clc1nc(Cl)c2sc3ccc(Br)cc3c2n1] | 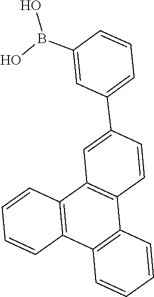 | 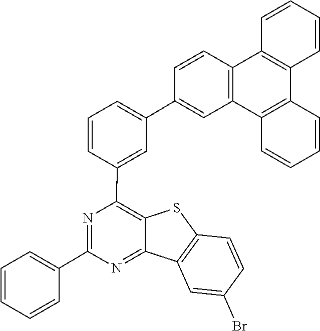 [SMILES: Brc1ccc2sc3c(-c4cccc(-c5ccc6c7ccccc7c7ccccc7c6c5)c4)nc(-c4ccccc4)nc3c2c1] | 49% |
| | 2201128-35-8 | 1235876-72-8 | | |
| 28a | 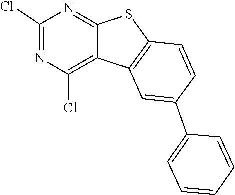 [SMILES: Clc1nc(Cl)c2c(n1)sc1ccc(-c3ccccc3)cc12] | 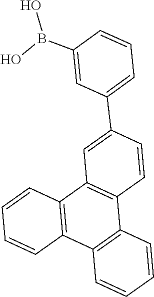 | 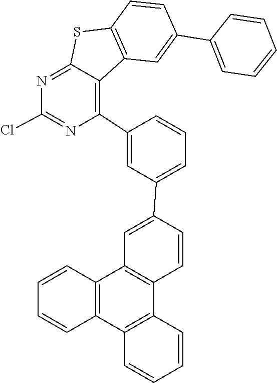 [SMILES: Clc1nc(-c2cccc(-c3ccc4c5ccccc5c5ccccc5c4c3)c2)c2c(n1)sc1ccc(-c3ccccc3)cc12] | 52% |
| | [2201128-08-5] | 1235876-72-8 | | |
| 29a | 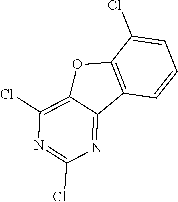 [SMILES: Clc1nc(Cl)c2oc3c(Cl)cccc3c2n1] | 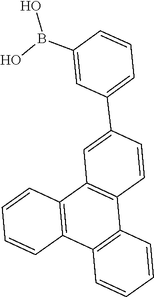 | 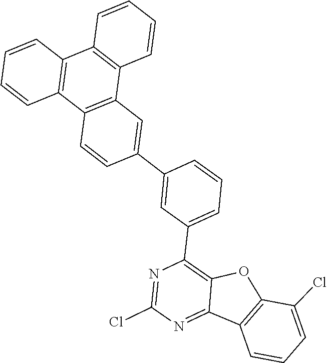 [SMILES: Clc1nc(-c2cccc(-c3ccc4c5ccccc5c5ccccc5c4c3)c2)c2oc3c(Cl)cccc3c2n1] | 54% |
| | [2303611-57-4] | 1235876-72-8 | | |
| 30a | 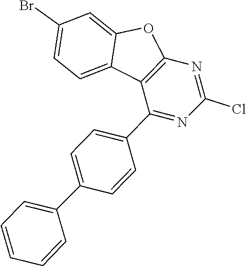 [SMILES: Clc1nc(-c2ccc(-c3ccccc3)cc2)c2c(n1)oc1cc(Br)ccc12] | 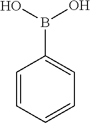 | 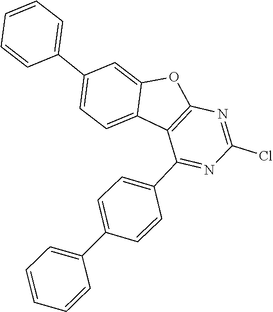 [SMILES: Clc1nc(-c2ccc(-c3ccccc3)cc2)c2c(n1)oc1cc(-c3ccccc3)ccc12] | 57% |
| 31a | 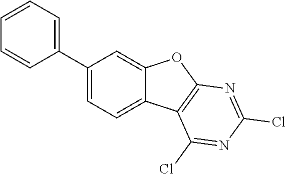 [SMILES: Clc1nc(Cl)c2c(n1)oc1cc(-c3ccccc3)ccc12] | 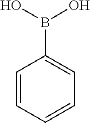 | 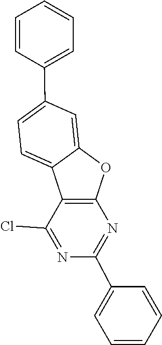 [SMILES: Clc1nc(-c2ccccc2)nc2oc3cc(-c4ccccc4)ccc3c12] | 66% |
| | [2201128-28-9] | | | |

### b) 8-Bromo-2,4-diphenylbenzo[4,5]furo[3,2-d]pyrimidine

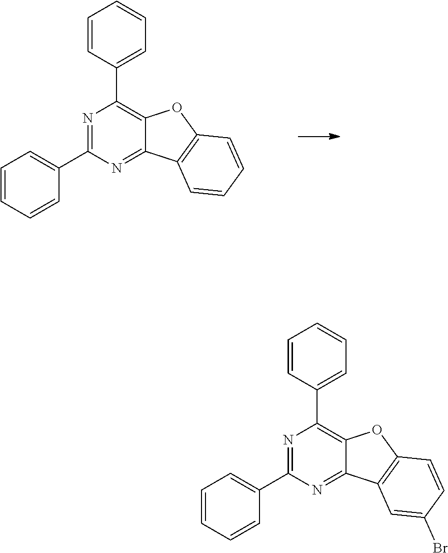 [SMILES: c1ccc(-c2nc(-c3ccccc3)c3oc4ccccc4c3n2)cc1 ; Brc1ccc2oc3c(-c4ccccc4)nc(-c4ccccc4)nc3c2c1]

61 g (190.0 mmol) of 2,4-diphenylbenzo[4,5]furo[3,2-d]pyrimidine are suspended in 2000 ml of acetic acid (100%) and 2000 ml of sulfuric acid (95-98%). 34 g (190 mmol) of NBS are added to this suspension in portions and the mixture is stirred in darkness for 2 hours. Thereafter, water/ice is added and the solids are removed and washed with ethanol. The residue is recrystallized in toluene. The yield is 65 g (163 mmol), corresponding to 86% of theory.

The following compounds are prepared in an analogous manner:

| | Reactant 1 | Product | Yield |
|---|---|---|---|
| 1b | 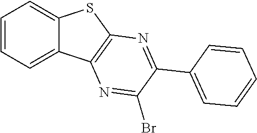 [SMILES: Brc1nc2c(nc1-c1ccccc1)sc1ccccc12] | 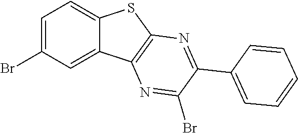 [SMILES: Brc1ccc2sc3nc(-c4ccccc4)c(Br)nc3c2c1] | 82% |
| | 2414945-47-2 | | |
| 2b | 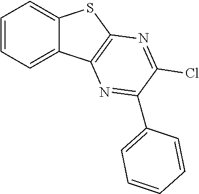 [SMILES: Clc1nc2sc3ccccc3c2nc1-c1ccccc1] | 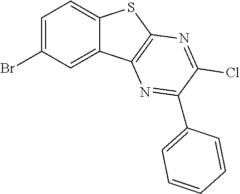 [SMILES: Clc1nc2sc3ccc(Br)cc3c2nc1-c1ccccc1] | 80% |

### c) 2,4-Diphenyl-8-(3-triphenylen-2-ylphenyl)benzofuro[3,2-d]pyrimidine

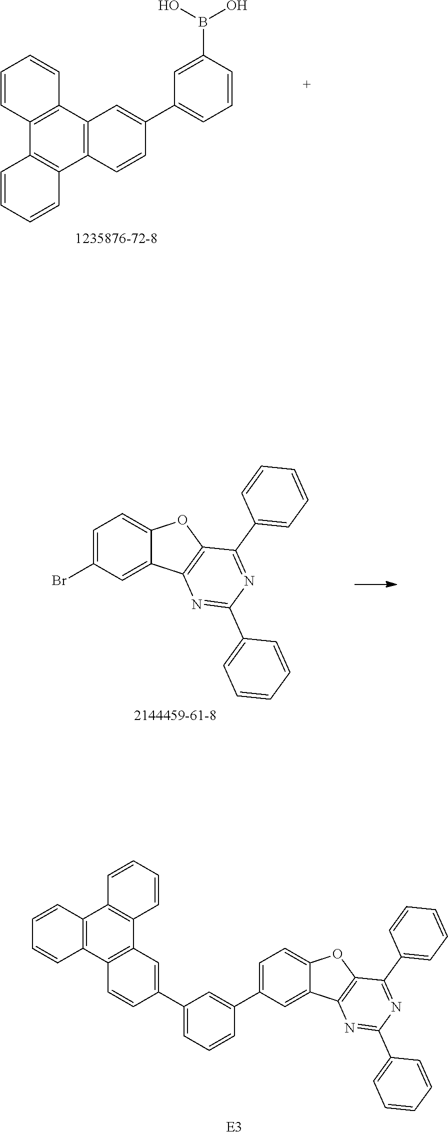 [SMILES: OB(O)c1cccc(-c2ccc3c4ccccc4c4ccccc4c3c2)c1 ; Brc1ccc2oc3c(-c4ccccc4)nc(-c4ccccc4)nc3c2c1 ; c1ccc(-c2nc(-c3ccccc3)c3oc4ccc(-c5cccc(-c6ccc7c8ccccc8c8ccccc8c7c6)c5)cc4c3n2)cc1]

62.5 g (156 mmol) of 8-bromo-2,4-diphenyl-benzo[4,5]furo[3,2-d]pyrimidine, 59 g (170 mmol) of (3-triphenylene-2-ylphenyl)boronic acid and 36 g (340 mmol) of sodium carbonate are suspended in 1000 ml of ethylene glycol diamine ether and 280 ml of water. 1.8 g (1.5 mmol) of tetrakis(triphenylphosphine)palladium(0) are added to this suspension, and the reaction mixture is heated under reflux for 16 h. After cooling, the organic phase is removed, filtered through silica gel and then concentrated to dryness. The product is purified via column chromatography on silica gel with toluene/heptane (1:2) and finally sublimed under high vacuum (p=5×10⁻⁷ mbar) (99.9% purity). The yield is 69 g (111 mmol), corresponding to 72% of theory.

The following-compounds are prepared in an analogous manner:

| | Reactant 1 | Reactant 2 | Product | Yield |
|---|---|---|---|---|
| 1c | 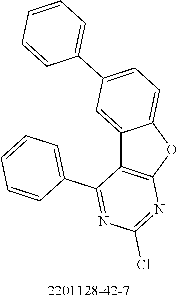 [SMILES: Clc1nc(-c2ccccc2)c2c(n1)oc1ccc(-c3ccccc3)cc12] | 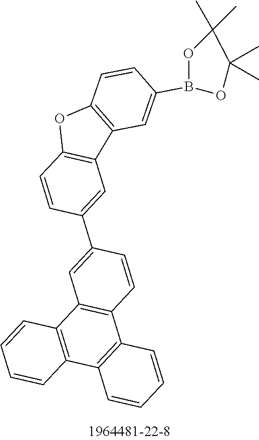 [SMILES: CC1(C)OB(c2ccc3oc4ccc(-c5ccc6c7ccccc7c7ccccc7c6c5)cc4c3c2)OC1(C)C] | 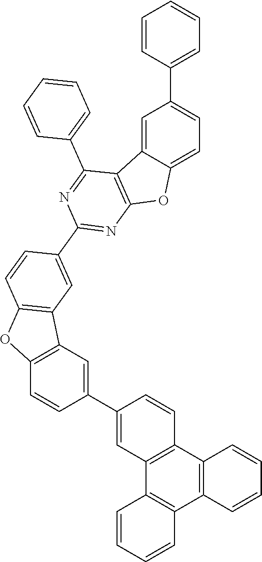 [SMILES: c1ccc(-c2ccc3oc4nc(-c5ccc6oc7ccc(-c8ccc9c%10ccccc%10c%10ccccc%10c9c8)cc7c6c5)nc(-c5ccccc5)c4c3c2)cc1] | 77% |
| 2c | 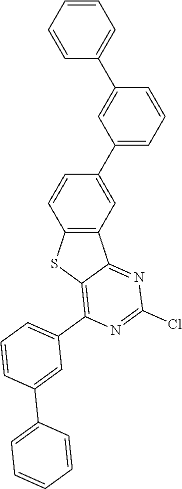 [SMILES: Clc1nc(-c2cccc(-c3ccccc3)c2)c2sc3ccc(-c4cccc(-c5ccccc5)c4)cc3c2n1] | 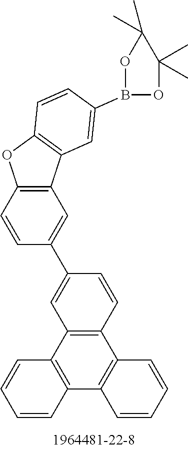 [SMILES: CC1(C)OB(c2ccc3oc4ccc(-c5ccc6c7ccccc7c7ccccc7c6c5)cc4c3c2)OC1(C)C] | 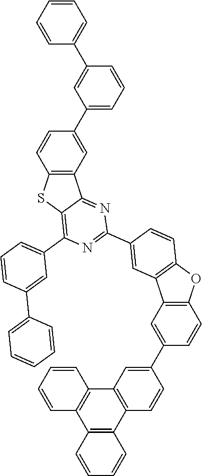 [SMILES: c1ccc(-c2cccc(-c3ccc4sc5c(-c6cccc(-c7ccccc7)c6)nc(-c6ccc7oc8ccc(-c9ccc%10c%11ccccc%11c%11ccccc%11c%10c9)cc8c7c6)nc5c4c3)c2)cc1] | 79% |
| 3c | 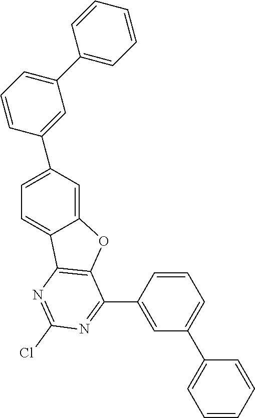 [SMILES: Clc1nc(-c2cccc(-c3ccccc3)c2)c2oc3cc(-c4cccc(-c5ccccc5)c4)ccc3c2n1] | 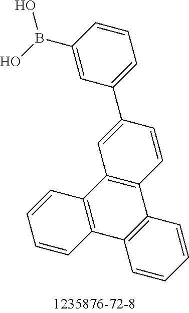 [SMILES: OB(O)c1cccc(-c2ccc3c4ccccc4c4ccccc4c3c2)c1] | 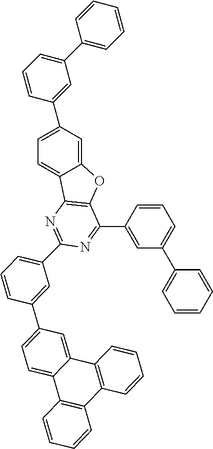 [SMILES: c1ccc(-c2cccc(-c3ccc4c(c3)oc3c(-c5cccc(-c6ccccc6)c5)nc(-c5cccc(-c6ccc7c8ccccc8c8ccccc8c7c6)c5)nc34)c2)cc1] | 70% |
| 4c | 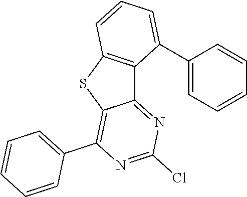 [SMILES: Clc1nc(-c2ccccc2)c2sc3cccc(-c4ccccc4)c3c2n1] | 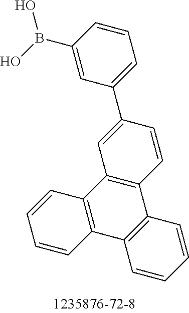 [SMILES: OB(O)c1cccc(-c2ccc3c4ccccc4c4ccccc4c3c2)c1] | 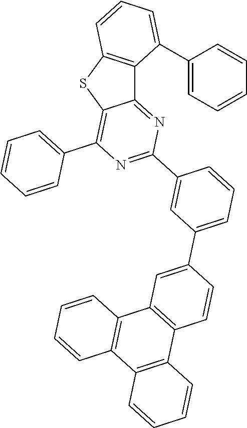 [SMILES: c1ccc(-c2nc(-c3cccc(-c4ccc5c6ccccc6c6ccccc6c5c4)c3)nc3c2sc2cccc(-c4ccccc4)c23)cc1] | 76% |
| 5c | 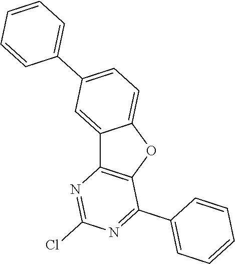 [SMILES: Clc1nc(-c2ccccc2)c2oc3ccc(-c4ccccc4)cc3c2n1] | 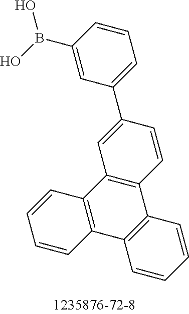 [SMILES: OB(O)c1cccc(-c2ccc3c4ccccc4c4ccccc4c3c2)c1] | 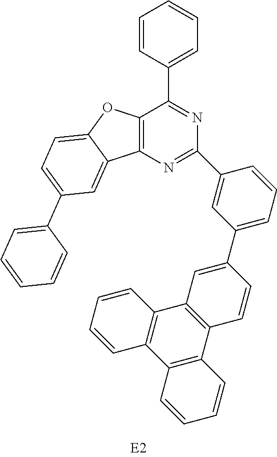 [SMILES: c1ccc(-c2ccc3oc4c(-c5ccccc5)nc(-c5cccc(-c6ccc7c8ccccc8c8ccccc8c7c6)c5)nc4c3c2)cc1] | 69% |
| 6c | 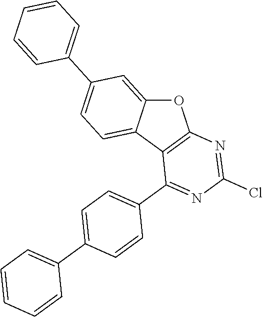 [SMILES: Clc1nc(-c2ccc(-c3ccccc3)cc2)c2c(n1)oc1cc(-c3ccccc3)ccc12] | 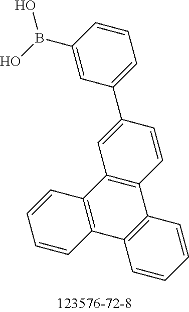 [SMILES: OB(O)c1cccc(-c2ccc3c4ccccc4c4ccccc4c3c2)c1] | 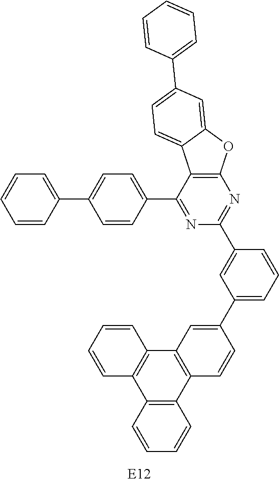 [SMILES: c1ccc(-c2ccc(-c3nc(-c4cccc(-c5ccc6c7ccccc7c7ccccc7c6c5)c4)nc4oc5cc(-c6ccccc6)ccc5c34)cc2)cc1] | 71% |
| 7c | 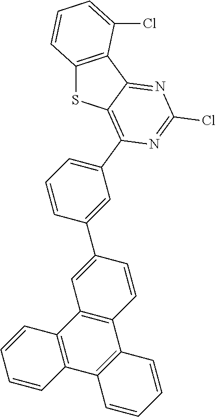 [SMILES: Clc1nc(-c2cccc(-c3ccc4c5ccccc5c5ccccc5c4c3)c2)c2sc3cccc(Cl)c3c2n1] | 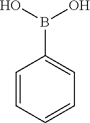 | 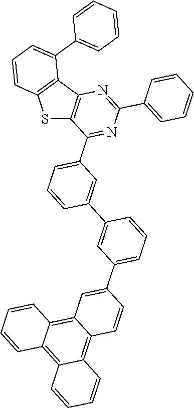 [SMILES: c1ccc(-c2nc(-c3cccc(-c4cccc(-c5ccc6c7ccccc7c7ccccc7c6c5)c4)c3)c3sc4cccc(-c5ccccc5)c4c3n2)cc1] | 77% |
| 8c | 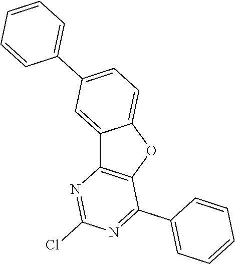 [SMILES: Clc1nc(-c2ccccc2)c2oc3ccc(-c4ccccc4)cc3c2n1] | 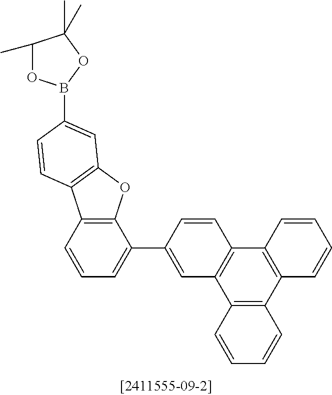 [SMILES: CC1OB(c2ccc3c(c2)oc2c(-c4ccc5c6ccccc6c6ccccc6c5c4)cccc23)OC1(C)C] | 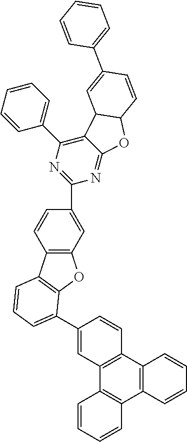 [SMILES: C1=CC2Oc3nc(-c4ccc5c(c4)oc4c(-c6ccc7c8ccccc8c8ccccc8c7c6)cccc45)nc(-c4ccccc4)c3C2C=C1c1ccccc1] | 79% |
| 9c | 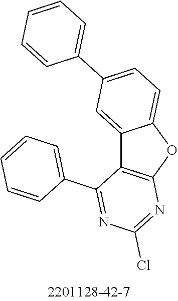 [SMILES: Clc1nc(-c2ccccc2)c2c(n1)oc1ccc(-c3ccccc3)cc12] | 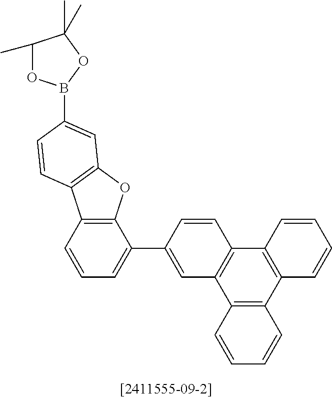 [SMILES: CC1OB(c2ccc3c(c2)oc2c(-c4ccc5c6ccccc6c6ccccc6c5c4)cccc23)OC1(C)C] | 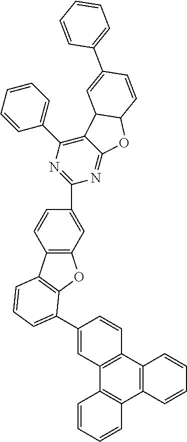 [SMILES: C1=CC2Oc3nc(-c4ccc5c(c4)oc4c(-c6ccc7c8ccccc8c8ccccc8c7c6)cccc45)nc(-c4ccccc4)c3C2C=C1c1ccccc1] | 75% |
| 10c | 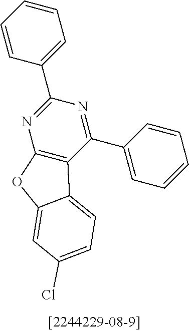 [SMILES: Clc1ccc2c(c1)oc1nc(-c3ccccc3)nc(-c3ccccc3)c12] | 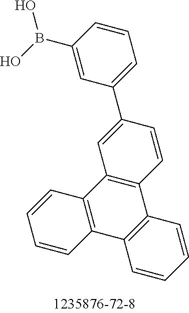 [SMILES: OB(O)c1cccc(-c2ccc3c4ccccc4c4ccccc4c3c2)c1] | 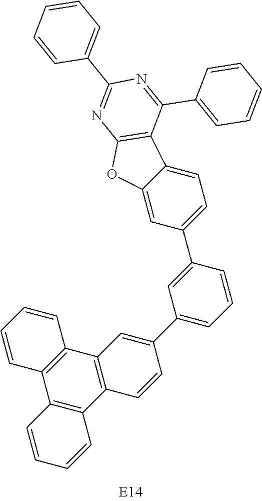 [SMILES: c1ccc(-c2nc(-c3ccccc3)c3c(n2)oc2cc(-c4cccc(-c5ccc6c7ccccc7c7ccccc7c6c5)c4)ccc23)cc1] | 68% |
| 11c | 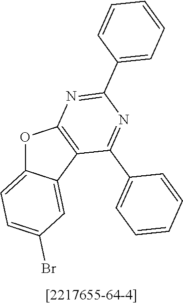 [SMILES: Brc1ccc2oc3nc(-c4ccccc4)nc(-c4ccccc4)c3c2c1] | 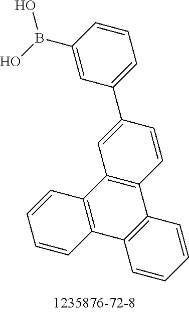 [SMILES: OB(O)c1cccc(-c2ccc3c4ccccc4c4ccccc4c3c2)c1] | 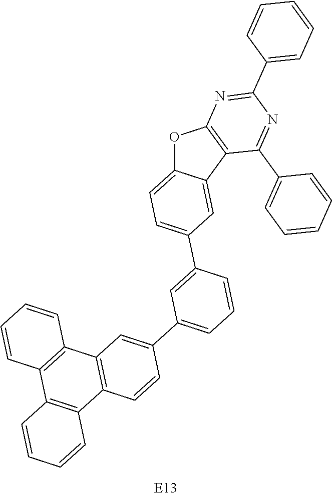 [SMILES: c1ccc(-c2nc(-c3ccccc3)c3c(n2)oc2ccc(-c4cccc(-c5ccc6c7ccccc7c7ccccc7c6c5)c4)cc23)cc1] | 78% |
| 12c | 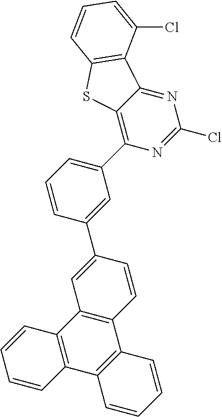 [SMILES: Clc1nc(-c2cccc(-c3ccc4c5ccccc5c5ccccc5c4c3)c2)c2sc3cccc(Cl)c3c2n1] | 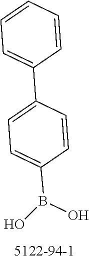 [SMILES: OB(O)c1ccc(-c2ccccc2)cc1] | 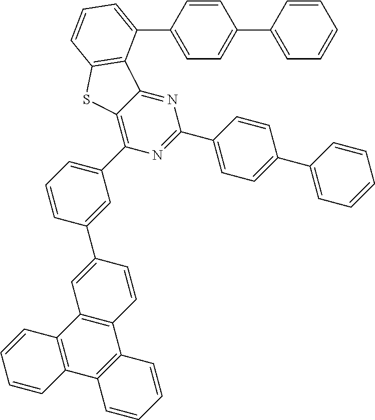 [SMILES: c1ccc(-c2ccc(-c3nc(-c4cccc(-c5ccc6c7ccccc7c7ccccc7c6c5)c4)c4sc5cccc(-c6ccc(-c7ccccc7)cc6)c5c4n3)cc2)cc1] | 66% |
| 13c | 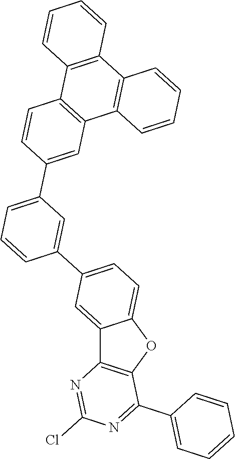 [SMILES: Clc1nc(-c2ccccc2)c2oc3ccc(-c4cccc(-c5ccc6c7ccccc7c7ccccc7c6c5)c4)cc3c2n1] | 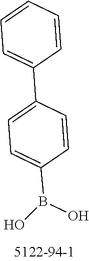 [SMILES: OB(O)c1ccc(-c2ccccc2)cc1] | 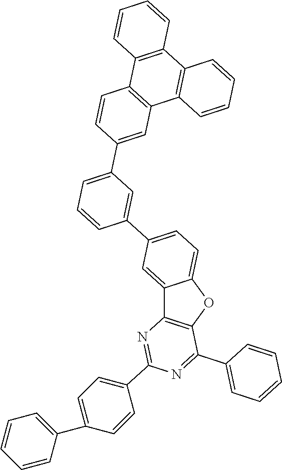 [SMILES: c1ccc(-c2ccc(-c3nc(-c4ccccc4)c4oc5ccc(-c6cccc(-c7ccc8c9ccccc9c9ccccc9c8c7)c6)cc5c4n3)cc2)cc1] | 76% |
| 14c | 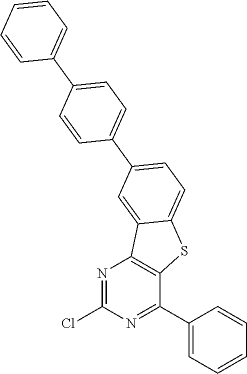 [SMILES: Clc1nc(-c2ccccc2)c2sc3ccc(-c4ccc(-c5ccccc5)cc4)cc3c2n1] | 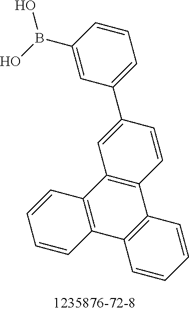 [SMILES: OB(O)c1cccc(-c2ccc3c4ccccc4c4ccccc4c3c2)c1] | 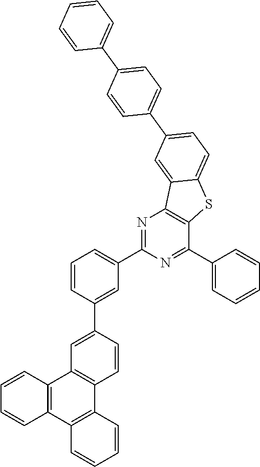 [SMILES: c1ccc(-c2ccc(-c3ccc4sc5c(-c6ccccc6)nc(-c6cccc(-c7ccc8c9ccccc9c9ccccc9c8c7)c6)nc5c4c3)cc2)cc1] | 70% |
| 15c | 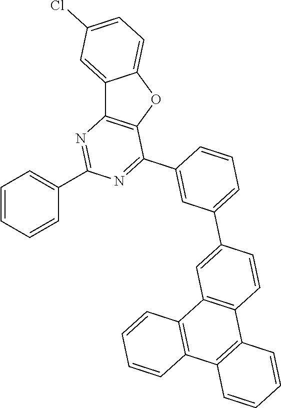 [SMILES: Clc1ccc2oc3c(-c4cccc(-c5ccc6c7ccccc7c7ccccc7c6c5)c4)nc(-c4ccccc4)nc3c2c1] | 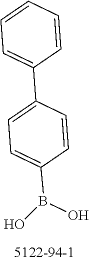 [SMILES: OB(O)c1ccc(-c2ccccc2)cc1] | 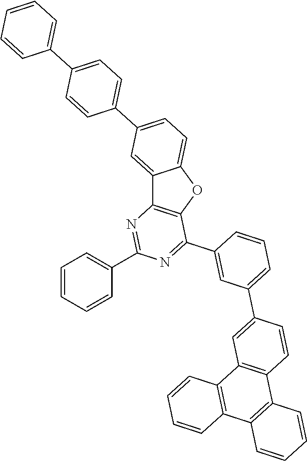 [SMILES: c1ccc(-c2ccc(-c3ccc4oc5c(-c6cccc(-c7ccc8c9ccccc9c9ccccc9c8c7)c6)nc(-c6ccccc6)nc5c4c3)cc2)cc1] | 76% |
| 16c | 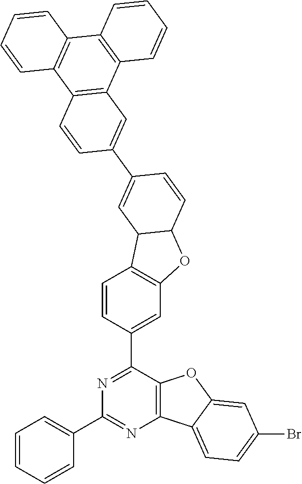 [SMILES: Brc1ccc2c(c1)oc1c(-c3ccc4c(c3)OC3C=CC(c5ccc6c7ccccc7c7ccccc7c6c5)=CC43)nc(-c3ccccc3)nc12] | 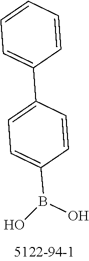 [SMILES: OB(O)c1ccc(-c2ccccc2)cc1] | 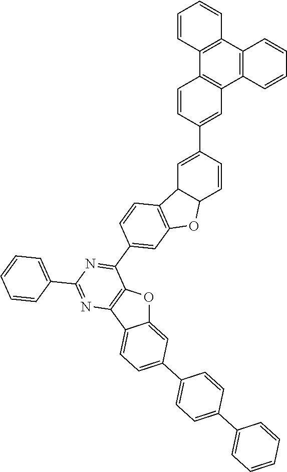 [SMILES: C1=CC2Oc3cc(-c4nc(-c5ccccc5)nc5c4oc4cc(-c6ccc(-c7ccccc7)cc6)ccc45)ccc3C2C=C1c1ccc2c3ccccc3c3ccccc3c2c1] | 71% |
| 17c | 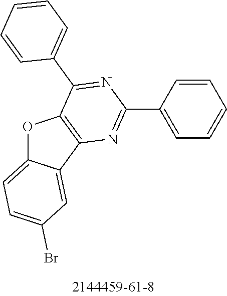 [SMILES: Brc1ccc2oc3c(-c4ccccc4)nc(-c4ccccc4)nc3c2c1] | 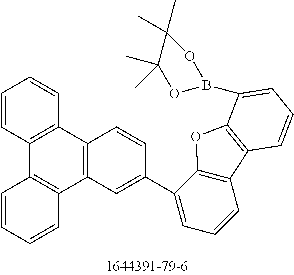 [SMILES: CC1(C)OB(c2cccc3c2oc2c(-c4ccc5c6ccccc6c6ccccc6c5c4)cccc23)OC1(C)C] | 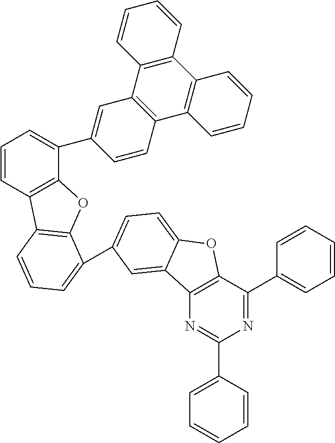 [SMILES: c1ccc(-c2nc(-c3ccccc3)c3oc4ccc(-c5cccc6c5oc5c(-c7ccc8c9ccccc9c9ccccc9c8c7)cccc56)cc4c3n2)cc1] | 64% |
| 18c | 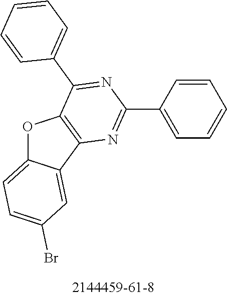 [SMILES: Brc1ccc2oc3c(-c4ccccc4)nc(-c4ccccc4)nc3c2c1] | 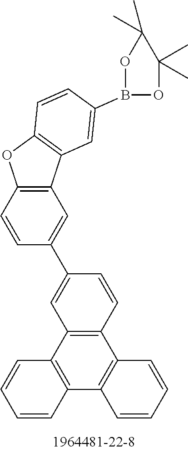 [SMILES: CC1(C)OB(c2ccc3oc4ccc(-c5ccc6c7ccccc7c7ccccc7c6c5)cc4c3c2)OC1(C)C] | 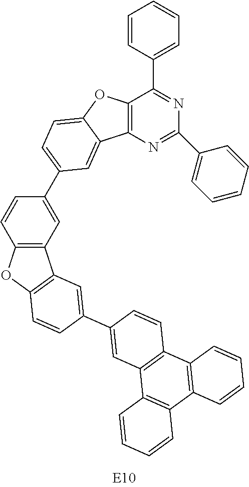 [SMILES: c1ccc(-c2nc(-c3ccccc3)c3oc4ccc(-c5ccc6oc7ccc(-c8ccc9c%10ccccc%10c%10ccccc%10c9c8)cc7c6c5)cc4c3n2)cc1] | 80% |
| 19c | 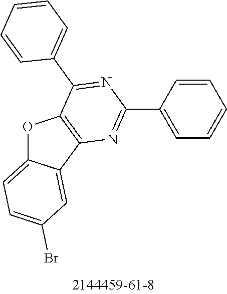 [SMILES: Brc1ccc2oc3c(-c4ccccc4)nc(-c4ccccc4)nc3c2c1] | 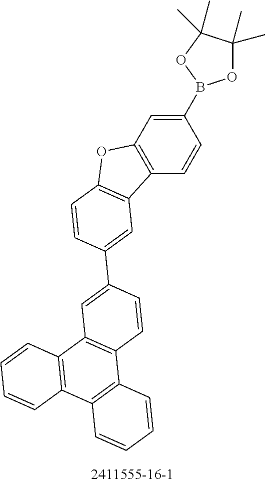 [SMILES: CC1(C)OB(c2ccc3c(c2)oc2ccc(-c4ccc5c6ccccc6c6ccccc6c5c4)cc23)OC1(C)C] | 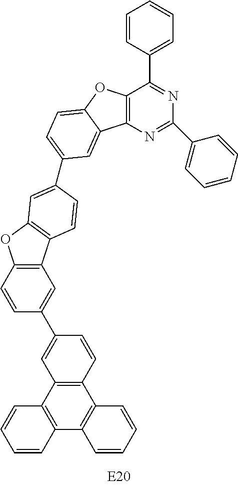 [SMILES: c1ccc(-c2nc(-c3ccccc3)c3oc4ccc(-c5ccc6c(c5)oc5ccc(-c7ccc8c9ccccc9c9ccccc9c8c7)cc56)cc4c3n2)cc1] | 81% |
| 20c | 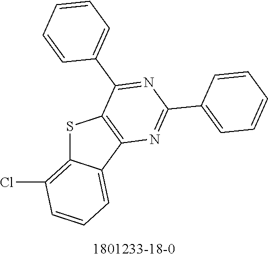 [SMILES: Clc1cccc2c1sc1c(-c3ccccc3)nc(-c3ccccc3)nc12] | 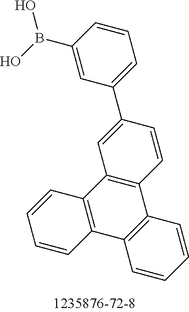 [SMILES: OB(O)c1cccc(-c2ccc3c4ccccc4c4ccccc4c3c2)c1] | 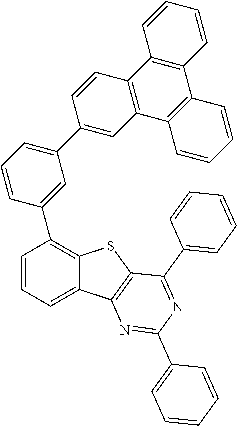 [SMILES: c1ccc(-c2nc(-c3ccccc3)c3sc4c(-c5cccc(-c6ccc7c8ccccc8c8ccccc8c7c6)c5)cccc4c3n2)cc1] | 76% |
| 21c | 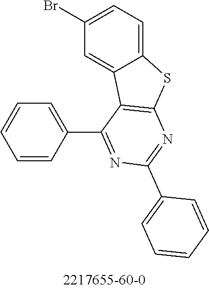 [SMILES: Brc1ccc2sc3nc(-c4ccccc4)nc(-c4ccccc4)c3c2c1] | 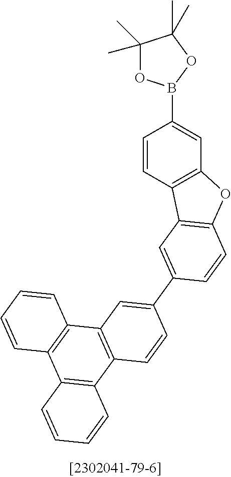 [SMILES: CC1(C)OB(c2ccc3c(c2)oc2ccc(-c4ccc5c6ccccc6c6ccccc6c5c4)cc23)OC1(C)C] | 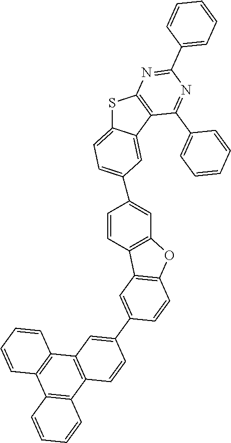 [SMILES: c1ccc(-c2nc(-c3ccccc3)c3c(n2)sc2ccc(-c4ccc5c(c4)oc4ccc(-c6ccc7c8ccccc8c8ccccc8c7c6)cc45)cc23)cc1] | 79% |
| 22c | 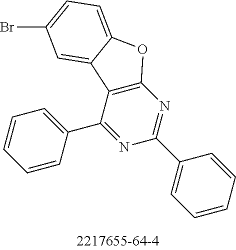 [SMILES: Brc1ccc2oc3nc(-c4ccccc4)nc(-c4ccccc4)c3c2c1] | 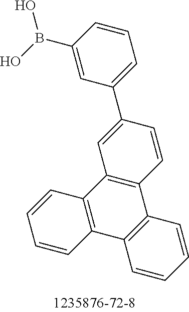 [SMILES: OB(O)c1cccc(-c2ccc3c4ccccc4c4ccccc4c3c2)c1] | 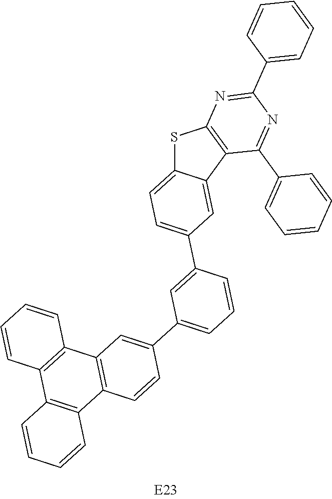 [SMILES: c1ccc(-c2nc(-c3ccccc3)c3c(n2)sc2ccc(-c4cccc(-c5ccc6c7ccccc7c7ccccc7c6c5)c4)cc23)cc1] | 64% |
| 23c | 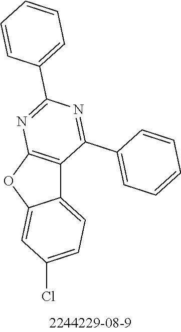 [SMILES: Clc1ccc2c(c1)oc1nc(-c3ccccc3)nc(-c3ccccc3)c12] | 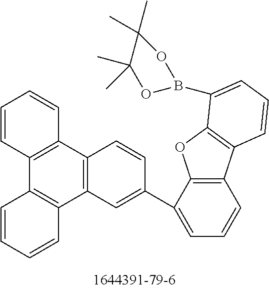 [SMILES: CC1(C)OB(c2cccc3c2oc2c(-c4ccc5c6ccccc6c6ccccc6c5c4)cccc23)OC1(C)C] | 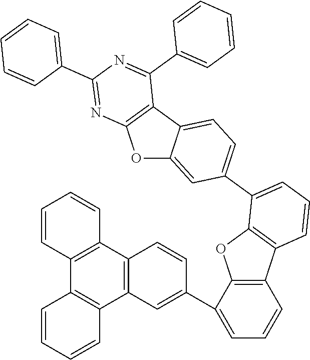 [SMILES: c1ccc(-c2nc(-c3ccccc3)c3c(n2)oc2cc(-c4cccc5c4oc4c(-c6ccc7c8ccccc8c8ccccc8c7c6)cccc45)ccc23)cc1] | 73% |
| 24c | 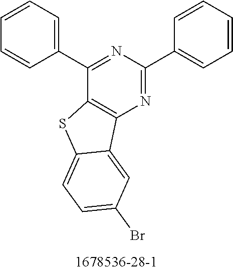 [SMILES: Brc1ccc2sc3c(-c4ccccc4)nc(-c4ccccc4)nc3c2c1] | 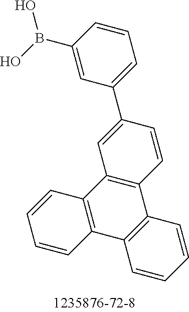 [SMILES: OB(O)c1cccc(-c2ccc3c4ccccc4c4ccccc4c3c2)c1] | 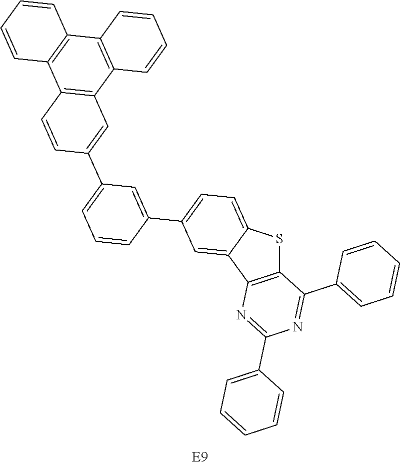 [SMILES: c1ccc(-c2nc(-c3ccccc3)c3sc4ccc(-c5cccc(-c6ccc7c8ccccc8c8ccccc8c7c6)c5)cc4c3n2)cc1] | 70% |
| 25c | 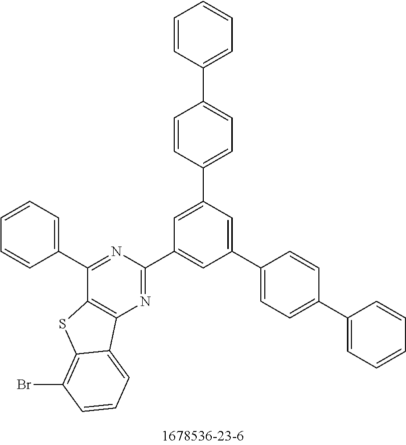 [SMILES: Brc1cccc2c1sc1c(-c3ccccc3)nc(-c3cc(-c4ccc(-c5ccccc5)cc4)cc(-c4ccc(-c5ccccc5)cc4)c3)nc12] | 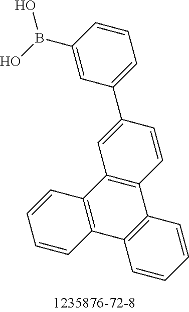 [SMILES: OB(O)c1cccc(-c2ccc3c4ccccc4c4ccccc4c3c2)c1] | 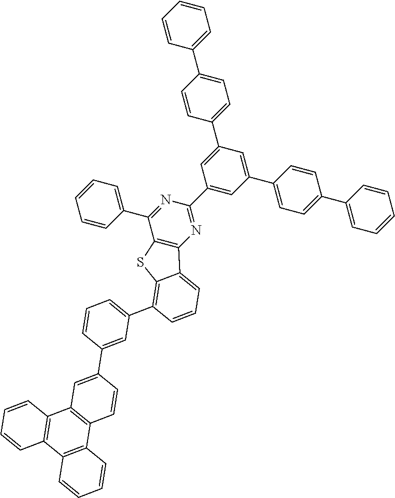 [SMILES: c1ccc(-c2ccc(-c3cc(-c4ccc(-c5ccccc5)cc4)cc(-c4nc(-c5ccccc5)c5sc6c(-c7cccc(-c8ccc9c%10ccccc%10c%10ccccc%10c9c8)c7)cccc6c5n4)c3)cc2)cc1] | 75% |
| 26c | 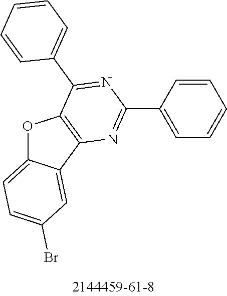 [SMILES: Brc1ccc2oc3c(-c4ccccc4)nc(-c4ccccc4)nc3c2c1] | 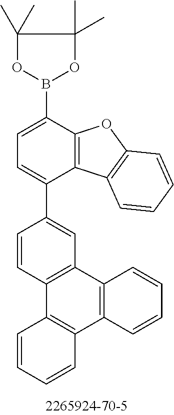 [SMILES: CC1(C)OB(c2ccc(-c3ccc4c5ccccc5c5ccccc5c4c3)c3c2oc2ccccc23)OC1(C)C] | 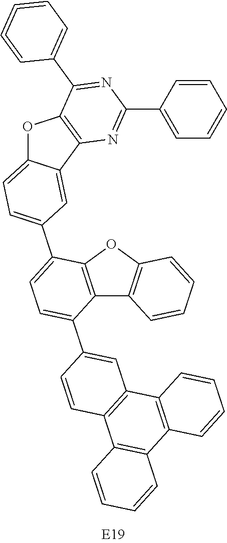 [SMILES: C1=C=CC(c2nc(-c3ccccc3)nc3c2oc2ccc(-c4ccc(-c5ccc6c7ccccc7c7ccccc7c6c5)c5c4oc4ccccc45)cc23)=CC=1] | 77% |
| 27c | 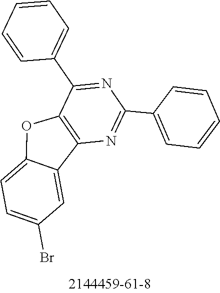 [SMILES: Brc1ccc2oc3c(-c4ccccc4)nc(-c4ccccc4)nc3c2c1] | 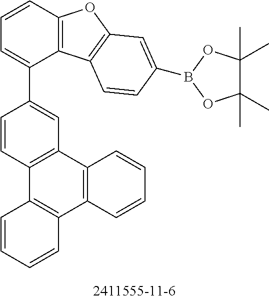 [SMILES: CC1(C)OB(c2ccc3c(c2)oc2cccc(-c4ccc5c6ccccc6c6ccccc6c5c4)c23)OC1(C)C] | 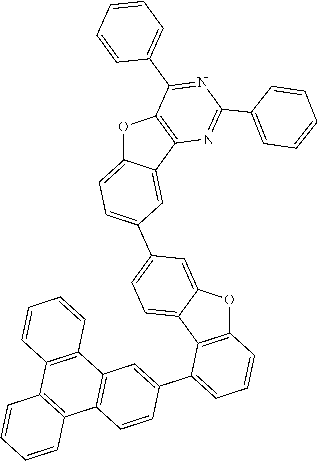 [SMILES: c1ccc(-c2nc(-c3ccccc3)c3oc4ccc(-c5ccc6c(c5)oc5cccc(-c7ccc8c9ccccc9c9ccccc9c8c7)c56)cc4c3n2)cc1] | 81% |
| 28c | 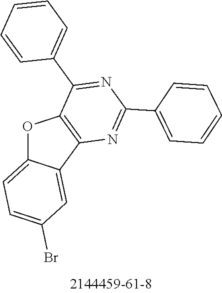 [SMILES: Brc1ccc2oc3c(-c4ccccc4)nc(-c4ccccc4)nc3c2c1] | 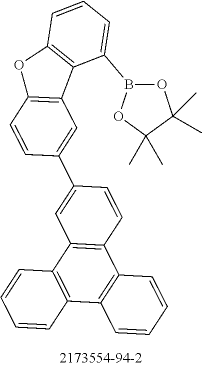 [SMILES: CC1(C)OB(c2cccc3oc4ccc(-c5ccc6c7ccccc7c7ccccc7c6c5)cc4c23)OC1(C)C] | 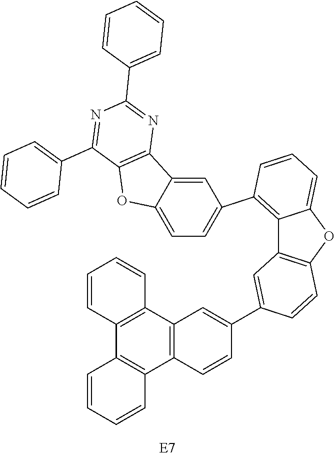 [SMILES: c1ccc(-c2nc(-c3ccccc3)c3oc4ccc(-c5cccc6oc7ccc(-c8ccc9c%10ccccc%10c%10ccccc%10c9c8)cc7c56)cc4c3n2)cc1] | 61% |
| 29c | 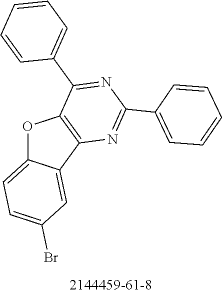 [SMILES: Brc1ccc2oc3c(-c4ccccc4)nc(-c4ccccc4)nc3c2c1] | 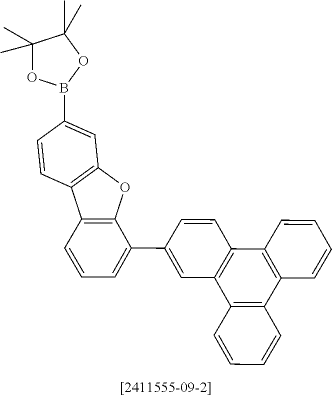 [SMILES: CC1(C)OB(c2ccc3c(c2)oc2c(-c4ccc5c6ccccc6c6ccccc6c5c4)cccc23)OC1(C)C] | 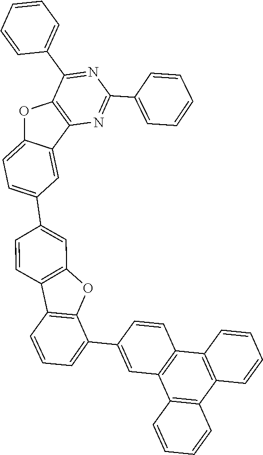 [SMILES: c1ccc(-c2nc(-c3ccccc3)c3oc4ccc(-c5ccc6c(c5)oc5c(-c7ccc8c9ccccc9c9ccccc9c8c7)cccc56)cc4c3n2)cc1] | 70% |
| 30c | 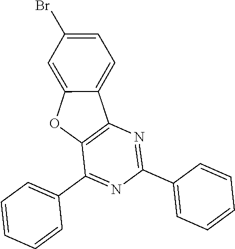 [SMILES: Brc1ccc2c(c1)oc1c(-c3ccccc3)nc(-c3ccccc3)nc12] | 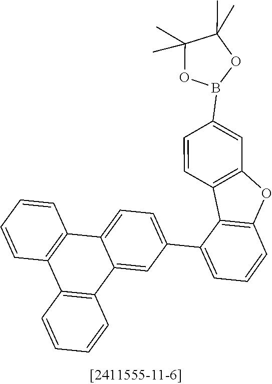 [SMILES: CC1(C)OB(c2ccc3c(c2)oc2cccc(-c4ccc5c6ccccc6c6ccccc6c5c4)c23)OC1(C)C] | 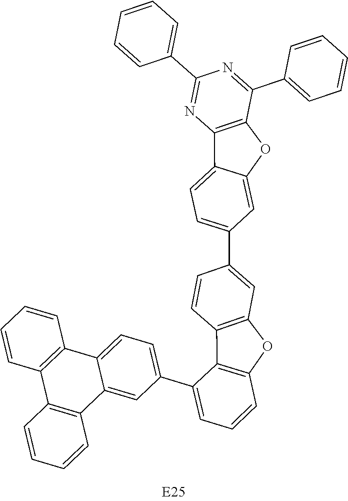 [SMILES: c1ccc(-c2nc(-c3ccccc3)c3oc4cc(-c5ccc6c(c5)oc5cccc(-c7ccc8c9ccccc9c9ccccc9c8c7)c56)ccc4c3n2)cc1] | 63% |
| 31c | 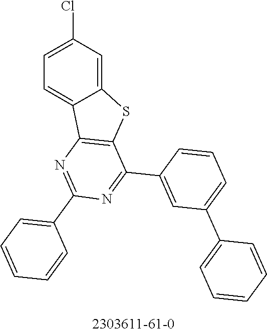 [SMILES: Clc1ccc2c(c1)sc1c(-c3cccc(-c4ccccc4)c3)nc(-c3ccccc3)nc12] | 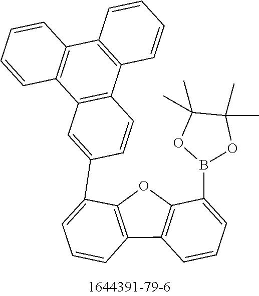 [SMILES: CC1(C)OB(c2cccc3c2oc2c(-c4ccc5c6ccccc6c6ccccc6c5c4)cccc23)OC1(C)C] | 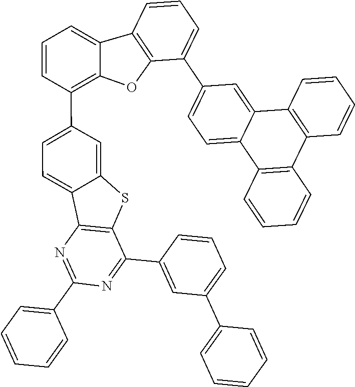 [SMILES: c1ccc(-c2cccc(-c3nc(-c4ccccc4)nc4c3sc3cc(-c5cccc6c5oc5c(-c7ccc8c9ccccc9c9ccccc9c8c7)cccc56)ccc34)c2)cc1] | 60% |
| 32c | 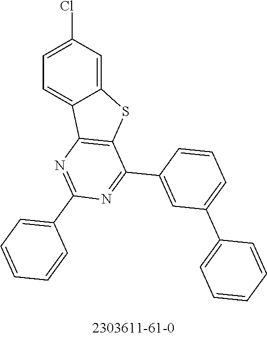 [SMILES: Clc1ccc2c(c1)sc1c(-c3cccc(-c4ccccc4)c3)nc(-c3ccccc3)nc12] | 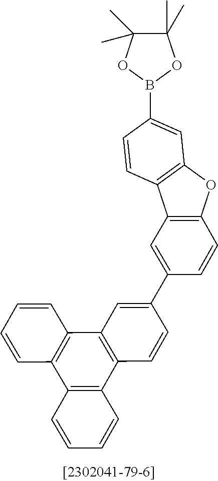 [SMILES: CC1(C)OB(c2ccc3c(c2)oc2ccc(-c4ccc5c6ccccc6c6ccccc6c5c4)cc23)OC1(C)C] | 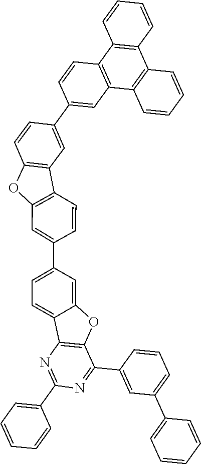 [SMILES: c1ccc(-c2cccc(-c3nc(-c4ccccc4)nc4c3oc3cc(-c5ccc6c(c5)oc5ccc(-c7ccc8c9ccccc9c9ccccc9c8c7)cc56)ccc34)c2)cc1] | 76% |
| 33c | 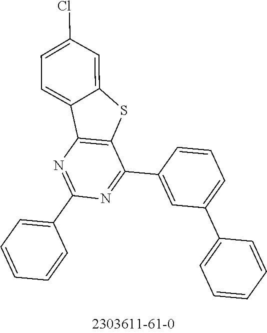 [SMILES: Clc1ccc2c(c1)sc1c(-c3cccc(-c4ccccc4)c3)nc(-c3ccccc3)nc12] | 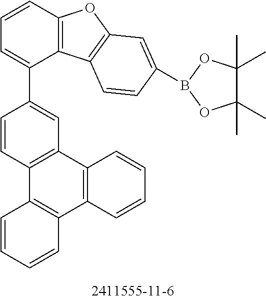 [SMILES: CC1(C)OB(c2ccc3c(c2)oc2cccc(-c4ccc5c6ccccc6c6ccccc6c5c4)c23)OC1(C)C] | 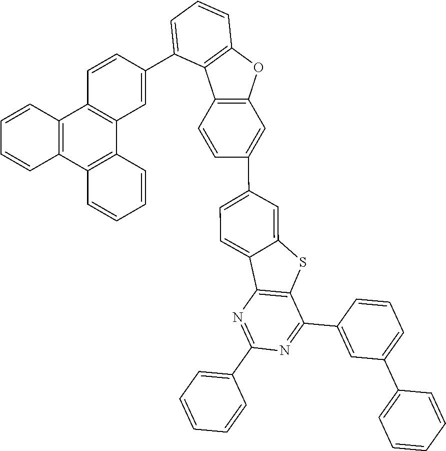 [SMILES: c1ccc(-c2cccc(-c3nc(-c4ccccc4)nc4c3sc3cc(-c5ccc6c(c5)oc5cccc(-c7ccc8c9ccccc9c9ccccc9c8c7)c56)ccc34)c2)cc1] | 82% |
| 34c | 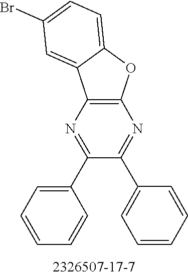 [SMILES: Brc1ccc2oc3nc(-c4ccccc4)c(-c4ccccc4)nc3c2c1] | 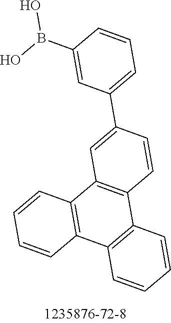 [SMILES: OB(O)c1cccc(-c2ccc3c4ccccc4c4ccccc4c3c2)c1] | 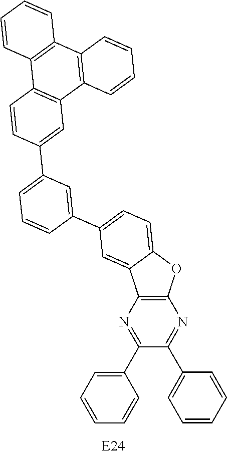 [SMILES: c1ccc(-c2nc3oc4ccc(-c5cccc(-c6ccc7c8ccccc8c8ccccc8c7c6)c5)cc4c3nc2-c2ccccc2)cc1] | 84% |
| 35c | 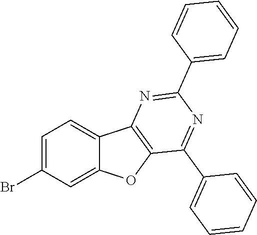 [SMILES: Brc1ccc2c(c1)oc1c(-c3ccccc3)nc(-c3ccccc3)nc12] | 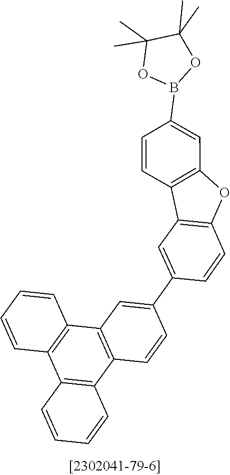 [SMILES: CC1(C)OB(c2ccc3c(c2)oc2ccc(-c4ccc5c6ccccc6c6ccccc6c5c4)cc23)OC1(C)C] | 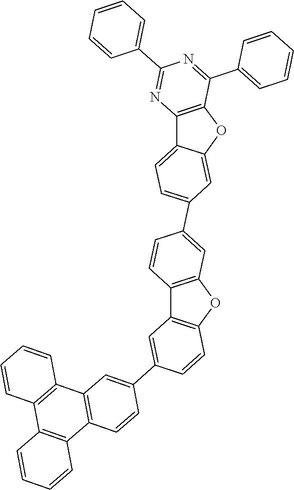 [SMILES: c1ccc(-c2nc(-c3ccccc3)c3oc4cc(-c5ccc6c(c5)oc5ccc(-c7ccc8c9ccccc9c9ccccc9c8c7)cc56)ccc4c3n2)cc1] | 83% |
| 36c | 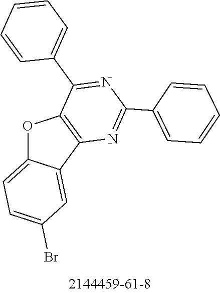 [SMILES: Brc1ccc2oc3c(-c4ccccc4)nc(-c4ccccc4)nc3c2c1] | 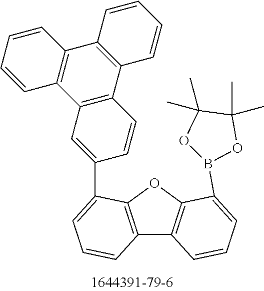 [SMILES: CC1(C)OB(c2cccc3c2oc2c(-c4ccc5c6ccccc6c6ccccc6c5c4)cccc23)OC1(C)C] | 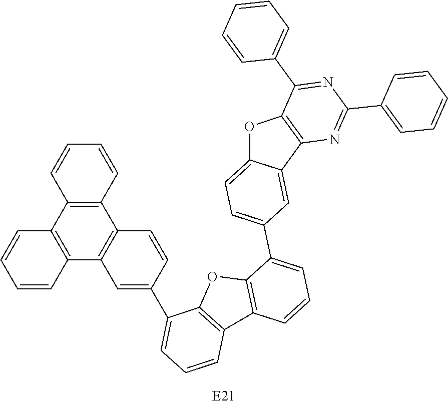 [SMILES: c1ccc(-c2nc(-c3ccccc3)c3oc4ccc(-c5cccc6c5oc5c(-c7ccc8c9ccccc9c9ccccc9c8c7)cccc56)cc4c3n2)cc1] | 85% |
| 37c | 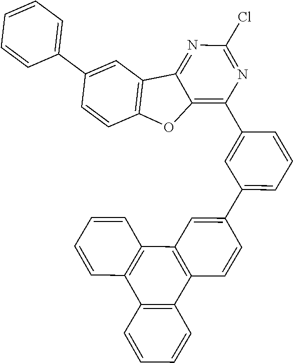 [SMILES: Clc1nc(-c2cccc(-c3ccc4c5ccccc5c5ccccc5c4c3)c2)c2oc3ccc(-c4ccccc4)cc3c2n1] | 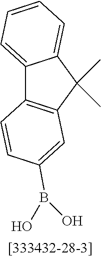 [SMILES: CC1(C)c2ccccc2-c2ccc(B(O)O)cc21] | 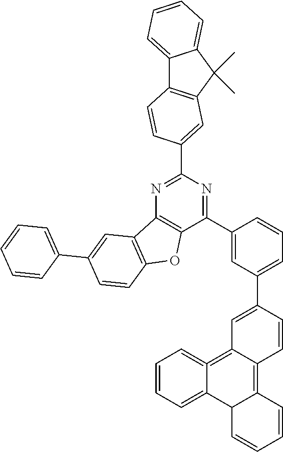 | 64% |
| 38c | 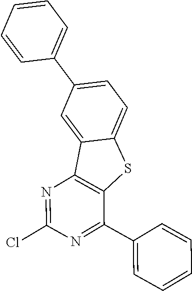 [SMILES: Clc1nc(-c2ccccc2)c2sc3ccc(-c4ccccc4)cc3c2n1] | 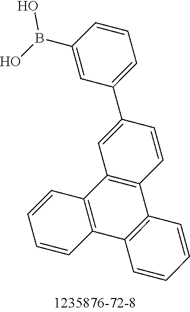 [SMILES: OB(O)c1cccc(-c2ccc3c4ccccc4c4ccccc4c3c2)c1] | 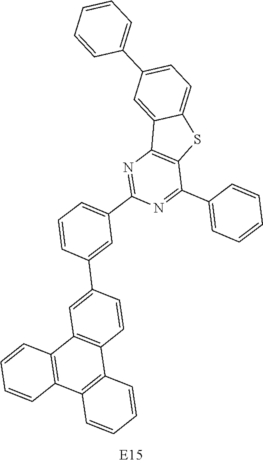 [SMILES: c1ccc(-c2ccc3sc4c(-c5ccccc5)nc(-c5cccc(-c6ccc7c8ccccc8c8ccccc8c7c6)c5)nc4c3c2)cc1] | 70% |
| 39c | 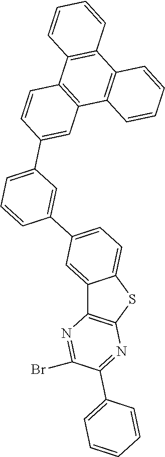 [SMILES: Brc1nc2c(nc1-c1ccccc1)sc1ccc(-c3cccc(-c4ccc5c6ccccc6c6ccccc6c5c4)c3)cc12] | 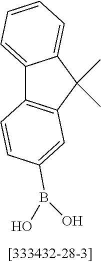 [SMILES: CC1(C)c2ccccc2-c2ccc(B(O)O)cc21] | 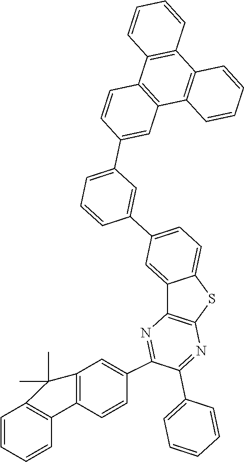 [SMILES: CC1(C)c2ccccc2-c2ccc(-c3nc4c(nc3-c3ccccc3)sc3ccc(-c5cccc(-c6ccc7c8ccccc8c8ccccc8c7c6)c5)cc34)cc21] | 73% |
| 40c | 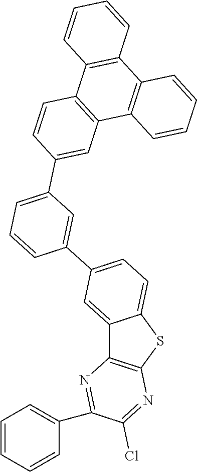 [SMILES: Clc1nc2sc3ccc(-c4cccc(-c5ccc6c7ccccc7c7ccccc7c6c5)c4)cc3c2nc1-c1ccccc1] | 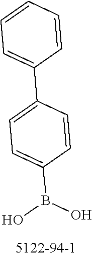 [SMILES: OB(O)c1ccc(-c2ccccc2)cc1] | 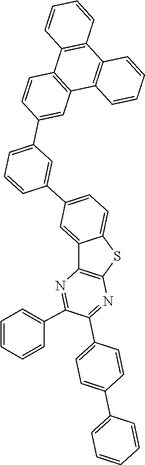 [SMILES: c1ccc(-c2ccc(-c3nc4sc5ccc(-c6cccc(-c7ccc8c9ccccc9c9ccccc9c8c7)c6)cc5c4nc3-c3ccccc3)cc2)cc1] | 78% |
| 41c | 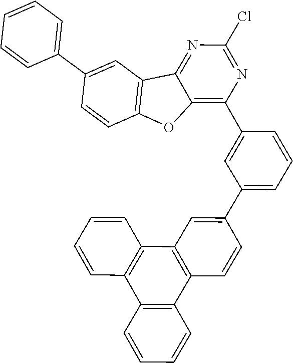 [SMILES: Clc1nc(-c2cccc(-c3ccc4c5ccccc5c5ccccc5c4c3)c2)c2oc3ccc(-c4ccccc4)cc3c2n1] | 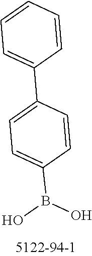 [SMILES: OB(O)c1ccc(-c2ccccc2)cc1] | 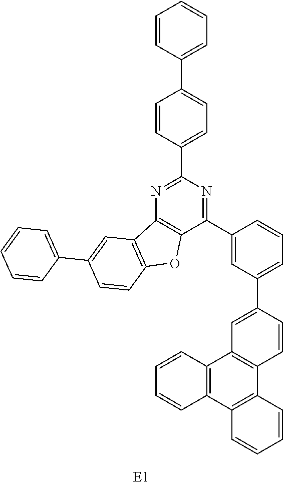 [SMILES: c1ccc(-c2ccc(-c3nc(-c4cccc(-c5ccc6c7ccccc7c7ccccc7c6c5)c4)c4oc5ccc(-c6ccccc6)cc5c4n3)cc2)cc1] | 79% |
| 42c | 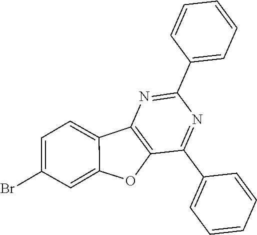 [SMILES: Brc1ccc2c(c1)oc1c(-c3ccccc3)nc(-c3ccccc3)nc12] | 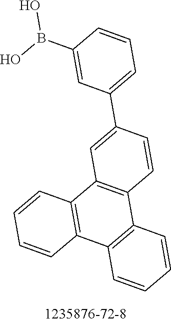 [SMILES: OB(O)c1cccc(-c2ccc3c4ccccc4c4ccccc4c3c2)c1] | 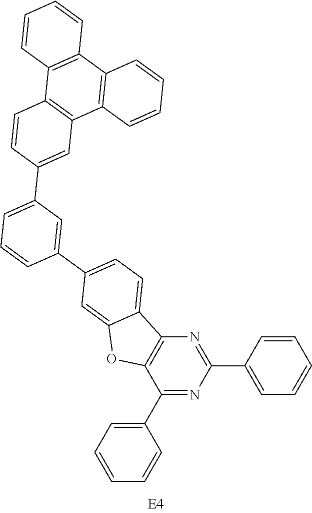 [SMILES: c1ccc(-c2nc(-c3ccccc3)c3oc4cc(-c5cccc(-c6ccc7c8ccccc8c8ccccc8c7c6)c5)ccc4c3n2)cc1] | 87% |
| 43c | 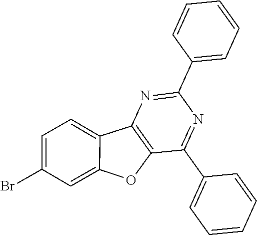 [SMILES: Brc1ccc2c(c1)oc1c(-c3ccccc3)nc(-c3ccccc3)nc12] | 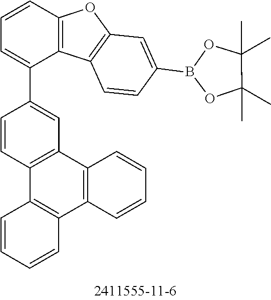 [SMILES: CC1(C)OB(c2ccc3c(c2)oc2cccc(-c4ccc5c6ccccc6c6ccccc6c5c4)c23)OC1(C)C] | 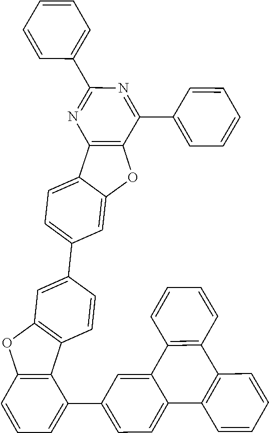 [SMILES: c1ccc(-c2nc(-c3ccccc3)c3oc4cc(-c5ccc6c(c5)oc5cccc(-c7ccc8c9ccccc9c9ccccc9c8c7)c56)ccc4c3n2)cc1] | 80% |
| 44c | 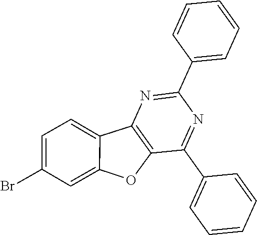 [SMILES: Brc1ccc2c(c1)oc1c(-c3ccccc3)nc(-c3ccccc3)nc12] | 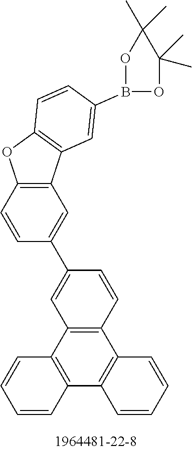 [SMILES: CC1(C)OB(c2ccc3oc4ccc(-c5ccc6c7ccccc7c7ccccc7c6c5)cc4c3c2)OC1(C)C] | 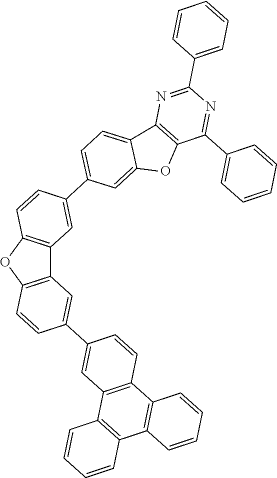 [SMILES: c1ccc(-c2nc(-c3ccccc3)c3oc4cc(-c5ccc6oc7ccc(-c8ccc9c%10ccccc%10c%10ccccc%10c9c8)cc7c6c5)ccc4c3n2)cc1] | 78% |
| 45c | 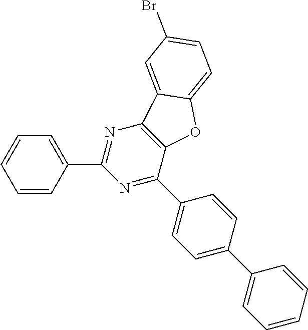 [SMILES: Brc1ccc2oc3c(-c4ccc(-c5ccccc5)cc4)nc(-c4ccccc4)nc3c2c1] | 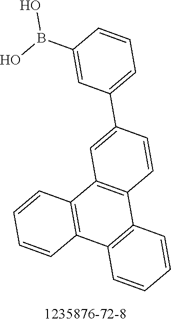 [SMILES: OB(O)c1cccc(-c2ccc3c4ccccc4c4ccccc4c3c2)c1] | 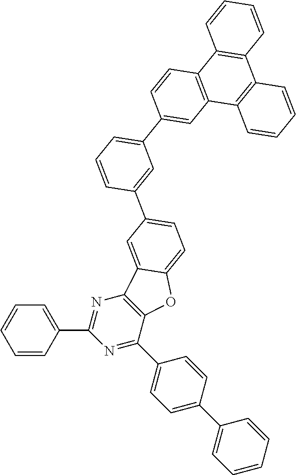 [SMILES: c1ccc(-c2ccc(-c3nc(-c4ccccc4)nc4c3oc3ccc(-c5cccc(-c6ccc7c8ccccc8c8ccccc8c7c6)c5)cc34)cc2)cc1] | 85% |
| 46c | 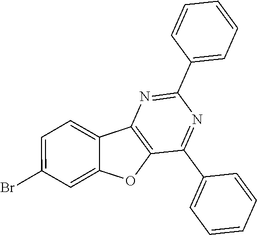 [SMILES: Brc1ccc2c(c1)oc1c(-c3ccccc3)nc(-c3ccccc3)nc12] | 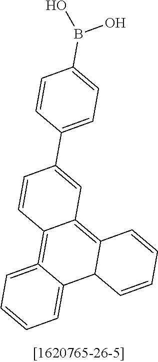 | 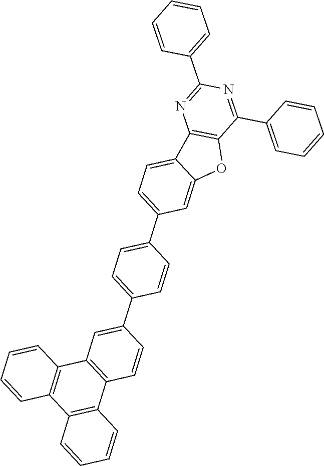 [SMILES: c1ccc(-c2nc(-c3ccccc3)c3oc4cc(-c5ccc(-c6ccc7c8ccccc8c8ccccc8c7c6)cc5)ccc4c3n2)cc1] | 76% |
| 47c | 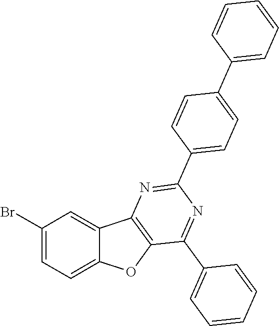 [SMILES: Brc1ccc2oc3c(-c4ccccc4)nc(-c4ccc(-c5ccccc5)cc4)nc3c2c1] | 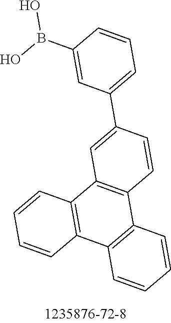 [SMILES: OB(O)c1cccc(-c2ccc3c4ccccc4c4ccccc4c3c2)c1] | 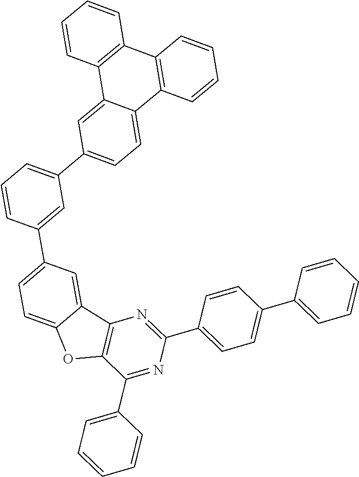 [SMILES: c1ccc(-c2ccc(-c3nc(-c4ccccc4)c4oc5ccc(-c6cccc(-c7ccc8c9ccccc9c9ccccc9c8c7)c6)cc5c4n3)cc2)cc1] | 80% |
| 48c | 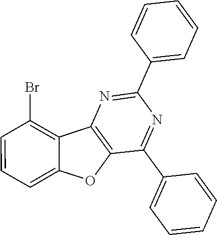 [SMILES: Brc1cccc2oc3c(-c4ccccc4)nc(-c4ccccc4)nc3c12] | 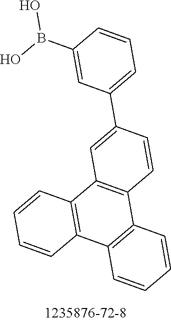 [SMILES: OB(O)c1cccc(-c2ccc3c4ccccc4c4ccccc4c3c2)c1] | 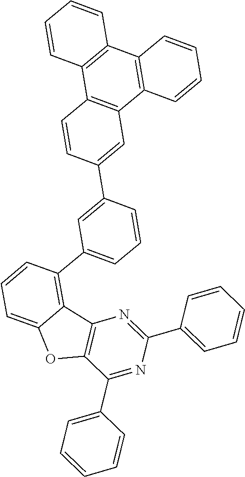 [SMILES: c1ccc(-c2nc(-c3ccccc3)c3oc4cccc(-c5cccc(-c6ccc7c8ccccc8c8ccccc8c7c6)c5)c4c3n2)cc1] | 77% |
| 49c | 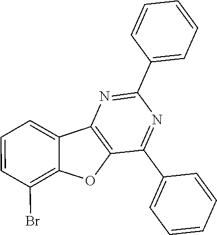 [SMILES: Brc1cccc2c1oc1c(-c3ccccc3)nc(-c3ccccc3)nc12] | 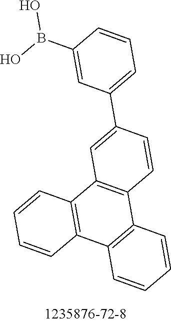 [SMILES: OB(O)c1cccc(-c2ccc3c4ccccc4c4ccccc4c3c2)c1] | 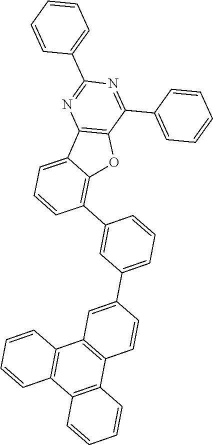 [SMILES: c1ccc(-c2nc(-c3ccccc3)c3oc4c(-c5cccc(-c6ccc7c8ccccc8c8ccccc8c7c6)c5)cccc4c3n2)cc1] | 78% |
| 50c | 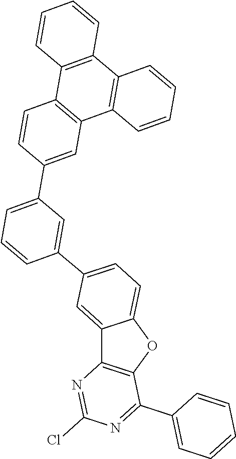 [SMILES: Clc1nc(-c2ccccc2)c2oc3ccc(-c4cccc(-c5ccc6c7ccccc7c7ccccc7c6c5)c4)cc3c2n1] | 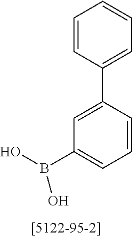 [SMILES: OB(O)c1cccc(-c2ccccc2)c1] | 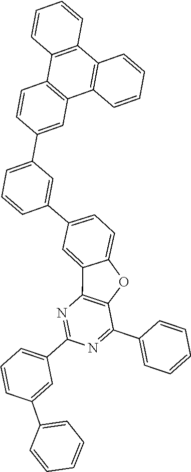 [SMILES: c1ccc(-c2cccc(-c3nc(-c4ccccc4)c4oc5ccc(-c6cccc(-c7ccc8c9ccccc9c9ccccc9c8c7)c6)cc5c4n3)c2)cc1] | 70% |
| 51c | 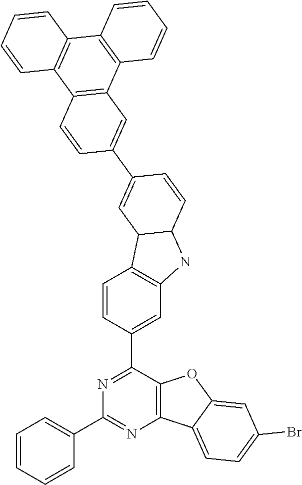 [SMILES: Brc1ccc2c(c1)oc1c(-c3ccc4c(c3)NC3C=CC(c5ccc6c7ccccc7c7ccccc7c6c5)=CC43)nc(-c3ccccc3)nc12] | 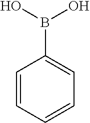 | 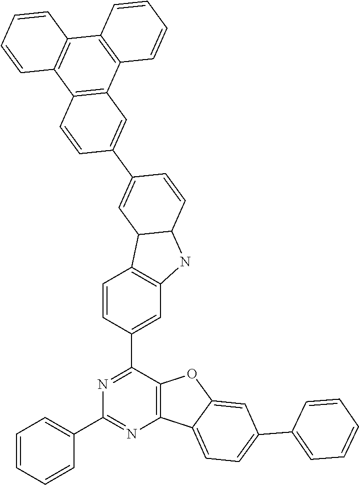 [SMILES: C1=CC2Nc3cc(-c4nc(-c5ccccc5)nc5c4oc4cc(-c6ccccc6)ccc45)ccc3C2C=C1c1ccc2c3ccccc3c3ccccc3c2c1] | 76% |
| 52c | 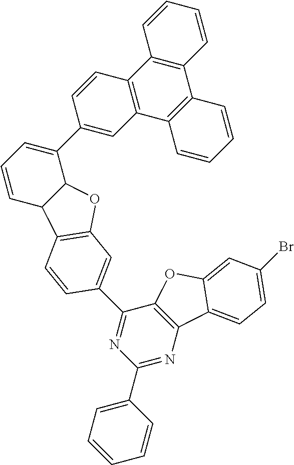 [SMILES: Brc1ccc2c(c1)oc1c(-c3ccc4c(c3)OC3C(c5ccc6c7ccccc7c7ccccc7c6c5)=CC=CC43)nc(-c3ccccc3)nc12] | 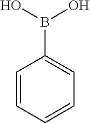 | 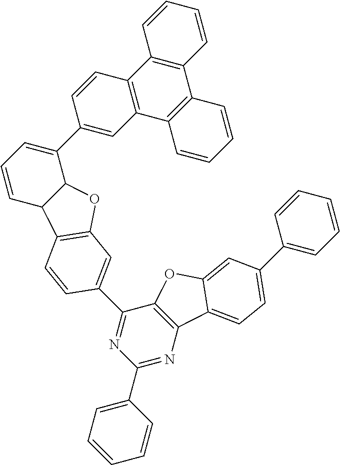 [SMILES: C1=CC2c3ccc(-c4nc(-c5ccccc5)nc5c4oc4cc(-c6ccccc6)ccc45)cc3OC2C(c2ccc3c4ccccc4c4ccccc4c3c2)=C1] | 72% |
| 53c | 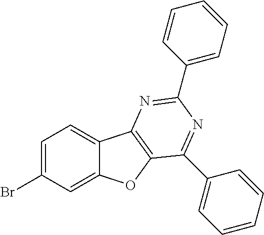 [SMILES: Brc1ccc2c(c1)oc1c(-c3ccccc3)nc(-c3ccccc3)nc12] | 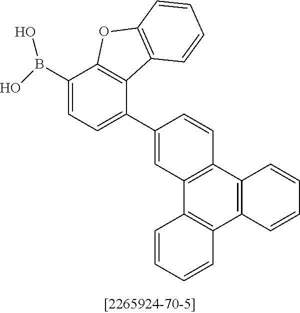 [SMILES: OB(O)c1ccc(-c2ccc3c4ccccc4c4ccccc4c3c2)c2c1oc1ccccc12] | 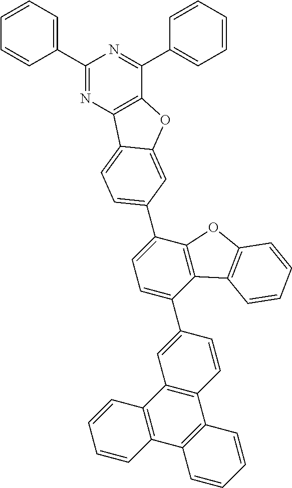 [SMILES: c1ccc(-c2nc(-c3ccccc3)c3oc4cc(-c5ccc(-c6ccc7c8ccccc8c8ccccc8c7c6)c6c5oc5ccccc56)ccc4c3n2)cc1] | 70% |
| 54c | 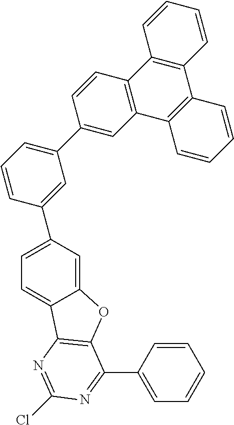 [SMILES: Clc1nc(-c2ccccc2)c2oc3cc(-c4cccc(-c5ccc6c7ccccc7c7ccccc7c6c5)c4)ccc3c2n1] | 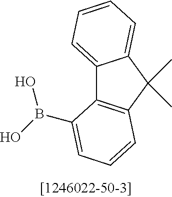 [SMILES: CC1(C)c2ccccc2-c2c(B(O)O)cccc21] | 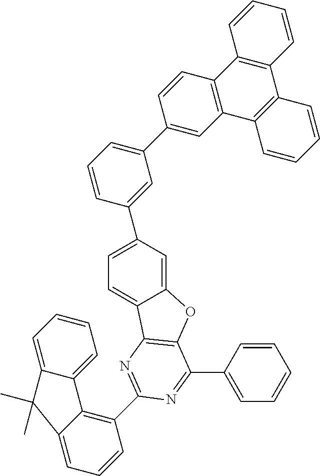 [SMILES: CC1(C)c2ccccc2-c2c(-c3nc(-c4ccccc4)c4oc5cc(-c6cccc(-c7ccc8c9ccccc9c9ccccc9c8c7)c6)ccc5c4n3)cccc21] | 79% |
| 55c | 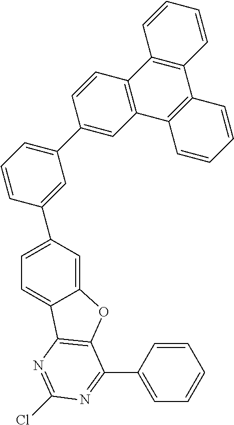 [SMILES: Clc1nc(-c2ccccc2)c2oc3cc(-c4cccc(-c5ccc6c7ccccc7c7ccccc7c6c5)c4)ccc3c2n1] | 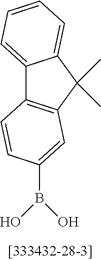 [SMILES: CC1(C)c2ccccc2-c2ccc(B(O)O)cc21] | 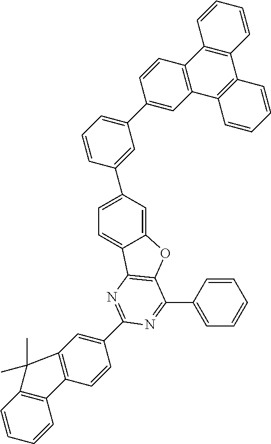 [SMILES: CC1(C)c2ccccc2-c2ccc(-c3nc(-c4ccccc4)c4oc5cc(-c6cccc(-c7ccc8c9ccccc9c9ccccc9c8c7)c6)ccc5c4n3)cc21] | 74% |
| 56c | 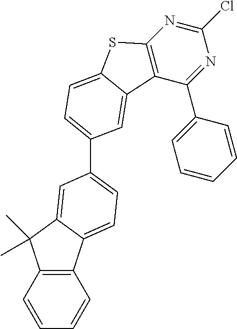 [SMILES: CC1(C)c2ccccc2-c2ccc(-c3ccc4sc5nc(Cl)nc(-c6ccccc6)c5c4c3)cc21] | 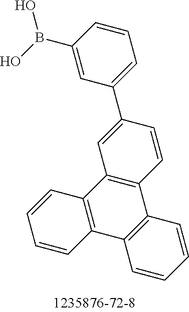 [SMILES: OB(O)c1cccc(-c2ccc3c4ccccc4c4ccccc4c3c2)c1] | 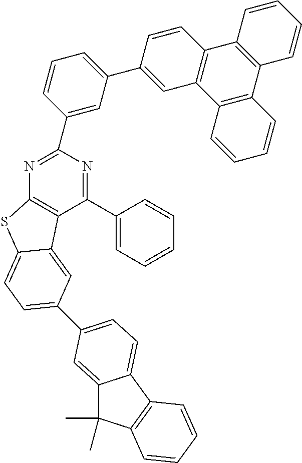 [SMILES: CC1(C)c2ccccc2-c2ccc(-c3ccc4sc5nc(-c6cccc(-c7ccc8c9ccccc9c9ccccc9c8c7)c6)nc(-c6ccccc6)c5c4c3)cc21] | 70% |
| 57c | 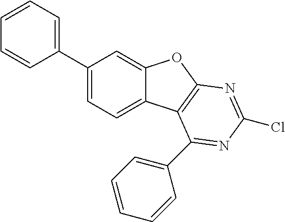 [SMILES: Clc1nc(-c2ccccc2)c2c(n1)oc1cc(-c3ccccc3)ccc12] | 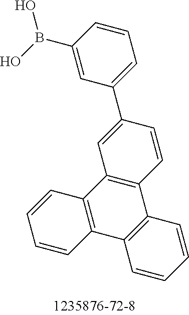 [SMILES: OB(O)c1cccc(-c2ccc3c4ccccc4c4ccccc4c3c2)c1] | 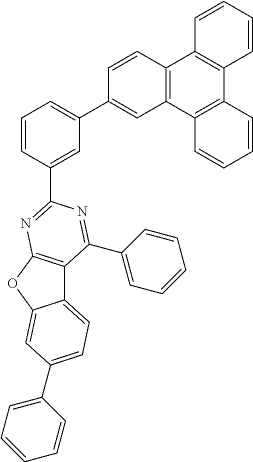 [SMILES: c1ccc(-c2ccc3c(c2)oc2nc(-c4cccc(-c5ccc6c7ccccc7c7ccccc7c6c5)c4)nc(-c4ccccc4)c23)cc1] | 73% |
| 58c | 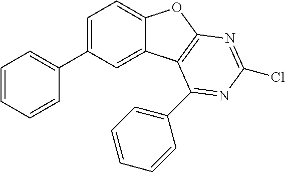 [SMILES: Clc1nc(-c2ccccc2)c2c(n1)oc1ccc(-c3ccccc3)cc12] | 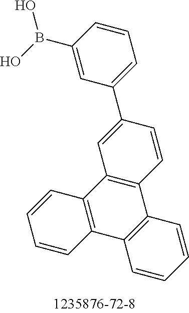 [SMILES: OB(O)c1cccc(-c2ccc3c4ccccc4c4ccccc4c3c2)c1] | 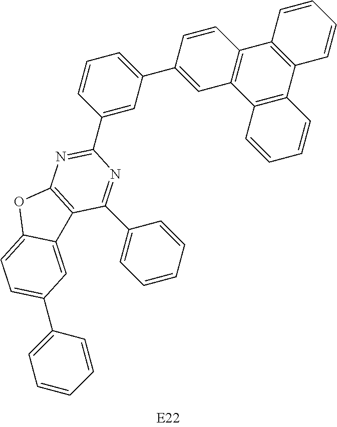 [SMILES: c1ccc(-c2ccc3oc4nc(-c5cccc(-c6ccc7c8ccccc8c8ccccc8c7c6)c5)nc(-c5ccccc5)c4c3c2)cc1] | 69% |
| 59c | 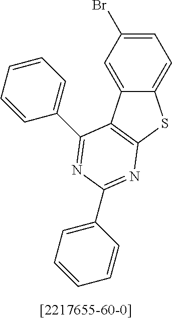 [SMILES: Brc1ccc2sc3nc(-c4ccccc4)nc(-c4ccccc4)c3c2c1] | 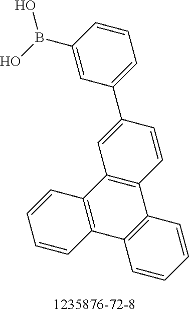 [SMILES: OB(O)c1cccc(-c2ccc3c4ccccc4c4ccccc4c3c2)c1] | 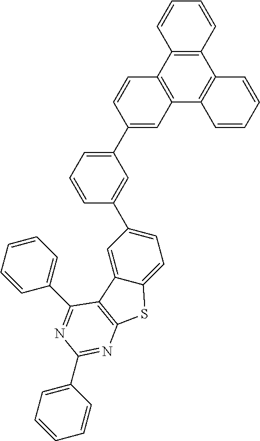 [SMILES: c1ccc(-c2nc(-c3ccccc3)c3c(n2)sc2ccc(-c4cccc(-c5ccc6c7ccccc7c7ccccc7c6c5)c4)cc23)cc1] | 68% |
| 60c | 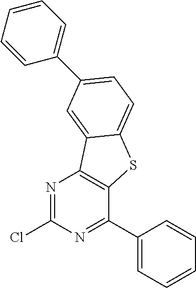 [SMILES: Clc1nc(-c2ccccc2)c2sc3ccc(-c4ccccc4)cc3c2n1] | 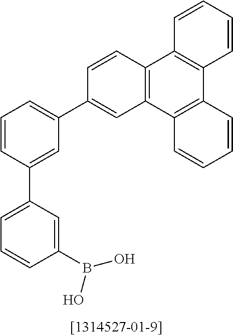 [SMILES: OB(O)c1cccc(-c2cccc(-c3ccc4c5ccccc5c5ccccc5c4c3)c2)c1] | 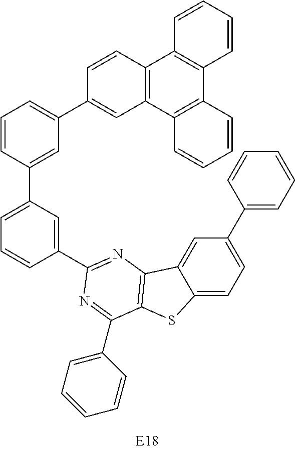 [SMILES: c1ccc(-c2ccc3sc4c(-c5ccccc5)nc(-c5cccc(-c6cccc(-c7ccc8c9ccccc9c9ccccc9c8c7)c6)c5)nc4c3c2)cc1] | 72% |
| 61c | 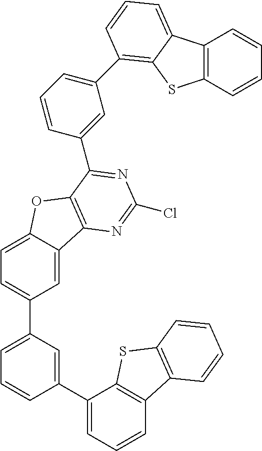 [SMILES: Clc1nc(-c2cccc(-c3cccc4c3sc3ccccc34)c2)c2oc3ccc(-c4cccc(-c5cccc6c5sc5ccccc56)c4)cc3c2n1] | 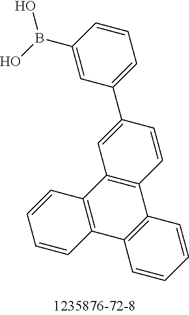 [SMILES: OB(O)c1cccc(-c2ccc3c4ccccc4c4ccccc4c3c2)c1] | 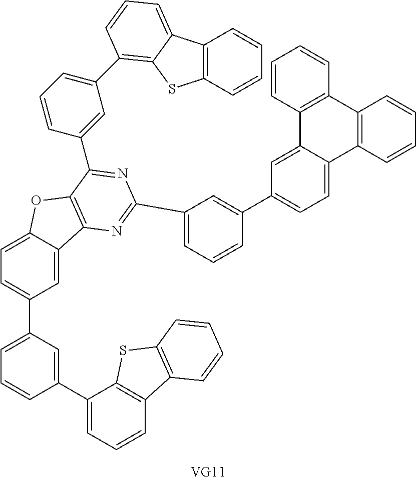 [SMILES: c1cc(-c2ccc3c4ccccc4c4ccccc4c3c2)cc(-c2nc(-c3cccc(-c4cccc5c4sc4ccccc45)c3)c3oc4ccc(-c5cccc(-c6cccc7c6sc6ccccc67)c5)cc4c3n2)c1] | 65% |
| 62c | 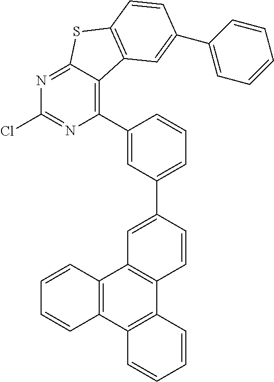 [SMILES: Clc1nc(-c2cccc(-c3ccc4c5ccccc5c5ccccc5c4c3)c2)c2c(n1)sc1ccc(-c3ccccc3)cc12] | 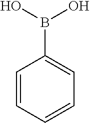 | 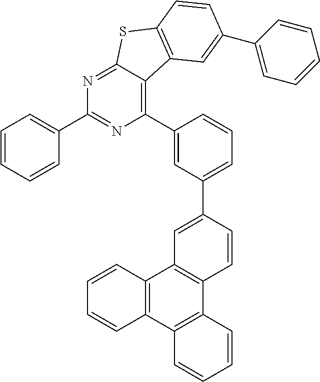 [SMILES: c1ccc(-c2ccc3sc4nc(-c5ccccc5)nc(-c5cccc(-c6ccc7c8ccccc8c8ccccc8c7c6)c5)c4c3c2)cc1] | 67% |
| 63 | 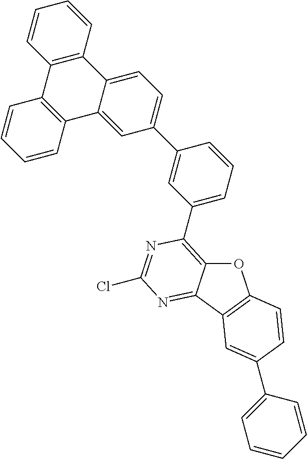 [SMILES: Clc1nc(-c2cccc(-c3ccc4c5ccccc5c5ccccc5c4c3)c2)c2oc3ccc(-c4ccccc4)cc3c2n1] | 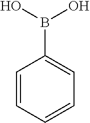 | 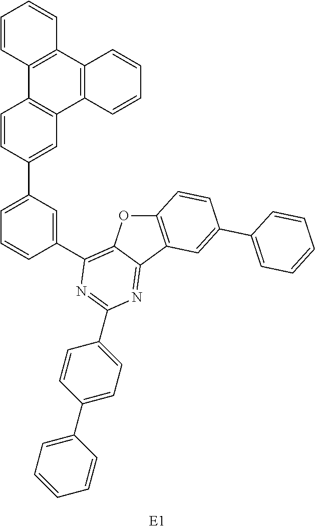 [SMILES: c1ccc(-c2ccc(-c3nc(-c4cccc(-c5ccc6c7ccccc7c7ccccc7c6c5)c4)c4oc5ccc(-c6ccccc6)cc5c4n3)cc2)cc1] | 61% |
| 64c | 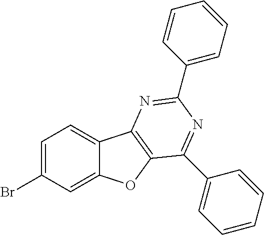 [SMILES: Brc1ccc2c(c1)oc1c(-c3ccccc3)nc(-c3ccccc3)nc12] | 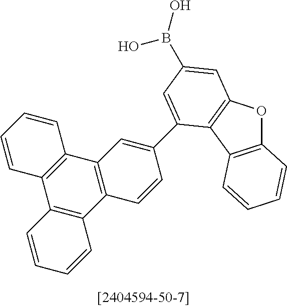 [SMILES: OB(O)c1cc(-c2ccc3c4ccccc4c4ccccc4c3c2)c2c(c1)oc1ccccc12] | 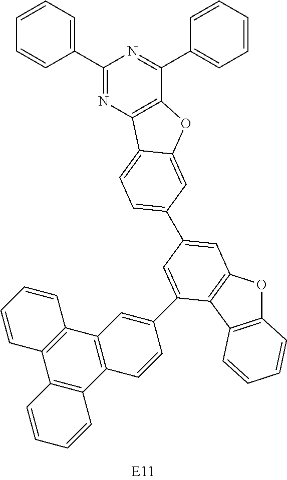 [SMILES: c1ccc(-c2nc(-c3ccccc3)c3oc4cc(-c5cc(-c6ccc7c8ccccc8c8ccccc8c7c6)c6c(c5)oc5ccccc56)ccc4c3n2)cc1] | 71% |
| 65c | 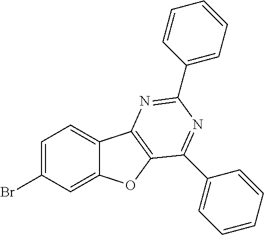 [SMILES: Brc1ccc2c(c1)oc1c(-c3ccccc3)nc(-c3ccccc3)nc12] | 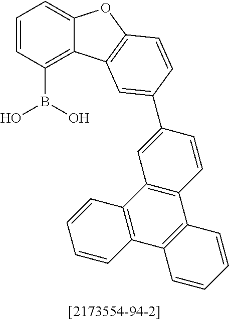 [SMILES: OB(O)c1cccc2oc3ccc(-c4ccc5c6ccccc6c6ccccc6c5c4)cc3c12] | 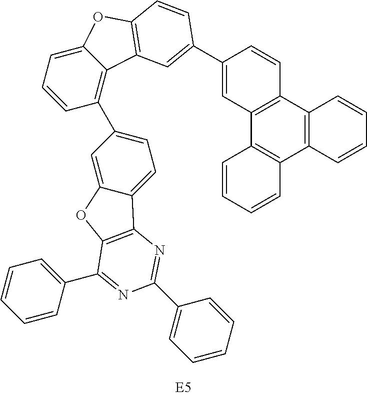 [SMILES: c1ccc(-c2nc(-c3ccccc3)c3oc4cc(-c5cccc6oc7ccc(-c8ccc9c%10ccccc%10c%10ccccc%10c9c8)cc7c56)ccc4c3n2)cc1] | 72% |
| 66c | 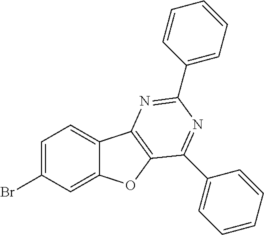 [SMILES: Brc1ccc2c(c1)oc1c(-c3ccccc3)nc(-c3ccccc3)nc12] | 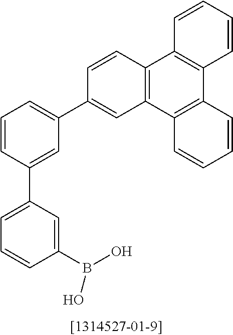 [SMILES: OB(O)c1cccc(-c2cccc(-c3ccc4c5ccccc5c5ccccc5c4c3)c2)c1] | 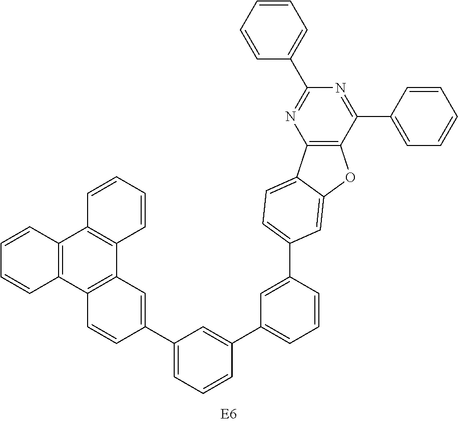 [SMILES: c1ccc(-c2nc(-c3ccccc3)c3oc4cc(-c5cccc(-c6cccc(-c7ccc8c9ccccc9c9ccccc9c8c7)c6)c5)ccc4c3n2)cc1] | 68% |
| 67C | 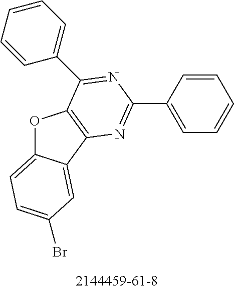 [SMILES: Brc1ccc2oc3c(-c4ccccc4)nc(-c4ccccc4)nc3c2c1] | 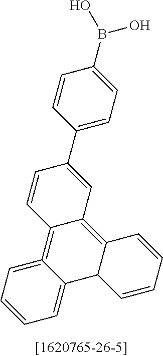 | 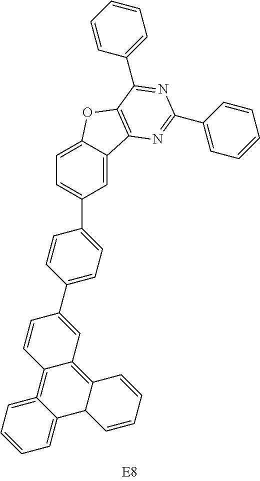 | 74% |
| 68c | 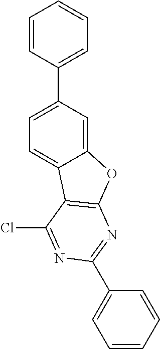 [SMILES: Clc1nc(-c2ccccc2)nc2oc3cc(-c4ccccc4)ccc3c12] | 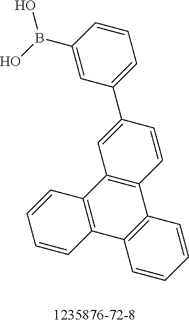 [SMILES: OB(O)c1cccc(-c2ccc3c4ccccc4c4ccccc4c3c2)c1] | 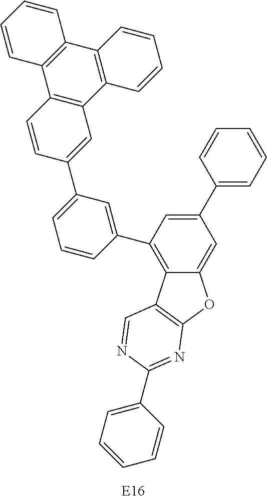 [SMILES: c1ccc(-c2cc(-c3cccc(-c4ccc5c6ccccc6c6ccccc6c5c4)c3)c3c(c2)oc2nc(-c4ccccc4)ncc23)cc1] | 68% |
| 69 | 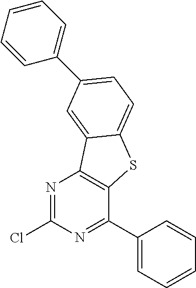 [SMILES: Clc1nc(-c2ccccc2)c2sc3ccc(-c4ccccc4)cc3c2n1] | 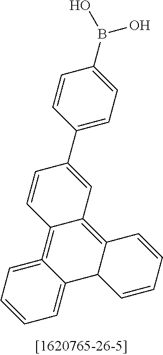 | 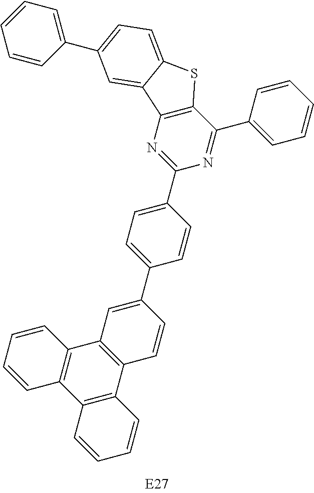 [SMILES: c1ccc(-c2ccc3sc4c(-c5ccccc5)nc(-c5ccc(-c6ccc7c8ccccc8c8ccccc8c7c6)cc5)nc4c3c2)cc1] | 60% |
| 70c | 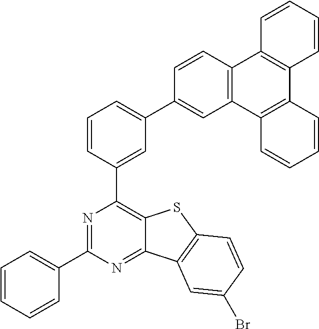 [SMILES: Brc1ccc2sc3c(-c4cccc(-c5ccc6c7ccccc7c7ccccc7c6c5)c4)nc(-c4ccccc4)nc3c2c1] | 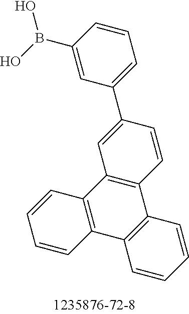 [SMILES: OB(O)c1cccc(-c2ccc3c4ccccc4c4ccccc4c3c2)c1] | 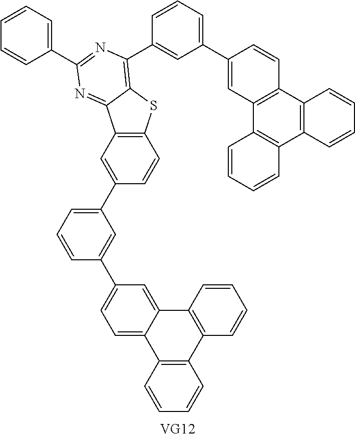 [SMILES: c1ccc(-c2nc(-c3cccc(-c4ccc5c6ccccc6c6ccccc6c5c4)c3)c3sc4ccc(-c5cccc(-c6ccc7c8ccccc8c8ccccc8c7c6)c5)cc4c3n2)cc1] | 67% |

### d) (3-Amino-6-bromo-benzofuran-2-yl)phenylmethanone

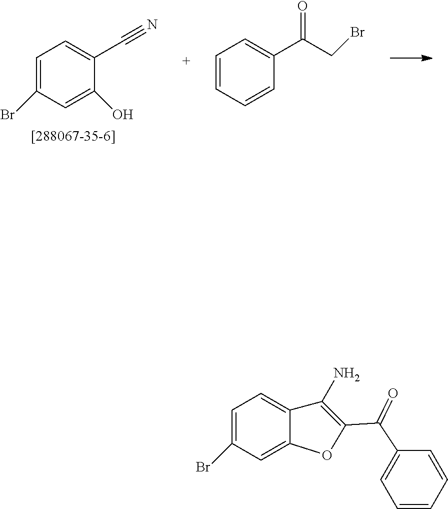 [SMILES: N#Cc1ccc(Br)cc1O ; O=C(CBr)c1ccccc1 ; Nc1c(C(=O)c2ccccc2)oc2cc(Br)ccc12]

100 g (505 mmol) of 4-bromo-2-hydroxybenzonitrile and 100 g (505 mmol) of 2-bromo-1-phenyl-ethanone are initially charged with 1500 ml of acetone. 1000 g of potassium carbonate are added to this solution in portions and subsequently heated to 70° C. and stirred for 2 hours at this temperature. After cooling, the precipitated solid is subjected to vacuum filtration and then stirred with water, subjected to vacuum filtration and subsequently re-washed with methanol. The yield is 160 g (443 mmol), corresponding to 87% of theory.

The following compounds are prepared in an analogous manner:

| | Reactant 1 | Reactant 2 | Product | Yield |
|---|---|---|---|---|
| 1d | 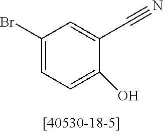 | 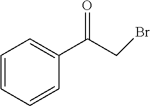 | 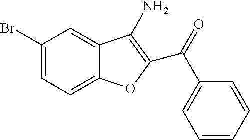 [SMILES: Nc1c(C(=O)c2ccccc2)oc2ccc(Br)cc12] | 88% |
| 2d | 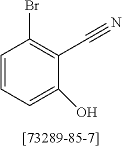 | 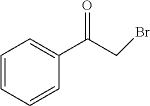 | 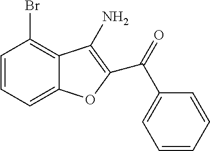 [SMILES: Nc1c(C(=O)c2ccccc2)oc2cccc(Br)c12] | 83% |
| 3d | 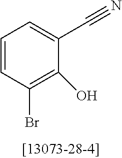 | 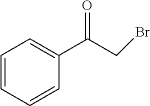 | 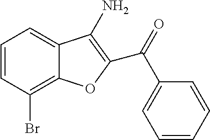 [SMILES: Nc1c(C(=O)c2ccccc2)oc2c(Br)cccc12] | 82% |

### e) 7-Bromo-2,4-diphenylbenzofuro[3,2-d]pyrimidine

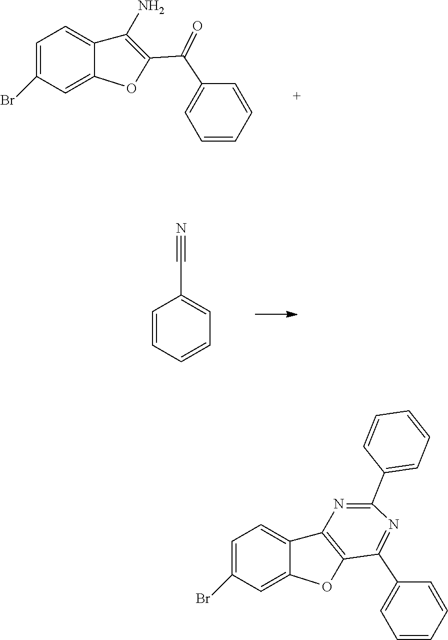 [SMILES: Nc1c(C(=O)c2ccccc2)oc2cc(Br)ccc12 ; N#Cc1ccccc1 ; Brc1ccc2c(c1)oc1c(-c3ccccc3)nc(-c3ccccc3)nc12]

Under argon 167 g (0.53 mol) of (3-amino-6-bromo-benzofuran-2-yl)phenylmethanone and 218 g (2.1 mol) of benzonitrile are initially charged with 2000 ml of o-xylene. 87.5 g (0.79 mol) of sodium tert-pentoxide are added to this solution and subsequently heated to 160° C. for two days. After cooling, the precipitated solid is subjected to vacuum filtration and then stirred with hot water, subjected to vacuum filtration and subsequently re-washed twice with n-heptane. The yield is 160 g (443 mmol), corresponding to 87% of theory.

The following compounds are prepared in an analogous manner:

| | Reactant 1 | Reactant 2 | Product | Yield |
|---|---|---|---|---|
| 1d | 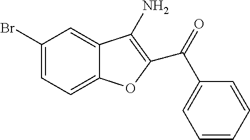 [SMILES: Nc1c(C(=O)c2ccccc2)oc2ccc(Br)cc12] | 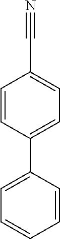 [SMILES: N#Cc1ccc(-c2ccccc2)cc1] | 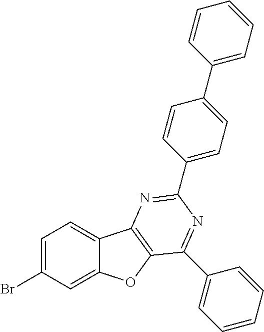 [SMILES: Brc1ccc2c(c1)oc1c(-c3ccccc3)nc(-c3ccc(-c4ccccc4)cc3)nc12] | 88% |
| 2d | 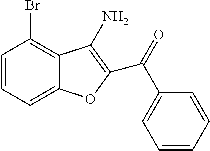 [SMILES: Nc1c(C(=O)c2ccccc2)oc2cccc(Br)c12] | 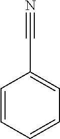 | 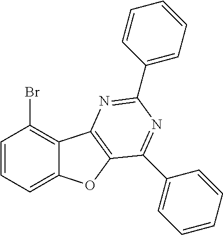 [SMILES: Brc1cccc2oc3c(-c4ccccc4)nc(-c4ccccc4)nc3c12] | 83% |
| 3d | 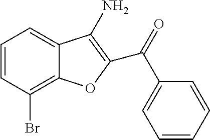 [SMILES: Nc1c(C(=O)c2ccccc2)oc2c(Br)cccc12] | 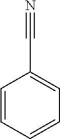 | 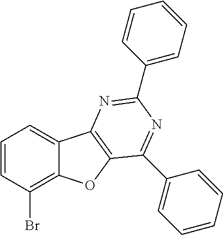 [SMILES: Brc1cccc2c1oc1c(-c3ccccc3)nc(-c3ccccc3)nc12] | 82% |

1.-15. (canceled)

16. An organic electroluminescent device comprising an anode, a cathode and at least one organic layer containing at least one light-emitting layer, wherein the at least one light-emitting layer contains at least one compound of the formula (1) as host material 1 and at least one compound of the formula (2) as host material 2, 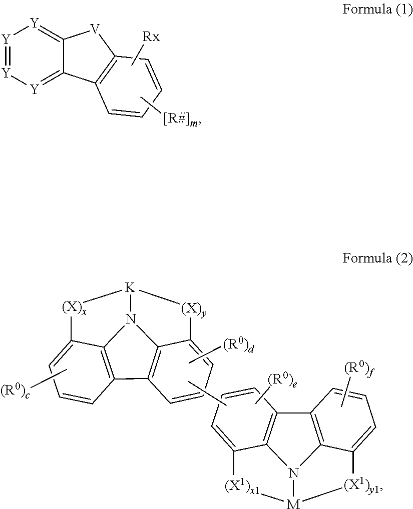
where the symbols and indices used are as follows:
Y is independently at each occurrence N, [L]ₙ-Ar₂ or [L]-R*, wherein precisely two Y are N and are separated by at least one group [L]-R* or L]ₙ-Ar₂;
V is O or S;
Rx is [L]ₙ-Ar₂ or [L]-R*;
R* is a triphenylenyl group which may be substituted with precisely one substituent R^{#}and/or may be substituted with one or more radicals R;
with the proviso that the substituent [L]-R* occurs precisely once in compounds of the formula (1);
n is 0 or 1;
m is 0 or 1;
L is independently at each occurrence identical or different and represents an arylene group having 6 to 20 carbon atoms, a divalent dibenzofuran group or a divalent dibenzothiophene group, each of which may be substituted with one or more radicals R;
Ar₂ is identical or different at each occurrence and represents an aromatic ring system which has 6 to 30 ring atoms and may be substituted by one or more radicals R;
R is identical or different at each occurrence and selected from D, F, CN, a straight-chain alkyl group having 1 to 20 carbon atoms or a branched or cyclic alkyl group having 3 to 20 carbon atoms, wherein one or more nonadjacent CH₂ groups may be replaced by R²C═CR², O or S and wherein one or more hydrogen atoms may be replaced by D, F, or CN;
R #is an aryl group having 6 to 20 carbon atoms which may be substituted with one or more radicals R;
R² is identical or different at each occurrence and selected from the group consisting of H, D, F, CN, a straight-chain alkyl group having 1 to 20 carbon atoms or a branched or cyclic alkyl group having 3 to 20 carbon atoms, wherein one or more nonadjacent CH₂ groups may be replaced by O or S and wherein one or more hydrogen atoms may be replaced by D, F, or CN;
K, M are each independently an unsubstituted or partially or completely deuterated or R*-monosubstituted aromatic ring system having 6 to 40 ring atoms when x and y are 0 and when x₁ and y₁ are 0, or
K, M each independently together with X or X¹ form a heteroaromatic ring system having 14 to 40 ring atoms, as soon as the value of x, x1, y and/or y1 is 1;
x, x1 are each independently at each occurrence 0 or 1;
y, y1 are each independently at each occurrence 0 or 1;
X and X¹ are each independently at each occurrence a bond or C(R⁺)₂;
R⁰ is independently at each occurrence an unsubstituted or partially or completely deuterated aromatic ring system having 6 to 18 ring atoms;
R⁺ is independently at each occurrence a straight-chain or branched alkyl group having 1 to 4 carbon atoms and
c, d, e and f are independently 0 or 1.

17. The organic electroluminescent device according to claim 16, characterized in that the host material 1 conforms to one of the formulae (1a), (1b) or (1c), 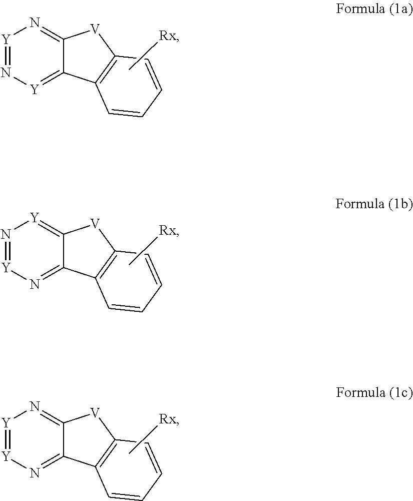
where the symbols Y, V and Rx used are as defined in claim 16.

18. The organic electroluminescent device according to claim 16, characterized in that the host material 2 conforms to one of the formulae (2a), (2b) or (2c), 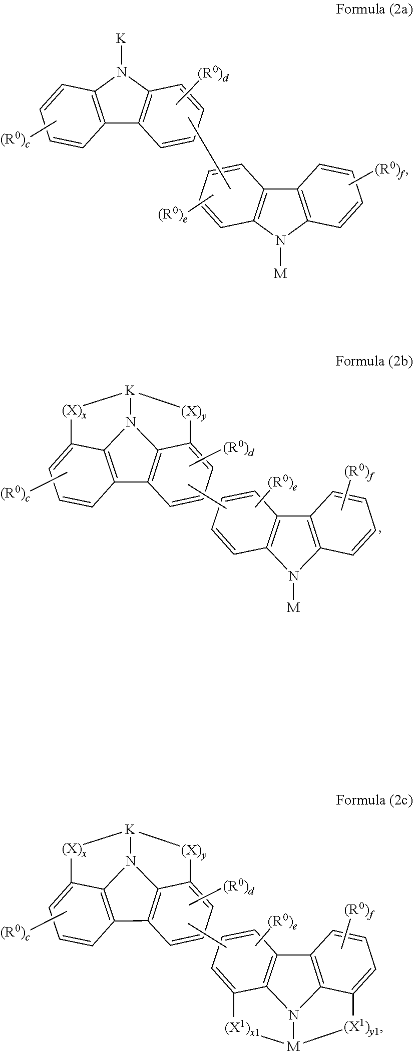
where the symbols and indices X, X¹, R⁰, c, d, e and f used are as defined in claim 16 and
K and M in compounds of the formula (2a) are each independently an unsubstituted or partially or completely deuterated or R*-monosubstituted aromatic ring system having 6 to 40 ring atoms;
M in compounds of the formula (2b) is an unsubstituted or partially or completely deuterated or R*-monosubstituted aromatic ring system having 6 to 40 ring atoms;
K in compounds of the formula (2b) together with X forms a heteroaromatic ring system having 14 to 40 ring atoms and x and y in compounds of the formula (2b) each independently represent 0 or 1 and the sum of x and y is at least 1; and
K and M in compounds of the formula (2c) each independently together with X or X¹ form a heteroaromatic ring system having 14 to 40 ring atoms; and
x, x1, y and y1 in compounds of the formula (2c) each independently represent 0 or 1 and the sum of x and y is at least 1 and the sum of x1 and y1 is at least 1.

19. The organic electroluminescent device according to claim 16, characterized in that in the host material 1 L is independently at each occurrence selected from the groups L-1 to L-23 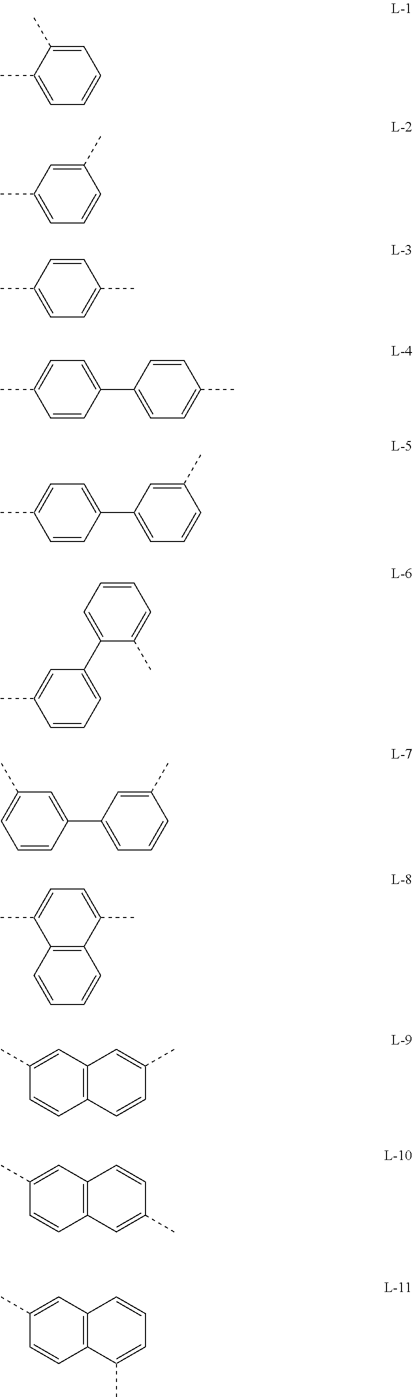 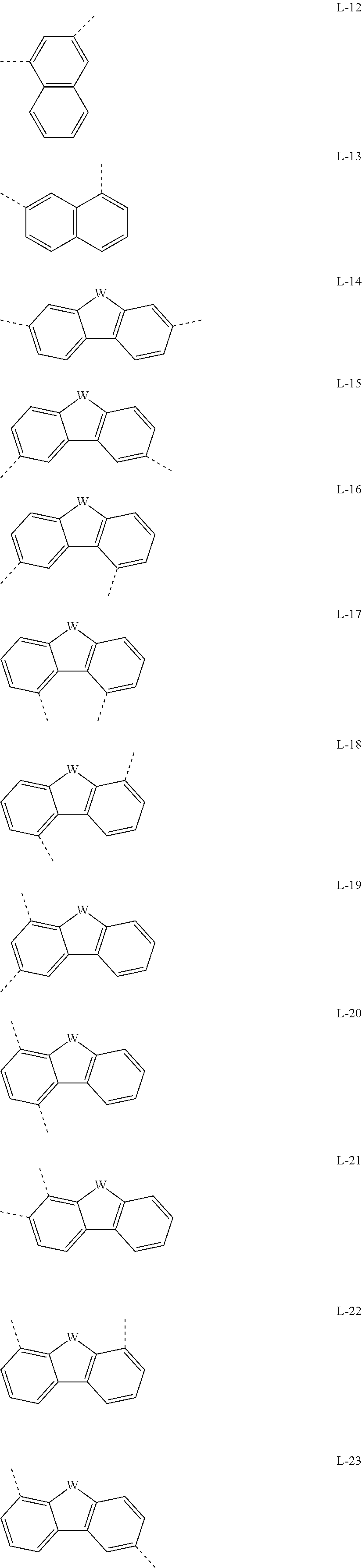
and wherein W is O or S.

20. The organic electroluminescent device according to claim 16, characterized in that the organic electroluminescent device is selected from organic light-emitting transistors (OLETs), organic field quench devices (OFQDs), organic light-emitting electrochemical cells (OLECs, LECs, LEECs), organic laser diodes (O-lasers) and organic light-emitting diodes (OLEDs).

21. The organic electroluminescent device according to claim 16, characterized in that this organic layer comprises, in addition to the light-emitting layer (EML), a hole injection layer (HIL), a hole transport layer (HTL), an electron transport layer (ETL), an electron injection layer (EIL) and/or a hole blocker layer (HBL).

22. The organic electroluminescent device according to claim 16, characterized in that the light-emitting layer, as well as the at least one host material 1 and the at least one host material 2, contains at least one phosphorescent emitter.

23. The organic electroluminescent device according to claim 16, characterized in that the organic layer comprises a hole injection layer (HIL) and/or a hole transport layer (HTL), the hole-injecting material and hole-transporting material of which is a monoamine that does not contain a carbazole unit.

24. A process for producing the device according to claim 16, characterized in that the organic layer is applied by gas phase deposition or from solution.

25. The process according to claim 23, characterized in that to produce the light-emitting layer the at least one compound of the formula (1) and the at least one compound of the formula (2) are deposited from the gas phase successively or simultaneously from at least two material sources, optionally with the at least one phosphorescent emitter.

26. The process according to claim 23, characterized in that to produce the light-emitting layer the at least one compound of the formula (1) and the at least one compound of the formula (2) are deposited from the gas phase as a mixture, successively or simultaneously with the at least one phosphorescent emitter.

27. The process according to claim 23, characterized in that to produce the light-emitting layer the at least one compound of the formula (1) and the at least one compound of the formula (2) are applied from a solution together with the at least one phosphorescent emitter.

28. A mixture comprising at least one compound of the formula (1) and at least one compound of the formula (2), 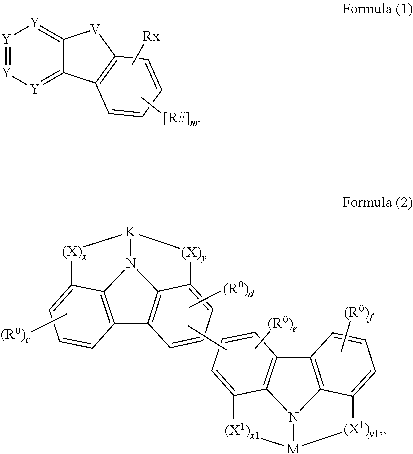
where the symbols and indices used are as follows:
Y is independently at each occurrence N, [L]ₙ-Ar₂ or [L]-R*, wherein precisely two Y are N and are separated by at least one group [L]-R* or [L]ₙ-Ar₂;
V is O or S;
Rx is [L]ₙ-Ar₂ or [L]-R*;
R* is a triphenylenyl group which may be substituted with precisely one substituent R^{#}and/or may be substituted with one or more radicals R;
with the proviso that the substituent [L]-R* occurs precisely once in compounds of the formula (1);
n is 0 or 1;
m is 0 or 1;
L is independently at each occurrence identical or different and represents an arylene group having 6 to 20 carbon atoms, a divalent dibenzofuran group or a divalent dibenzothiophene group, each of which may be substituted with one or more radicals R;
Ar₂ is identical or different at each occurrence and represents an aromatic ring system which has 6 to 30 ring atoms and may be substituted by one or more radicals R;
R is identical or different at each occurrence and selected from D, F, CN, a straight-chain alkyl group having 1 to 20 carbon atoms or a branched or cyclic alkyl group having 3 to 20 carbon atoms, wherein one or more nonadjacent CH₂ groups may be replaced by R²C═CR², O or S and wherein one or more hydrogen atoms may be replaced by D, F, or CN;
R #is an aryl group having 6 to 20 carbon atoms which may be substituted with one or more radicals R;
R² is identical or different at each occurrence and selected from the group consisting of H, D, F, CN, a straight-chain alkyl group having 1 to 20 carbon atoms or a branched or cyclic alkyl group having 3 to 20 carbon atoms, wherein one or more nonadjacent CH₂ groups may be replaced by O or S and wherein one or more hydrogen atoms may be replaced by D, F, or CN;
K, M are each independently an unsubstituted or partially or completely deuterated aromatic or R*-monosubstituted ring system having 6 to 40 ring atoms when x and y are 0 and when x₁ and y₁ are 0, or
K, M each independently together with X or X¹ form a heteroaromatic ring system having 14 to 40 ring atoms, as soon as the value of x, x1, y and/or y1 is 1;
x, x1 are each independently at each occurrence 0 or 1;
y, y1 are each independently at each occurrence 0 or 1;
X and X¹ are each independently at each occurrence a bond or C(R³⁰)₂;
R⁰ is independently at each occurrence an unsubstituted or partially or completely deuterated aromatic ring system having 6 to 18 ring atoms;
R⁺ is independently at each occurrence a straight-chain or branched alkyl group having 1 to 4 carbon atoms; and
c, d, e and f are independently 0 or 1.

29. The mixture according to claim 28, characterized in that the mixture consists of at least one compound of the formula (1), at least one compound of the formula (2) and a phosphorescent emitter.

30. A formulation comprising a mixture according to claim 28 and at least one solvent.
